(19) United States
(12) Patent Application Publication
(10) Pub. No.: US 2025/0311535 A1
(43) Pub. Date: Oct. 2, 2025

(54) ORGANIC ELECTROLUMINESCENT MATERIALS AND DEVICES

(71) Applicant: Universal Display Corporation, Ewing, NJ (US)

(72) Inventors: Marcus COLE, Burlington, NJ (US); Alexey Borisovich DYATKIN, Ambler, PA (US); Elena SHEINA, Yardley, PA (US); Tyler FLEETHAM, Yardley, PA (US); Sotirios TOTOKOTSOPOULOS, Wilmington, DE (US); Diana LAMP, Media, PA (US)

(73) Assignee: Universal Display Corporation, Ewing, NJ (US)

(21) Appl. No.: 19/090,535

(22) Filed: Mar. 26, 2025

Related U.S. Application Data
(60) Provisional application No. 63/572,727, filed on Apr. 1, 2024.

(51) Int. Cl. H10K 50/12; H10K 85/30; H10K 85/40; H10K 85/60; H10K 101/25

(52) U.S. Cl. CPC H10K 50/121; H10K 85/342; H10K 85/40; H10K 85/615; H10K 85/654; H10K 85/656; H10K 85/6572; H10K 85/6574; H10K 85/658; H10K 2101/25

(57) ABSTRACT

A compound having a first ligand L_{A} including a structure of Formula I,

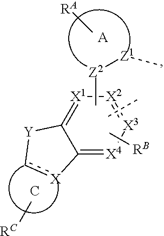

where at least one R^{B} or R^{C} is a substituent comprising a structure of Formula II,

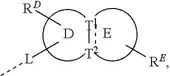

or Formula III,

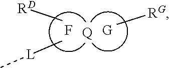

is provided. Each of moieties A and C to G is a ring or a polycyclic fused ring system; Q is B, C, Si, or Ge; each of T¹ and T² is C, N, or B; the rings of moiety D and moiety E that contain T¹ and T² are both aromatic rings; each of X, X¹ to X⁴, Z¹, and Z² is C or N; Y is a linking group; L is a direct bond or a ring or ring system; and each R^{A} to R^{G} is hydrogen or a General Substituent defined herein. Formulations, OLEDs, and consumer products containing the same are also provided.

### CROSS-REFERENCES TO RELATED APPLICATIONS

This application claims priority under 35 U.S.C. § 119(e) to U.S. Provisional Application No. 63/572,727, filed on Apr. 1, 2024, the entire contents of which are incorporated herein by reference.

### FIELD

The present disclosure generally relates to organic or metal coordination compounds and formulations and their various uses including as emitters, sensitizers, charge transporters, or exciton transporters in devices such as organic light emitting diodes and related electronic devices and consumer products.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound having a first ligand L_{A} comprising a structure of Formula I,

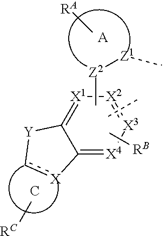

In Formula I: at least one R^{B} or R^{C} is a substituent comprising a structure of Formula II,

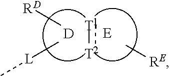

### or Formula III,

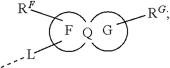

each of moiety A, moiety C, moiety D, moiety E, moiety F, and moiety G is independently a monocyclic ring or a polycyclic fused ring system, wherein the monocyclic ring or each ring of the polycyclic fused ring system is independently a 5-membered to 10-membered carbocyclic or heterocyclic ring.
Q is selected from the group consisting of B, C, Si, and Ge;
each of X, X¹ to X⁴, Z¹, and Z² is independently C or N;
each of T¹ and T² is independently C, N, or B;
the rings of moiety D and moiety E that contain T¹ and T² are both aromatic rings;
each [symbol] represents a single bond or a double bond;
Y is selected from the group consisting of BR, BRR′, NR, PR, P(O)R, O, S, Se, C═O, C═S, C═Se, C═NR′, C═CRR′, S═O, SO₂, CRR′, SiRR′, and GeRR′;
L is a direct bond or a substituted or unsubstituted monocyclic or polycyclic ring system;
each of R^{A}, R^{B}, R^{C}, R^{D}, R^{E}, R^{F}, and R^{G} independently represents mono to the maximum allowable substitution, or no substitution;
each R, R′, R^{A}, R^{B}, R^{C}, R^{D}, R^{E}, R^{F}, and R^{G} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M, having an atomic mass of at least 40;
metal M can be coordinated to other ligands;
L_{A} can be joined with other ligands to comprise a bidentate, tridentate, tetradentate, pentadentate, or hexadentate ligand; and any two substituents can be joined or fused to form a ring.

In another aspect, the present disclosure provides a formulation comprising a compound having a first ligand L_{A} comprising a structure of Formula I described herein.

In yet another aspect, the present disclosure provides an OLED having an organic layer comprising a compound having a first ligand L_{A} comprising a structure of Formula I described herein.

In yet another aspect, the present disclosure provides a consumer product comprising an OLED with an organic layer comprising a compound having a first ligand L_{A} comprising a structure of Formula I described herein.

### BRIEF DESCRIPTION OF THE DRAWINGS

FIG. 1 shows an organic light emitting device.

FIG. 2 shows an inverted organic light emitting device that does not have a separate electron transport layer.

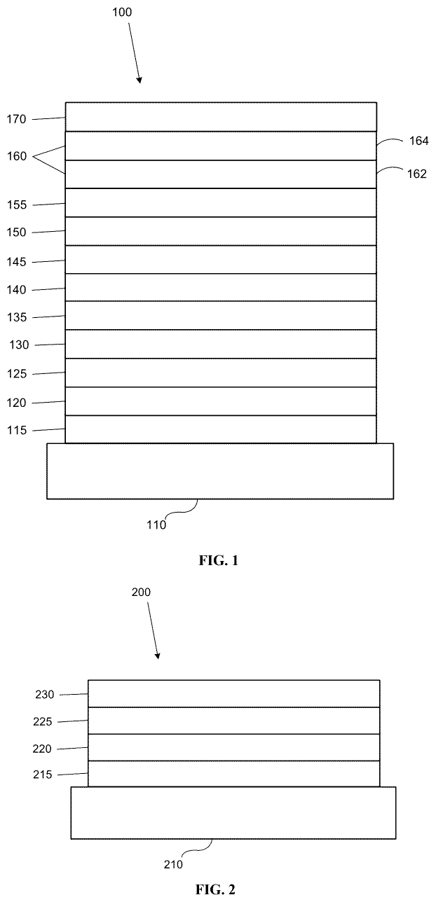

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.3731, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SRₛ group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure.

Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and the preferred alkyl groups include methyl, ethyl, n-propyl, iso-propyl, n-butyl, sec-butyl, iso-butyl, tert-butyl, n-pentyl, 2-methylbutyl, 3-methylbutyl, 2,2-dimethylpropyl, 1,3-dimethylpropyl, 1,1-dimethylpropyl, 2-ethylpropyl, 1,2-dimethylpropyl, n-hexyl, 2-methylpentyl, 3-methylpentyl, 2,2-dimethylbutyl, 2,3-dimethylbutyl, n-heptyl, 2-methylhexyl, 3-methylhexyl, 2,2-dimethylpentyl, 2,3-dimethylpentyl, 2,4-dimethylpentyl, 3,3-dimethylpentyl, 3-ethylpentyl, 2,2,3-trimethylbutyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group canbe further substituted orfused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5λ²,9λ²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[fh]quinoxaline and dibenzo[fh]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of

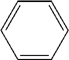

implies to include C₆H₆, C₆D₆, CH₃D₃, and any other partially deuterated variants thereof. Some common basic partially or fully deuterated group include, without limitation, CD₃, CD₂C(CH₃)₃, C(CD₃)₃, and CD₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

In one aspect, the present disclosure provides a compound having a first ligand L_{A} comprising a structure of Formula

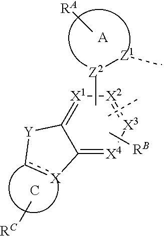

### In Formula I:

at least one R^{B} or R^{C} is a substituent comprising a structure of Formula II,

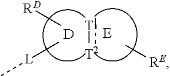

### or Formula III,

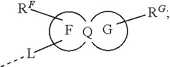

each of moiety A, moiety C, moiety D, moiety E, moiety F, and moiety G is independently a monocyclic ring or a polycyclic fused ring system, wherein the monocyclic ring or each ring of the polycyclic fused ring system is independently a 5-membered to 10-membered carbocyclic or heterocyclic ring.
Q is selected from the group consisting of B, C, Si, and Ge;
each of X, X¹ to X⁴, Z¹, and Z² is independently C or N;
each of T¹ and T² is independently C, N, or B;
the rings of moiety D and moiety E that contain T¹ and T² are both aromatic rings;
each [symbol] represents a single bond or a double bond;
Y is selected from the group consisting of BR, BRR′, NR, PR, P(O)R, O, S, Se, C═O, C═S, C═Se, C═NR′, C═CRR′, S═O, SO₂, CRR′, SiRR′, and GeRR′; L is a direct bond or a substituted or unsubstituted monocyclic or polycyclic ring system;
each of R^{A}, R^{B}, R^{C}, R^{D}, R^{E}, R^{F}, and R^{G} independently represents mono to the maximum allowable substitution, or no substitution;
each R, R′, R^{A}, R^{B}, R^{C}, R^{D}, R^{E}, R^{F}, and R^{G} is independently hydrogen, or a substituent selected from the group consisting of the General Substituents defined herein;
L_{A} is coordinated to a metal M, having an atomic mass of at least 40;
metal M can be coordinated to other ligands;
L_{A} can be joined with other ligands to comprise a bidentate, tridentate, tetradentate, pentadentate, or hexadentate ligand; and
any two substituents can be joined or fused to form a ring.

In some embodiments, if moiety C is a 6-membered monocyclic ring, then (a) at least one of R^{D} and R^{E} comprises a cyclic or heterocyclic group; and (b) if Formula II is present and the combination of moieties D and E is a substituted 9-phenanthrene or a substituted 9-carbazole, then at least one of R^{D} and R^{E} is not phenyl.

In some embodiments, if moiety C comprises at least three fused 6-membered rings and Formula III is present, then formula III is not

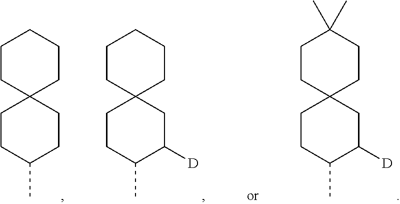

In some embodiments, the first ligand L_{A} consists essentially of a structure of Formula I. In some embodiments, the first ligand L_{A} has a structure of Formula I.

In some embodiments, at least one R^{A}, R^{B}, R^{C}, R^{D}, R^{E}, R^{F}, or R^{G} is a substituent selected from the group consisting of the General Substituents defined herein. In some embodiments, at least one R^{A} is a substituent selected from the group consisting of the General Substituents defined herein. In some embodiments, at least one R^{B} is a substituent selected from the group consisting of the General Substituents defined herein. In some embodiments, at least one R^{C} is a substituent selected from the group consisting of the General Substituents defined herein. In some embodiments, at least one R^{D} is a substituent selected from the group consisting of the General Substituents defined herein. In some embodiments, at least one R^{E} is a substituent selected from the group consisting of the General Substituents defined herein. In some embodiments, at least one R^{F} is a substituent selected from the group consisting of the General Substituents defined herein. In some embodiments, at least one R^{G} is a substituent selected from the group consisting of the General Substituents defined herein. In some embodiments, at least one R^{A}, R^{B}, R^{C}, R^{D}, R^{E}, R^{F}, or R^{G} is a substituent selected from the group consisting of the Preferred General Substituents defined herein.

In some embodiments of Formula I, at least one R, R′, R^{A}, R^{B}, R^{C}, R^{D}, R^{E}, R^{F}, or R^{G} is partially or fully deuterated. In some embodiments, at least one R^{A} is partially or fully deuterated. In some embodiments, at least one R^{B} is partially or fully deuterated. In some embodiments, at least one R^{C} is partially or fully deuterated. In some embodiments, at least one R^{D} is partially or fully deuterated. In some embodiments, at least one R^{E} is partially or fully deuterated. In some embodiments, at least one R or R′ is partially or fully deuterated.

In some embodiments, each of moiety A, moiety C, moiety D, moiety E, moiety F, and moiety G is independently a monocyclic ring or a polycyclic fused ring system, wherein the monocyclic ring or each ring of the polycyclic fused ring system is independently a 5-membered or 6-membered carbocyclic or heterocyclic ring. In some embodiments, each of moiety A, moiety C, moiety D, and moiety E is independently a monocyclic ring or a polycyclic fused ring system, wherein the monocyclic ring or each ring of the polycyclic fused ring system is independently a 5-membered or 6-membered aryl or heteroaryl ring.

In some embodiments, each R, R′, R^{A}, R^{B}, R^{C}, R^{D}, R^{E}, R^{F}, and R^{G} is independently hydrogen, or a substituent selected from the group consisting of the Preferred General Substituents defined herein. In some embodiments, each R, R′, R^{A}, R^{B}, R^{C}, R^{D}, R^{E}, R^{F}, and R^{G} is independently hydrogen, or a substituent selected from the group consisting of the More Preferred General Substituents defined herein. In some embodiments, each R, R′, R^{A}, R^{B}, R^{C}, R^{D}, R^{E}, R^{F}, and R^{G} is independently hydrogen, or a substituent selected from the group consisting of the Even More Preferred General Substituents defined herein.

In some embodiments, each R, R′, R^{A}, R^{B}, R^{C}, R^{D}, R^{E}, R^{F}, and R^{G} is independently hydrogen, or a substituent selected from the group consisting of the Most Preferred General Substituents defined herein.

In some embodiments, metal M is selected from the group consisting of Ir, Rh, Re, Ru, Os, Pt, Pd, Ag, Au, and Cu. In some embodiments, metal M is Ir. In some embodiments, metal M is Pt or Pd. In some embodiments, metal M is Pt. In some embodiments, metal M is Pd.

In some embodiments, each of moiety A and moiety C is independently selected from the group consisting of the following Cyclic Moiety Group: benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, the aza variant includes one N on a benzo ring. In some embodiments, the aza variant includes one N on a benzo ring and the N is bonded to the metal M]

In some embodiments, moiety A is a monocyclic ring. In some embodiments, moiety A is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety A is pyridine.

In some embodiments, moiety A is a polycyclic fused ring system. In some embodiments, moiety A is selected from the group consisting of naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, aza-benzimidazole-derived carbene, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety A is benzimidazole.

In some embodiments, wherein moiety C is a monocyclic ring. In some embodiments, moiety C is selected from the group consisting of benzene, pyridine, pyrimidine, pyridazine, pyrazine, triazine, imidazole, pyrazole, pyrrole, oxazole, furan, thiophene, thiazole, and triazole. In some embodiments, moiety C is benzene or pyridine. In some embodiments, moiety C is pyridine where the N is ortho to Y.

In some embodiments, moiety C is a polycyclic fused ring system. In some embodiments, moiety C is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety C is naphthalene or phenanthrene.

In some embodiments, at least one of moiety A, moiety C, moiety D, moiety E, moiety F, or moiety G can independently be a polycyclic fused ring structure. In some embodiments, at least one of moiety A, moiety C, moiety D, moiety E, moiety F, or moiety G can independently be a polycyclic fused ring structure comprising at least two fused rings. In some embodiments, the polycyclic fused ring structure has one 6-membered ring and one 5-membered ring. In some such embodiments, either the 5-membered ring or the 6-membered ring can coordinate to the metal. In some embodiments, the polycyclic fused ring structure has two 6-membered rings. In some embodiments, at least one of moiety A, moiety C, moiety D, moiety E, moiety F, or moiety G can independently be selected from the group consisting of benzofuran, benzothiophene, benzoselenophene, naphthalene, and aza-variants thereof.

In some embodiments, at least one of moiety A, moiety C, moiety D, moiety E, moiety F, or moiety G can independently be a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, at least one of moiety A, moiety C, moiety D, moiety E, moiety F, or moiety G can independently be selected from the group consisting of dibenzofuran, dibenzothiophene, dibenzoselenophene, and aza-variants thereof. In some such embodiments, at least one of moiety A, moiety C, moiety D, moiety E, moiety F, or moiety G can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, at least one of moiety A, moiety C, moiety D, moiety E, moiety F, or moiety G can independently be a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, at least one of moiety A, moiety C, moiety D, moiety E, moiety F, or moiety G can independently be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, at least one of moiety A, moiety C, moiety D, moiety E, moiety F, or moiety G can independently be an aza version of the polycyclic fused rings described above. In some such embodiments, at least one of moiety A, moiety C, moiety D, moiety E, moiety F, or moiety G can independently contain exactly one aza N atom. In some such embodiments, at least one of moiety A, moiety C, moiety D, moiety E, moiety F, or moiety G contains exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho position of the aza N atom is substituted.

In some embodiments, X is C. In some embodiments, X is N.

In some embodiments, each of X¹ to X⁴ is C. In some embodiments, at least one of X¹ to X⁴ is N. In some embodiments, exactly one of X¹ to X⁴ is N. In some embodiments, X¹ is N. In some embodiments, X² is N. In some embodiments, X³ is N. In some embodiments, X⁴ is N.

In some embodiments, the one of X¹ to X⁴ that is coordinated to metal M is N. In some such embodiments, the rest of X¹ to X⁴ are C.

In some embodiments, the one of X¹ to X⁴ that is coordinated to metal M is C.

In some embodiments, the one of X¹ to X⁴ that is bonded to Z² is N. In some embodiments, the one of X¹ to X⁴ that is bonded to Z² is C.

In some embodiments, Z¹ is N and Z² is C. In some embodiments, Z¹ is carbene carbon C and Z² is N. In some embodiments, Z¹ and Z² are both C.

In some embodiments, the [symbol] formed with X is a double bond. In some embodiments, the [symbol] formed with X is a second bond.

In some embodiments, Y is selected from the group consisting of O, S, and Se. In some embodiments, Y is O. In some embodiments, Y is S. In some embodiments, Y is Se.

In some embodiments, Y is selected from the group consisting of BR, NR, and PR. In some embodiments, Y is selected from the group consisting of BRR′, CRR′, SiRR′, and GeRR′. In some embodiments, Y is selected from the group consisting of P(O)R, C═O, C═S, C═Se, C═NR, C═CRR′, S═O, and SO₂. In some embodiments, Y is selected CRR′.

In some embodiments, the first ligand L_{A} comprises at least one electron-withdrawing group selected from the group consisting of the following LIST EWG1: F, CF₃, CN, COCH₃, CHO, COCF₃, COOMe, COOCF₃, NO₂, SF₃, SiF₃, PF₄, SFS, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl,

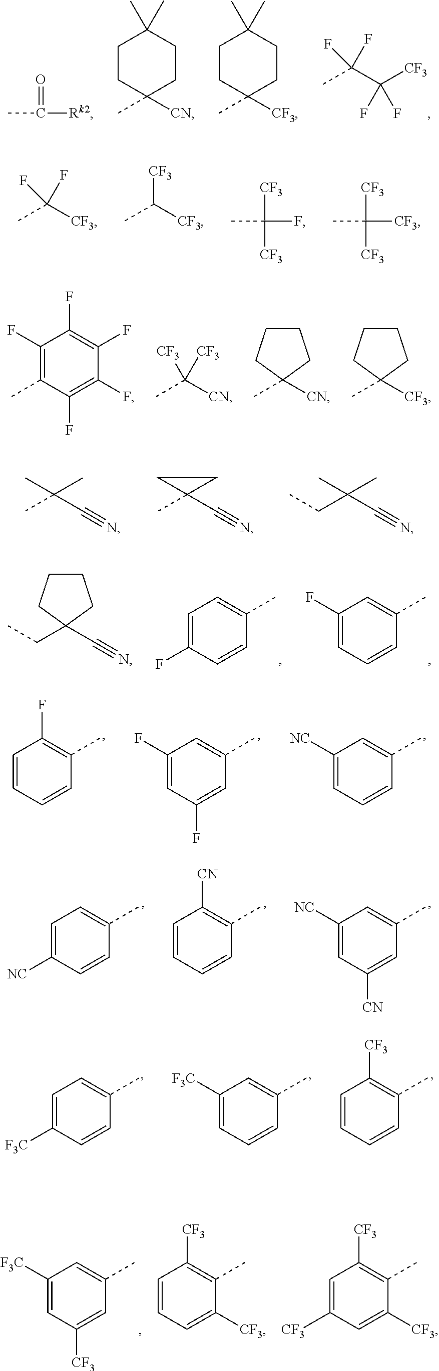

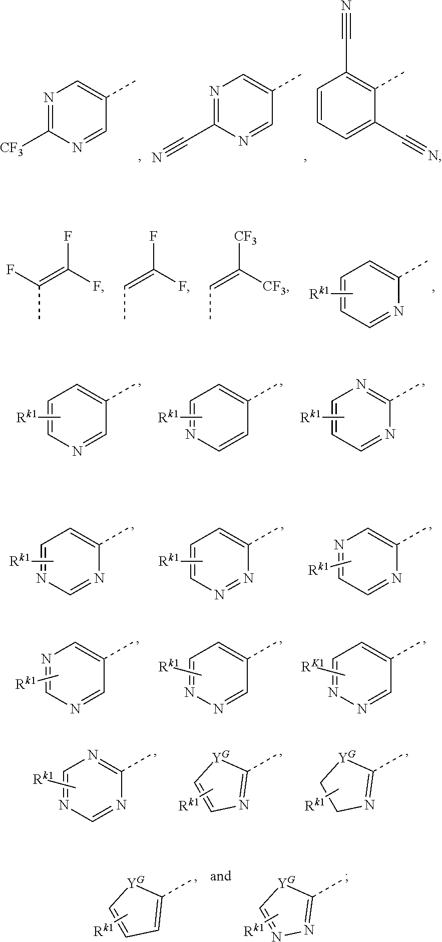

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k}, R^{k2}, R^{k3}, Rₑ, and R_{f} is independently a hydrogen, or a substituent selected from the group consisting of the General Substituents defined herein.

In some embodiments, the first ligand L_{A} comprises at least one electron-withdrawing group selected from the group consisting of the structures of the following EWG2 List:

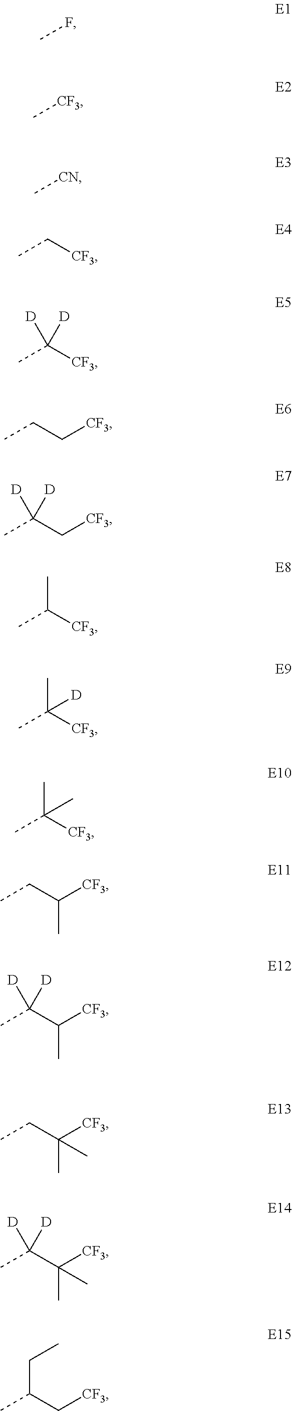

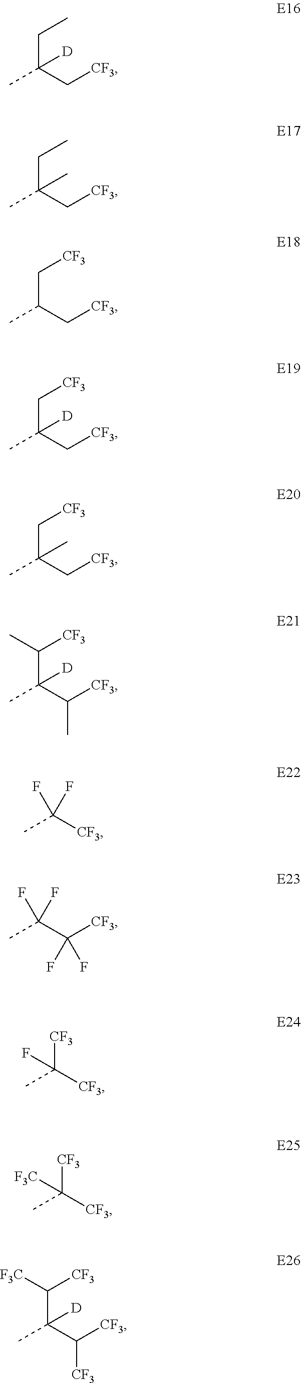

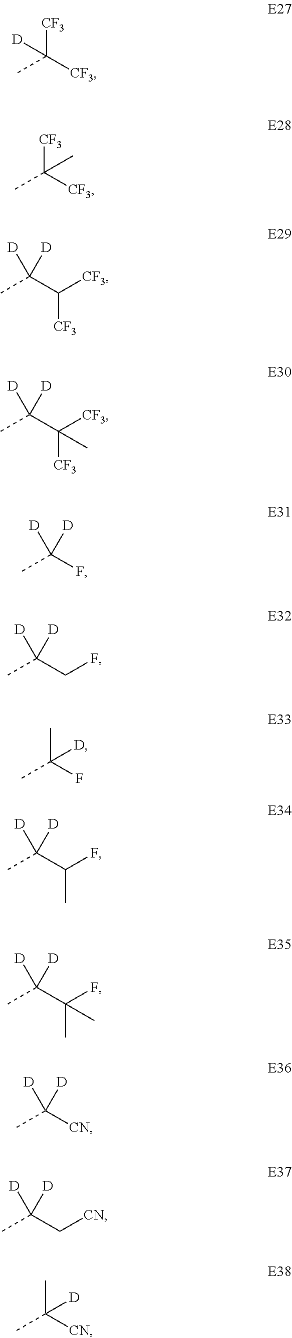

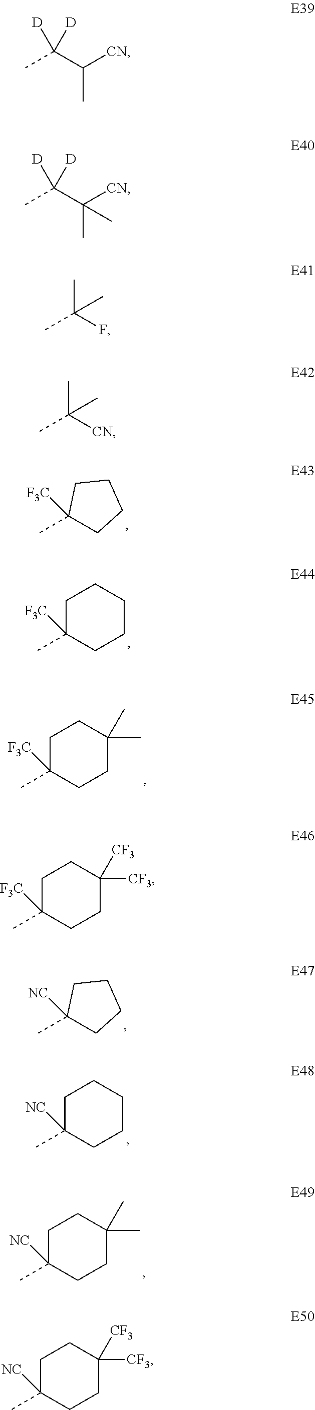

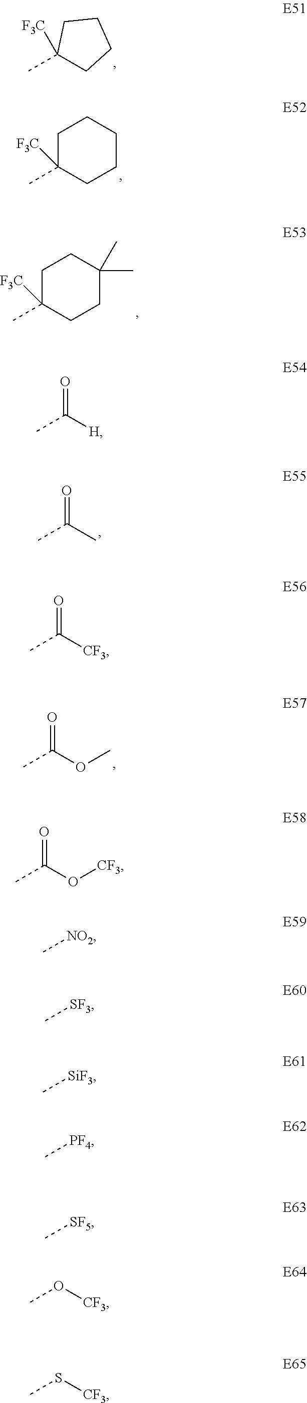

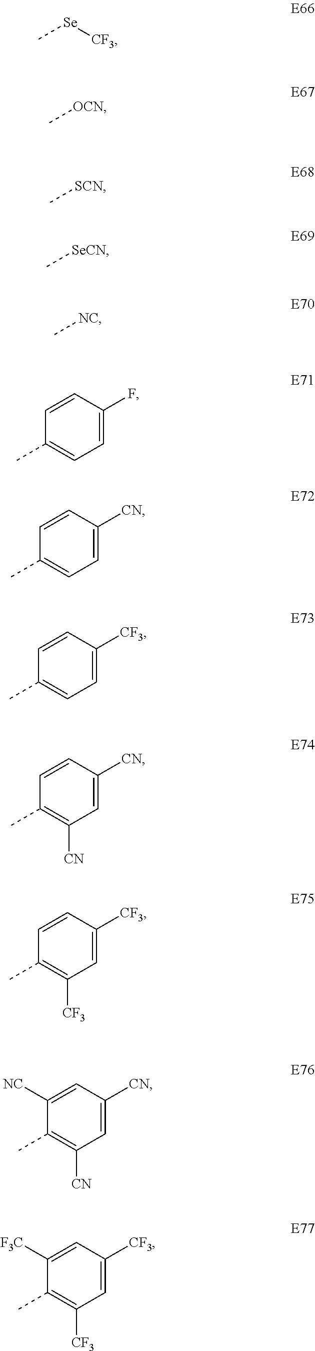

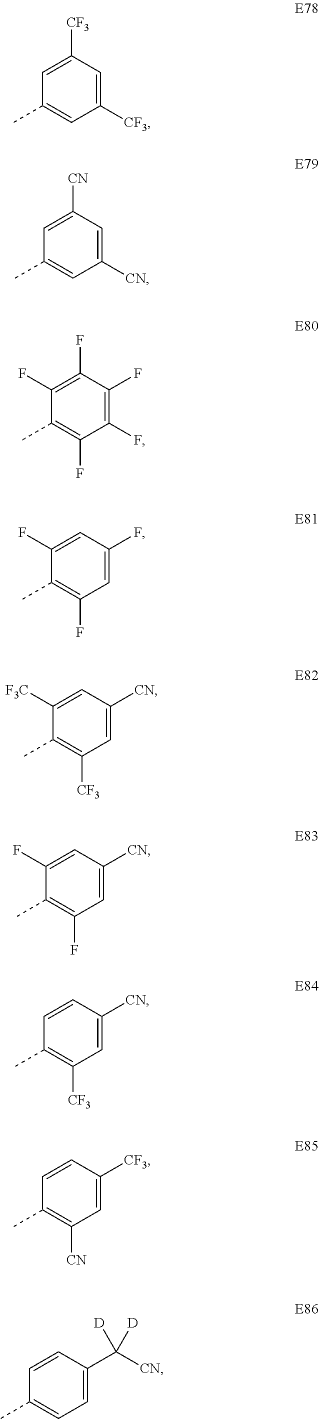

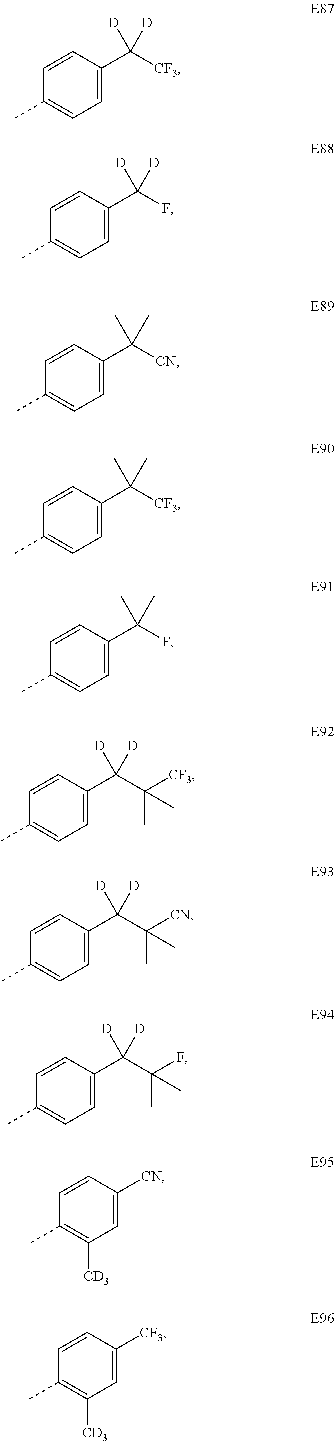

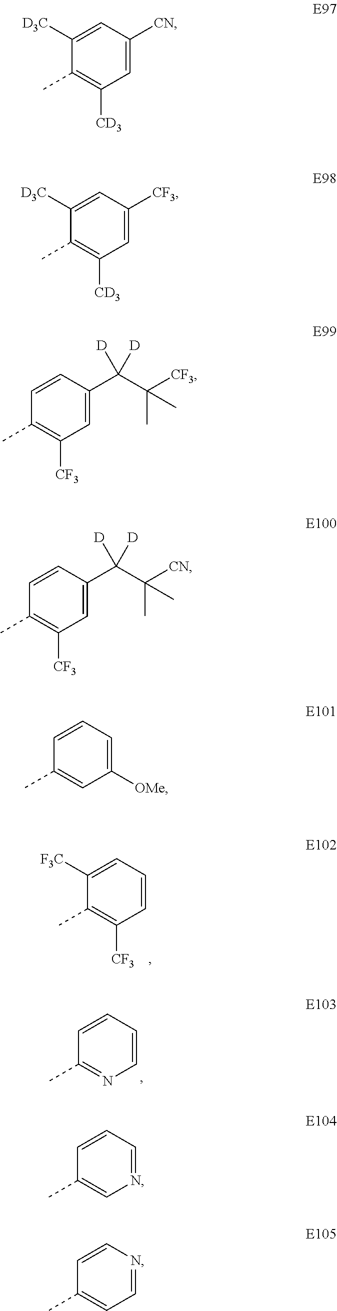

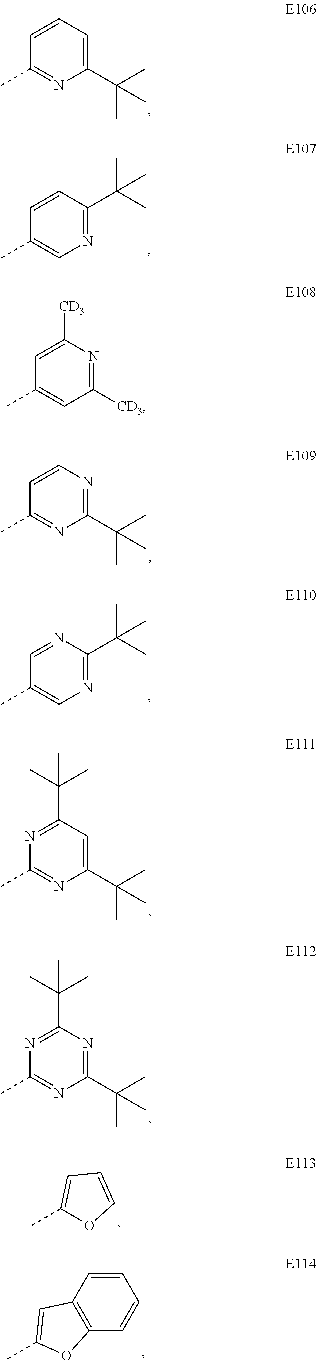

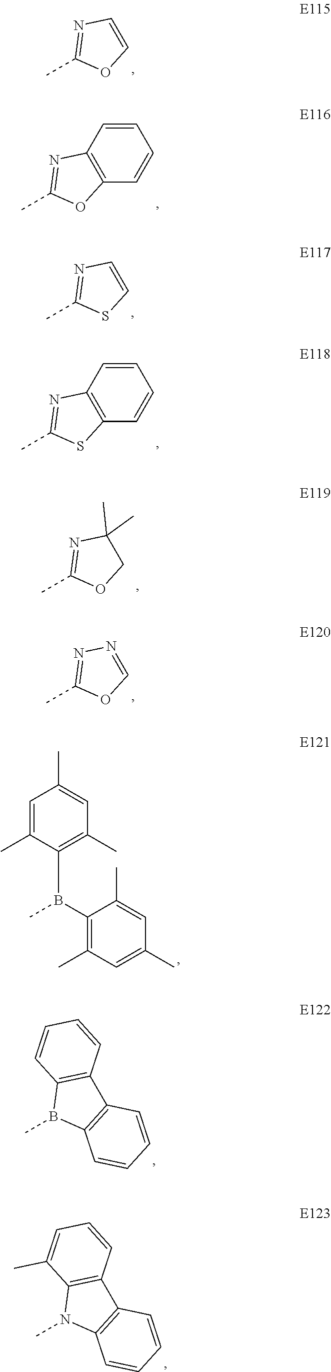

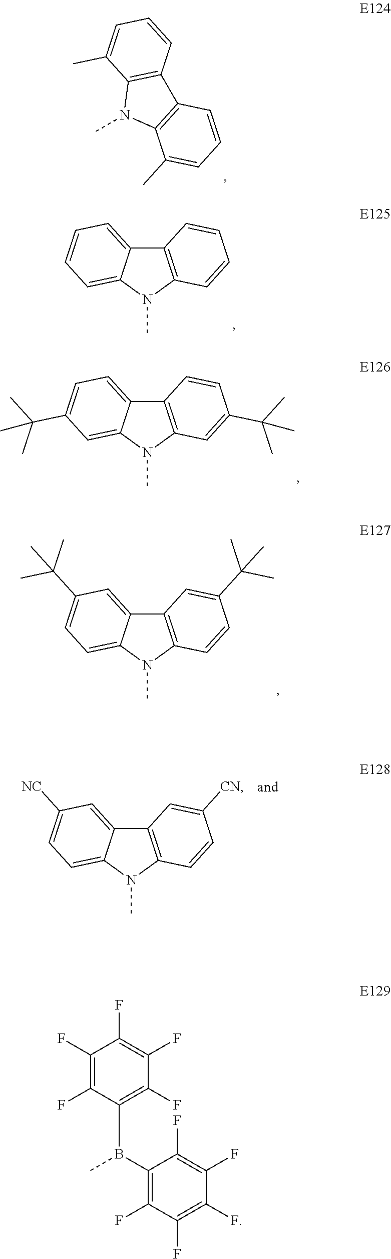

In some embodiments, the first ligand L_{A} comprises at least one electron-withdrawing group selected from the group consisting of the structures of the following EWG3 LIST:

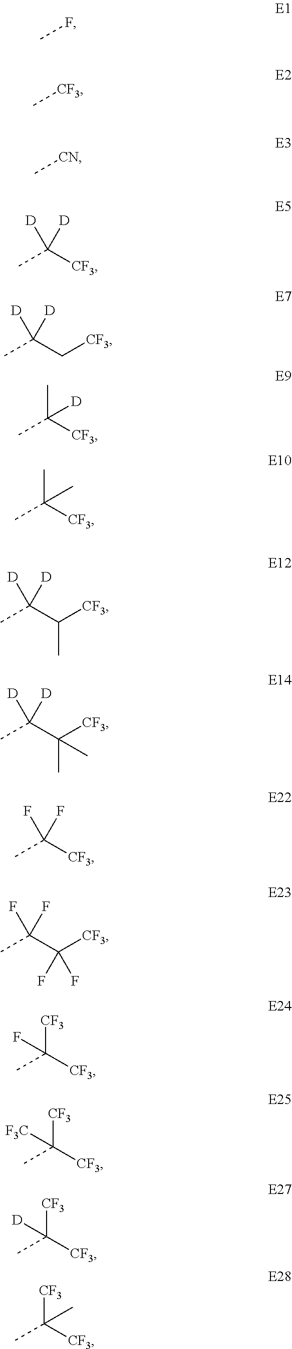

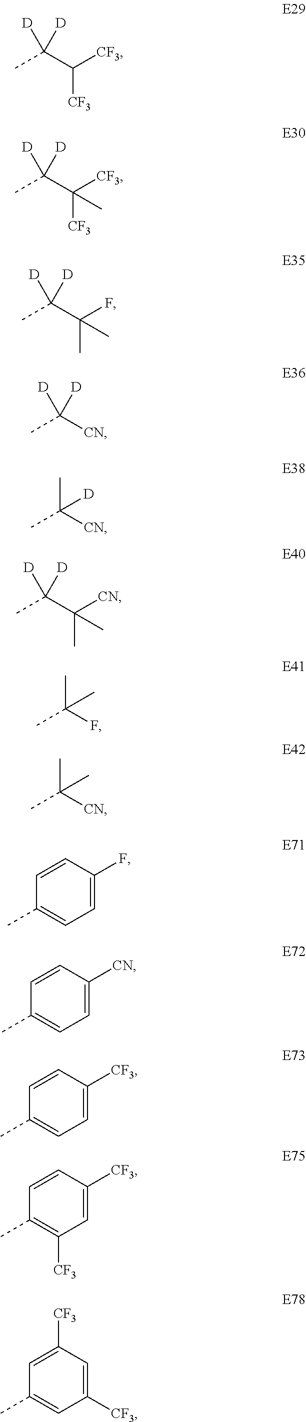

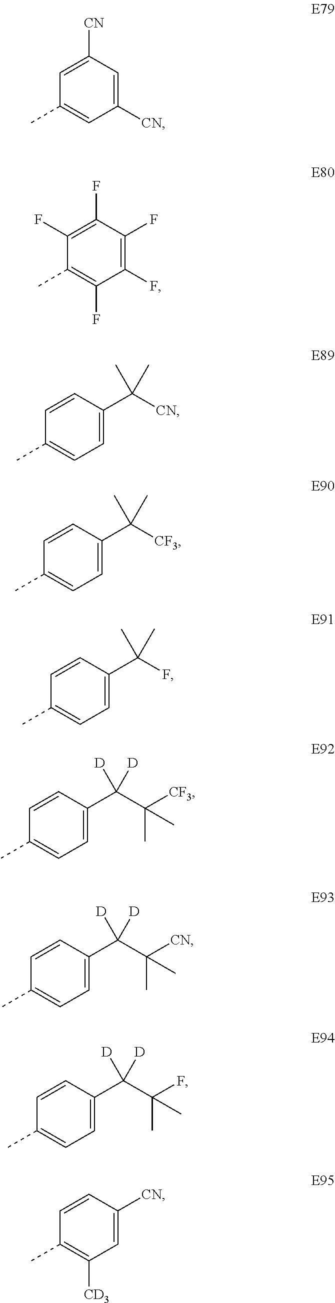

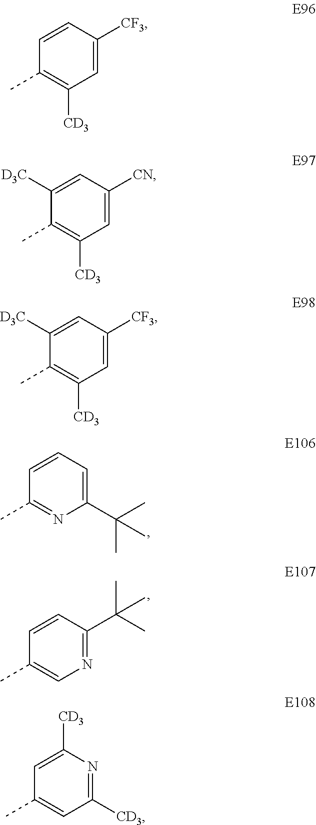

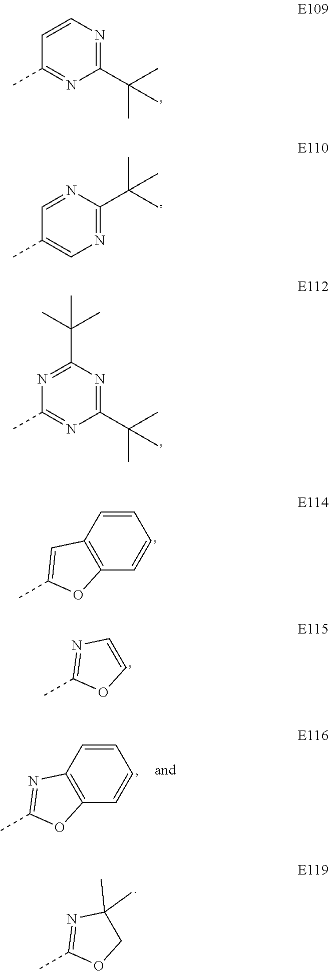

In some embodiments, the first ligand L_{A} comprises at least one electron-withdrawing group selected from the group consisting of the structures of the following EWG4 LIST:

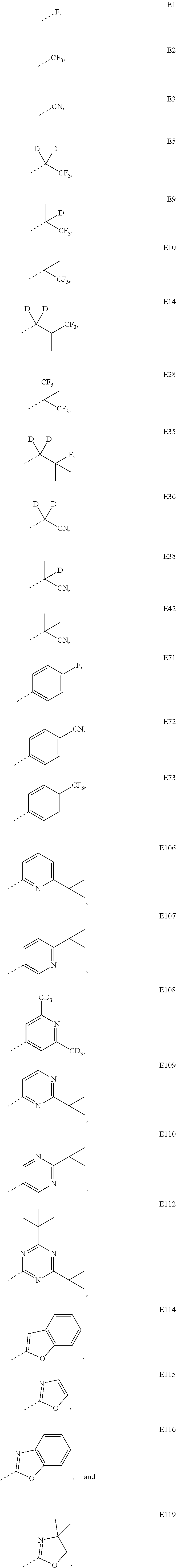

In some embodiments, the first ligand L_{A} comprises at least one π-electron deficient electron-withdrawing group selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

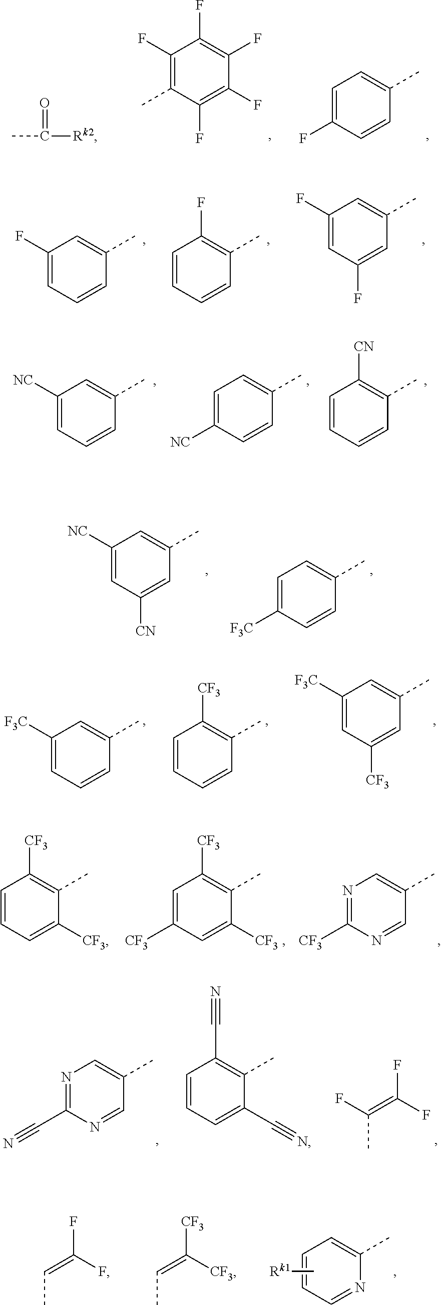

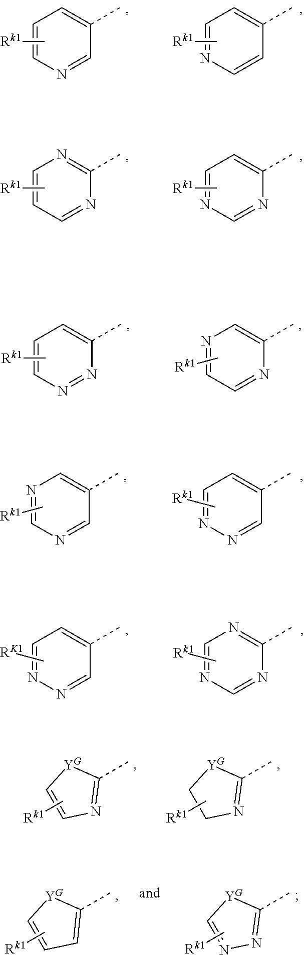

wherein the variables are the same as previously defined.

In some embodiments, the compound comprises an electron-withdrawing group from the EWG1 LIST as defined herein. In some embodiments, the compound comprises an electron-withdrawing group from the EWG2 LIST as defined herein. In some embodiments, the compound comprises an electron-withdrawing group from the EWG3 LIST as defined herein. In some embodiments, the compound comprises an electron-withdrawing group from the EWG4 LIST as defined herein. In some embodiments, the compound comprises an electron-withdrawing group from the Pi-EWG LIST as defined herein.

In some embodiments, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments, at least one R^{B} is or comprises an electron-withdrawing group from the EWG1 LIST as defined herein. In some embodiments, at least one R^{B} is or comprises an electron-withdrawing group from the EWG2 LIST as defined herein. In some embodiments, at least one R^{B} is or comprises an electron-withdrawing group from the EWG3 LIST as defined herein. In some embodiments, at least one R^{B} is or comprises an electron-withdrawing group from the EWG4 LIST as defined herein. In some embodiments, at least one R^{B} is or comprises an electron-withdrawing group from the Pi-EWG LIST as defined herein.

In some embodiments, at least one R^{C} is or comprises an electron-withdrawing group from the EWG1 LIST as defined herein. In some embodiments, at least one R^{C} is or comprises an electron-withdrawing group from the EWG2 LIST as defined herein. In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined herein.

In some embodiments, at least one R^{D} is or comprises an electron-withdrawing group from the EWG1 LIST as defined herein. In some embodiments, at least one R^{D} is or comprises an electron-withdrawing group from the EWG2 LIST as defined herein. In some embodiments, at least one R^{D} is or comprises an electron-withdrawing group from the EWG3 LIST as defined herein. In some embodiments, at least one R^{D} is or comprises an electron-withdrawing group from the EWG4 LIST as defined herein. In some embodiments, at least one R^{D} is or comprises an electron-withdrawing group from the Pi-EWG LIST as defined herein.

In some embodiments, at least one R^{E} is or comprises an electron-withdrawing group from the EWG1 LIST as defined herein. In some embodiments, at least one R^{E} is or comprises an electron-withdrawing group from the EWG2 LIST as defined herein. In some embodiments, at least one R^{E} is or comprises an electron-withdrawing group from the EWG3 LIST as defined herein. In some embodiments, at least one R^{E} is or comprises an electron-withdrawing group from the EWG4 LIST as defined herein. In some embodiments, at least one R^{E} is or comprises an electron-withdrawing group from the Pi-EWG LIST as defined herein.

In some embodiments, at least one R^{F} is or comprises an electron-withdrawing group from the EWG1 LIST as defined herein. In some embodiments, at least one R^{F} is or comprises an electron-withdrawing group from the EWG2 LIST as defined herein. In some embodiments, at least one R^{F} is or comprises an electron-withdrawing group from the EWG3 LIST as defined herein. In some embodiments, at least one R^{F} is or comprises an electron-withdrawing group from the EWG4 LIST as defined herein. In some embodiments, at least one R^{F} is or comprises an electron-withdrawing group from the Pi-EWG LIST as defined herein.

In some embodiments, at least one R^{G} is or comprises an electron-withdrawing group from the EWG1 LIST as defined herein. In some embodiments, at least one R^{G} is or comprises an electron-withdrawing group from the EWG2 LIST as defined herein. In some embodiments, at least one R^{G} is or comprises an electron-withdrawing group from the EWG3 LIST as defined herein. In some embodiments, at least one R^{G} is or comprises an electron-withdrawing group from the EWG4 LIST as defined herein. In some embodiments, at least one R^{G} is or comprises an electron-withdrawing group from the Pi-EWG LIST as defined herein.

In some embodiments, at least one R^{A} is not hydrogen. In some embodiments, each R^{A} is hydrogen.

In some embodiments, at least one R^{A} comprises at least one C atom. In some embodiments, at least one R^{A} comprises a substituent selected from the group consisting of alkyl, cycloalkyl, silyl, germyl, aryl, heteroaryl, and combinations thereof.

In some embodiments, at least one R^{A} is a substituted or unsubstituted cyclic moiety. In some embodiments, an atom adjacent to the bond with moiety A comprises at least one C atom. In some embodiments, two atoms adjacent to the bond with moiety A comprises at least one C atom. In some embodiments, the substituted or unsubstituted cyclic moiety is substituted or unsubstituted benzene.

In some embodiments where at least one R^{A} is a substituted or unsubstituted cyclic moiety, an atom adjacent to the bond with moiety A comprises a substituent selected from the group consisting of alkyl, cycloalkyl, silyl, germyl, aryl, heteroaryl, and combinations thereof. In some embodiments, two atoms adjacent to the bond with moiety Aare independently selected from the group consisting of alkyl, cycloalkyl, silyl, germyl, aryl, heteroaryl, and combinations thereof. In some embodiments, the substituted or unsubstituted cyclic moiety is substituted or unsubstituted benzene.

In some embodiments, at least one R^{B} is not hydrogen. In some embodiments, each R^{B} is hydrogen. In some embodiments, at least one R^{B} comprises at least one C atom. In some embodiments, at least one R^{B} comprises a substituent selected from the group consisting of alkyl, cycloalkyl, silyl, germyl, aryl, heteroaryl, and combinations thereof.

In some embodiments, at least one R^{C} is not hydrogen. In some embodiments, each R^{C} is hydrogen. In some embodiments, at least one R^{C} comprises at least one C atom. In some embodiments, at least one R^{C} comprises a substituent selected from the group consisting of alkyl, cycloalkyl, silyl, germyl, aryl, heteroaryl, and combinations thereof.

In some embodiments, at least one R^{B} or R^{C} is a substituent comprising a structure of Formula II,

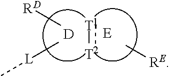

In some embodiments comprising Formula II, T¹ and T² are both C. In some embodiments comprising Formula II, T¹ is C and T² is N. In some embodiments comprising Formula II, T¹ and T² are both N or B.

In some embodiments comprising Formula II, at least one is N or B. In some embodiments comprising Formula II, at least one is N. In some embodiments comprising Formula II, at least one is B. In some embodiments comprising Formula II, one is N and the other is B.

In some embodiments comprising Formula II, the [symbol] bonding T¹ and T² together is a single bond. In some embodiments comprising Formula II, the [symbol] bonding T¹ and T² together is a double bond.

In some embodiments, at least one of moiety D and E is a polycyclic fused ring system.

In some embodiments, at least one of moiety D or moiety E comprises a 5-membered ring.

In some embodiments, at least one of moiety D or moiety E comprises at least one partially or fully saturated ring.

In some embodiments, at least one of moiety D or moiety E comprises a ring having 7 to 10 ring atoms.

In some embodiments, the combination of moiety D and moiety E is not a substituted 9-carbazole or 9-phenanthrene.

In some embodiments, the combination of moiety D and moiety E is not a substituted carbazole or phenanthrene. In some embodiments, the combination of moiety D and moiety E is not a dibenzofuran. In some embodiments, moiety D is not indole.

In some embodiments, moiety D is not naphthalene.

In some embodiments, moiety D comprises at least one fully or partially saturated ring.

In some embodiments, moiety D comprises at least one heteroatom. In some embodiments comprising Formula II, moiety D comprises at least one heteroatom other than T¹ or T². In some embodiments, at least one of T¹ or T² is a heteroatom.

In some embodiments, moiety D is a 5-membered ring.

In some embodiments, each of moiety D and moiety E is independently selected from the group consisting of the following Cyclic Moiety Group: benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, the aza variant includes one N on a benzo ring.

In some embodiments, moiety D is a monocyclic ring. In some embodiments, moiety D is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety D is benzene, oxazole, cyclohexane, or 1,2-azaborinine.

In some embodiments, moiety D is a polycyclic fused ring system. In some embodiments, moiety D is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, aza-benzimidazole-derived carbene, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety D is naphthalene or benzoxazole.

In some embodiments, moiety D comprises an aromatic ring fused to a partially saturated ring. In some embodiments, moiety D comprises an aromatic ring that comprises T¹ and T².

In some embodiments, moiety E is a monocyclic ring. In some embodiments, moiety E is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole. In some embodiments, moiety E is benzene, oxazole, cyclohexane, or 1,2-azaborinine.

In some embodiments, moiety E is a polycyclic fused ring system. In some embodiments, moiety E is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, aza-benzimidazole-derived carbene, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene. In some embodiments, moiety E is naphthalene or benzoxazole.

In some embodiments, moiety E comprises an aromatic ring fused to a partially saturated ring. In some such embodiments, moiety E comprises an aromatic ring comprising T¹ and T².

In some embodiments of Formula II, L is a direct bond.

In some embodiments of Formula II, L is a substituted or unsubstituted monocyclic or polycyclic ring system. In some embodiments of Formula II, L is substituted or unsubstituted benzene or substituted or unsubstituted biphenyl. In some embodiments of Formula II, L is selected from the group consisting of the Cyclic Moiety List defined herein, which may be substituted or unsubstituted.

In some embodiments, at least one R^{D} is not hydrogen. In some embodiments, each R^{D} is hydrogen. In some embodiments, each R^{D} is not hydrogen.

In some embodiments, at least one R^{D} comprises at least one C atom. In some embodiments, at least one R^{D} comprises a substituent selected from the group consisting of alkyl, cycloalkyl, heterocycloalkyl, silyl, germyl, aryl, heteroaryl, and combinations thereof.

In some embodiments, at least one R^{D} is a substituted or unsubstituted cyclic moiety. In some embodiments, at least one R^{D} is benzene. In some embodiments, at least one R^{D} is pyridine. In some embodiments, at least one R^{D} is cyclohexane.

In some embodiments, at least one R^{E} is not hydrogen. In some embodiments, each R^{E} is hydrogen. In some embodiments, each R^{E} is not hydrogen.

In some embodiments, at least one R^{E} comprises at least one C atom. In some embodiments, at least one R^{E} comprises a substituent selected from the group consisting of alkyl, cycloalkyl, heterocycloalkyl, silyl, germyl, aryl, heteroaryl, and combinations thereof.

In some embodiments, at least one R^{E} is a substituted or unsubstituted cyclic moiety. In some embodiments, at least one R^{E} is benzene. In some embodiments, at least one R^{E} is pyridine. In some embodiments, at least one R^{E} is cyclohexane.

In some embodiments, at least one R^{D} or R^{E} is selected from the group consisting of alkyl, heteroalkyl cycloalkyl, heterocycloalkyl, heteroaryl, silyl, and combinations thereof. In some embodiments, at least one R^{D} or R^{E} comprises a cycloalkyl group.

In some embodiments, the structure of Formula II is selected from the structures of the following LIST 1:

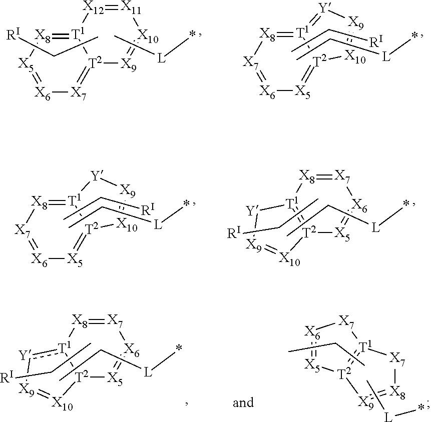

wherein
each of X₅ to X₁₂ is independently C or N;
Y′ is selected from the group consisting of BR, BRR′, NR, PR, P(O)R, O, S, Se, C═O, C═S, C═Se, C═NR′, C═CRR′, S═O, SO₂, CR, CRR′, SiRR′, and GeRR′;
each [symbol] represents a single bond or a double bond;
R¹ represents mono to the maximum allowable substitution, or no substitution; each R, R′, and R¹ is independently hydrogen, or a substituent selected from the group consisting of the General Substituents defined herein; and
any two substituents can be joined or feud to form a ring.

In some embodiments, the structure of Formula II is selected from the structures of the following LIST 2:

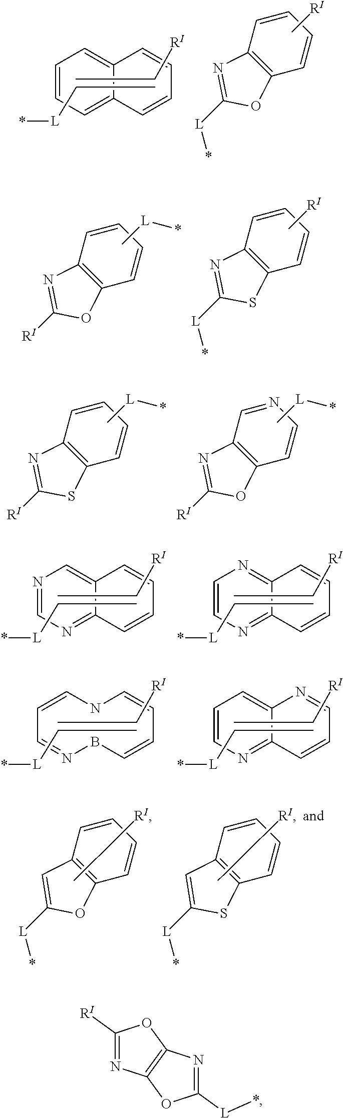

wherein each variable is defined above.

In some embodiments, at least one R^{B} or R^{C} is a substituent comprises a structure of Formula III,

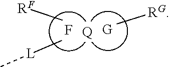

In some embodiments, Q is B. In some embodiments, Q is C. In some embodiments, Q is Si. In some embodiments, Q is Ge.

In some embodiments, at least one of moiety F or moiety G comprises an aryl or heteroaryl ring.

In some embodiments, at least one of moiety F or moiety G comprises a ring comprising 7 to 10 ring atoms.

In some embodiments, at least one of moiety F or moiety G comprises a ring comprising 7 to 10 ring atoms that includes Q.

In some embodiments, the ring of moiety F comprising Q is a 5-membered or 6-membered ring.

In some embodiments, the ring of moiety F comprising Q is a 5-membered ring. In some embodiments, the ring of moiety F comprising Q is a 6-membered ring.

In some embodiments, the ring of moiety F comprising Q includes no heteroatoms or no heteroatoms other than Q. In some embodiments, the ring of moiety F comprising Q includes no heteroatoms and Q is C. In some embodiments, the ring of moiety F comprising Q includes no heteroatoms except for Q, which is Si, Ge, or B.

In some embodiments, the ring of moiety F comprising Q includes at least one heteroatom excluding Q. In some embodiments, the ring of moiety F comprising Q includes exactly one heteroatom excluding Q. In some such embodiments, the heteroatom is Si. In some embodiment, the heteroatom is N. In some embodiments, the heteroatom is O.

In some embodiments, moiety F comprises a ring comprising 7 to 10 ring atoms. In some embodiments, moiety F comprises a ring comprising 7 to 10 ring atoms, that includes Q.

In some embodiments, moiety F comprises an aryl or heteroaryl moiety. In some embodiments, moiety F comprises a ring selected from benzene, pyridine, or pyrimidine.

In some embodiments, moiety F comprises two separate aryl or heteroaryl moieties. In some such embodiments, each of the aryl or heteroaryl moieties is independently benzene, pyridine, or pyrimidine.

In some embodiments, the ring of moiety G comprising Q is a 5-membered or 6-membered ring.

In some embodiments, the ring of moiety G comprising Q is a 5-membered ring. In some embodiments, the ring of moiety G comprising Q is a 6-membered ring.

In some embodiments, the ring of moiety G comprising Q includes no heteroatoms or no heteroatoms other than Q. In some embodiments, the ring of moiety G comprising Q includes no heteroatoms and Q is C. In some embodiments, the ring of moiety G comprising Q includes no heteroatoms, except that Q is Si, Ge, or B.

In some embodiments, the ring of moiety G comprising Q includes at least one heteroatom excluding Q. In some embodiments, the ring of moiety G comprising Q includes exactly one heteroatom excluding Q. In some such embodiments, the at least one heteroatom comprises or exactly one heteroatom is Si. In some such embodiments, the at least one heteroatom comprises or exactly one heteroatom is N. In some such embodiments, the at least one heteroatom comprises or exactly one heteroatom is O.

In some embodiments, moiety G comprises a ring comprising 7 to 10 ring atoms. In some embodiments, moiety G comprises a ring comprising 7 to 10 ring atoms, that includes Q.

In some embodiments, moiety G comprises an aryl or heteroaryl moiety. In some such embodiments, the aryl or heteroaryl moiety is benzene, pyridine, or pyrimidine.

In some embodiments, moiety G comprises two separate aryl or heteroaryl moieties. In some such embodiments, each aryl or heteroaryl moiety is independently benzene, pyridine, or pyrimidine.

In some embodiments of Formula III, L is a direct bond. In some embodiments of Formula III, L is a substituted or unsubstituted monocyclic or polycyclic ring system. In some embodiments of Formula III, L is substituted or unsubstituted benzene or substituted or unsubstituted biphenyl. In some embodiments of Formula III, L is selected from the group consisting of the Cyclic Moiety List defined herein, which may be substituted or unsubstituted.

In some embodiments, at least one R^{F} is not hydrogen. In some embodiments, each R^{F} is hydrogen. In some embodiments, each R^{F} is not hydrogen.

In some embodiments, at least one R^{F} comprises at least one C atom. In some embodiments, at least one R^{F} comprises a substituent selected from the group consisting of alkyl, cycloalkyl, heterocycloalkyl, silyl, germyl, aryl, heteroaryl, and combinations thereof.

In some embodiments, at least one R^{F} is a substituted or unsubstituted cyclic moiety. In some embodiments, at least one R^{F} is benzene. In some embodiments, at least one R^{F} is pyridine. In some embodiments, at least one R^{F} is cyclohexane.

In some embodiments, at least one R^{G} is not hydrogen. In some embodiments, each R^{G} is hydrogen. In some embodiments, each R^{G} is not hydrogen.

In some embodiments, at least one R^{G} comprises at least one C atom. In some embodiments, at least one R^{G} comprises a substituent selected from the group consisting of alkyl, cycloalkyl, heterocycloalkyl, silyl, germyl, aryl, heteroaryl, and combinations thereof.

In some embodiments, at least one R^{G} is a substituted or unsubstituted cyclic moiety. In some embodiments, at least one R^{G} is benzene. In some embodiments, at least one R^{G} is pyridine. In some embodiments, at least one R^{G} is cyclohexane.

In some embodiments, at least one R^{F} or R^{G} is selected from the group consisting of alkyl, heteroalkyl cycloalkyl, heterocycloalkyl, heteroaryl, silyl, and combinations thereof. In some embodiments, at least one R^{F} or R^{G} comprises a cycloalkyl group.

In some embodiments, the structure of Formula III is selected from the structures of the following LIST 3:

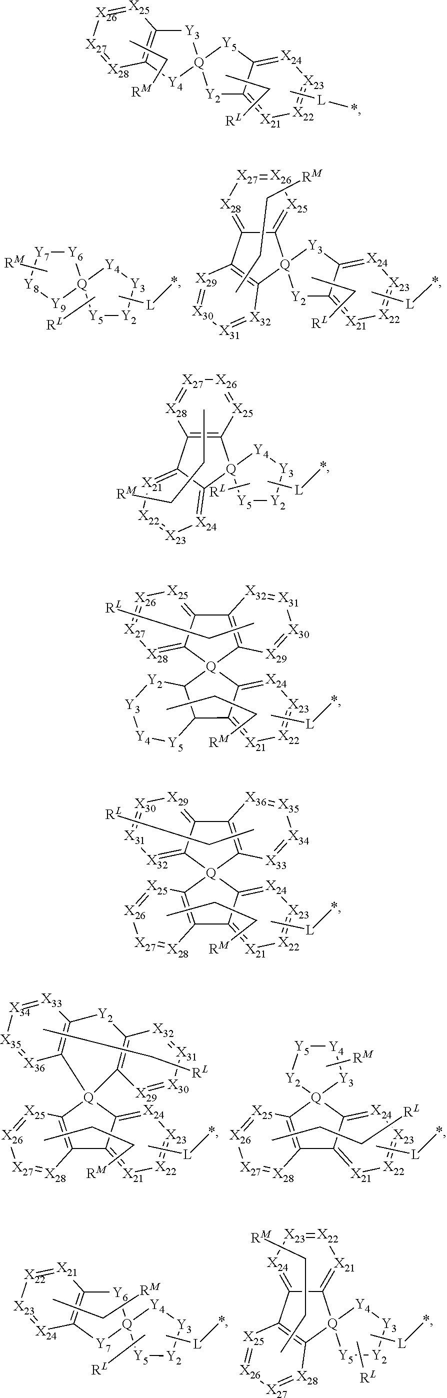

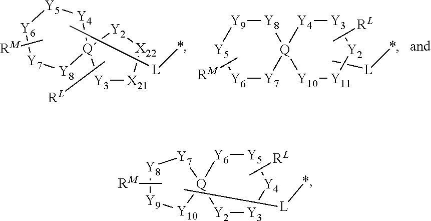

wherein
X₂₁ to X₃₆ are each independently C or N;
each of Y₁ to Y₁₁ is selected from the group consisting of B, N, P, P(O), O, S, Se, C═O, C═S, C═Se, C═NR′, C═CRR′, S═O, SO₂, C, Si, and Ge;
each of R^{L} and R^{N} independently represents mono to the maximum allowable substitution, or no substitution;
each R, R′, R^{L}, and R^{M} is independently hydrogen, or a substituent selected from the group consisting of the General Substituents defined herein; and
any two substituents can be joined or fused to form a ring.

In some embodiments, the structure of Formula III is selected from the structures of the following LIST 4:

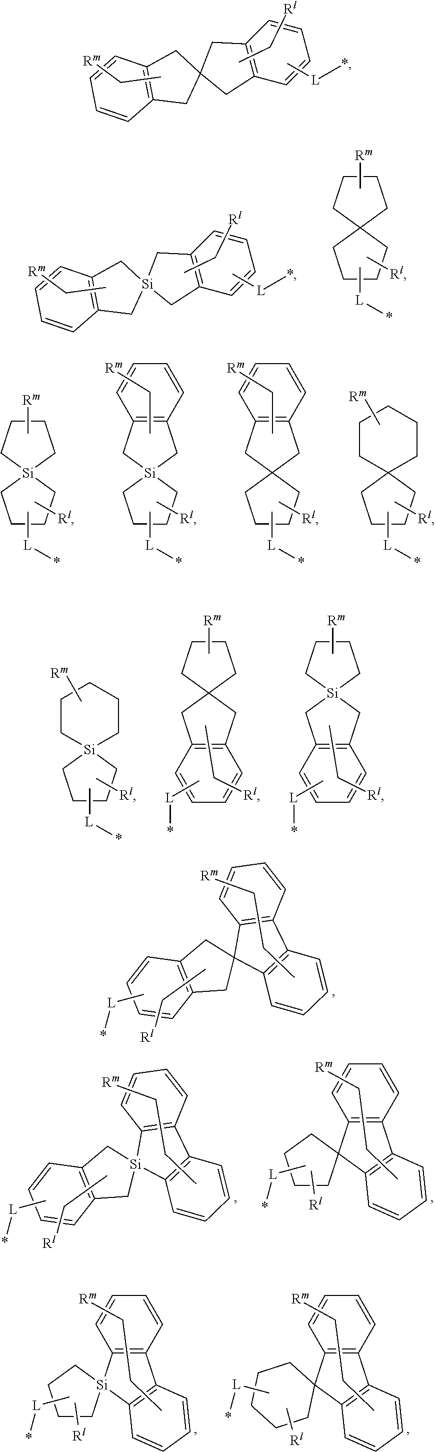

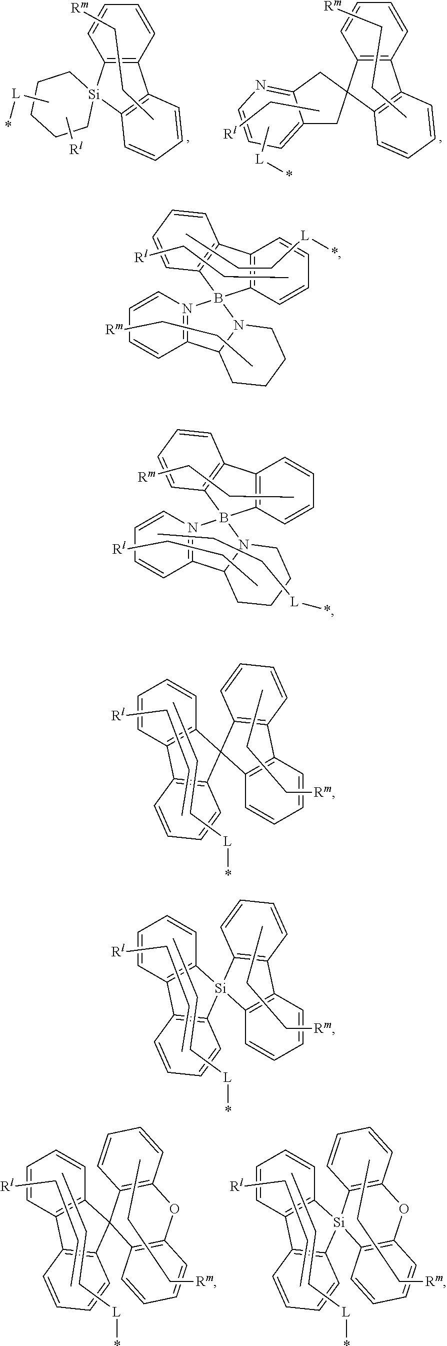

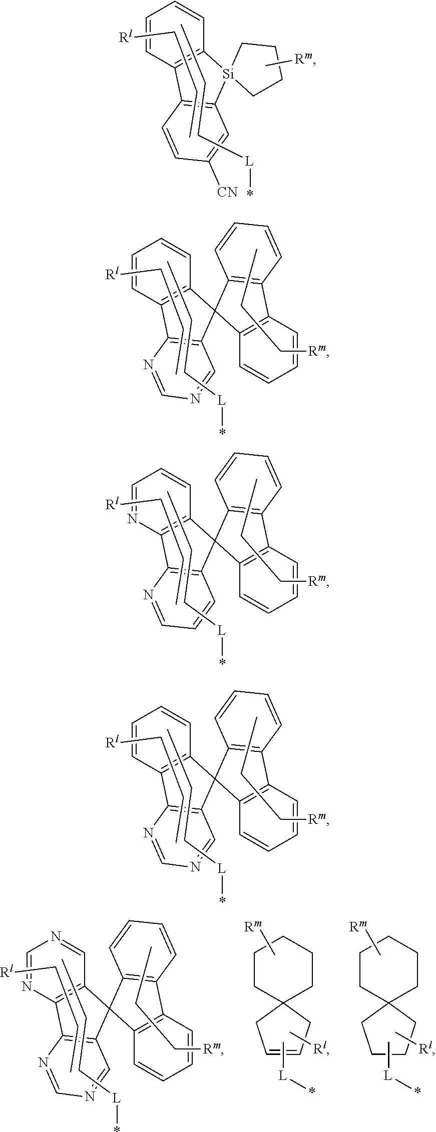

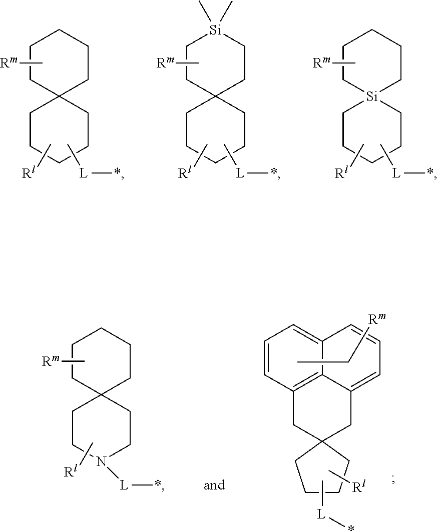

wherein:
each of R^{l} and R^{m} independently represents mono to the maximum allowable substitution, or no substitution;
each R^{l} and R^{m} is independently hydrogen, or a substituent selected from the group consisting of the General Substituents defined herein; and
any two substituents can be joined or fused to form a ring.

In some embodiments, the structure of Formula II or Formula III is selected from the structures of the following LIST 5:

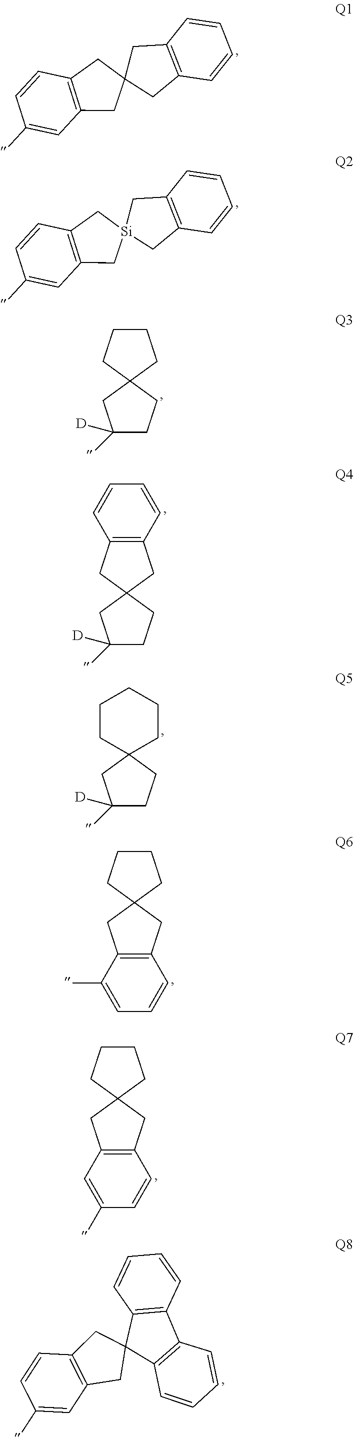

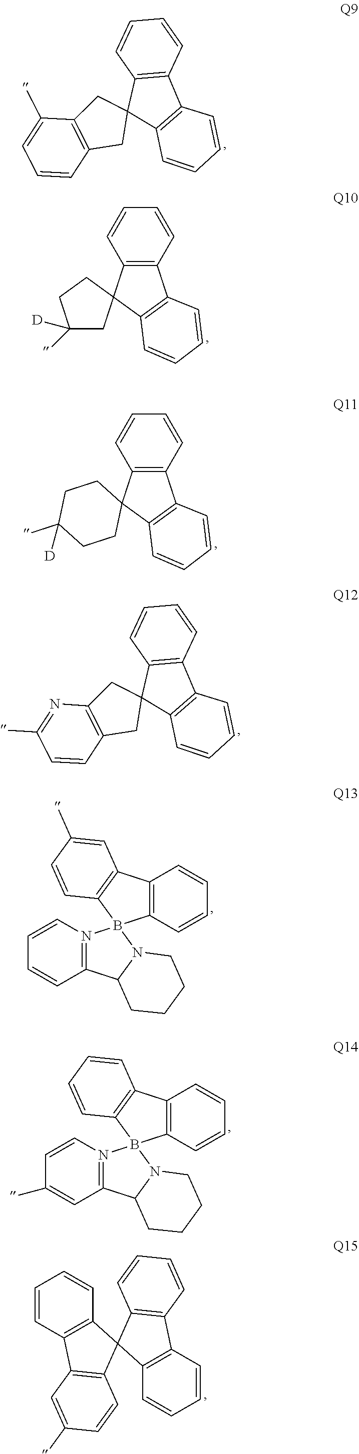

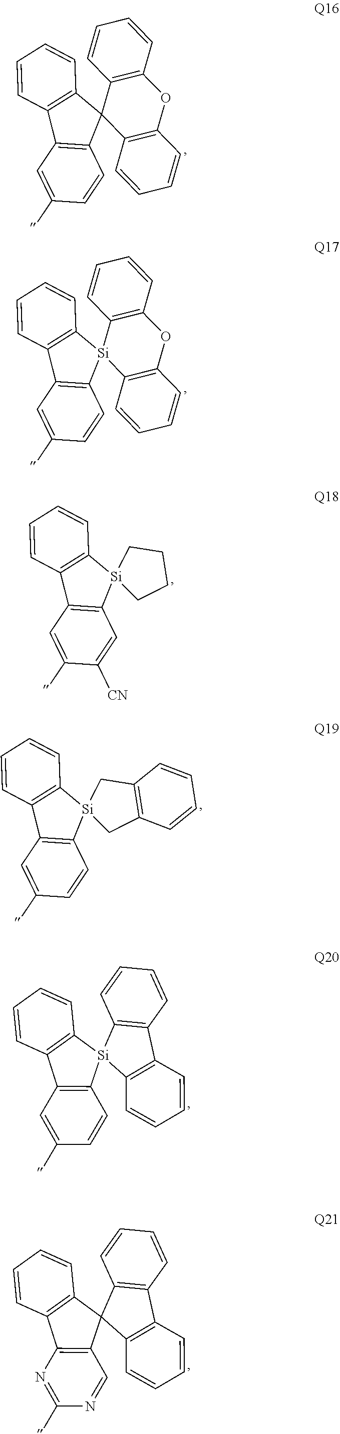

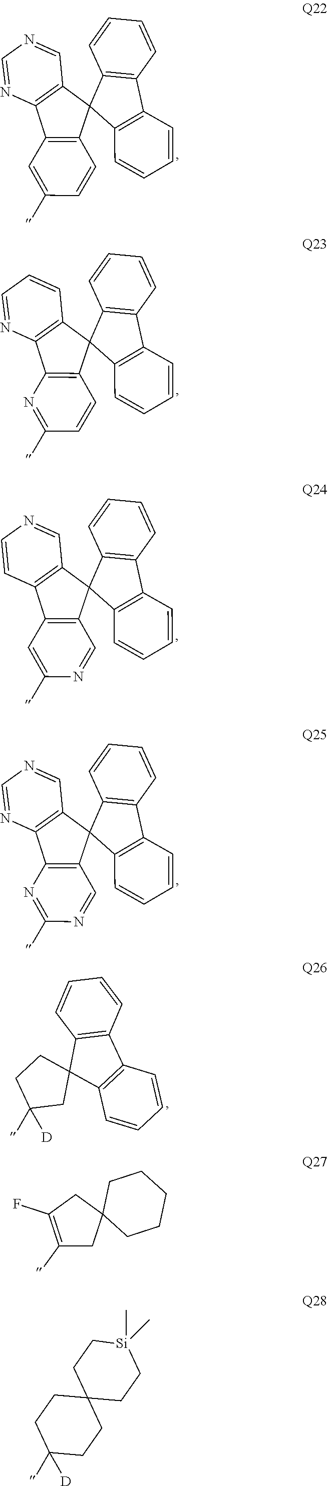

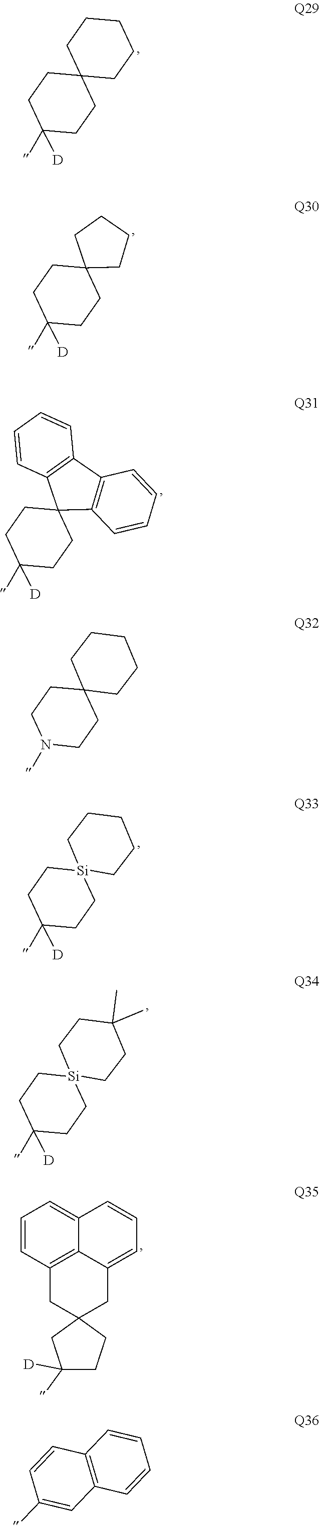

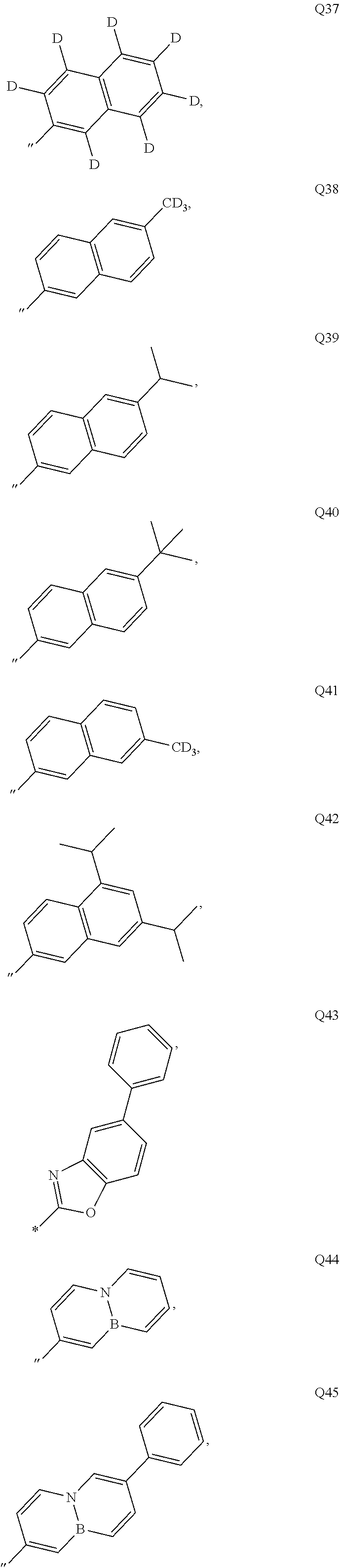

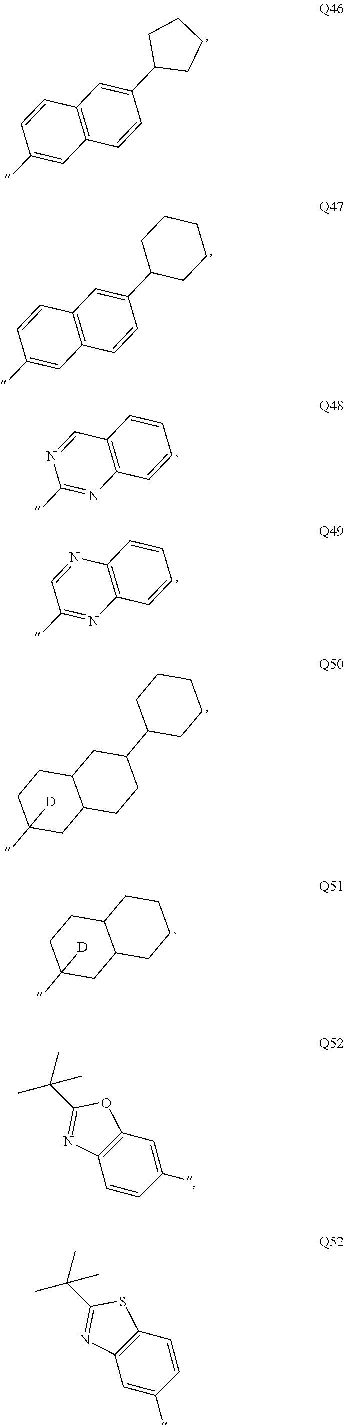

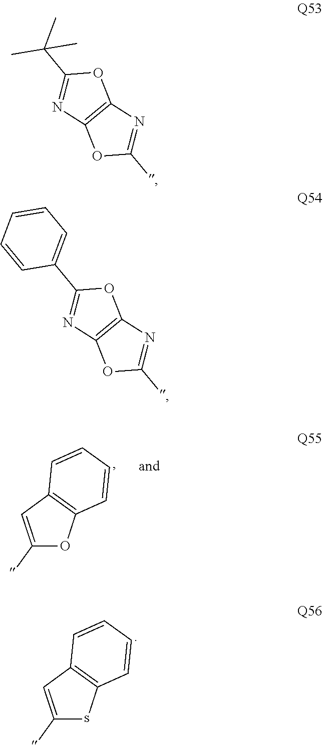

In some embodiments, the ligand L_{A} is selected from the group consisting of the structures of the following LIST 6:

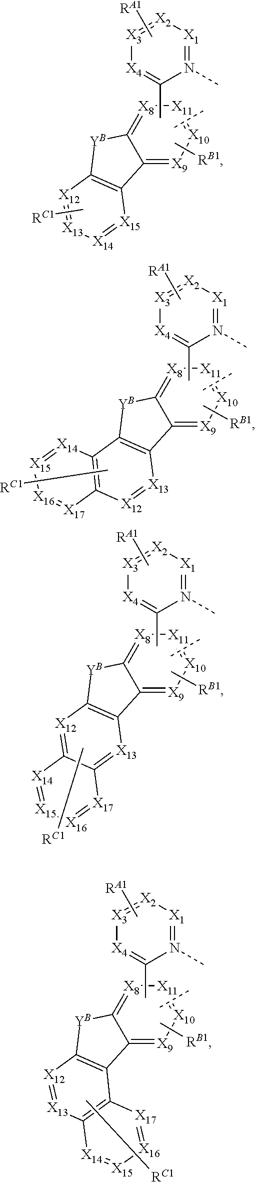

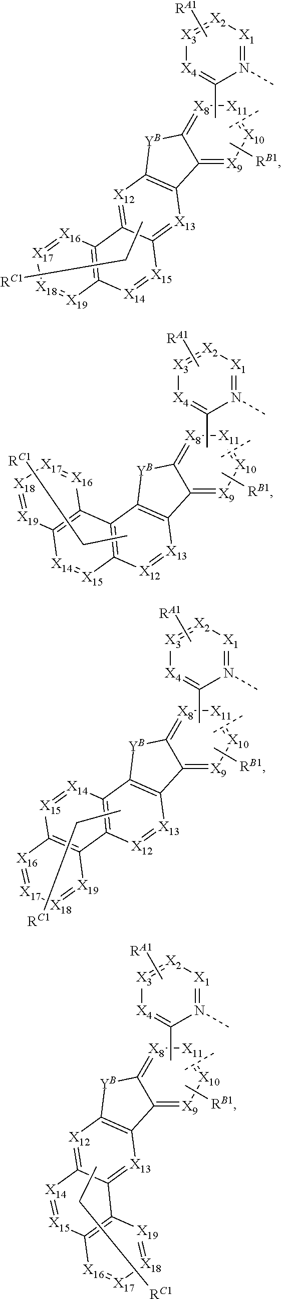

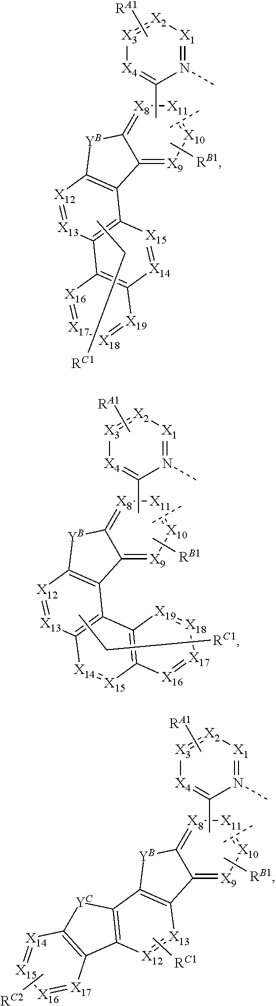

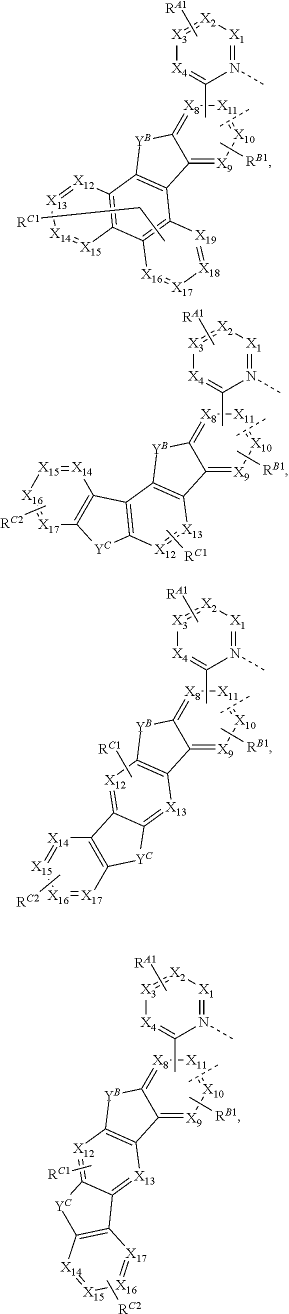

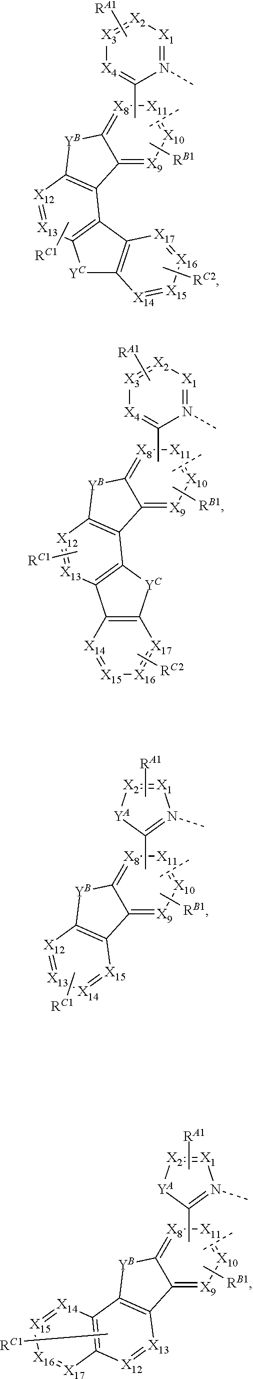

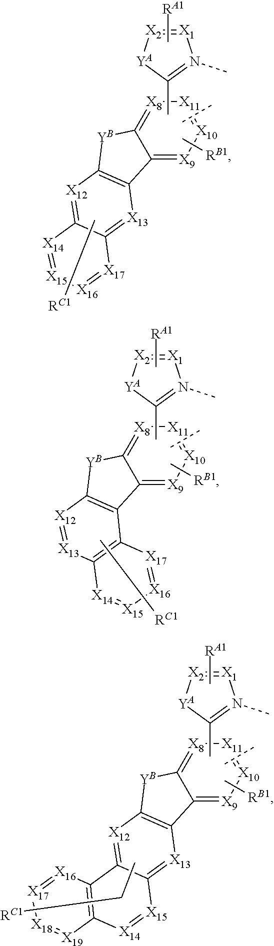

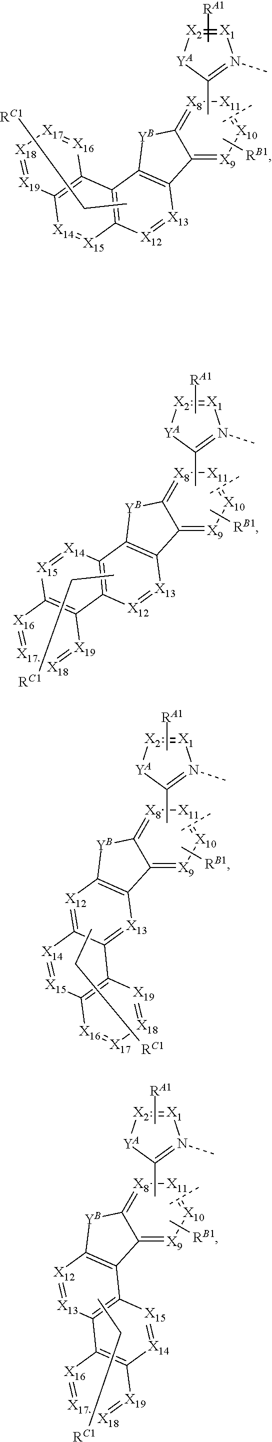

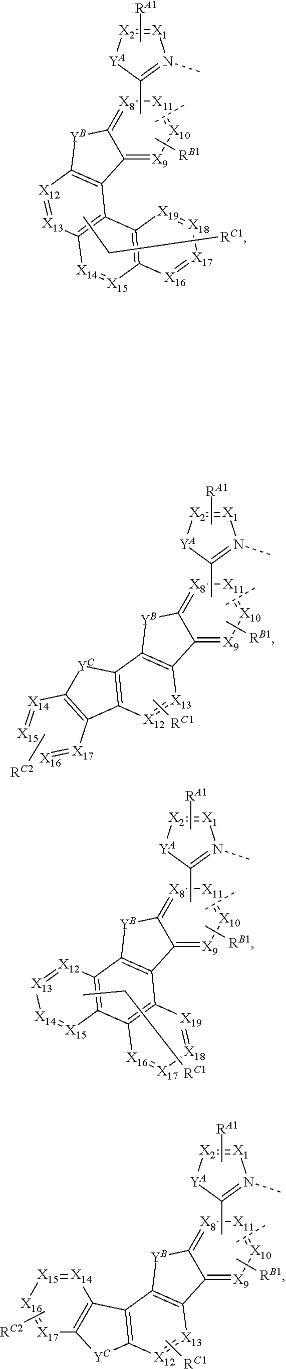

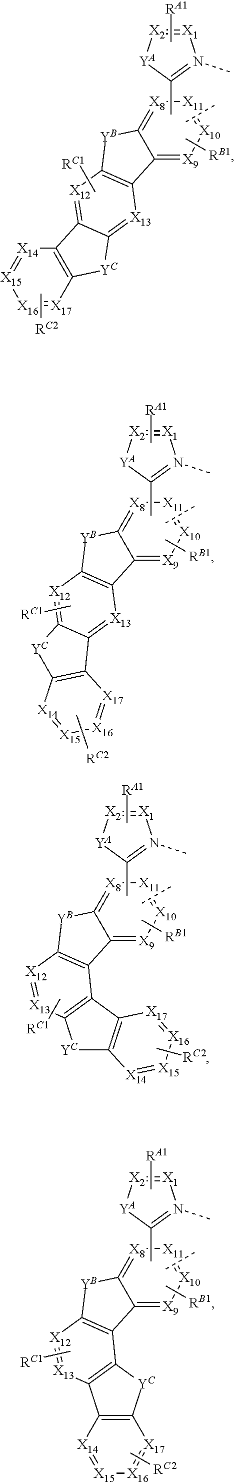

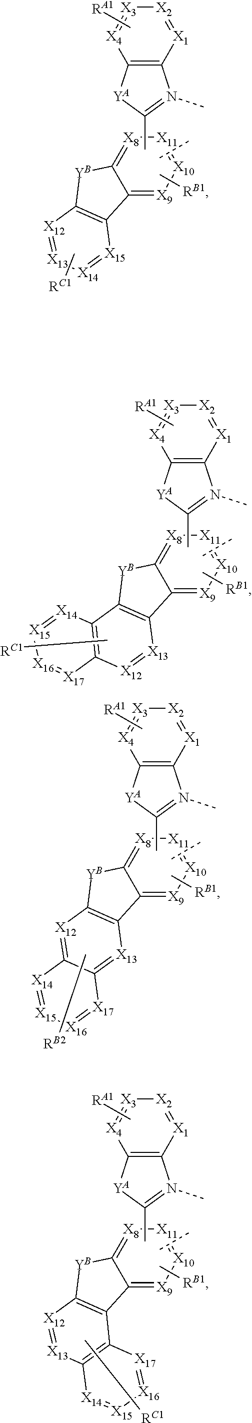

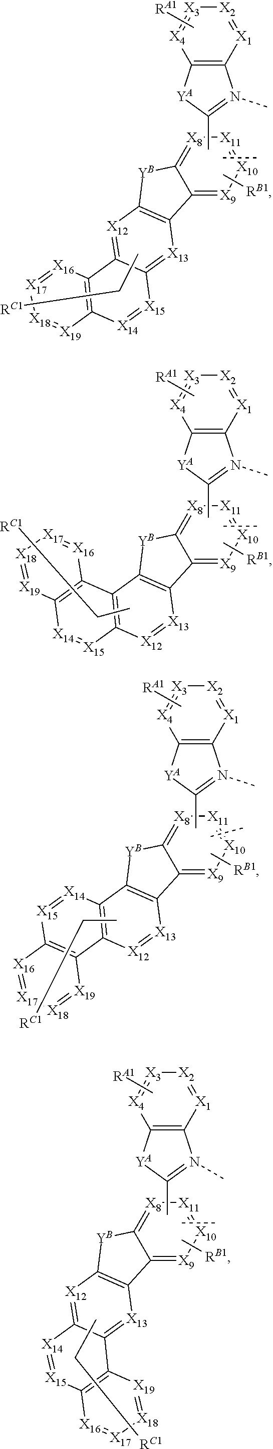

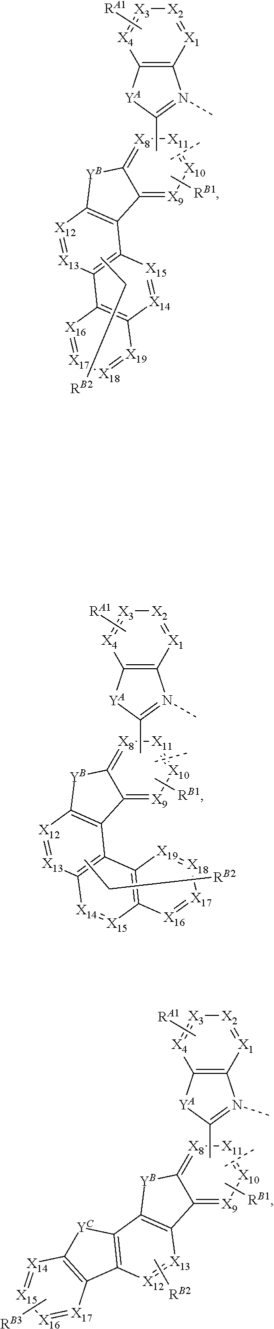

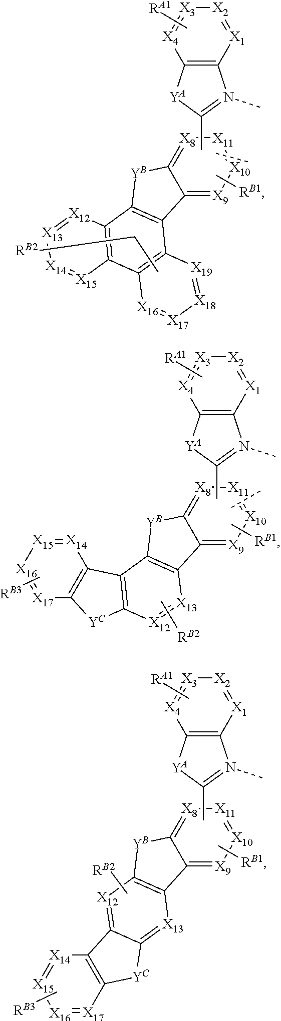

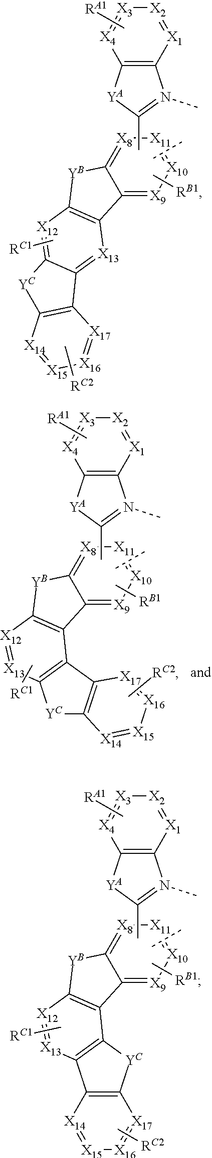

wherein:
X₁ to X₁₉ are each independently C or N;
each of Y, Y^{A}, Y^{B}, and Y^{C} is independently selected from the group consisting of BRₑ, NRₑ, PRₑ, O, S, Se, C═O, S═O, SO₂, CReR_{f}, SiRₑR_{f}, and GeReR_{f};
each R^{A1}, R^{B1}, R^{C1}, and R^{C2} independently represent from mono to the maximum possible number of substitutions, or no substitution;
each R^{A1}, R^{B1}, R^{C1}, R^{C2}, Rₑ, and R_{f} is independently a hydrogen, or a substituent selected from the group consisting of the General Substituents defined herein;
any two substituents can be joined or fused to form a ring; and
at least one of R^{B1}, R^{C1}, or R^{C2} comprises or is a structure selected from the structures in LIST 1, LIST 2, LIST 3, LIST 4, and LIST 5.

In some embodiments where ligand L_{A} is selected from LIST 6, at least one R^{A1}, R^{B1}, R^{C1}, or R^{C2} is selected from the group consisting of the General Substituents defined herein. In some embodiments, at least one R^{A1} is selected from the group consisting of the General Substituents defined herein. In some embodiments, at least one R^{B1} is selected from the group consisting of the General Substituents defined herein. In some embodiments, at least one R^{C1} is selected from the group consisting of the General Substituents defined herein. In some embodiments, at least one R^{C2} is selected from the group consisting of the General Substituents defined herein. In some embodiments, at least one R^{A1}, R^{B1}, R^{C1}, or R^{C2} is selected from the group consisting of the Preferred General Substituents defined herein.

In some embodiments where ligand L_{A} is selected from LIST 6, X₈ is C and connected to the top N containing ring. In some embodiments, X₉ is C and connected to the top N containing ring. In some embodiments, X₁₀ is C and connected to the top N containing ring. In some embodiments, X₁₈ is C and connected to the top N containing ring. In some embodiments, each of Y^{B} and Y^{C} is independently O.

In some embodiments where ligand L_{A} is selected from LIST 6, two R^{A1} are joined to form a fused ring. In some such embodiments, the fused ring may be benzene, pyridine, pyrimidine, pyridazine, pyrazine, triazine, imidazole, imidazole derived carbene, pyrazole, pyrrole, oxazole, furan, thiophene, thiazole, or triazole. In some such embodiments, the fused ring may be benzene.

In some embodiments where ligand L_{A} is selected from LIST 6, Y^{A} may be NR* and R* comprises a structure of Formula XA,

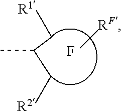

wherein:
ring F′ is a 5-membered to 10-membered carbocyclic or heterocyclic ring;
R^{F} represents mono to tri-substitutions, or no substitutions; and
each R^{1′}, R^{2′}, and R^{F′} is independently hydrogen or a substituent selected from the group consisting of deuterium, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, ether, ester, phosphino, selenyl, and combinations thereof, and combinations thereof.

In some embodiments, ring F′ is a 5-membered or 6-membered carbocyclic or heterocyclic ring. In some embodiments, ring F′ is a 5-membered or 6-membered aryl or heteroaryl ring.

In some embodiments, R^{1′} and R^{2′} are each independently hydrogen, deuterium, or R^{1′} and R^{2′} are joined with an R^{F′} to form a ring. In some embodiments, at least one of R^{1′} and R^{2′} is not hydrogen or deuterium.

In some embodiments, each of R^{1′} and R^{2′} is independently selected from the group consisting of alkyl, cycloalkyl, silyl, germyl, and combinations thereof.

In some embodiments, R^{1′} and R^{2′} are the same. In some embodiments, R^{1′} and R^{2′} are different.

In some embodiments, each of R^{1′} and R^{2′} comprises at least one carbon atom. In some embodiments, each of R^{1′} and R^{2′} comprises at least two carbon atoms. In some embodiments, each of R^{1′} and R^{2′} comprises at least three carbon atoms. In some embodiments, each of R^{1′} and R^{2′} comprises at least four carbon atoms.

In some embodiments, at least one R^{F′} is not hydrogen or deuterium. In some embodiments, at least one R^{F′} is selected from the group consisting of alkyl, cycloalkyl, silyl, germyl, and combinations thereof.

In some embodiments, ring F′ is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole.

In some embodiments where ligand L_{A} is selected from LIST 6, Y^{A} may be NR* and R* comprises a structure of Formula XB,

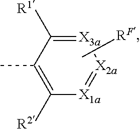

wherein each of X₁ₐ, X₂ₐ, and X₃ₐ is independently C or N.

In some embodiments, the R^{F′} bonded to X₂ₐ is selected from the group consisting of alkyl, cycloalkyl, silyl, germyl, and combinations thereof. In some embodiments, the R^{F′} bonded to X₂ₐ is alkyl. In some embodiments, the R^{F′} bonded to X₂ₐ is aryl or heteroaryl. In some embodiments, the R^{F′} bonded to X₂ₐ is silyl. In some embodiments, the R^{F′} bonded to X₂ₐ is germyl.

In some embodiments, each of X₁ₐ, X₂a, and X₃a is C.

In some embodiments where ligand L_{A} is selected from LIST 6, Y^{A} may be NR* and R* comprises a structure of Formula XC,

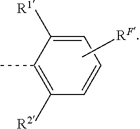

In some embodiments of Formula XC, the R^{F′} meta to both R^{1′} and R^{2′} has a structure of Formula XC.

In some embodiments of Formula XC, at least one of R^{1′} or R^{2′} is not hydrogen or deuterium. In some embodiments of Formula XC, each of R^{1′} and R^{2′} is independently selected from the group consisting of alkyl, cycloalkyl, aryl, heteroaryl, silyl, germyl, and combinations thereof. In some such embodiments, R^{1′} and R^{2′} are the same, while R^{1′} and R^{2′} are different in other embodiments.

In some embodiments of Formula XC, each of R^{1′} and R^{2′} is hydrogen or deuterium.

In some embodiments of Formula XC, at least one R^{F′} is not hydrogen or deuterium.

In some embodiments of Formula XC, at least one R^{F′} is selected from the group consisting of alkyl, cycloalkyl, aryl, heteroaryl, silyl, germyl, and combinations thereof. In some embodiments of Formula XC, the R^{F′} meta to both R^{1′} and R^{2′} is selected from the group consisting of alkyl, cycloalkyl, aryl, heteroaryl, silyl, germyl, and combinations thereof.

In some embodiments of Formula XC, the R^{F′} meta to both R^{1′} and R^{2′} is selected from the group consisting of aryl, alkyl, silyl, germyl, and combinations thereof. In some embodiments of Formula XC, the R^{F′} meta to both R^{1′} and R^{2′} is selected from the group consisting of phenyl, t-butyl, Si(Me)₃, Si(Ph)₃, Ge(Me)₃, Ge(Ph)₃, and combinations thereof. In some embodiments of Formula XC, the R^{F′} meta to both R^{1′} and R^{2′} is phenyl, t-butyl, Si(Me)₃, Si(Ph)₃, Ge(Me)₃, or Ge(Ph)₃.

In some embodiments of Formula XC, the R^{F′} meta to both R^{1′} and R^{2′} is phenyl. In some embodiments of Formula XC, the R^{F′} meta to both R^{1′} and R^{2′} is t-butyl. In some embodiments of Formula XC, the R^{F′} meta to both R^{1′} and R^{2′} is Si(Me)₃ or Si(Ph)₃. In some embodiments of Formula XC, the R^{F′} meta to both R^{1′} and R^{2′} is Ge(Me)₃ or Ge(Ph)₃.

In some embodiments where ligand L_{A} is selected from LIST 6, X₁₂ is C and connected to a structure selected from LIST 1, LIST 2, LIST 3, LIST 4, or LIST 5. In some embodiments, X₁₃ is C and connected to a structure selected from LIST 1, LIST 2, LIST 3, LIST 4, or LIST 5. In some embodiments, X₁₄ is C and connected to a structure selected from LIST 1, LIST 2, LIST 3, LIST 4, or LIST 5. In some embodiments, X₁₅ is C and connected to a structure selected from LIST 1, LIST 2, LIST 3, LIST 4, or LIST 5. In some embodiments, X₁₆ is C and connected to a structure selected from LIST 1, LIST 2, LIST 3, LIST 4, or LIST 5. In some embodiments, X₁₇ is C and connected to a structure selected from LIST 1, LIST 2, LIST 3, LIST 4, or LIST 5. In some embodiments, X₁₈ is C and connected to a structure selected from LIST 1, LIST 2, LIST 3, LIST 4, or LIST 5. In some embodiments, X₈ is C and connected to a structure selected from LIST 1, LIST 2, LIST 3, LIST 4, or LIST 5. In some embodiments, X₉ is C and connected to a structure selected from LIST 1, LIST 2, LIST 3, LIST 4, or LIST 5. In some embodiments, X₁₀ is C and connected to a structure selected from LIST 1, LIST 2, LIST 3, LIST 4, or LIST 5. In some embodiments, X₁₁ is C and connected to a structure selected from LIST 1, LIST 2, LIST 3, LIST 4, or LIST 5.

In some embodiments where ligand L_{A} is selected from LIST 6, at least one of R^{A1}, R^{B1}, R^{C1}, or R^{C2} is partially or fully deuterated. In some embodiments, at least one R^{A1} is partially or fully deuterated. In some embodiments, at least one R^{BI} is partially or fully deuterated. In some embodiments, at least one R^{C1} is partially or fully deuterated. In some embodiments, at least R^{C2} is partially or fully deuterated. In some embodiments,

In some embodiments where ligand L_{A} is selected from LIST 6, at least one R^{A1} is or comprises an electron-withdrawing group from the EWG1 LIST as defined herein. In some embodiments, at least one R^{A1} is or comprises an electron-withdrawing group from the EWG2 LIST as defined herein. In some embodiments, at least one R^{A1} is or comprises an electron-withdrawing group from the EWG3 LIST as defined herein. In some embodiments, at least one R^{A1} is or comprises an electron-withdrawing group from the EWG4 LIST as defined herein. In some embodiments, at least one R^{A1} is or comprises an electron-withdrawing group from the Pi-EWG LIST as defined herein.

In some embodiments where ligand L_{A} is selected from LIST 6, at least one R^{B1} is or comprises an electron-withdrawing group from the EWG1 LIST as defined herein. In some embodiments, at least one R^{B1} is or comprises an electron-withdrawing group from the EWG2 LIST as defined herein. In some embodiments, at least one R^{B1} is or comprises an electron-withdrawing group from the EWG3 LIST as defined herein. In some embodiments, at least one R^{B1} is or comprises an electron-withdrawing group from the EWG4 LIST as defined herein. In some embodiments, at least one R^{B1} is or comprises an electron-withdrawing group from the Pi-EWG LIST as defined herein.

In some embodiments where ligand L_{A} is selected from LIST 6, at least one R^{C1} is or comprises an electron-withdrawing group from the EWG1 LIST as defined herein. In some embodiments, at least one R^{C1} is or comprises an electron-withdrawing group from the EWG2 LIST as defined herein. In some embodiments, at least one R^{C1} is or comprises an electron-withdrawing group from the EWG3 LIST as defined herein. In some embodiments, at least one R^{C1} is or comprises an electron-withdrawing group from the EWG4 LIST as defined herein. In some embodiments, at least one R^{C1} is or comprises an electron-withdrawing group from the Pi-EWG LIST as defined herein.

In some embodiments where ligand L_{A} is selected from LIST 6, at least R^{C2} is or comprises an electron-withdrawing group from the EWG1 LIST as defined herein. In some embodiments, at least R^{C2} is or comprises an electron-withdrawing group from the EWG2 LIST as defined herein. In some embodiments, at least R^{C2} is or comprises an electron-withdrawing group from the EWG3 LIST as defined herein. In some embodiments, at least R^{C2} is or comprises an electron-withdrawing group from the EWG4 LIST as defined herein. In some embodiments, at least R^{C2} is or comprises an electron-withdrawing group from the Pi-EWG LIST as defined.

In some embodiments, the ligand L_{A} is selected from the group consisting of the structures of the following LIST 7:

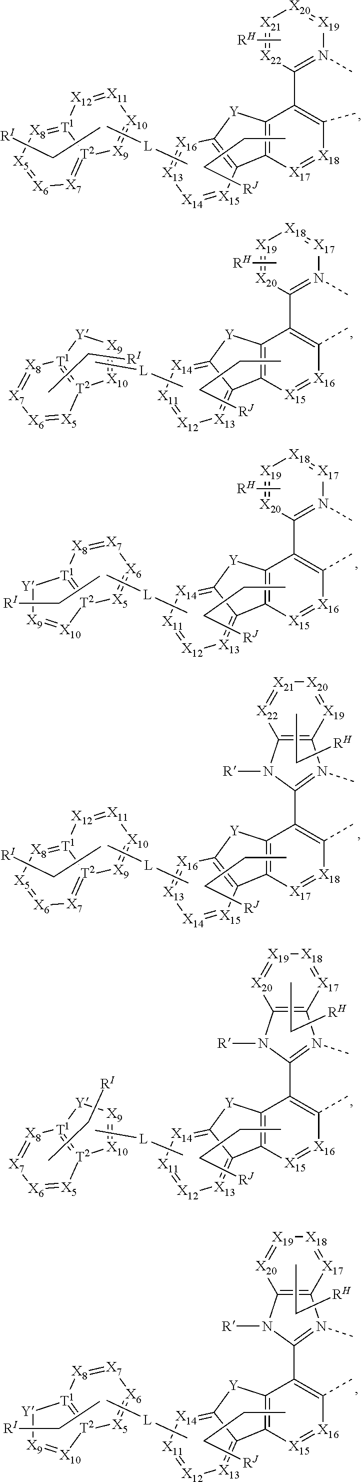

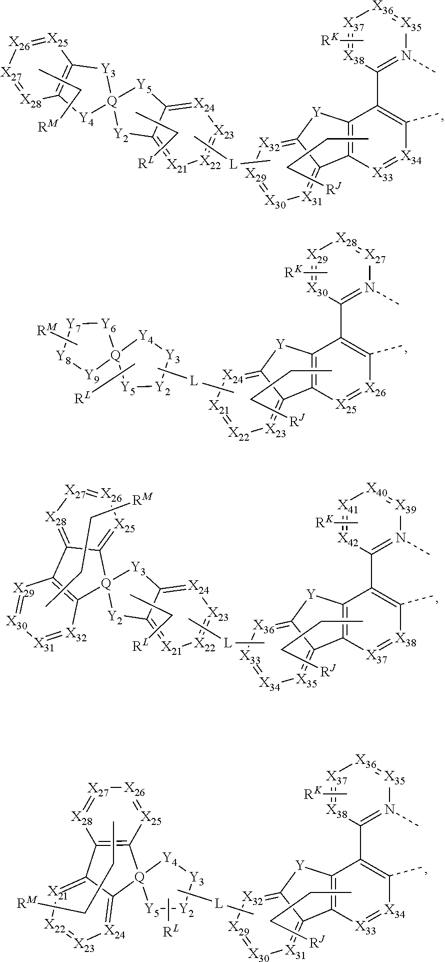

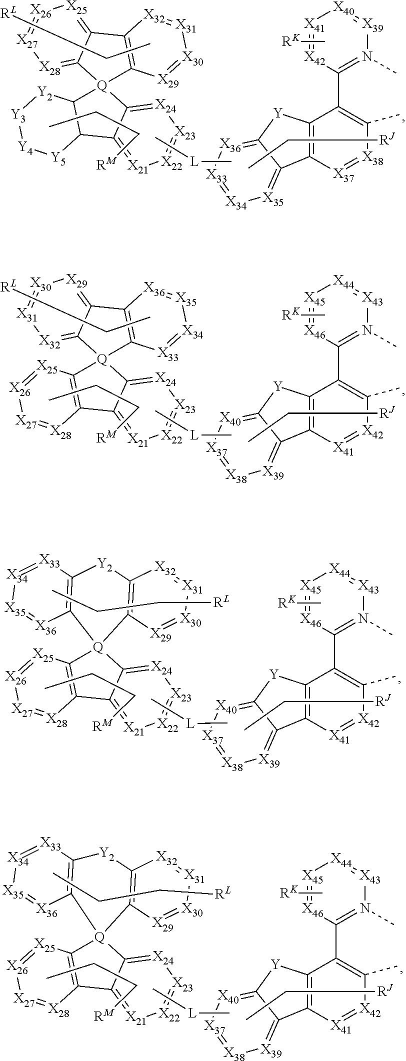

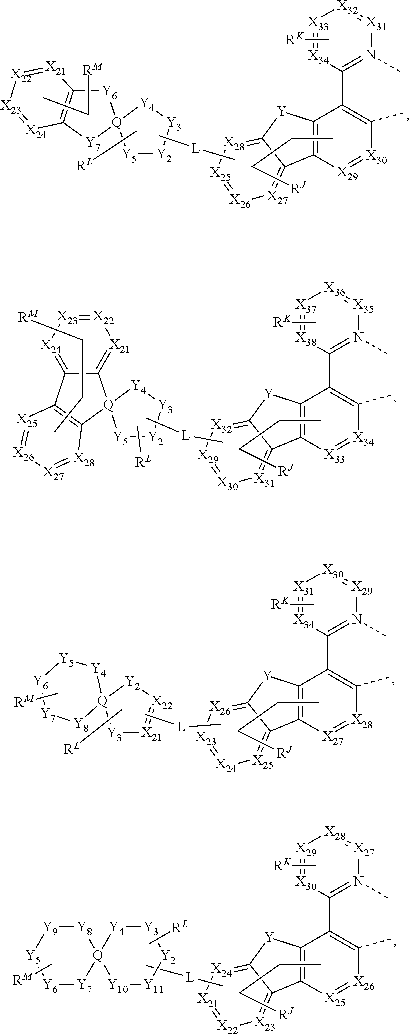

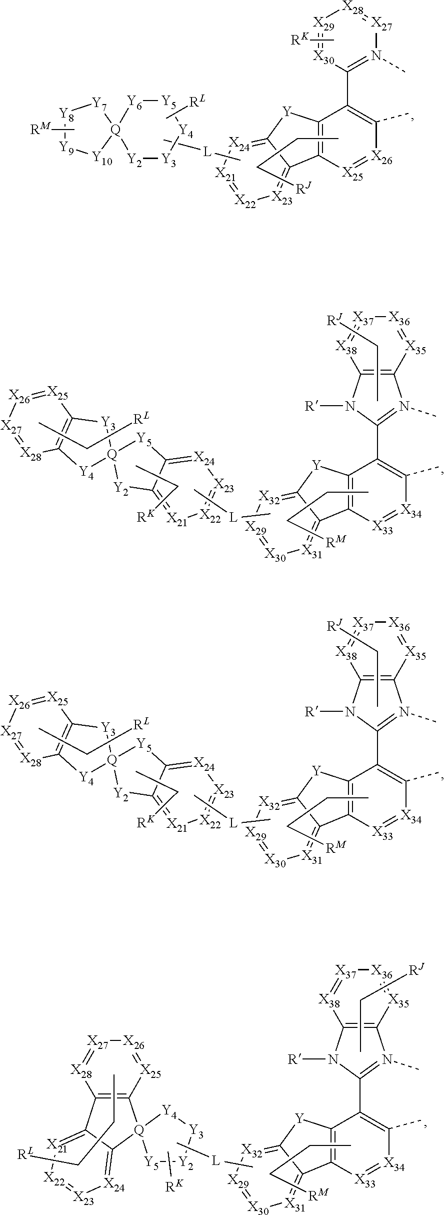

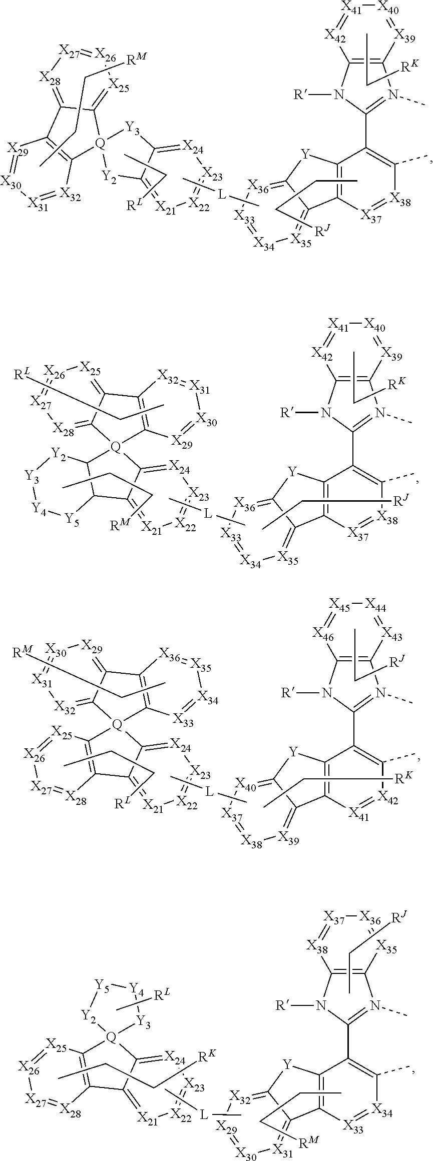

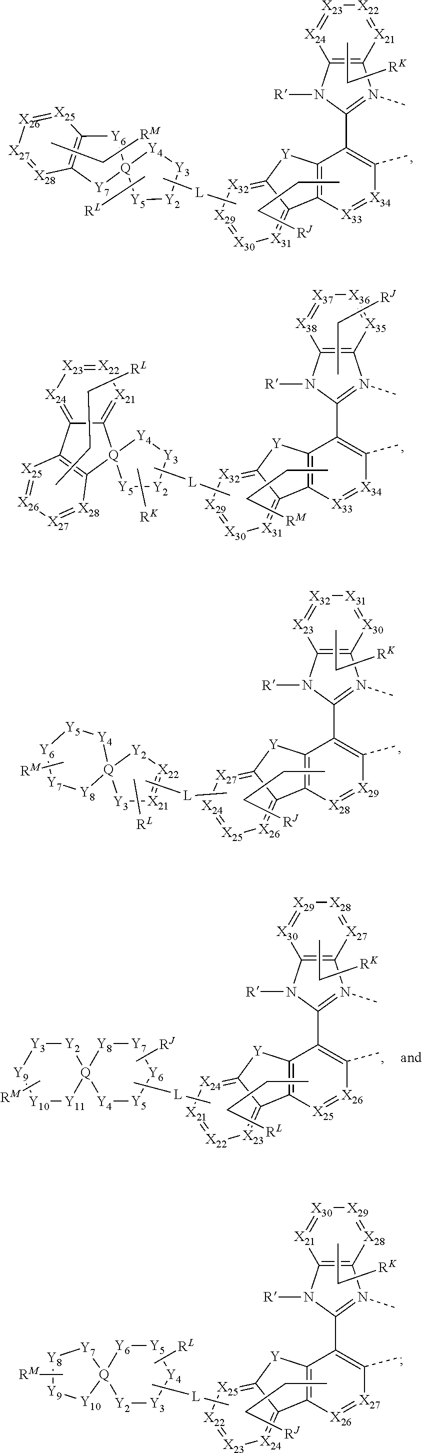

wherein
each of X₅ to X₄₆ is independently C or N;
each of Y₁ to Y₁₁ is independently selected from the group consisting of B, N, P, P(O), O, S, Se, C═O, C═S, C═Se, C═NR′, C═CRR′, S═O, SO₂, C, Si, and Ge;
each of R^{H}, R^{I}, R^{J}, R^{K}, R^{L}, and R^{M} independently represents mono to the maximum allowable substitution, or no substitution;
each R, R′, R^{H}, R^{I}, R^{J}, R^{K}, R^{L}, and R^{M} is independently hydrogen, or a substituent selected from the group consisting of the General Substituents defined herein;
the remaining variables are the same as previously defined; and
any two substituents can be joined or fused to form a ring.

It should be understood that even though for each structure in LIST 7, L is only shown to link Formula II or Formula III to Formula I from a particular ring of Formula II or Formula III, the linking can be from any other ring of Formula II or Formula III. It should also be understood that even though Formula II or Formula III is only shown to be linked to the bottom non-metal chelating ring of Formula I, Formula II or Formula III can also be linked to the bottom metal chelating ring of Formula I.

In some embodiments where ligand L_{A} is selected from LIST 7, at least one R^{H}, R^{I}, R^{H}, R^{K}, R^{L}, or R^{M} is selected from the group consisting of the General Substituents defined herein. In some embodiments, at least one R^{H} is selected from the group consisting of the General Substituents defined herein. In some embodiments, at least one R^{I} is selected from the group consisting of the General Substituents defined herein. In some embodiments, at least one R^{J} is selected from the group consisting of the General Substituents defined herein. In some embodiments, at least one R^{K} is selected from the group consisting of the General Substituents defined herein. In some embodiments, at least one R^{L} is selected from the group consisting of the General Substituents defined herein. In some embodiments, at least one R^{M} is selected from the group consisting of the General Substituents defined herein. In some embodiments, at least one R^{H}, R^{I}, R^{J}, R^{K}, R^{L}, or R^{M} is selected from the group consisting of the Preferred General Substituents defined herein.

In some embodiments, where ligand L_{A} is selected from LIST 7, at least one of R^{H}, R^{I}, R^{J}, R^{K}, R^{L}, or R^{M} is partially or fully deuterated. In some embodiments, at least one R^{H} is partially or fully deuterated. In some embodiments, at least one R′ is partially or fully deuterated. In some embodiments, at least one R^{J} is partially or fully deuterated. In some embodiments, at least R^{K} is partially or fully deuterated. In some embodiments, at least R^{L} is partially or fully deuterated. In some embodiments, at least R^{M} is partially or fully deuterated.

In some embodiments where ligand L_{A} is selected from LIST 7, two R^{H}, two R^{J}, or two R^{K} are joined to form a fused ring. In some such embodiments, the fused ring may be benzene, pyridine, pyrimidine, pyridazine, pyrazine, triazine, imidazole, imidazole derived carbene, pyrazole, pyrrole, oxazole, furan, thiophene, thiazole, or triazole. In some such embodiments, the fused ring may be benzene. In some embodiments, Y is O.

In some embodiments where ligand L_{A} is selected from LIST 7, R′ is or comprises a structure of Formula XA, Formula XB, or Formula XC as described herein. In such embodiments, all the Formula XA, Formula XB, or Formula XC related embodiments can be equally applied here.

In some embodiments where ligand L_{A} is selected from LIST 7, at least one R^{H} is or comprises an electron-withdrawing group from the EWG1 LIST as defined herein. In some embodiments, at least one R^{H} is or comprises an electron-withdrawing group from the EWG2 LIST as defined herein. In some embodiments, at least one R^{H} is or comprises an electron-withdrawing group from the EWG3 LIST as defined herein. In some embodiments, at least one R^{H} is or comprises an electron-withdrawing group from the EWG4 LIST as defined herein. In some embodiments, at least one R^{H} is or comprises an electron-withdrawing group from the Pi-EWG LIST as defined herein.

In some embodiments where ligand L_{A} is selected from LIST 7, at least one R′ is or comprises an electron-withdrawing group from the EWG1 LIST as defined herein. In some embodiments, at least one R′ is or comprises an electron-withdrawing group from the EWG2 LIST as defined herein. In some embodiments, at least one R¹ is or comprises an electron-withdrawing group from the EWG3 LIST as defined herein. In some embodiments, at least one R¹ is or comprises an electron-withdrawing group from the EWG4 LIST as defined herein. In some embodiments, at least one R¹ is or comprises an electron-withdrawing group from the Pi-EWG LIST as defined herein.

In some embodiments where ligand L_{A} is selected from LIST 7, at least one R¹ is or comprises an electron-withdrawing group from the EWG1 LIST as defined herein. In some embodiments, at least one R^{J} is or comprises an electron-withdrawing group from the EWG2 LIST as defined herein. In some embodiments, at least one R^{J} is or comprises an electron-withdrawing group from the EWG3 LIST as defined herein. In some embodiments, at least one R^{J} is or comprises an electron-withdrawing group from the EWG4 LIST as defined herein. In some embodiments, at least one R^{J} is or comprises an electron-withdrawing group from the Pi-EWG LIST as defined herein.

In some embodiments where ligand L_{A} is selected from LIST 7, at least R^{K} is or comprises an electron-withdrawing group from the EWG1 LIST as defined herein. In some embodiments, at least R^{K} is or comprises an electron-withdrawing group from the EWG2 LIST as defined herein. In some embodiments, at least R^{K} is or comprises an electron-withdrawing group from the EWG3 LIST as defined herein. In some embodiments, at least R^{K} is or comprises an electron-withdrawing group from the EWG4 LIST as defined herein. In some embodiments, at least R^{K} is or comprises an electron-withdrawing group from the Pi-EWG LIST as defined.

In some embodiments where ligand L_{A} is selected from LIST 7, at least R^{L} is or comprises an electron-withdrawing group from the EWG1 LIST as defined herein. In some embodiments, at least R^{L} is or comprises an electron-withdrawing group from the EWG2 LIST as defined herein. In some embodiments, at least R^{L} is or comprises an electron-withdrawing group from the EWG3 LIST as defined herein. In some embodiments, at least R^{L} is or comprises an electron-withdrawing group from the EWG4 LIST as defined herein. In some embodiments, at least R^{L} is or comprises an electron-withdrawing group from the Pi-EWG LIST as defined.

In some embodiments where ligand L_{A} is selected from LIST 7, at least R^{M} is or comprises an electron-withdrawing group from the EWG1 LIST as defined herein. In some embodiments, at least R^{M} is or comprises an electron-withdrawing group from the EWG2 LIST as defined herein. In some embodiments, at least R^{M} is or comprises an electron-withdrawing group from the EWG3 LIST as defined herein. In some embodiments, at least R^{M} is or comprises an electron-withdrawing group from the EWG4 LIST as defined herein. In some embodiments, at least R^{M} is or comprises an electron-withdrawing group from the Pi-EWG LIST as defined.

In some embodiments, the ligand L_{A} is selected from the group consisting of structures of the following LIST 8:

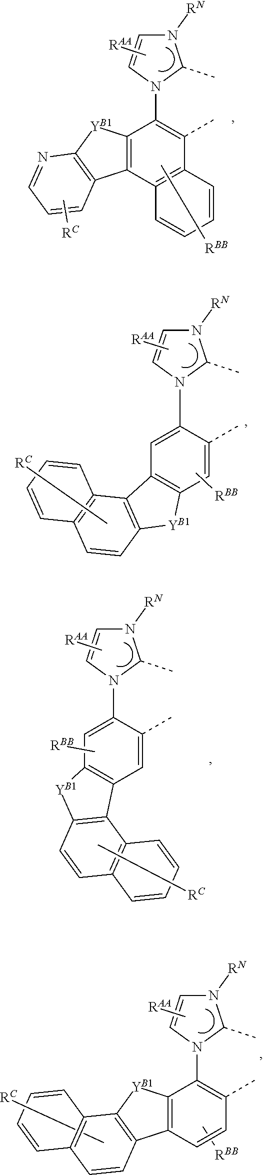

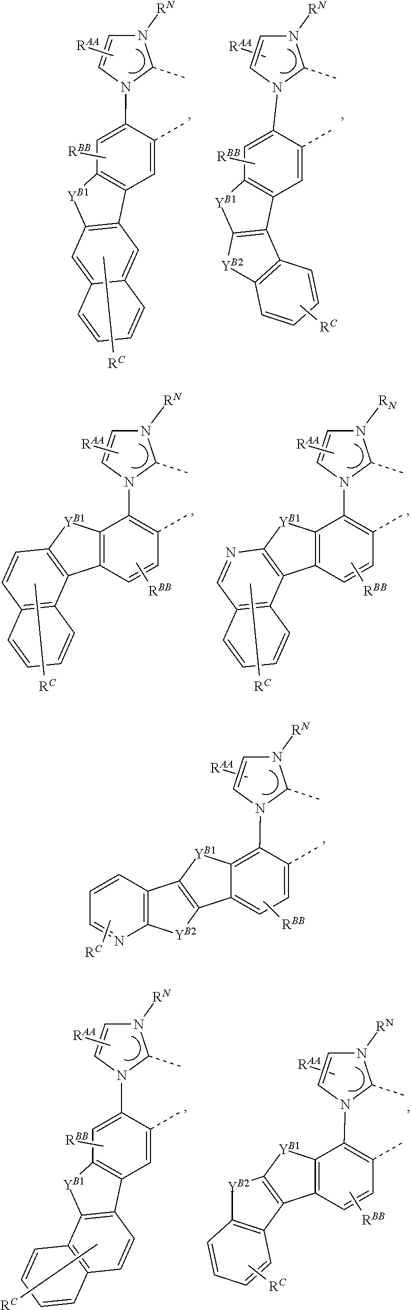

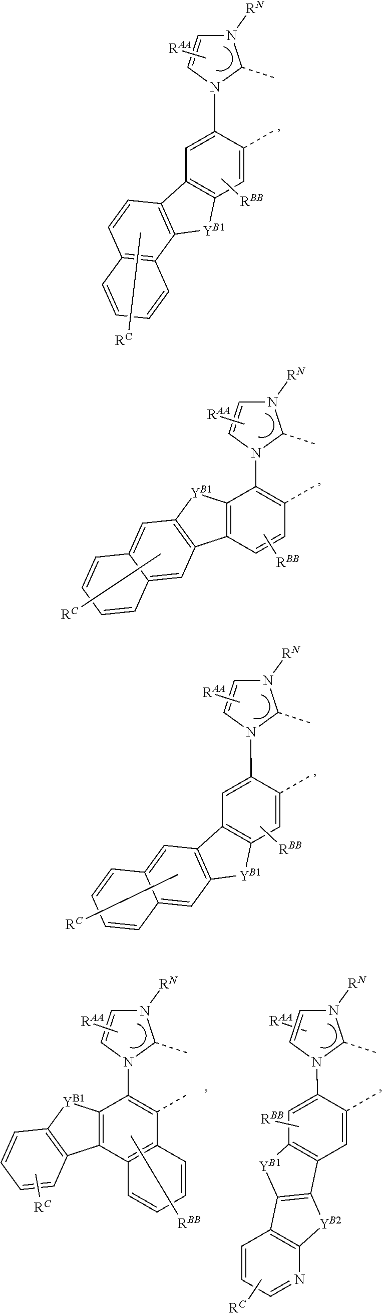

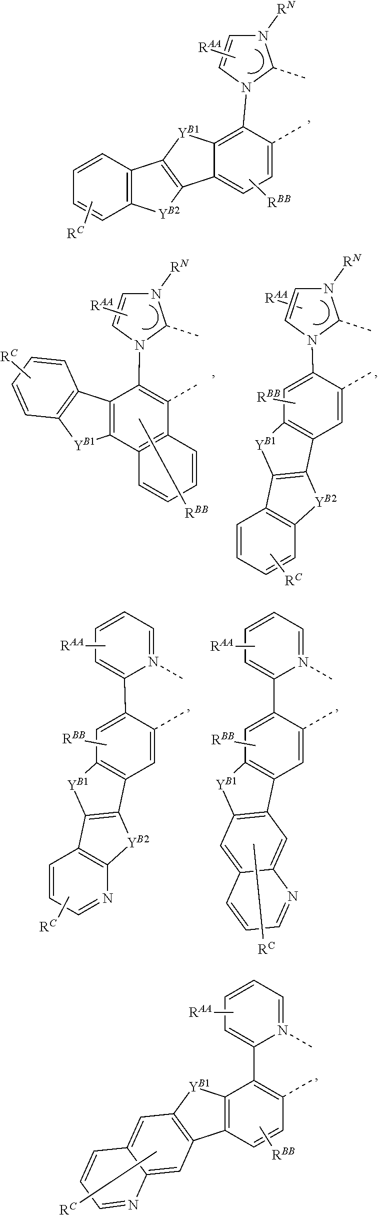

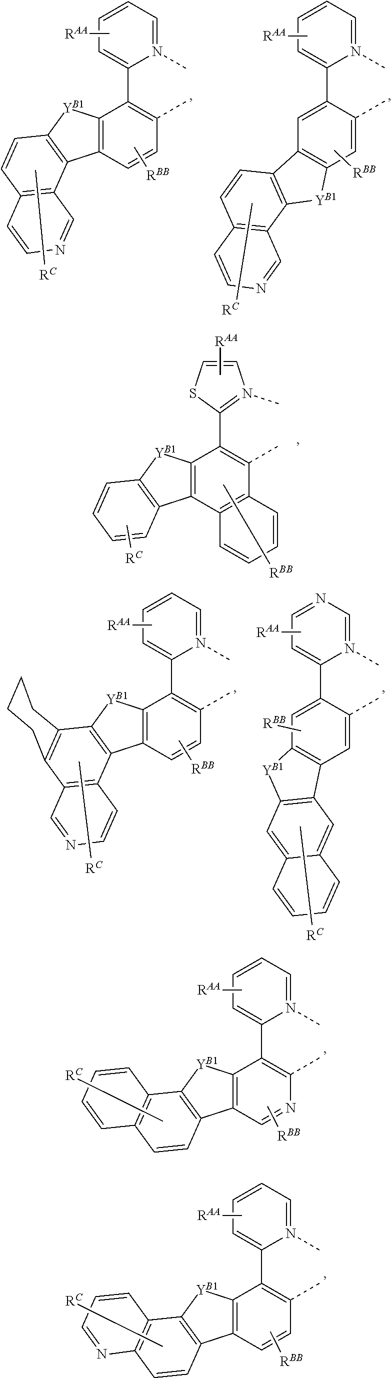

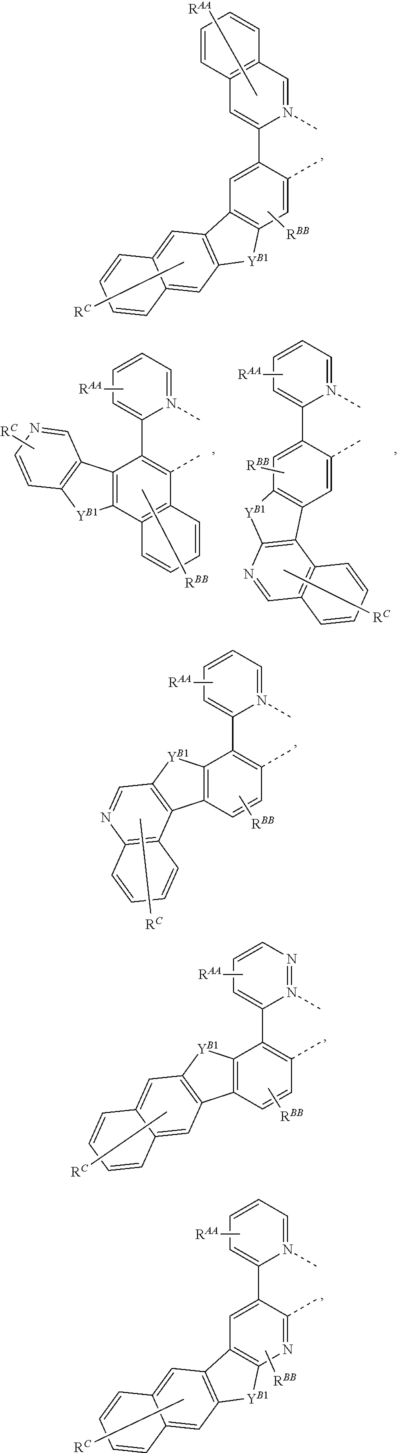

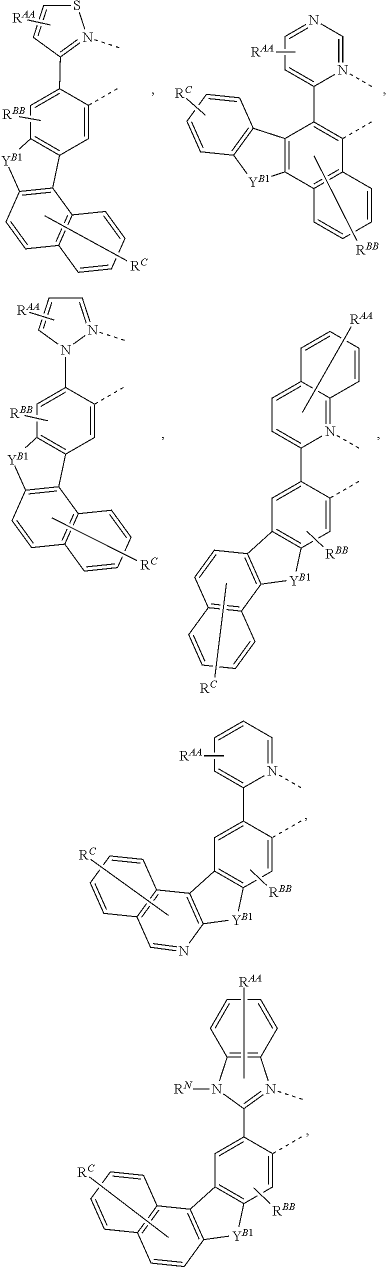

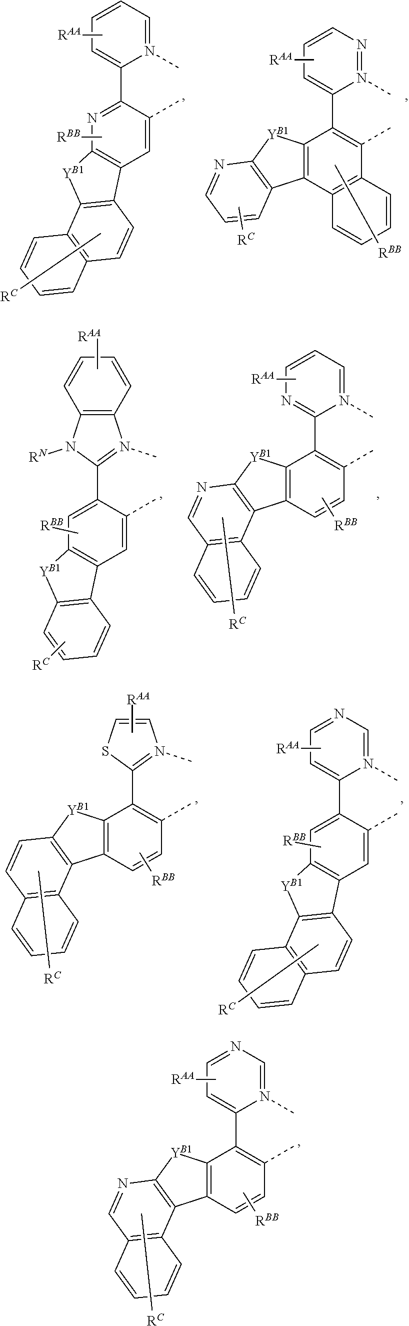

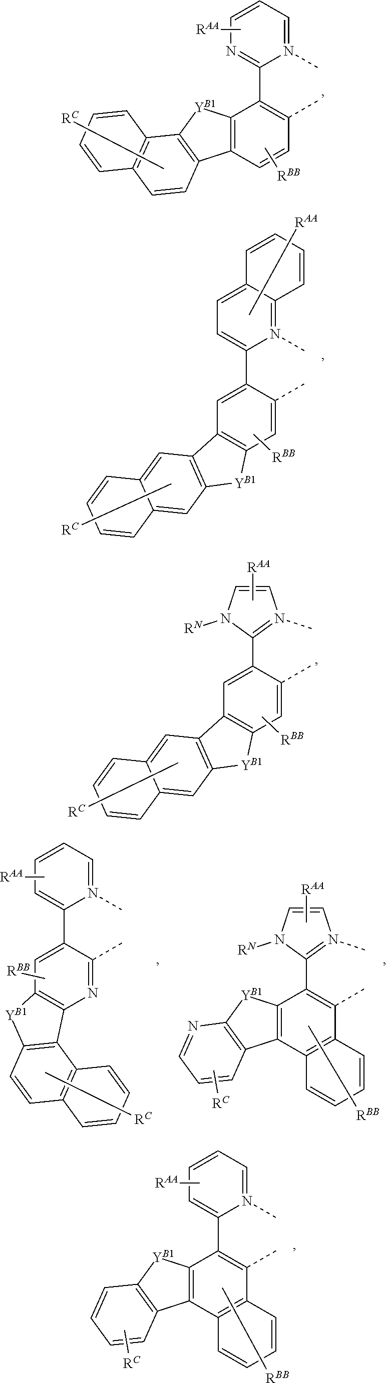

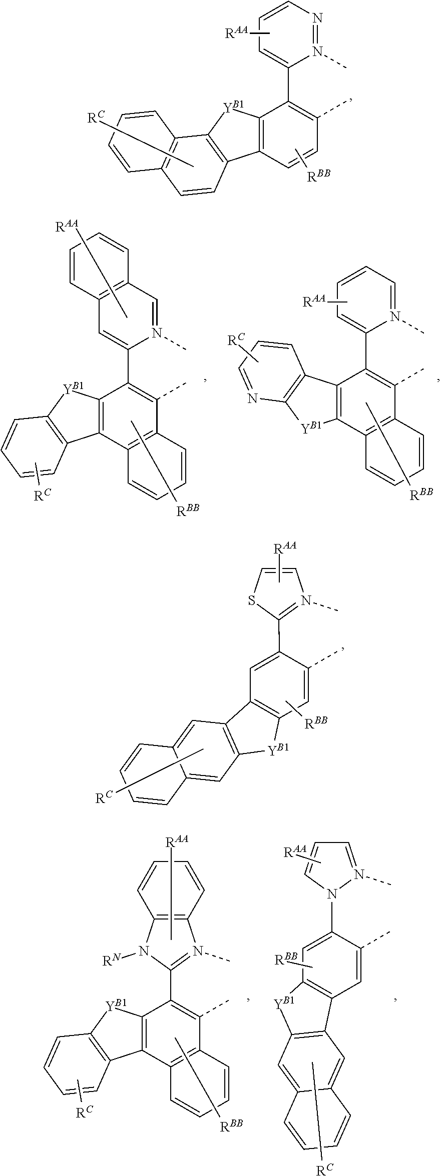

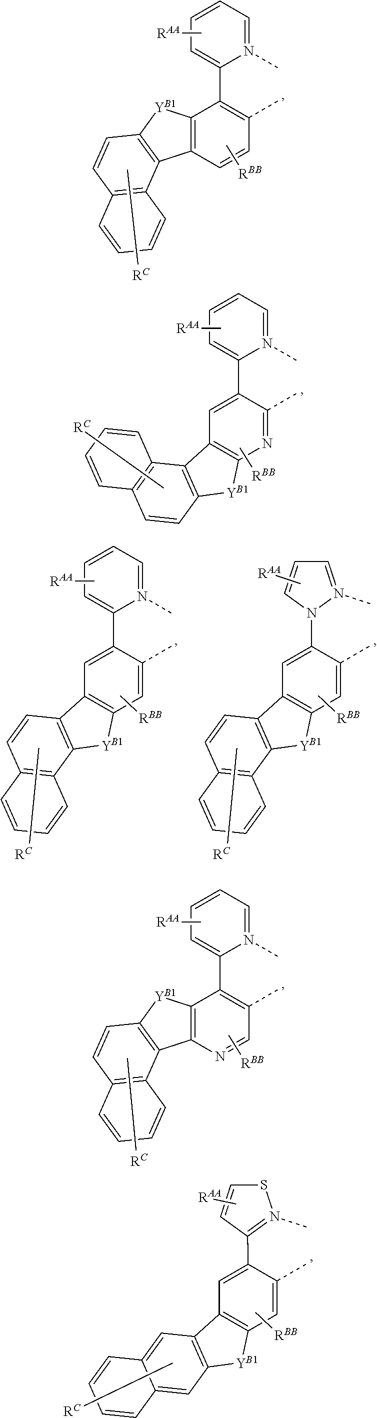

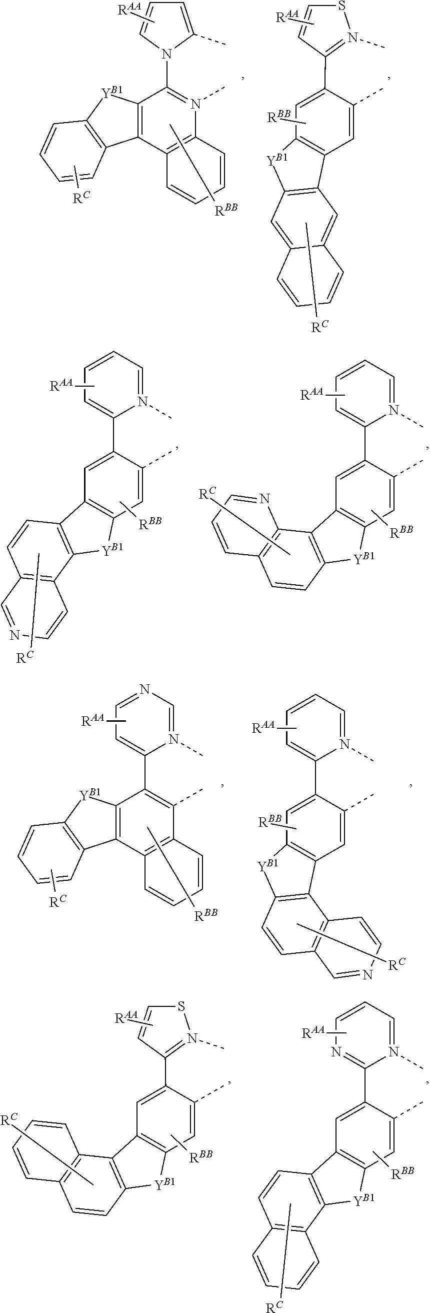

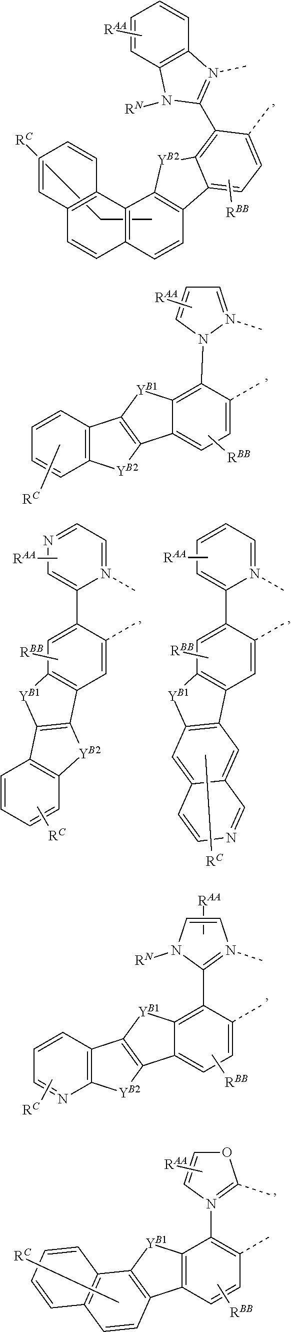

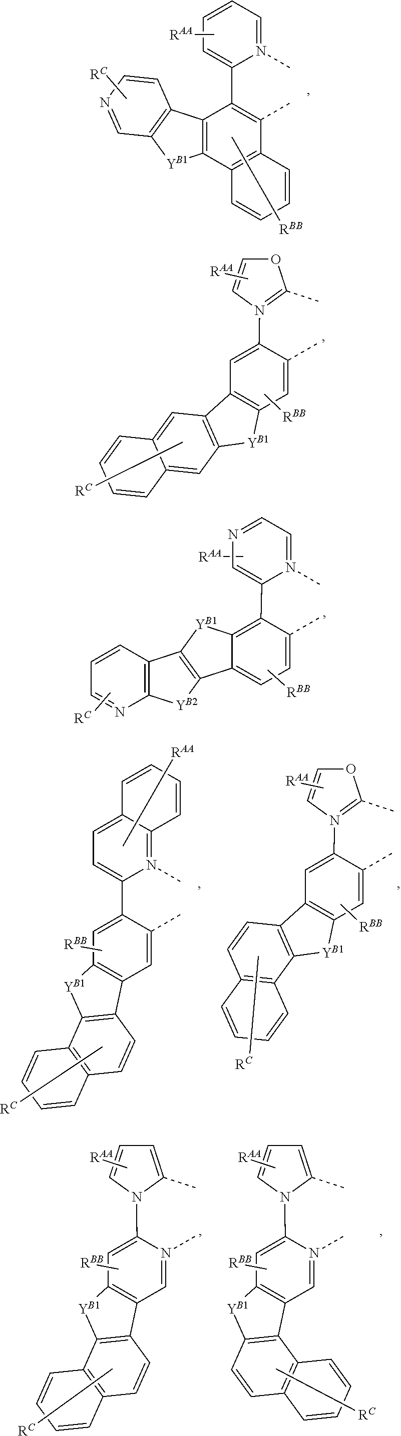

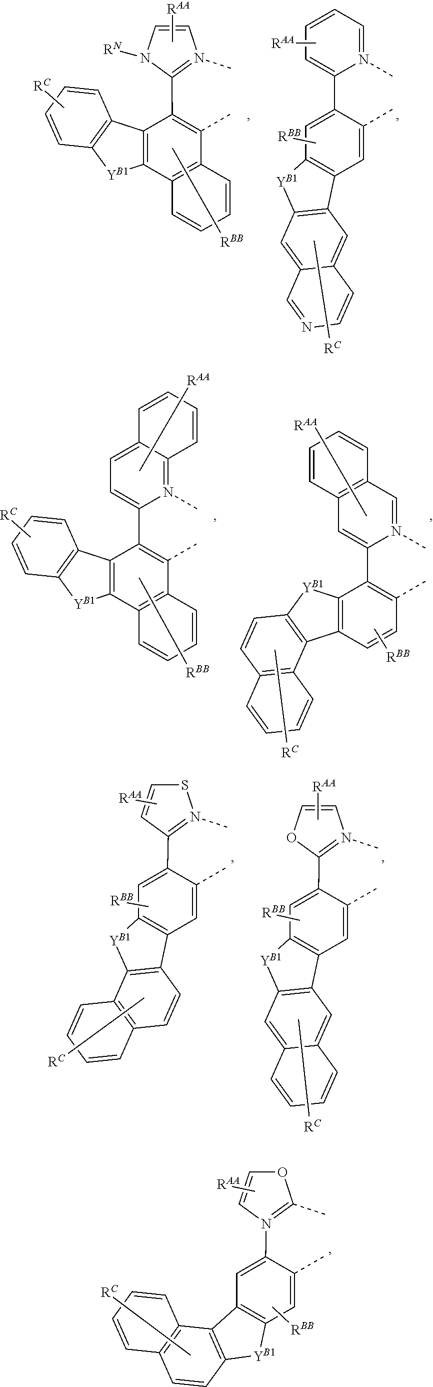

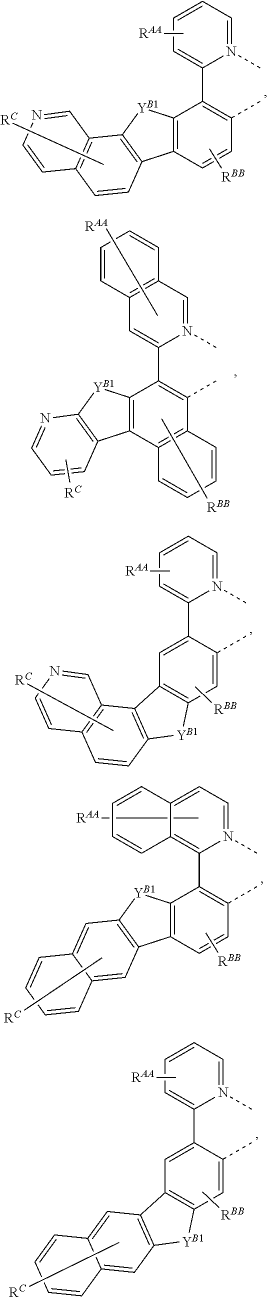

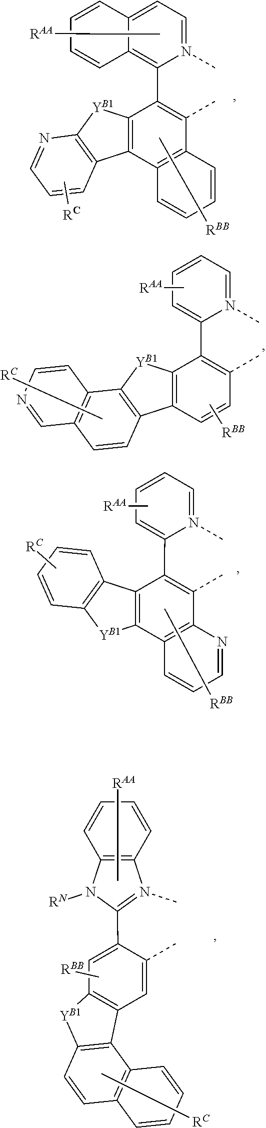

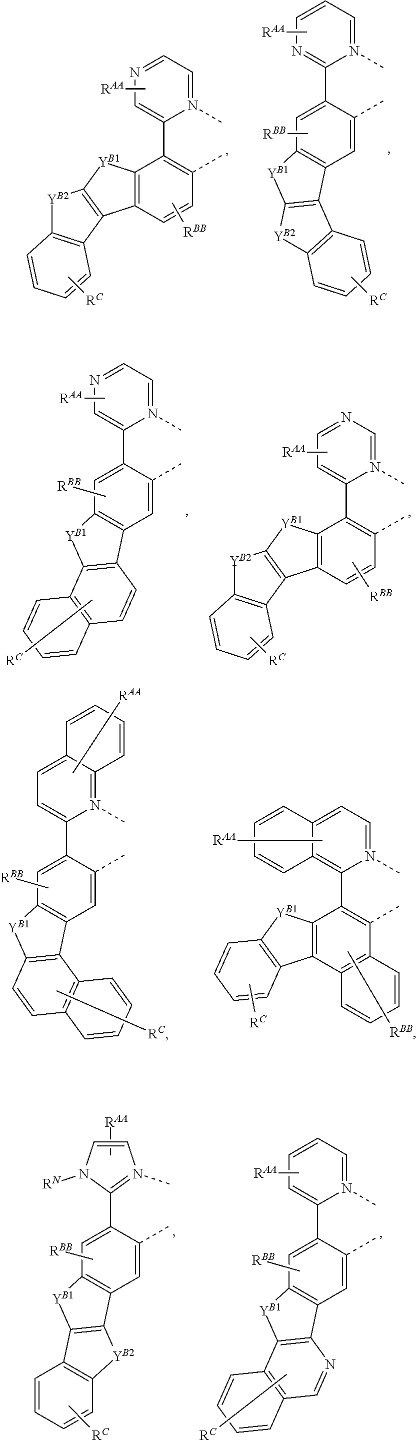

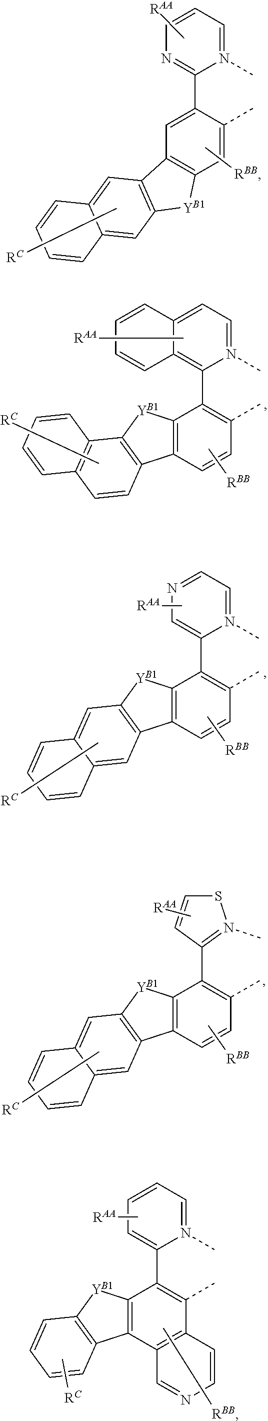

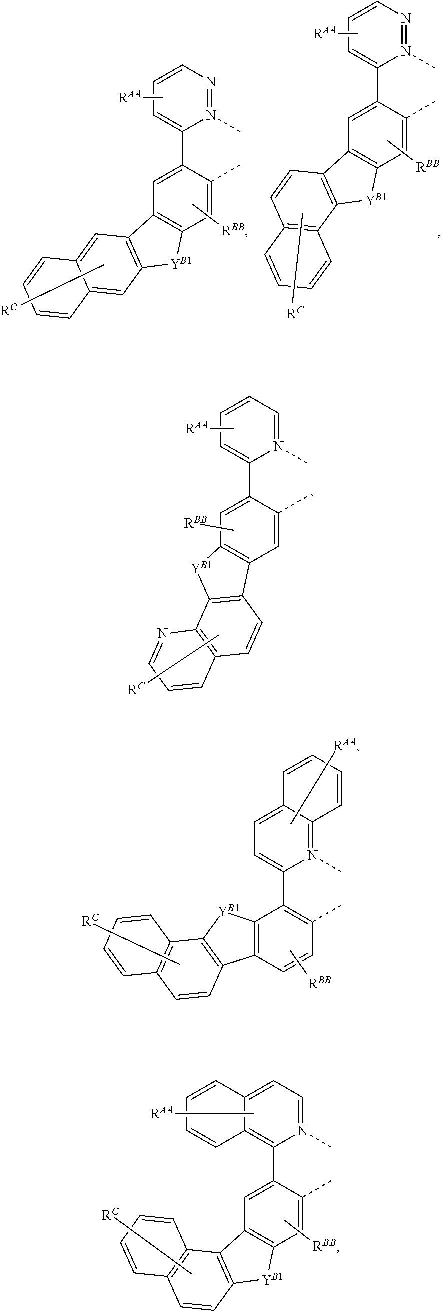

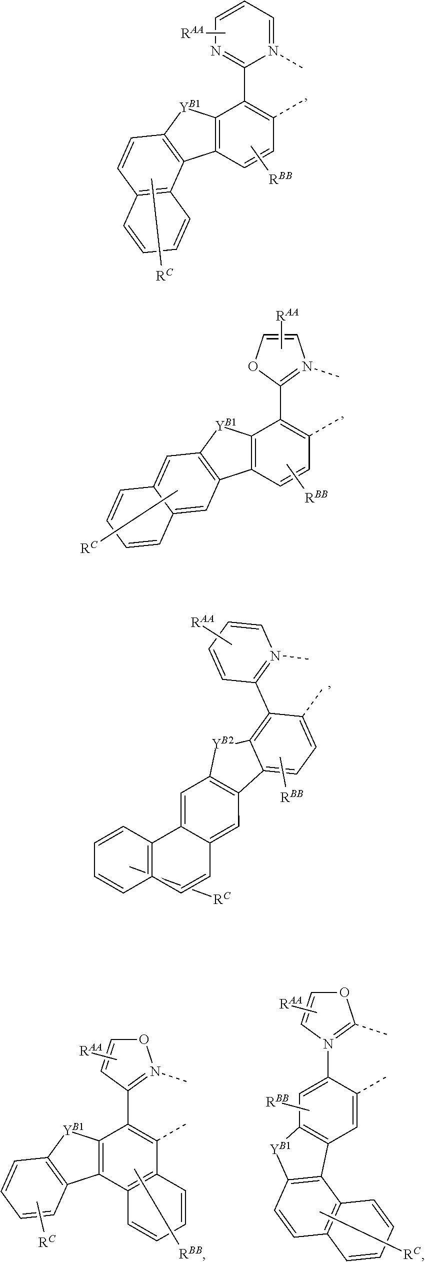

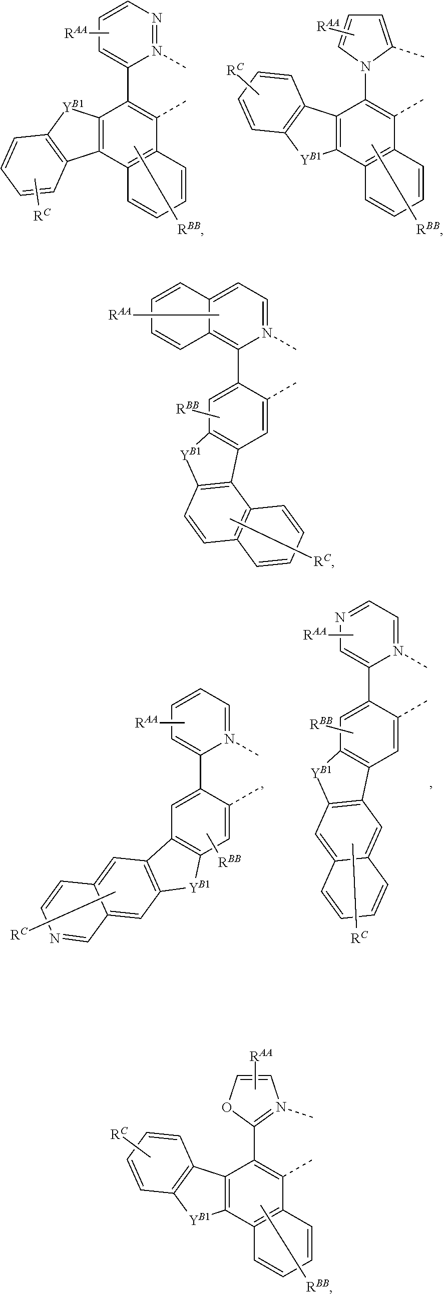

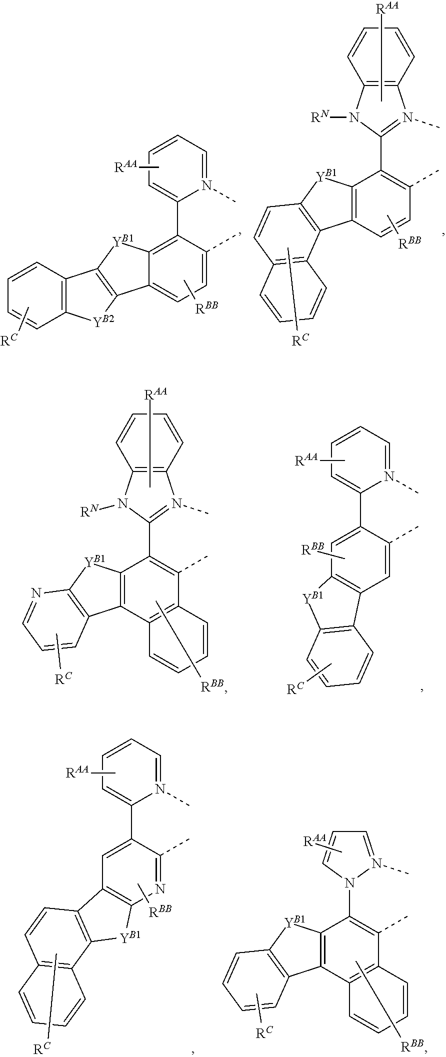

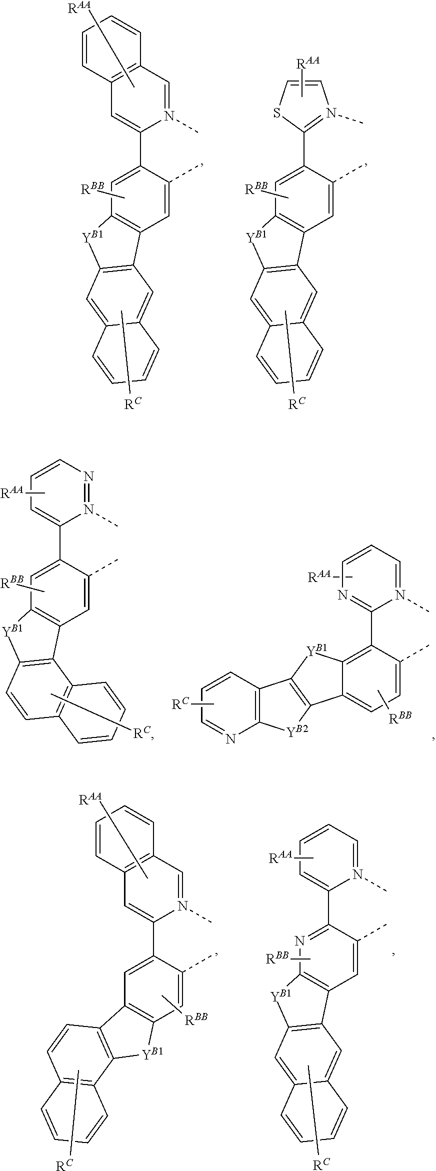

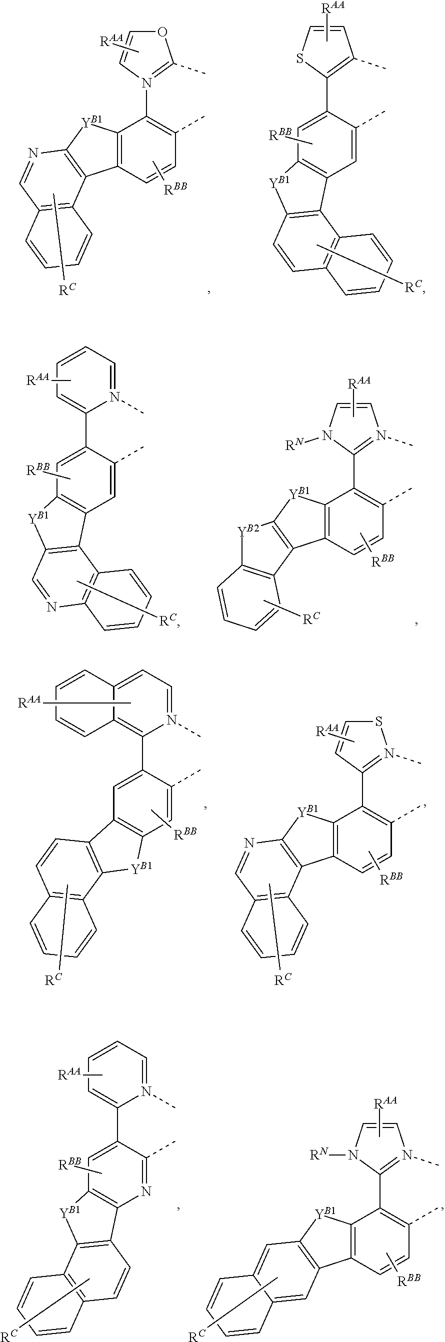

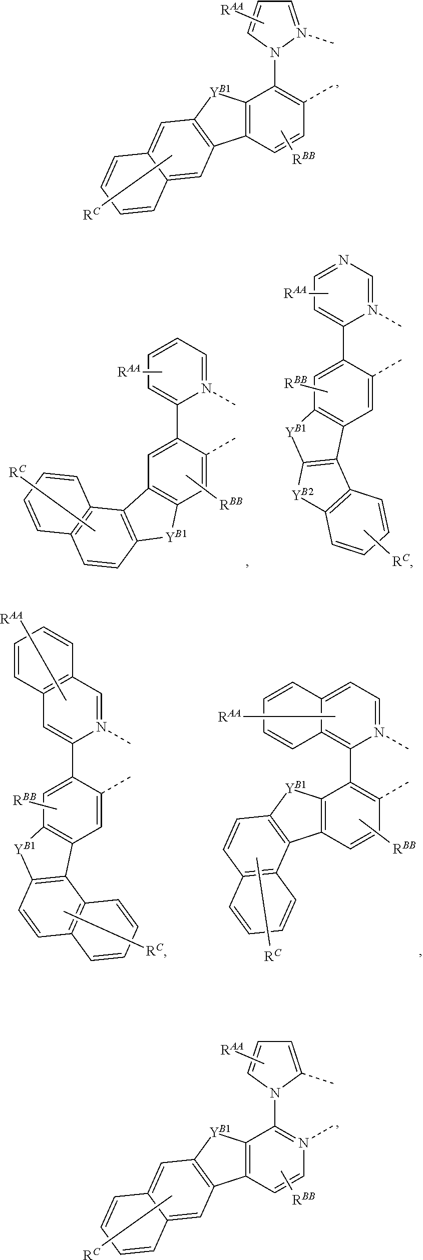

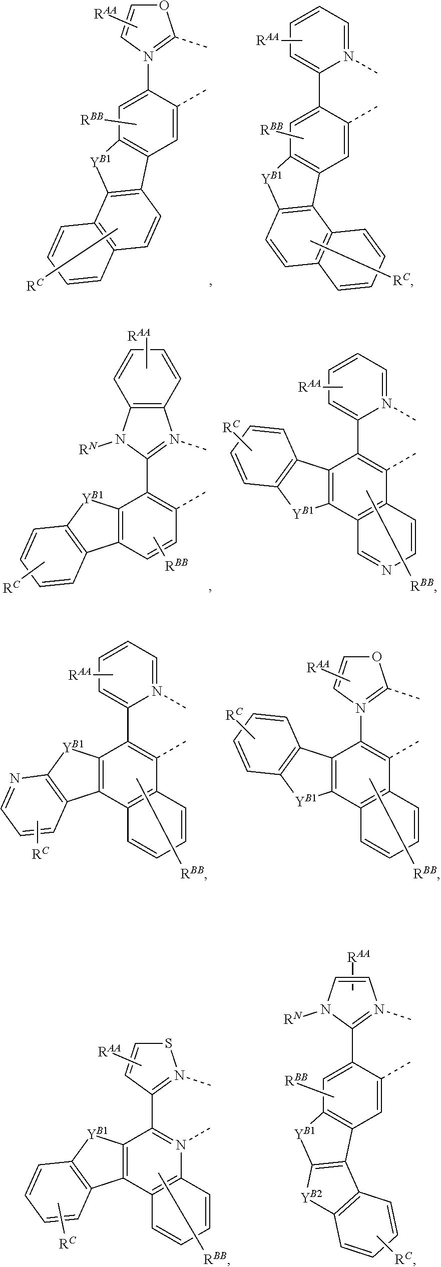

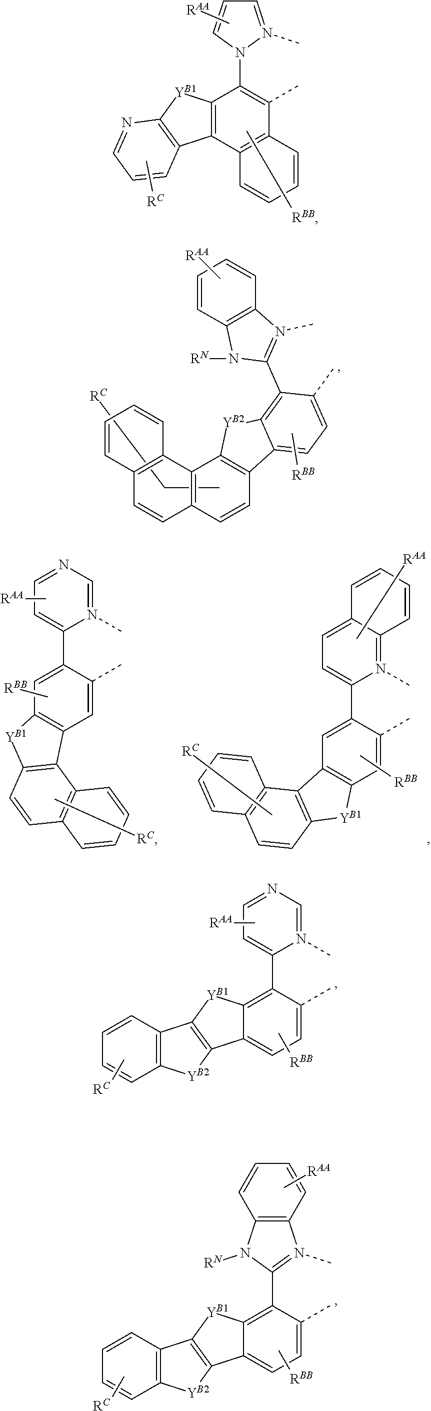

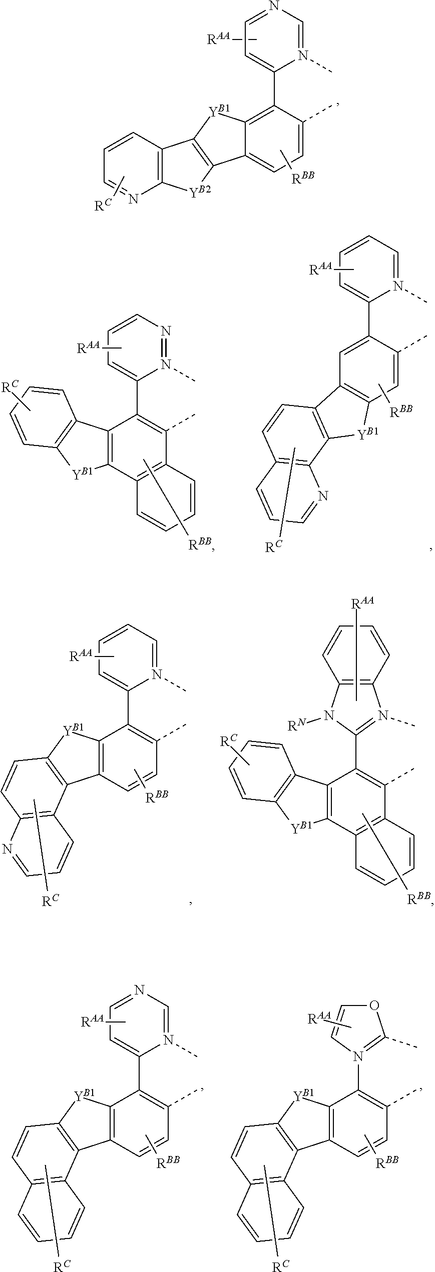

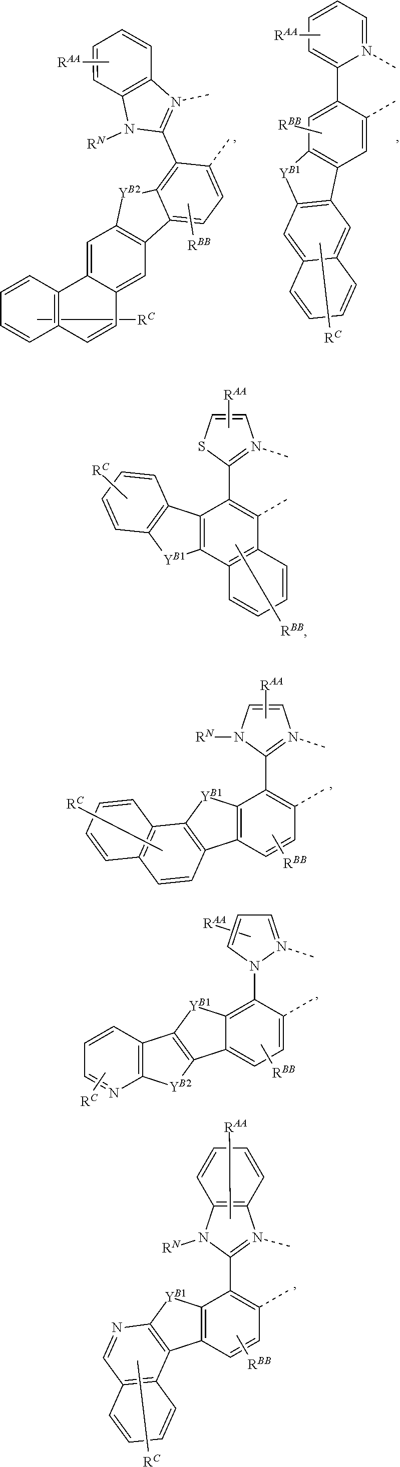

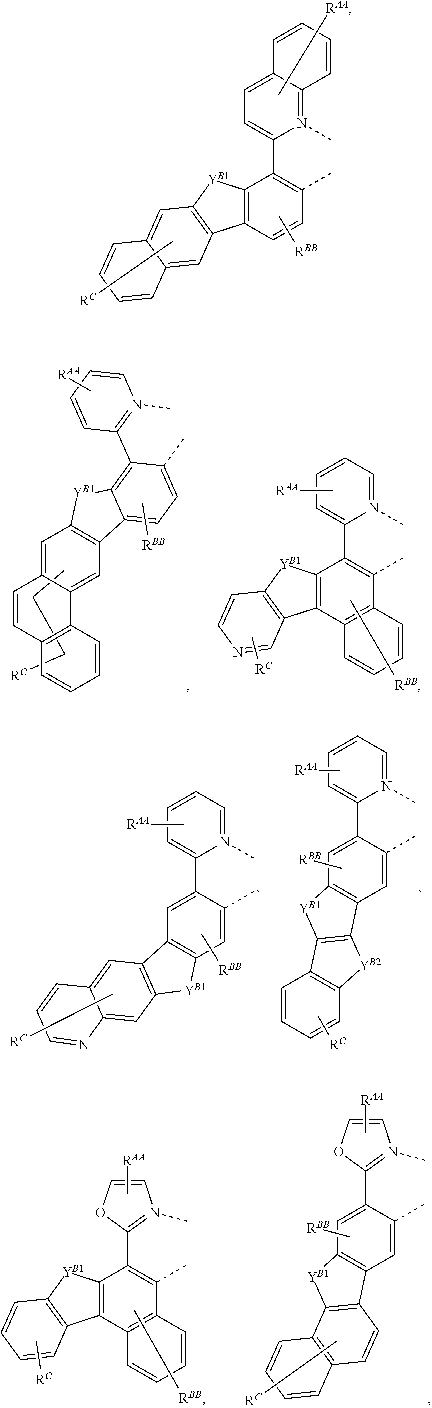

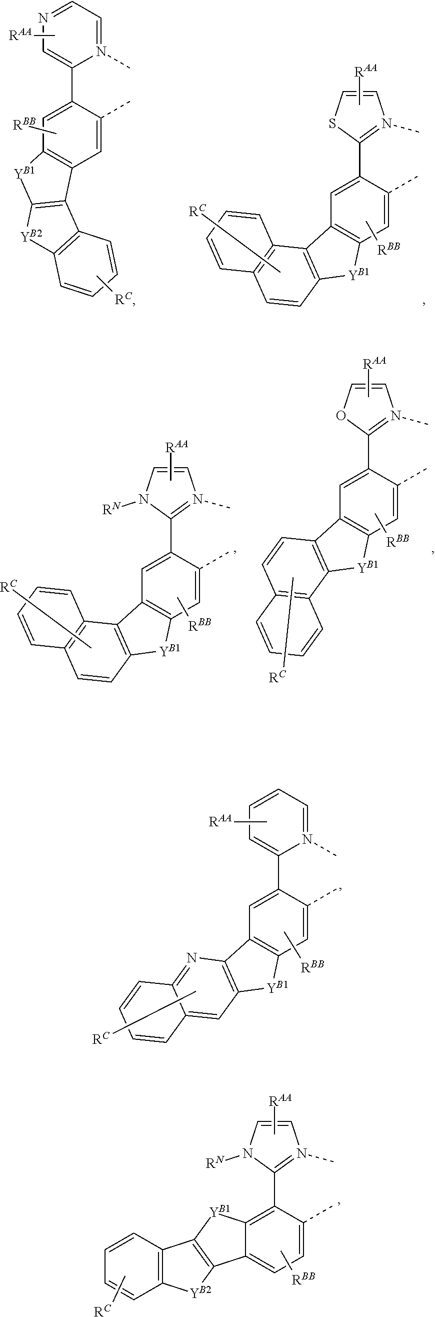

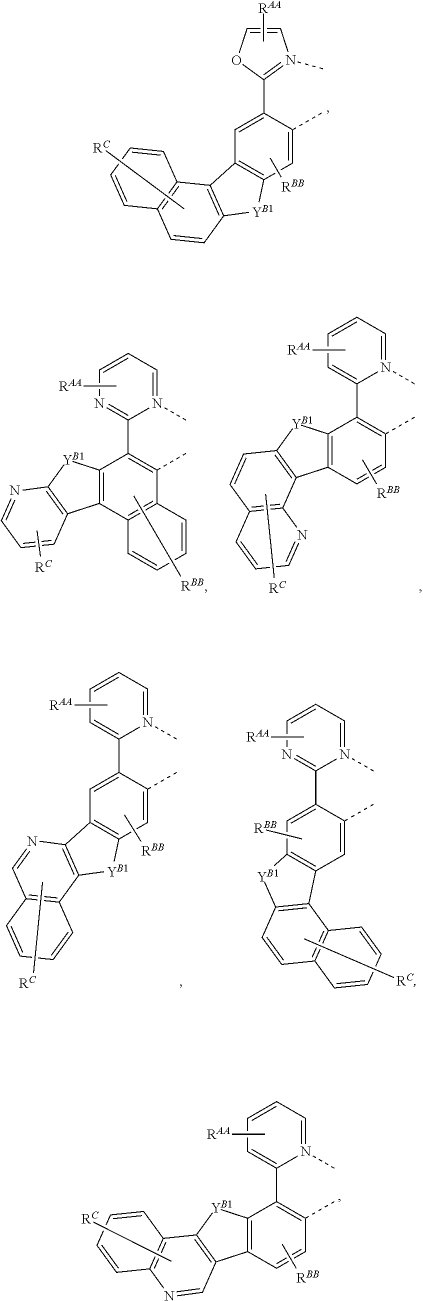

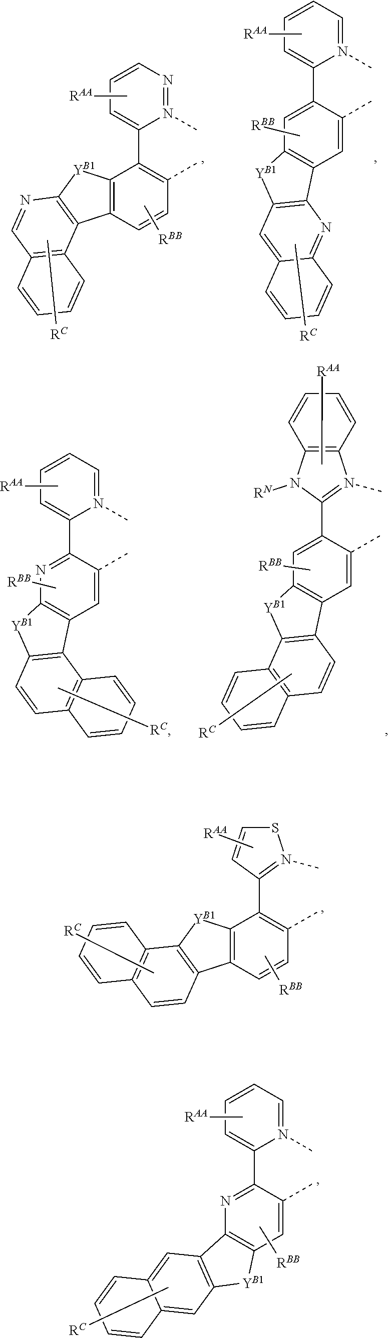

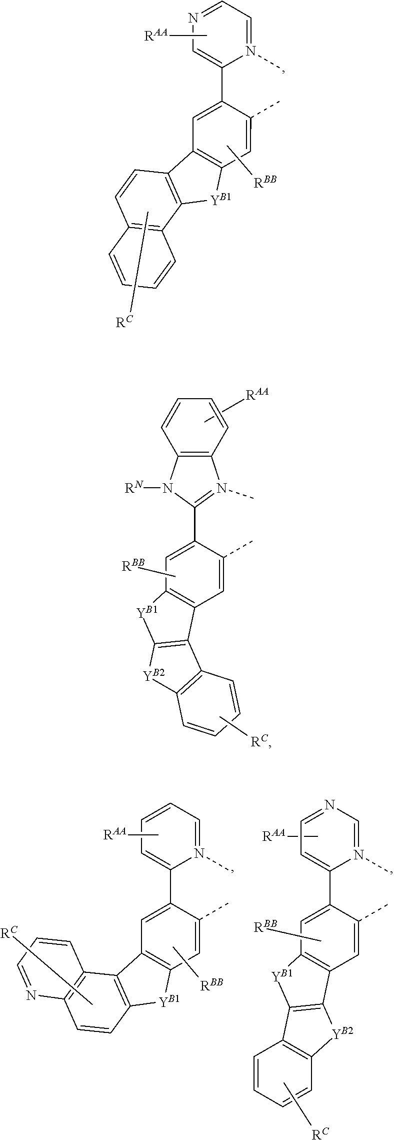

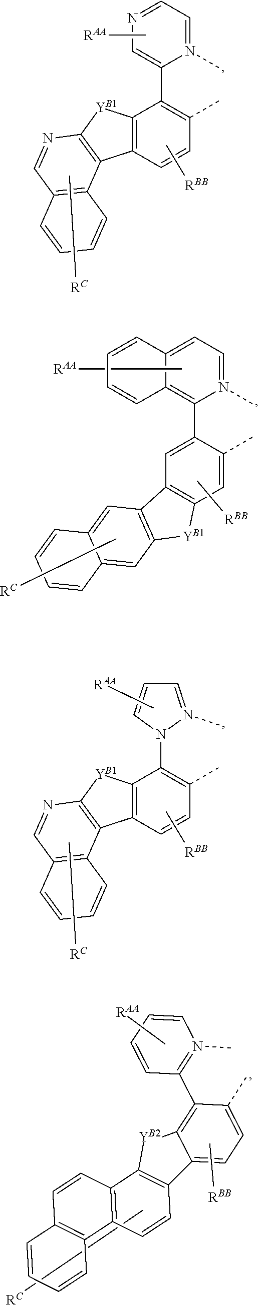

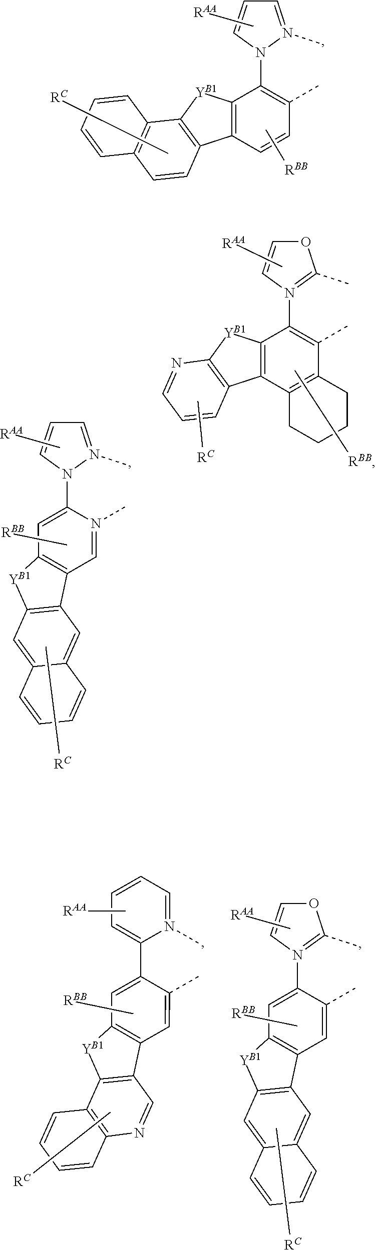

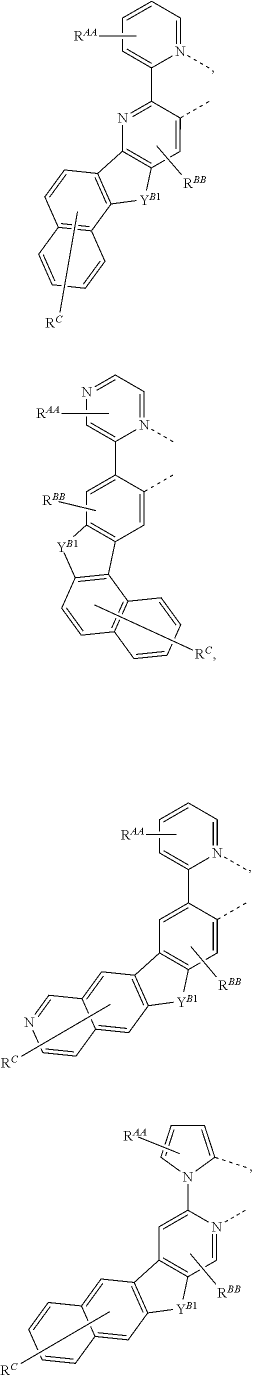

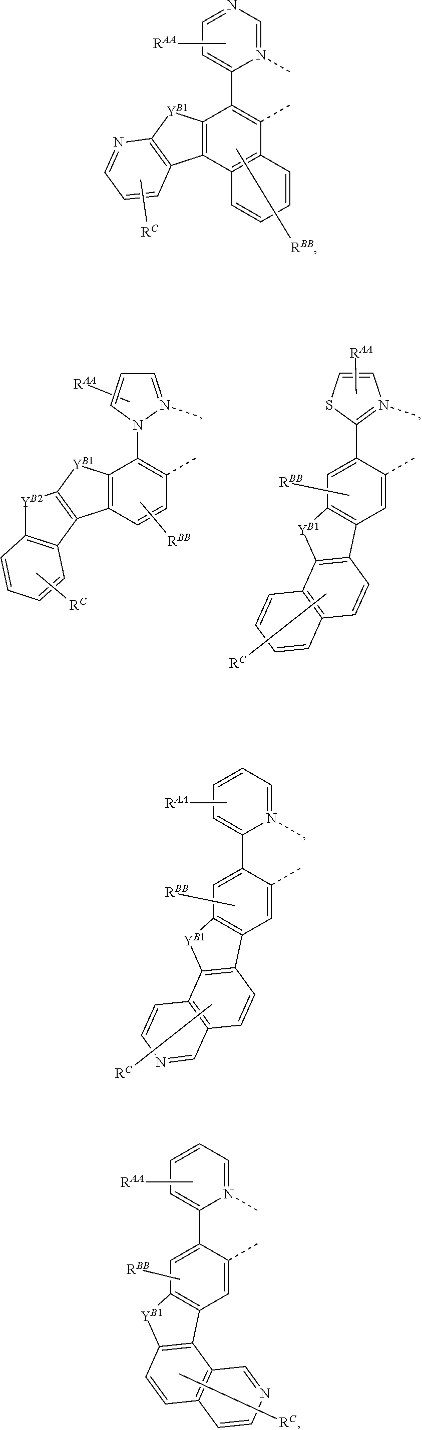

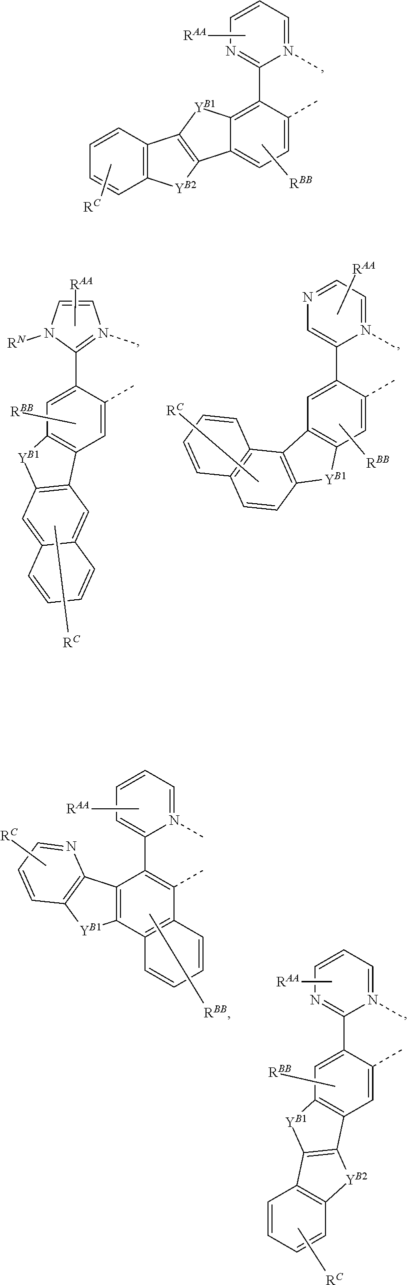

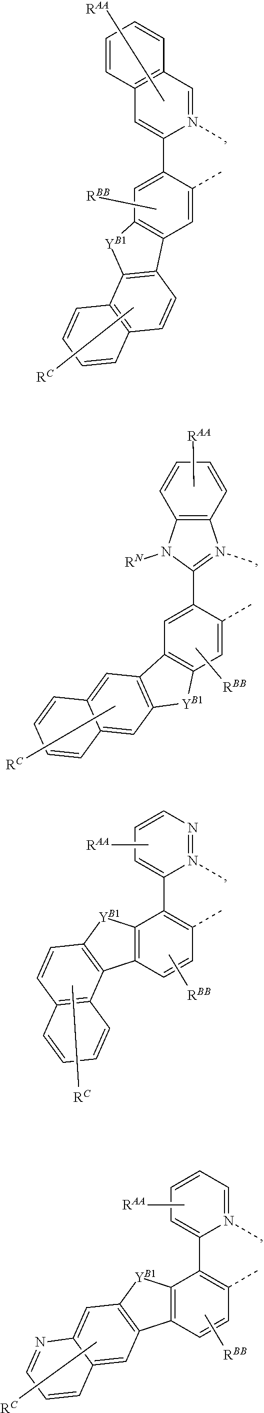

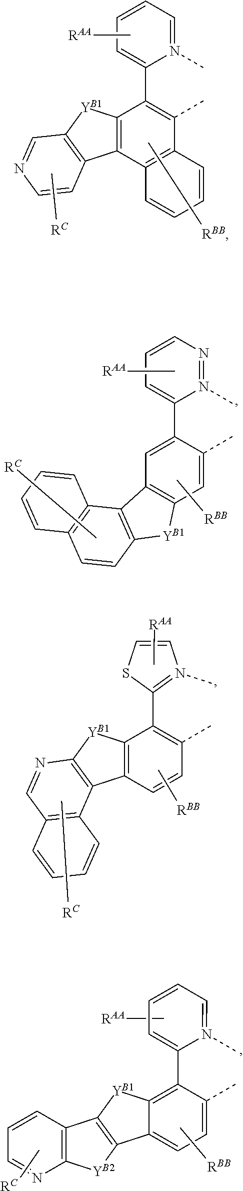

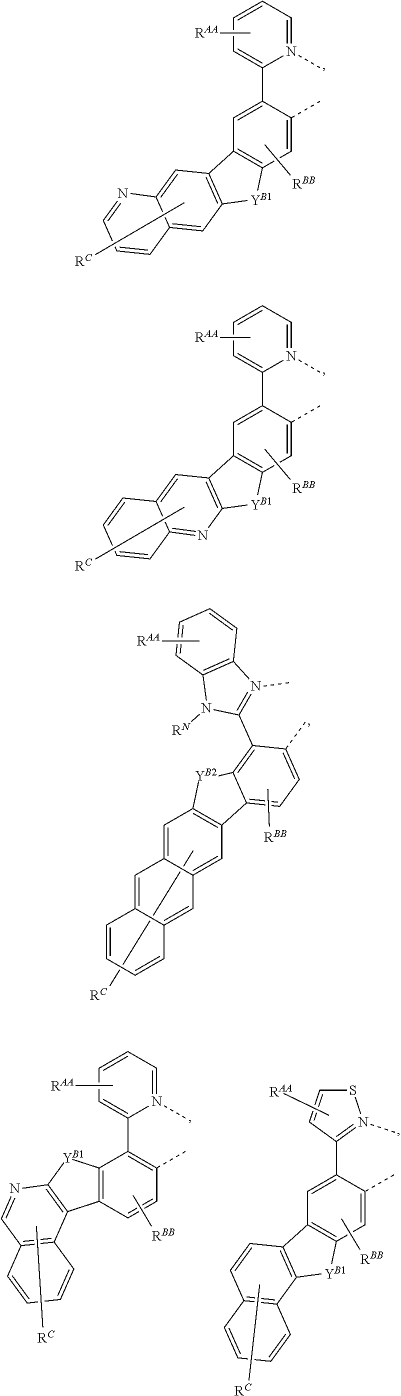

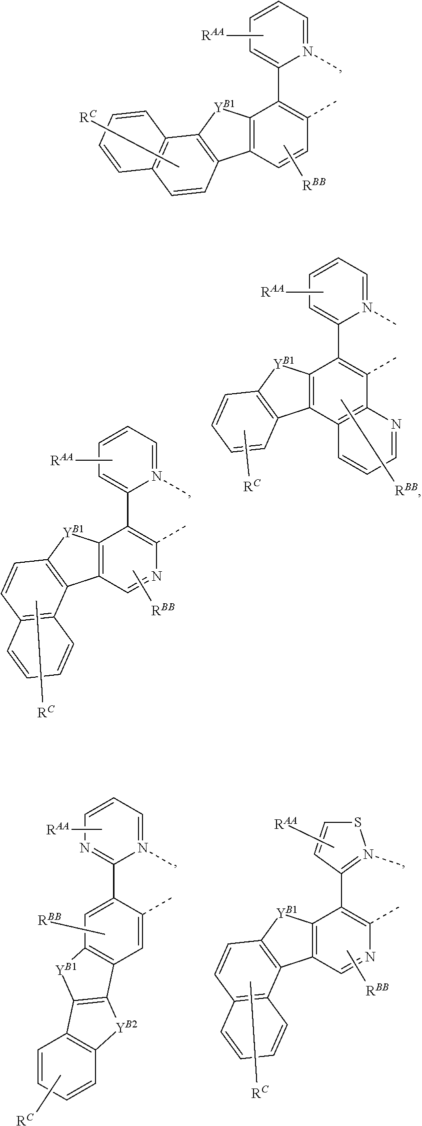

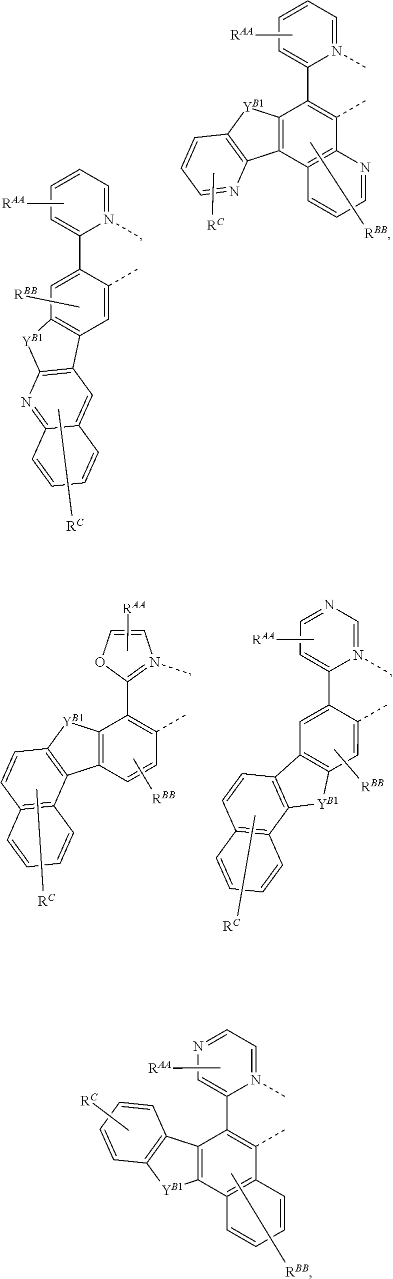

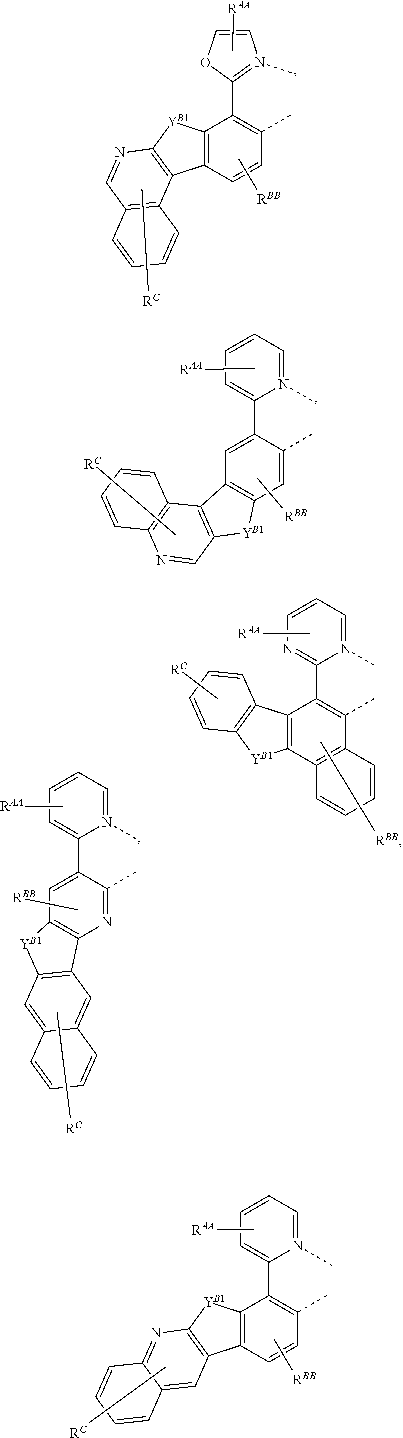

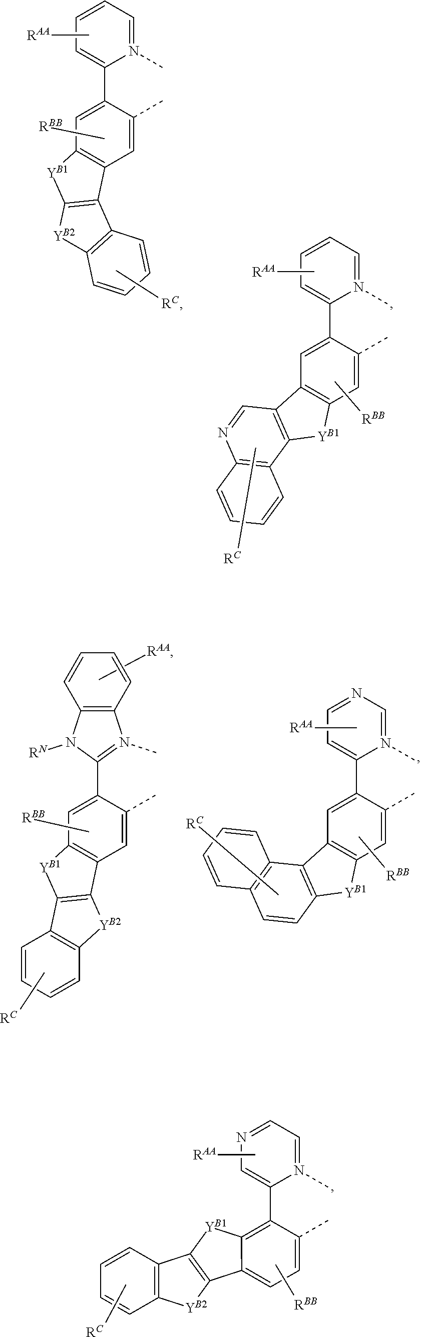

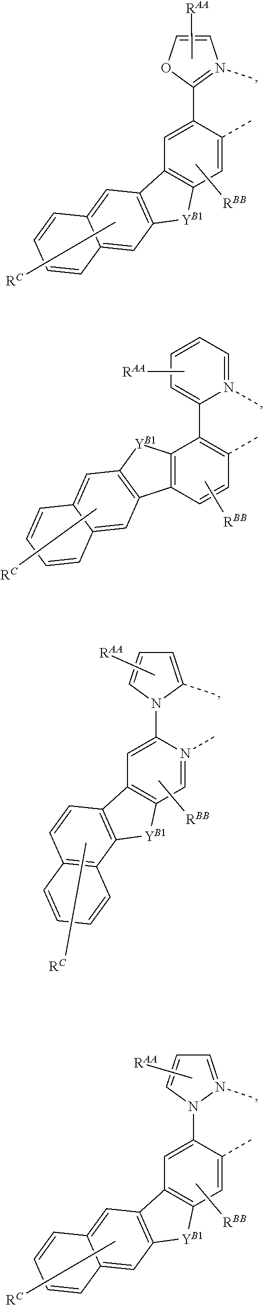

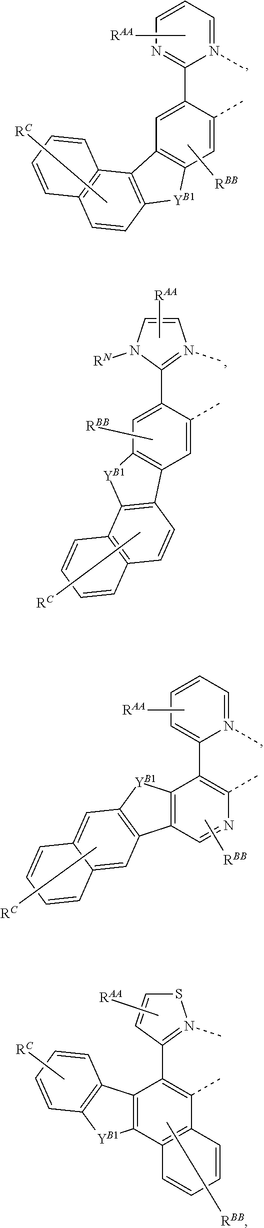

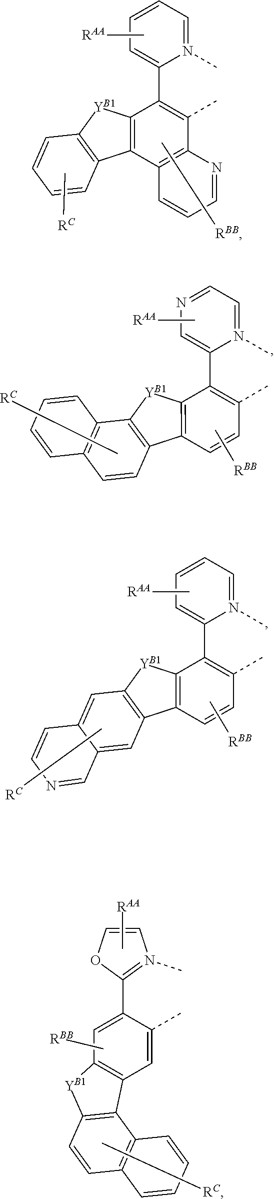

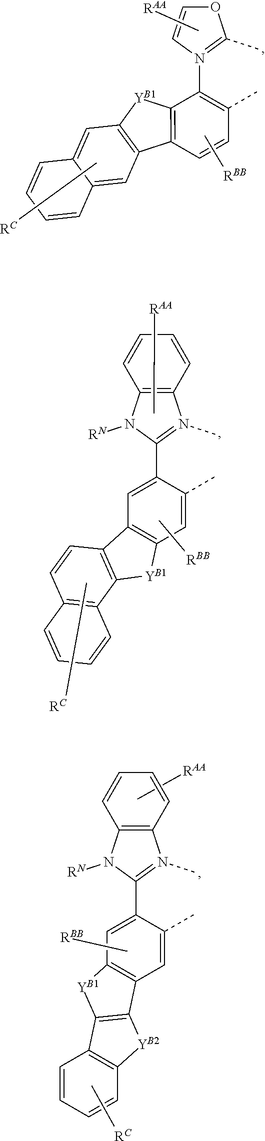

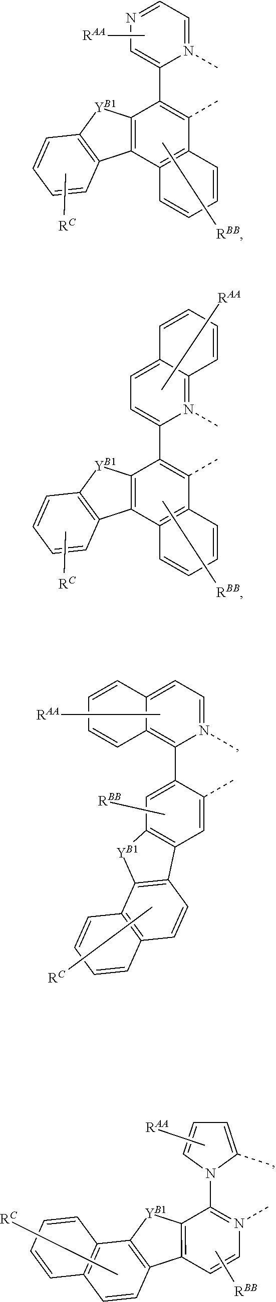

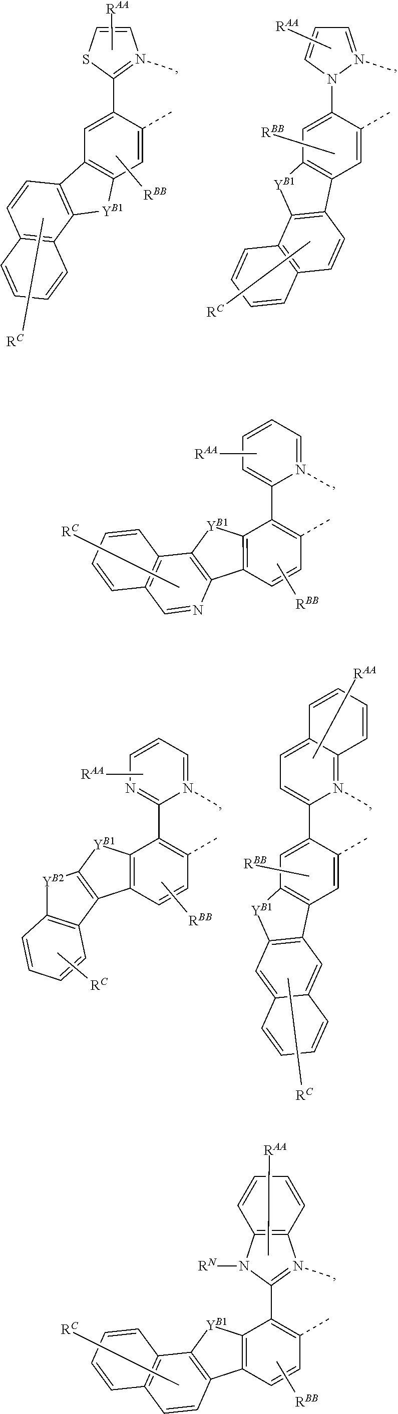

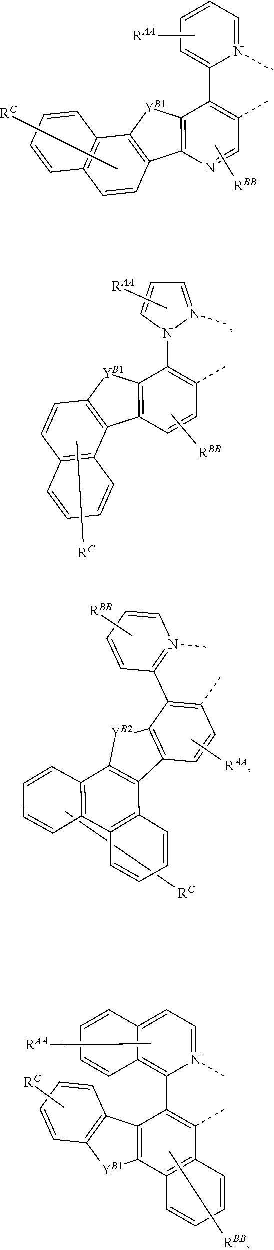

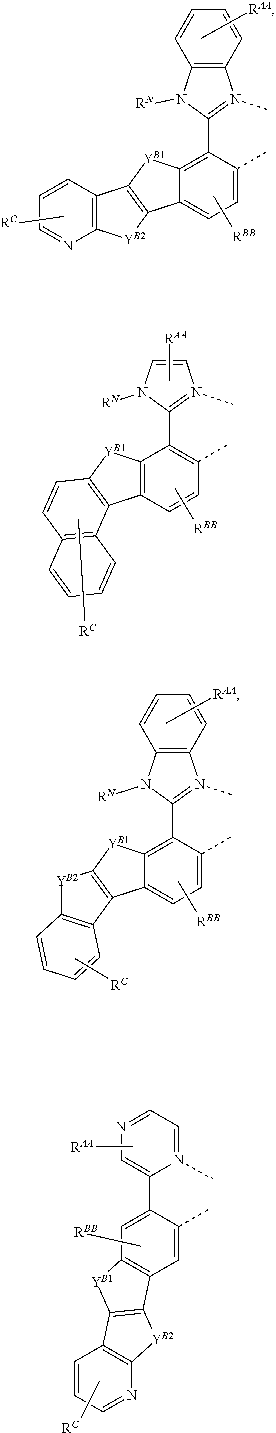

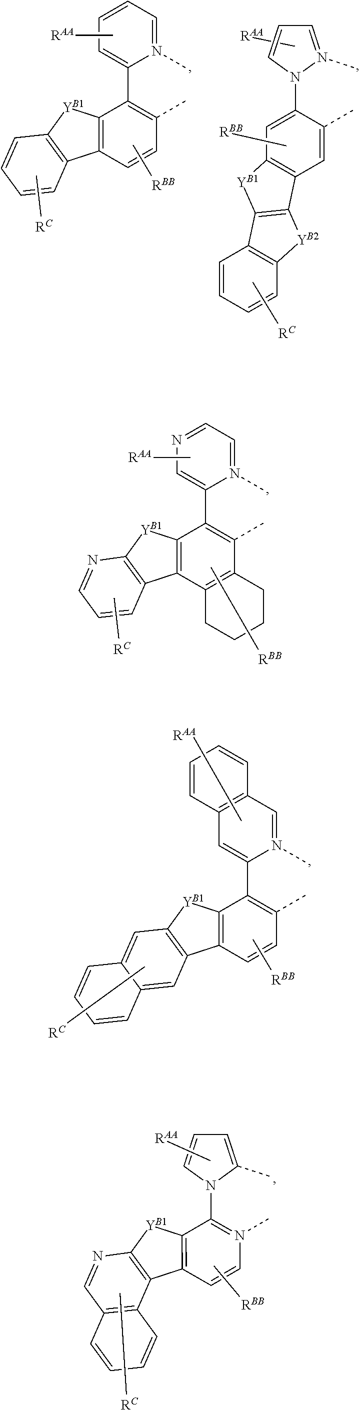

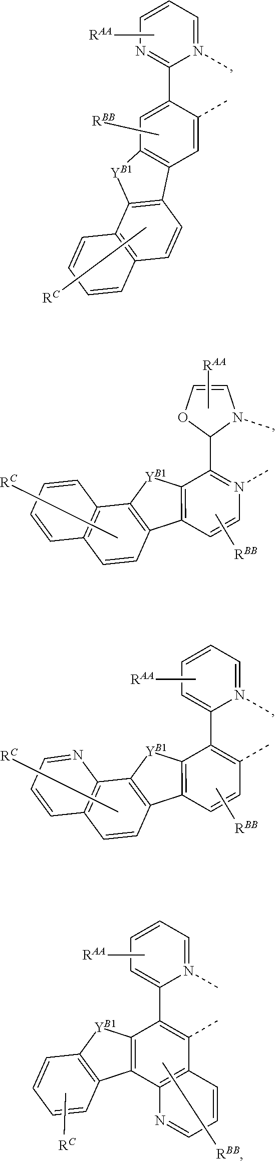

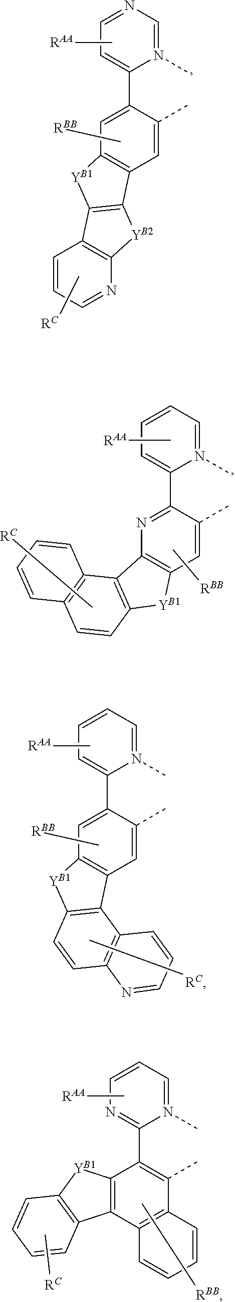

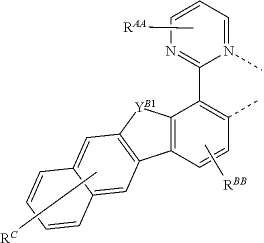

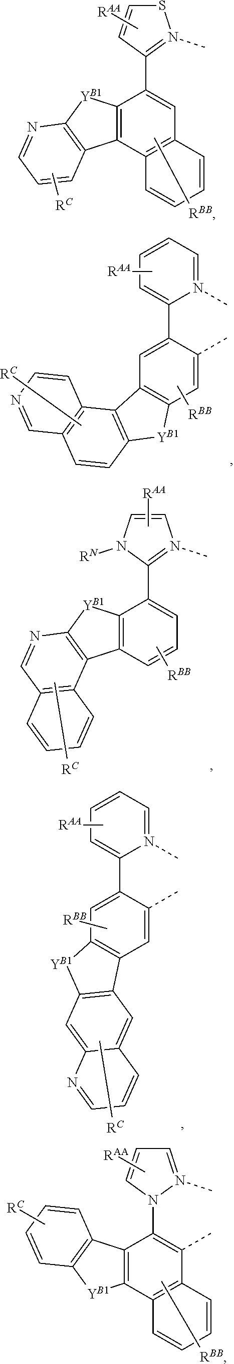

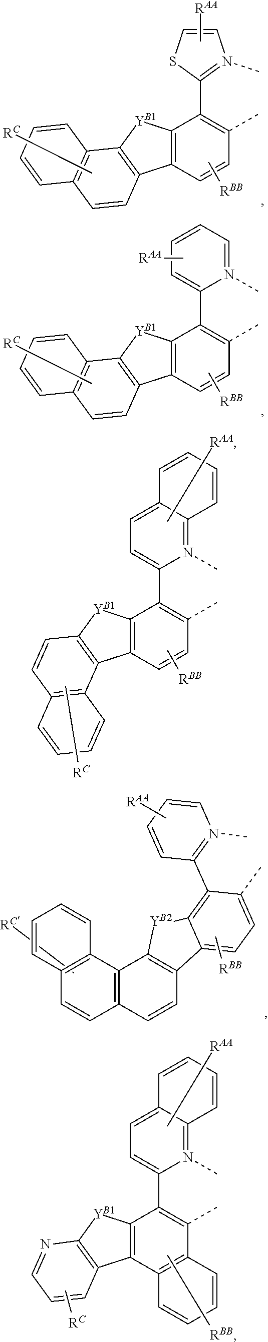

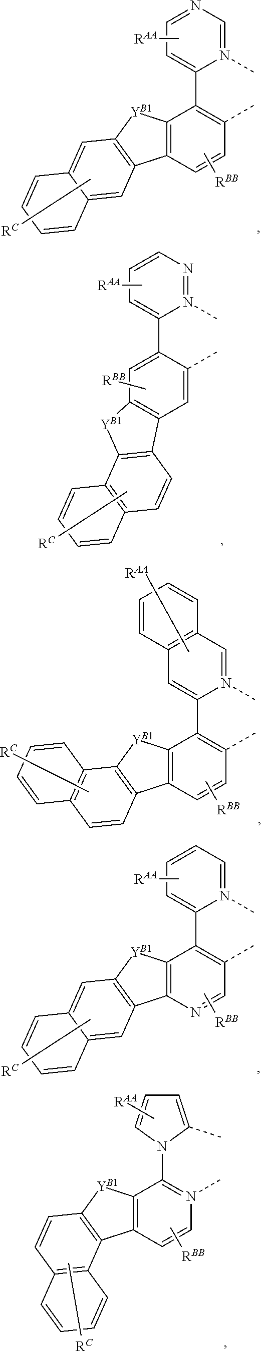

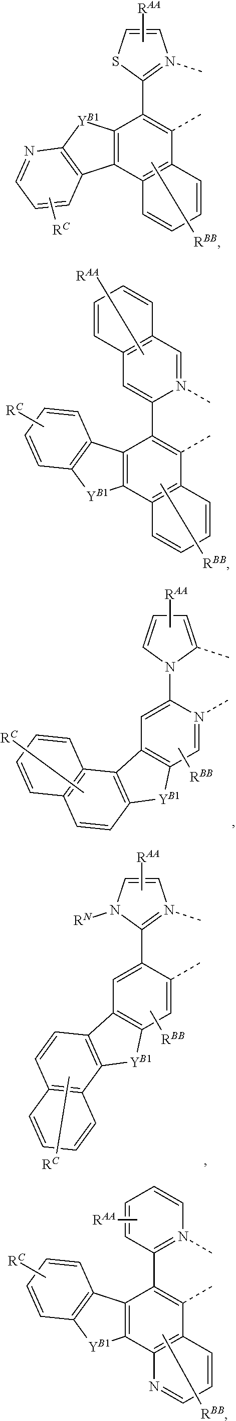

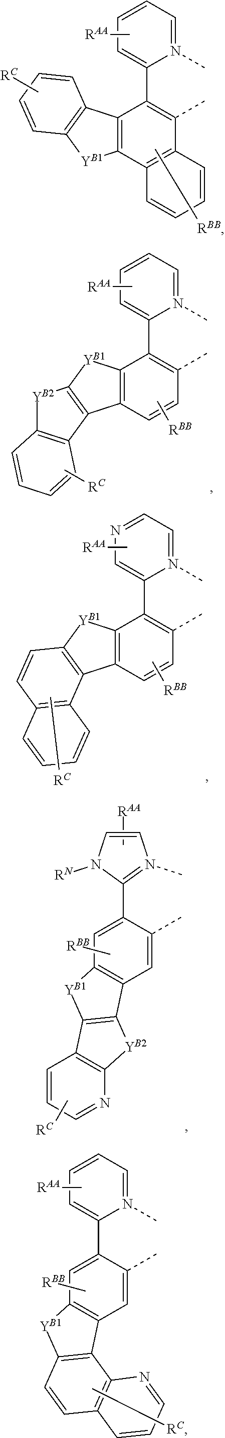

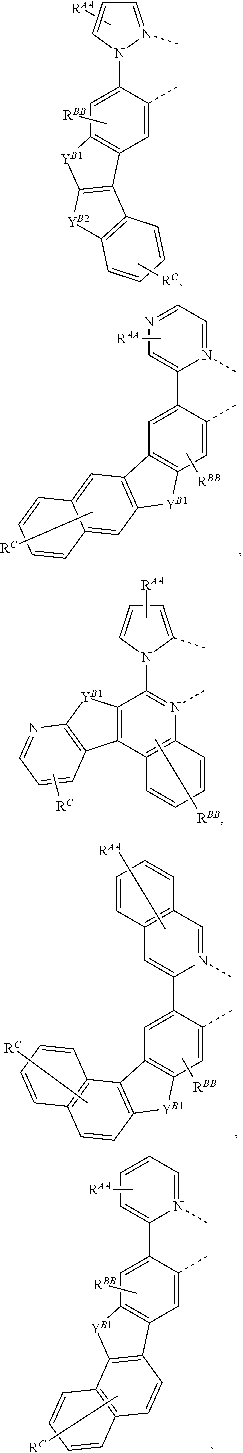

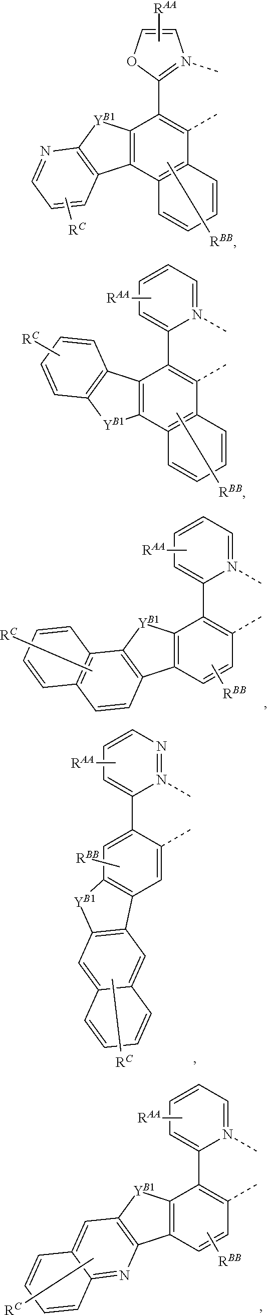

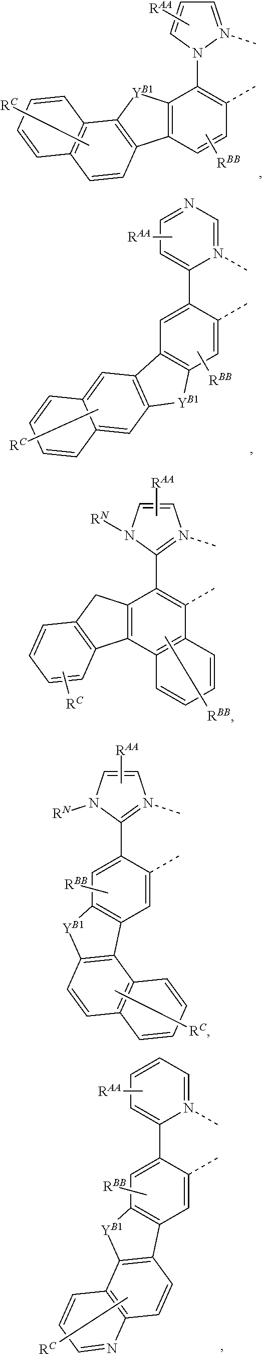

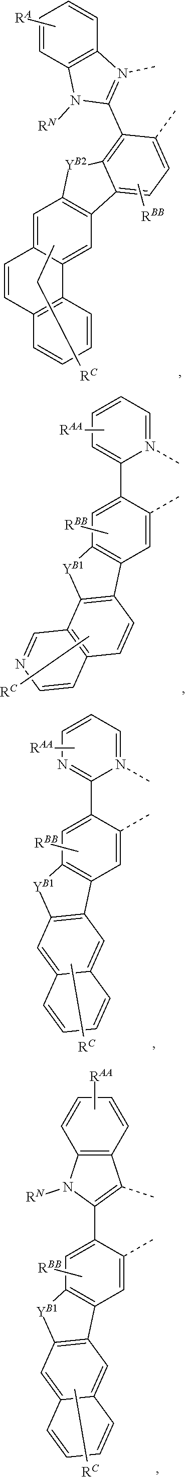

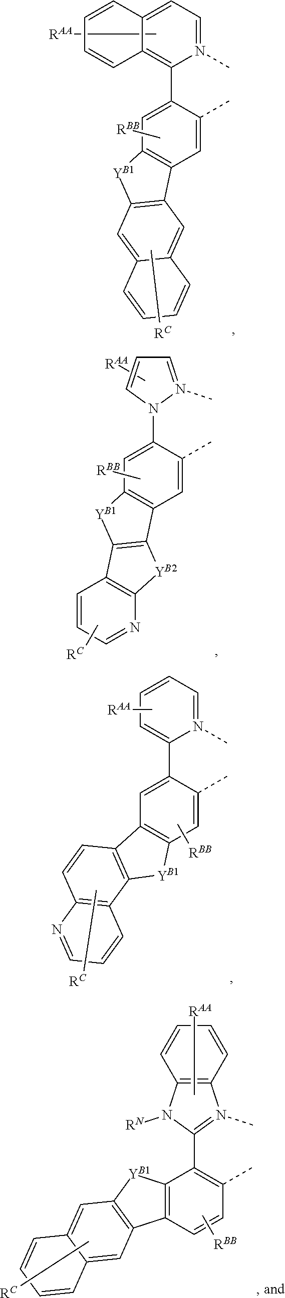

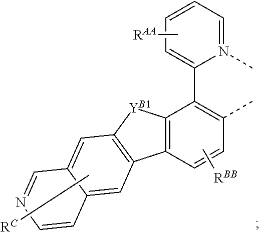

### Wherein:

each of Y^{B1} and Y^{B2} is independently selected from the group consisting of BR, BRR′, NR, PR, P(O)R, O, S, Se, C═O, C═S, C═Se, C═NR, C═CRR′, S═O, SO₂, CRR′, SiRR′, and GeRR′;
each of R^{AA}, R^{BB}, and R^{C} independently represents mono to the maximum allowable substitutions, or no substitutions; each R^{N}, R^{AA}, R^{BB}, and R^{C} is independently hydrogen, or a substituent selected from the group consisting of the General Substituents defined herein;
at least one of R^{BB} or R^{C} is selected from the group of structures in LIST 1, LIST 2, LIST 3, LIST 4, and LIST 5 described herein; and
any two substituents can be joined or fused to form a ring.

In some embodiments where ligand L_{A} is selected from LIST 8, at least one R^{AA}, R^{BB}, or R^{C} is selected from the group consisting of the General Substituents defined herein. In some embodiments, at least one R^{AA} is selected from the group consisting of the General Substituents defined herein. In some embodiments, at least one R^{BB} is selected from the group consisting of the General Substituents defined herein. In some embodiments, at least one R^{C} is selected from the group consisting of the General Substituents defined herein. In some embodiments, at least one R^{AA}, R^{BB}, or R^{C} is selected from the group consisting of the Preferred General Substituents defined herein.

In some embodiments, where ligand L_{A} is selected from LIST 8, at least one of R^{AA}, R^{BB}, or R^{C} is partially or fully deuterated. In some embodiments, at least one R^{AA} is partially or fully deuterated. In some embodiments, at least one R^{BB} is partially or fully deuterated. In some embodiments, at least one R^{C} is partially or fully deuterated.

In some embodiments where ligand L_{A} is selected from LIST 8, two R^{AA} are joined to form a fused ring. In some such embodiments, the fused ring may be benzene, pyridine, pyrimidine, pyridazine, pyrazine, triazine, imidazole, imidazole derived carbene, pyrazole, pyrrole, oxazole, furan, thiophene, thiazole, or triazole. In some such embodiments, the fused ring may be benzene. In some embodiments, Y^{B1} is O.

In some embodiments where ligand L_{A} is selected from LIST 8, RN is or comprises a structure of Formula XA, Formula XB, or Formula XC as described herein. In such embodiments, all the Formula XA, Formula XB, or Formula XC related embodiments can be equally applied here.

In some embodiments where ligand L_{A} is selected from LIST 8, at least one R^{AA} is or comprises an electron-withdrawing group from the EWG1 LIST as defined herein. In some embodiments, at least one R^{AA} is or comprises an electron-withdrawing group from the EWG2 LIST as defined herein. In some embodiments, at least one R^{AA} is or comprises an electron-withdrawing group from the EWG3 LIST as defined herein. In some embodiments, at least one R^{AA} is or comprises an electron-withdrawing group from the EWG4 LIST as defined herein. In some embodiments, at least one R^{AA} is or comprises an electron-withdrawing group from the Pi-EWG LIST as defined herein.

In some embodiments where ligand L_{A} is selected from LIST 8, at least one R^{BB} is or comprises an electron-withdrawing group from the EWG1 LIST as defined herein. In some embodiments, at least one R^{BB} is or comprises an electron-withdrawing group from the EWG2 LIST as defined herein. In some embodiments, at least one R^{BB} is or comprises an electron-withdrawing group from the EWG3 LIST as defined herein. In some embodiments, at least one R^{BB} is or comprises an electron-withdrawing group from the EWG4 LIST as defined herein. In some embodiments, at least one R^{BB} is or comprises an electron-withdrawing group from the Pi-EWG LIST as defined herein.

In some embodiments where ligand L_{A} is selected from LIST 8, at least one R^{C} is or comprises an electron-withdrawing group from the EWG1 LIST as defined herein. In some embodiments, at least one R^{C} is or comprises an electron-withdrawing group from the EWG2 LIST as defined herein. In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined herein.

The some embodiments, the ligand L_{A} is selected from the group consisting of the structures of the following LIST 9:

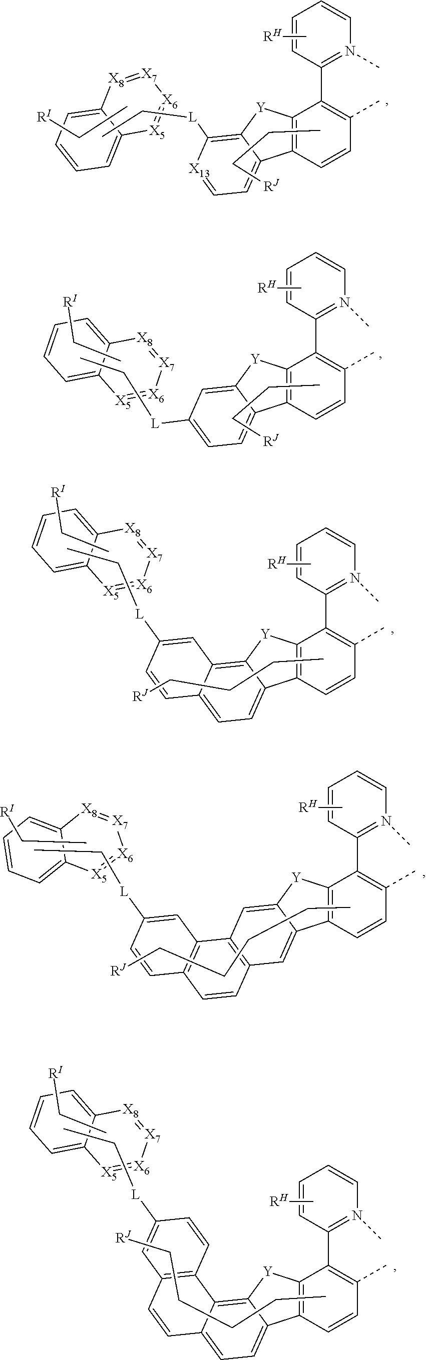

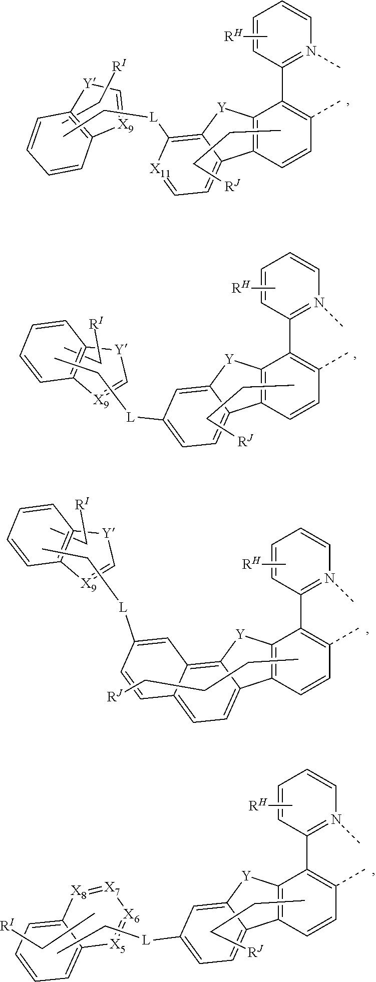

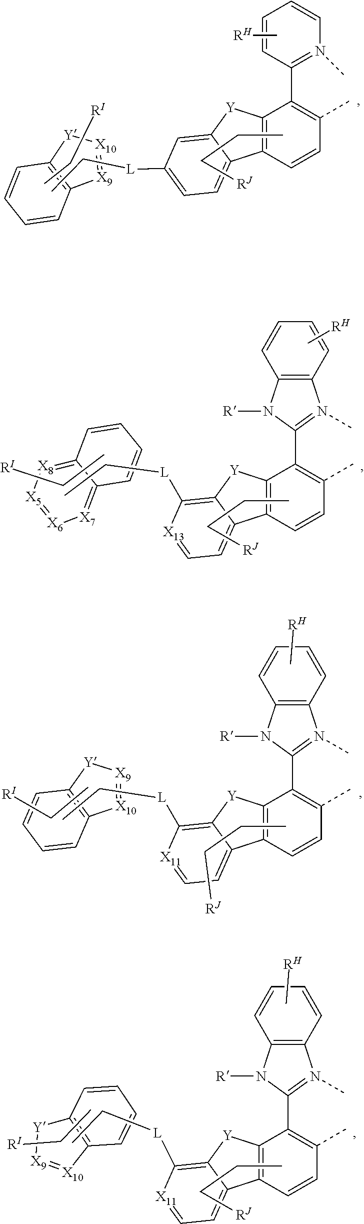

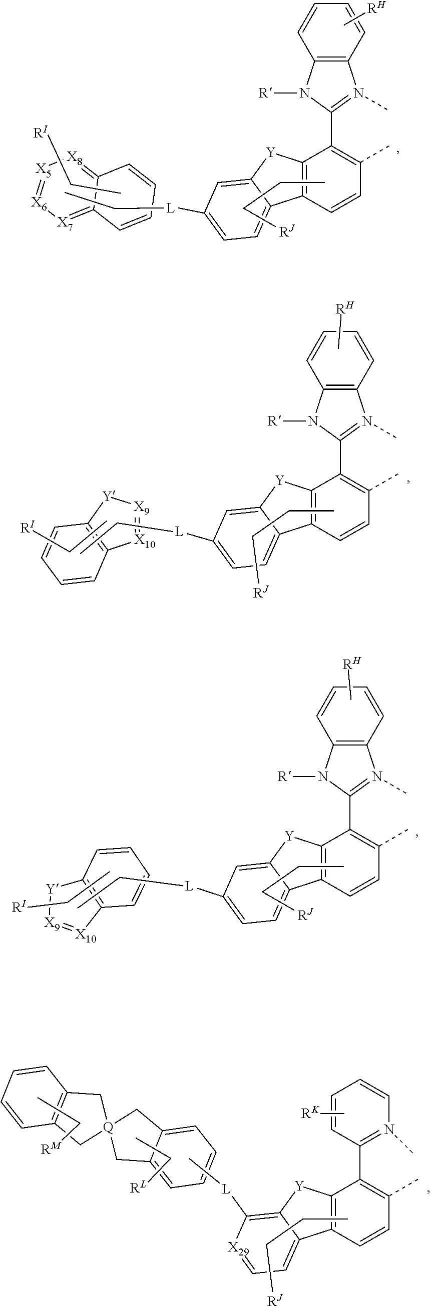

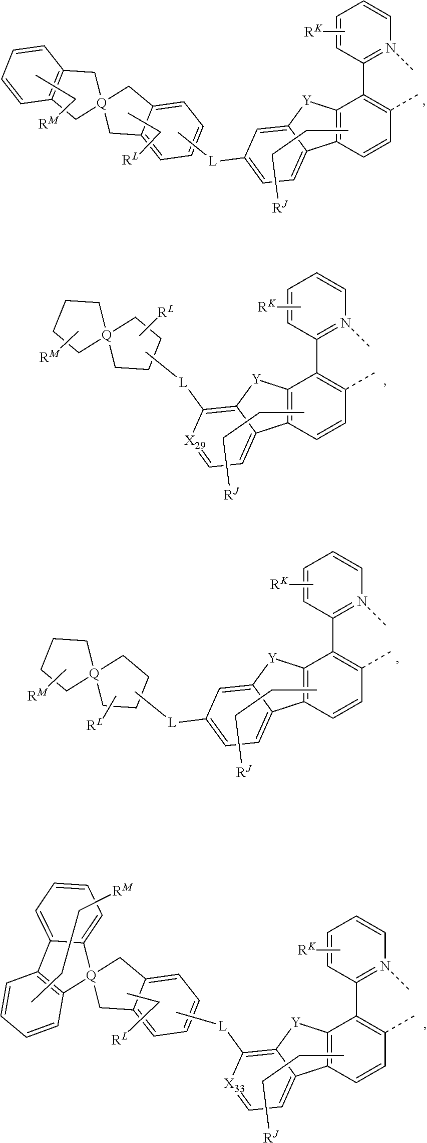

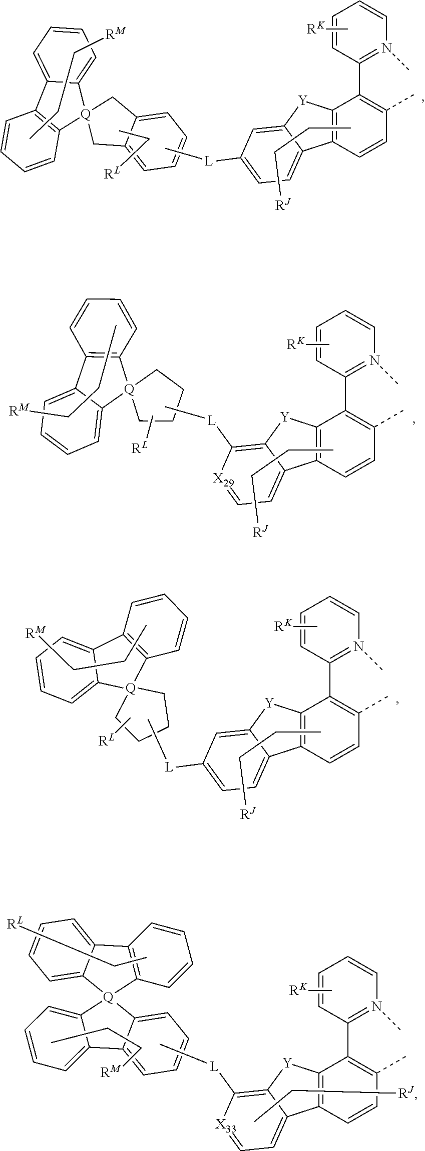

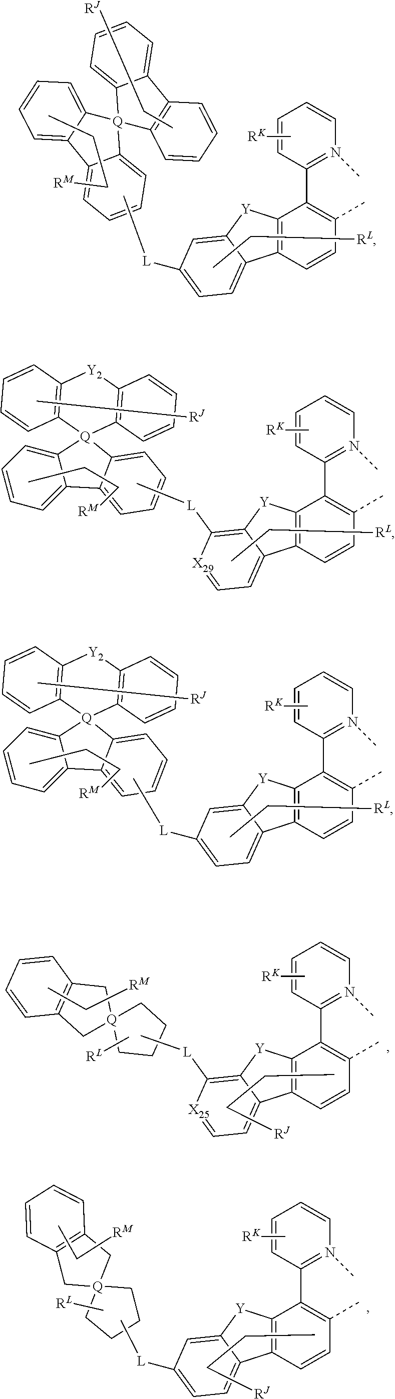

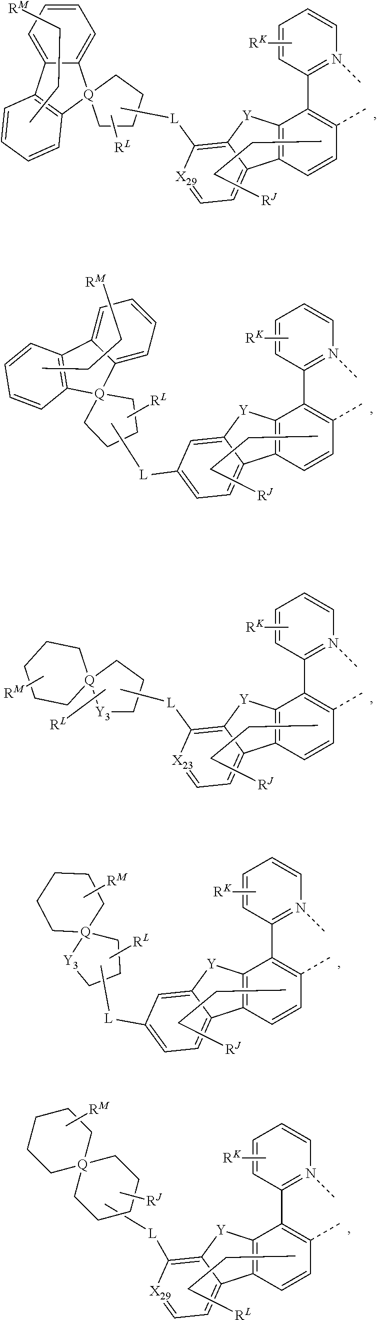

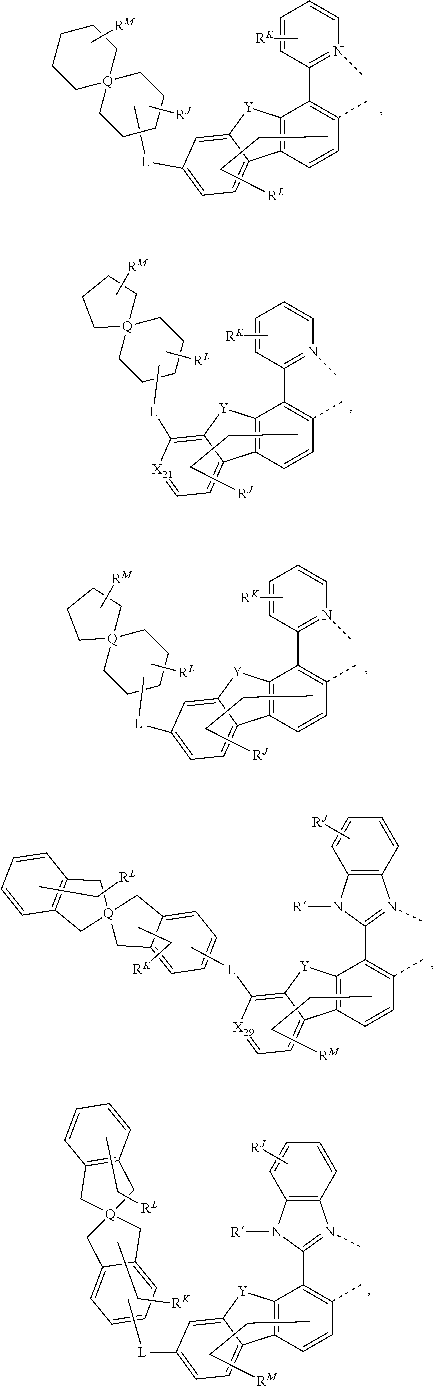

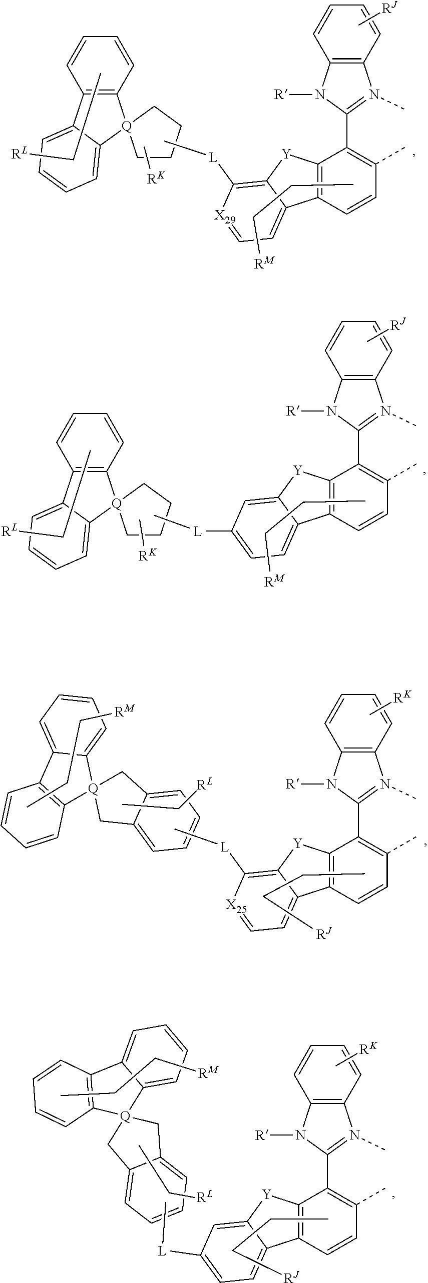

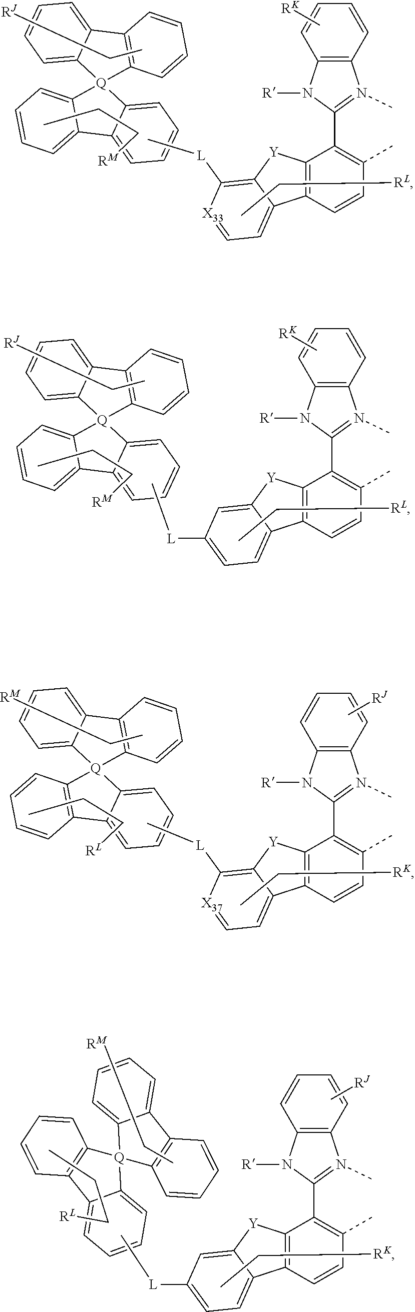

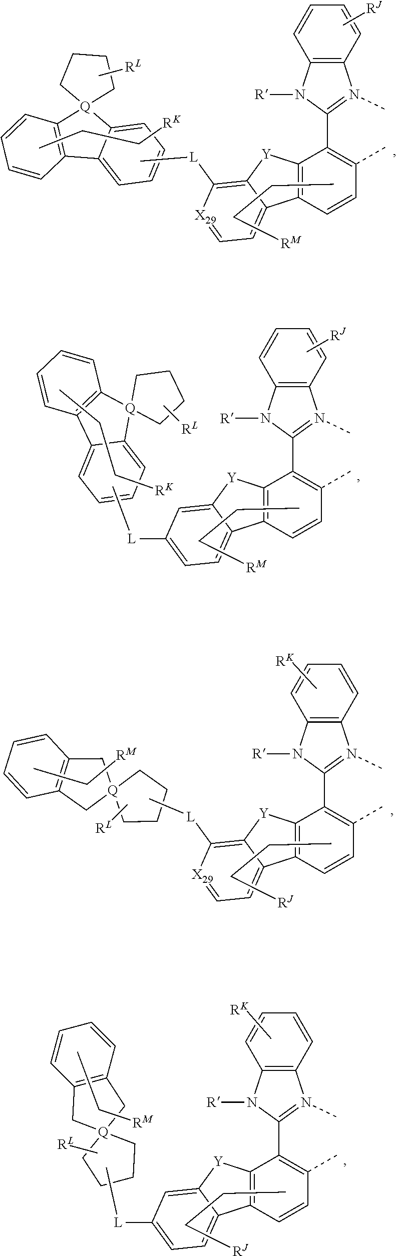

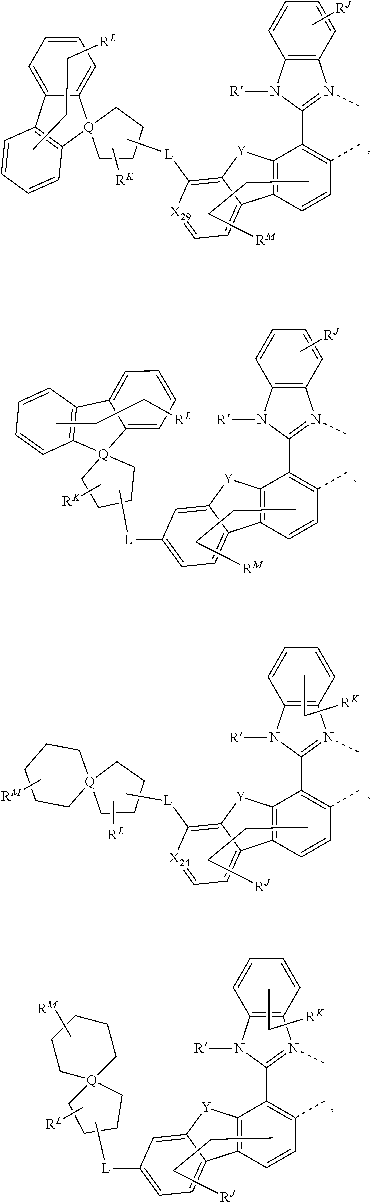

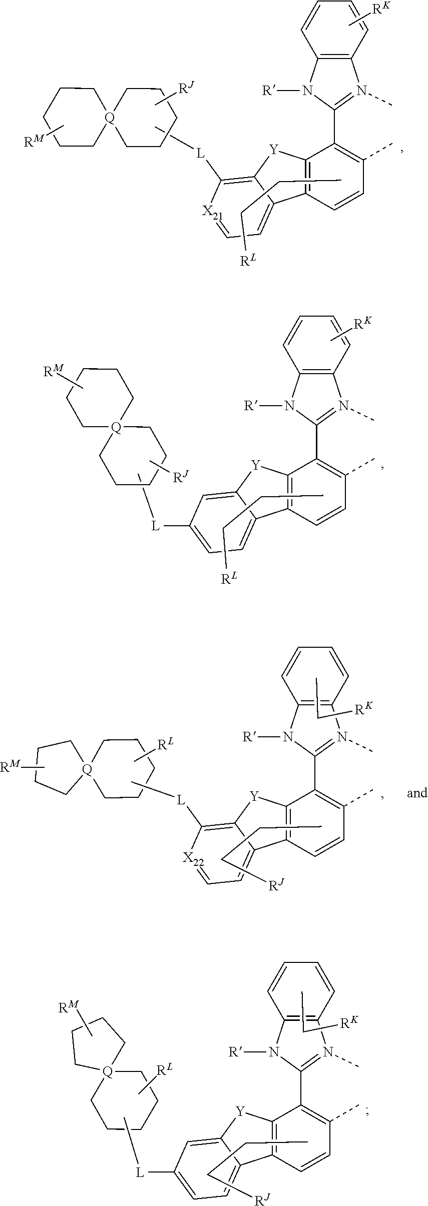

wherein
each of X₅ to X₃₃ is independently C or N;
each of Y₂ to Y₃ is independently selected from the group consisting of B, N, P, P(O), O, S, Se, C═O, C═S, C═Se, C═NR′, C═CRR′, S═O, SO₂, C, Si, and Ge;
each of R^{H}, R^{I}, R^{J}, R^{K}, R^{L}, and R^{M} independently represents mono to the maximum allowable substitution, or no substitution;
each R, R′, R^{H}, R^{I}, R^{J}, R^{K}, R^{L}, and R^{M} is independently hydrogen, or a substituent selected from the group consisting of the General Substituents;
the remaining variables are the same as previously defined; and
any two substituents can be joined or fused to form a ring.

In some embodiments where ligand L_{A} is selected from LIST 9, at least one R^{H}, R^{I}, R^{J}, R^{K}, R^{L}, or R^{M} is selected from the group consisting of the General Substituents defined herein. In some embodiments, at least one R^{H} is selected from the group consisting of the General Substituents defined herein. In some embodiments, at least one R¹ is selected from the group consisting of the General Substituents defined herein. In some embodiments, at least one R^{J} is selected from the group consisting of the General Substituents defined herein. In some embodiments, at least one R^{K} is selected from the group consisting of the General Substituents defined herein. In some embodiments, at least one R^{L} is selected from the group consisting of the General Substituents defined herein. In some embodiments, at least one R^{M} is selected from the group consisting of the General Substituents defined herein. In some embodiments, at least one R^{H}, R^{I}, R^{J}, R^{K}, R^{L}, or R^{M} is selected from the group consisting of the Preferred General Substituents defined herein.

In some embodiments, where ligand L_{A} is selected from LIST 9, at least one of R^{H}, R^{I}, R^{J}, R^{K}, R^{L}, R^{M} or R^{N} is partially or fully deuterated. In some embodiments, at least one R^{H} is partially or fully deuterated. In some embodiments, at least one R^{I} is partially or fully deuterated. In some embodiments, at least one R^{I} is partially or fully deuterated. In some embodiments, at least R^{K} is partially or fully deuterated. In some embodiments, at least R^{L} is partially or fully deuterated. In some embodiments, at least R^{M} is partially or fully deuterated. In some embodiments, at least R^{N} is partially or fully deuterated.

In some embodiments where ligand L_{A} is selected from LIST 9, two R^{H}, two R, or two R^{K} are joined to form a fused ring. In some such embodiments, the fused ring may be benzene, pyridine, pyrimidine, pyridazine, pyrazine, triazine, imidazole, imidazole derived carbene, pyrazole, pyrrole, oxazole, furan, thiophene, thiazole, or triazole. In some such embodiments, the fused ring may be benzene. In some embodiments, Y is O.

In some embodiments where ligand L_{A} is selected from LIST 9, R′ is or comprises a structure of Formula XA, Formula XB, or Formula XC as described herein. In such embodiments, all the Formula XA, Formula XB, or Formula XC related embodiments can be equally applied here.

In some embodiments where ligand L_{A} is selected from LIST 9, at least one R^{H} is or comprises an electron-withdrawing group from the EWG1 LIST as defined herein. In some embodiments, at least one R^{H} is or comprises an electron-withdrawing group from the EWG2 LIST as defined herein. In some embodiments, at least one R^{H} is or comprises an electron-withdrawing group from the EWG3 LIST as defined herein. In some embodiments, at least one R^{H} is or comprises an electron-withdrawing group from the EWG4 LIST as defined herein. In some embodiments, at least one R^{H} is or comprises an electron-withdrawing group from the Pi-EWG LIST as defined herein.

In some embodiments where ligand L_{A} is selected from LIST 9, at least one R^{I} is or comprises an electron-withdrawing group from the EWG1 LIST as defined herein. In some embodiments, at least one R^{I} is or comprises an electron-withdrawing group from the EWG2 LIST as defined herein. In some embodiments, at least one R^{I} is or comprises an electron-withdrawing group from the EWG3 LIST as defined herein. In some embodiments, at least one R^{I} is or comprises an electron-withdrawing group from the EWG4 LIST as defined herein. In some embodiments, at least one R^{I} is or comprises an electron-withdrawing group from the Pi-EWG LIST as defined herein.

In some embodiments where ligand L_{A} is selected from LIST 9, at least one R^{J} is or comprises an electron-withdrawing group from the EWG1 LIST as defined herein. In some embodiments, at least one R^{J} is or comprises an electron-withdrawing group from the EWG2 LIST as defined herein. In some embodiments, at least one R^{J} is or comprises an electron-withdrawing group from the EWG3 LIST as defined herein. In some embodiments, at least one R^{J} is or comprises an electron-withdrawing group from the EWG4 LIST as defined herein. In some embodiments, at least one R′ is or comprises an electron-withdrawing group from the Pi-EWG LIST as defined herein.

In some embodiments where ligand L_{A} is selected from LIST 9, at least R^{K} is or comprises an electron-withdrawing group from the EWG1 LIST as defined herein. In some embodiments, at least R^{K} is or comprises an electron-withdrawing group from the EWG2 LIST as defined herein. In some embodiments, at least R^{K} is or comprises an electron-withdrawing group from the EWG3 LIST as defined herein. In some embodiments, at least R^{K} is or comprises an electron-withdrawing group from the EWG4 LIST as defined herein. In some embodiments, at least R^{K} is or comprises an electron-withdrawing group from the Pi-EWG LIST as defined.

In some embodiments where ligand L_{A} is selected from LIST 9, at least R^{L} is or comprises an electron-withdrawing group from the EWG1 LIST as defined herein. In some embodiments, at least R^{L} is or comprises an electron-withdrawing group from the EWG2 LIST as defined herein. In some embodiments, at least R^{L} is or comprises an electron-withdrawing group from the EWG3 LIST as defined herein. In some embodiments, at least R^{L} is or comprises an electron-withdrawing group from the EWG4 LIST as defined herein. In some embodiments, at least R^{L} is or comprises an electron-withdrawing group from the Pi-EWG LIST as defined.

In some embodiments where ligand L_{A} is selected from LIST 9, at least R^{M} is or comprises an electron-withdrawing group from the EWG1 LIST as defined herein. In some embodiments, at least R^{M} is or comprises an electron-withdrawing group from the EWG2 LIST as defined herein. In some embodiments, at least R^{M} is or comprises an electron-withdrawing group from the EWG3 LIST as defined herein. In some embodiments, at least R^{M} is or comprises an electron-withdrawing group from the EWG4 LIST as defined herein. In some embodiments, at least R^{M} is or comprises an electron-withdrawing group from the Pi-EWG LIST as defined.

In some embodiments, the ligand L_{A} is selected from L_{Ai}-(L)(Q)(Y′)(R^{a})(R^{b})(R^{c}), wherein i is an integer from 1 to 122, each of R^{a}, R^{b}, and R^{c}, is independently selected from the group consisting of R1 to R120; L is selected from the group consisting of L1 to L28, Q is selected from the group consisting of Q1 to Q56, Y′ is selected from the group consisting of Y1 to Y4, wherein each of L_{A1}-(L1)(Q1)(Y1)(R1)(R1)(R1) to L_{A140}-(L28)(Q56)(Y4)(R120)(R120)(R120) is defined in the following LIST 10:

| Compound | Structure of compound |
|---|---|
| L_{A1}-(L)(Q)(Y′)(R^{a})(R^{b})(R^{c}), wherein L_{A1}- (L1)(Q1)(Y1)(R1)(R1)(R1) to L_{A1}- (L28)(Q56)(Y4)(R120)(R120) (R120) have the structure | 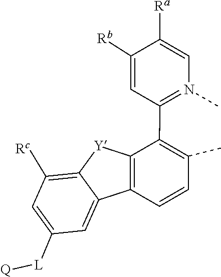 |
| L_{A2}- (L)(Q)(Y′)(R^{a})(R^{b})(R^{c}), wherein L_{A2}- (L1)(Q1)(Y1)(R1)(R1) (R1) to L_{A2}- (L28)(Q56)(Y4)(R120) (R120)(R120) have the structure | 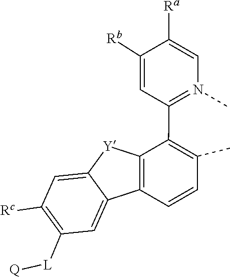 |
| L_{A3}-(L)(Q)(Y′)(R^{a})(R^{b})(R^{c}), wherein L_{A3}- (L1)(Q1)(Y1)(R1)(R1)(R1) to L_{A3}- (L28)(Q56)(Y4)(R120)(R120) (R120) have the structure | 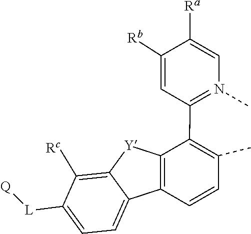 |
| L_{A4}- (L)(Q)(Y′)(R^{a})(R^{b})(R^{c}), wherein L_{A4}- (L1)(Q1)(Y1)(R1)(R1) (R1) to L_{A4}- (L28)(Q56)(Y4)(R120) (R120)(R120) have the structure | 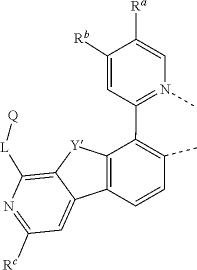 |
| L_{A5}-(L)(Q)(Y′)(R^{a})(R^{b})(R^{c}), wherein L_{A5}- (L1)(Q1)(Y1)(R1)(R1)(R1) to L_{A5}- (L28)(Q56)(Y4)(R120)(R120) (R120) have the structure | 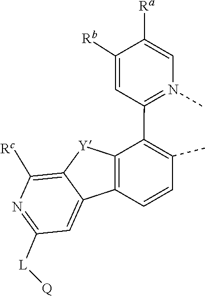 |
| L_{A6}- (L)(Q)(Y′)(R^{a})(R^{b})(R^{c}), wherein L_{A6}- (L1)(Q1)(Y1)(R1)(R1) (R1) to L_{A6}- (L28)(Q56)(Y4)(R120) (R120)(R120) have the structure | 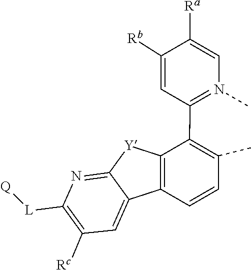 |
| L_{A7}-(L)(Q)(Y′)(R^{a})(R^{b})(R^{c}), wherein L_{A7}- (L1)(Q1)(Y1)(R1)(R1)(R1) to L_{A7}- (L28)(Q56)(Y4)(R120)(R120) (R120) have the structure | 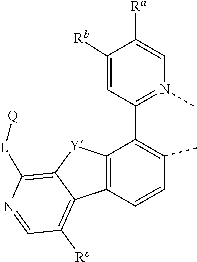 |
| L_{A8}- (L)(Q)(Y′)(R^{a})(R^{b})(R^{c}), wherein L_{A8}- (L1)(Q1)(Y1)(R1)(R1) (R1) to L_{A8}- (L28)(Q56)(Y4)(R120) (R120)(R120) have the structure | 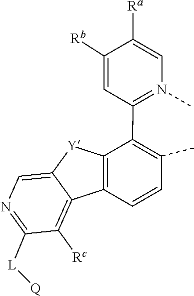 |
| L_{A9}-(L)(Q)(Y′)(R^{a})(R^{b})(R^{c}), wherein L_{A9}- (L1)(Q1)(Y1)(R1)(R1)(R1) to L_{A9}- (L28)(Q56)(Y4)(R120)(R120) (R120) have the structure | 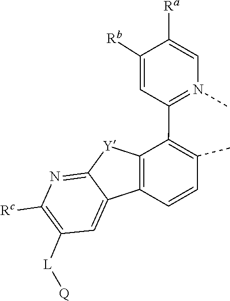 |
| L_{A10}- (L)(Q)(Y′)(R^{a})(R^{b})(R^{c}), wherein L_{A10}- (L1)(Q1)(Y1)(R1)(R1) (R1) to L_{A10}- (L28)(Q56)(Y4)(R120) (R120)(R120) have the structure | 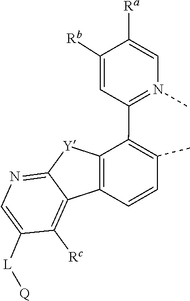 |
| L_{A11}-(L)(Q)(Y′)(R^{a})(R^{b})(R^{c}), wherein L_{A11}- (L1)(Q1)(Y1)(R1)(R1)(R1) to L_{A11}- (L28)(Q56)(Y4)(R120)(R120) (R120) have the structure | 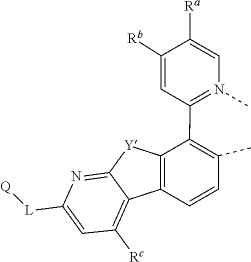 |
| L_{A12}- (L)(Q)(Y′)(R^{a})(R^{b})(R^{c}), wherein L_{A12}- (L1)(Q1)(Y1)(R1)(R1) (R1) to L_{A12}- (L28)(Q56)(Y4)(R120) (R120)(R120) have the structure | 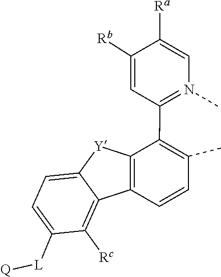 |
| L_{A13}-(L)(Q)(Y′)(R^{a})(R^{b})(R^{c}), wherein L_{A13}- (L1)(Q1)(Y1)(R1)(R1)(R1) to L_{A13}- (L28)(Q56)(Y4)(R120)(R120) (R120) have the structure | 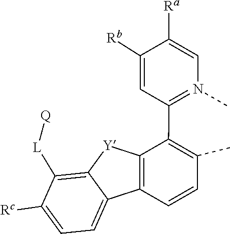 |
| L_{A14}- (L)(Q)(Y′)(R^{a})(R^{b})(R^{c}), wherein L_{A14}- (L1)(Q1)(Y1)(R1)(R1) (R1) to L_{A14}- (L28)(Q56)(Y4)(R120) (R120)(R120) have the structure | 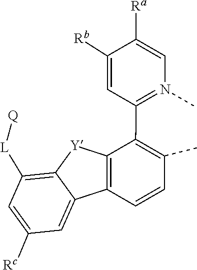 |
| L_{A15}-(L)(Q)(Y′)(R^{a})(R^{b})(R^{c}), wherein L_{A15}- (L1)(Q1)(Y1)(R1)(R1)(R1) to L_{A15}- (L28)(Q56)(Y4)(R120)(R120) (R120) have the structure | 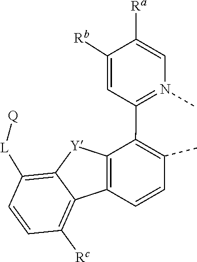 |
| L_{A16}- (L)(Q)(Y′)(R^{a})(R^{b})(R^{c}), wherein L_{A16}- (L1)(Q1)(Y1)(R1)(R1) (R1) to L_{A16}- (L28)(Q56)(Y4)(R120) (R120)(R120) have the structure | 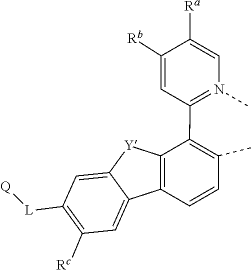 |
| L_{A17}-(L)(Q)(Y′)(R^{a})(R^{b})(R^{c}), wherein L_{A17}- (L1)(Q1)(Y1)(R1)(R1)(R1) to L_{A17}- (L28)(Q56)(Y4)(R120)(R120) (R120) have the structure | 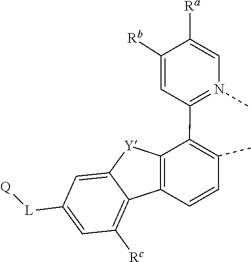 |
| L_{A18}- (L)(Q)(Y′)(R^{a})(R^{b})(R^{c}), wherein L_{A18}- (L1)(Q1)(Y1)(R1)(R1) (R1) to L_{A18}- (L28)(Q56)(Y4)(R120) (R120)(R120) have the structure | 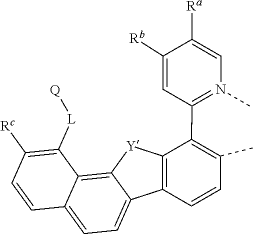 |
| L_{A19}-(L)(Q)(Y′)(R^{a})(R^{b})(R^{c}), wherein L_{A19}- (L1)(Q1)(Y1)(R1)(R1)(R1) to L_{A19}- (L28)(Q56)(Y4)(R120)(R120) (R120) have the structure | 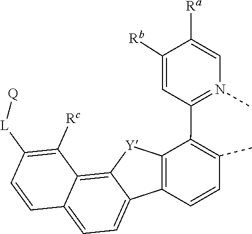 |
| L_{A20}- (L)(Q)(Y′)(R^{a})(R^{b})(R^{c}), wherein L_{A20}- (L1)(Q1)(Y1)(R1)(R1) (R1) to L_{A20}- (L28)(Q56)(Y4)(R120) (R120)(R120) have the structure | 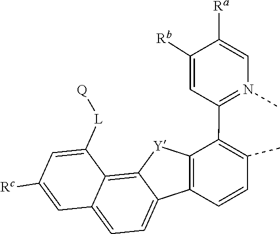 |
| L_{A21}-(L)(Q)(Y′)(R^{a})(R^{b})(R^{c}), wherein L_{A21}- (L1)(Q1)(Y1)(R1)(R1)(R1) to L_{A21}- (L28)(Q56)(Y4)(R120)(R120) (R120) have the structure | 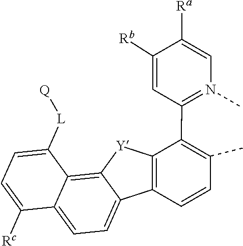 |
| L_{A22}- (L)(Q)(Y′)(R^{a})(R^{b})(R^{c}), wherein L_{A22}- (L1)(Q1)(Y1)(R1)(R1) (R1) to L_{A22}- (L28)(Q56)(Y4)(R120) (R120)(R120) have the structure | 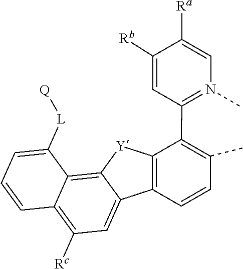 |
| L_{A23}-(L)(Q)(Y′)(R^{a})(R^{b})(R^{c}), wherein L_{A23}- (L1)(Q1)(Y1)(R1)(R1)(R1) to L_{A23}- (L28)(Q56)(Y4)(R120)(R120) (R120) have the structure | 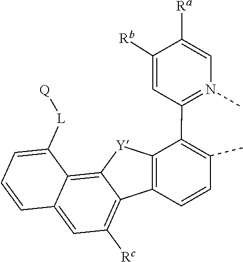 |
| L_{A24}- (L)(Q)(Y′)(R^{a})(R^{b})(R^{c}), wherein L_{A24}- (L1)(Q1)(Y1)(R1)(R1) (R1) to L_{A24}- (L28)(Q56)(Y4)(R120) (R120)(R120) have the structure | 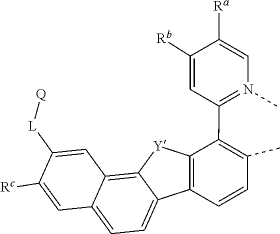 |
| L_{A25}-(L)(Q)(Y′)(R^{a})(R^{b})(R^{c}), wherein L_{A25}- (L1)(Q1)(Y1)(R1)(R1)(R1) to L_{A25}- (L28)(Q56)(Y4)(R120)(R120) (R120) have the structure | 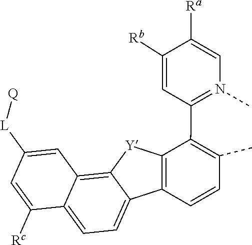 |
| L_{A26}- (L)(Q)(Y′)(R^{a})(R^{b})(R^{c}), wherein L_{A26}- (L1)(Q1)(Y1)(R1)(R1) (R1) to L_{A26}- (L28)(Q56)(Y4)(R120) (R120)(R120) have the structure | 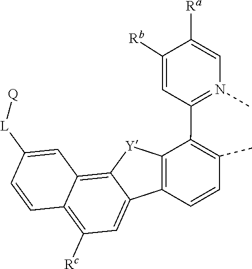 |
| L_{A27}-(L)(Q)(Y′)(R^{a})(R^{b})(R^{c}), wherein L_{A27}- (L1)(Q1)(Y1)(R1)(R1)(R1) to L_{A27}- (L28)(Q56)(Y4)(R120)(R120) (R120) have the structure | 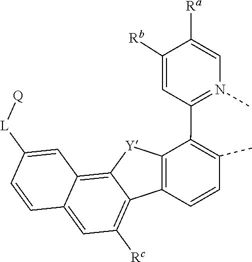 |
| L_{A28}- (L)(Q)(Y′)(R^{a})(R^{b})(R^{c}), wherein L_{A28}- (L1)(Q1)(Y1)(R1)(R1) (R1) to L_{A28}- (L28)(Q56)(Y4)(R120) (R120)(R120) have the structure | 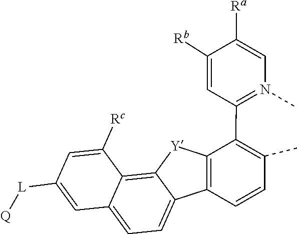 |
| L_{A29}-(L)(Q)(Y′)(R^{a})(R^{b})(R^{c}), wherein L_{A29}- (L1)(Q1)(Y1)(R1)(R1)(R1) to L_{A29}- (L28)(Q56)(Y4)(R120)(R120) (R120) have the structure | 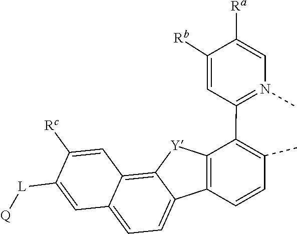 |
| L_{A30}- (L)(Q)(Y′)(R^{a})(R^{b})(R^{c}), wherein L_{A30}- (L1)(Q1)(Y1)(R1)(R1) (R1) to L_{A30}- (L28)(Q56)(Y4)(R120) (R120)(R120) have the structure | 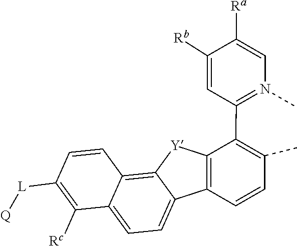 |
| L_{A31}-(L)(Q)(Y′)(R^{a})(R^{b})(R^{c}), wherein L_{A31}- (L1)(Q1)(Y1)(R1)(R1)(R1) to L_{A31}- (L28)(Q56)(Y4)(R120)(R120) (R120) have the structure | 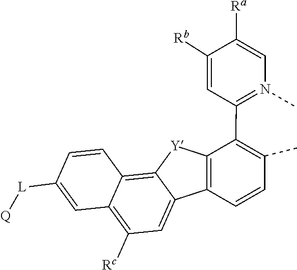 |
| L_{A32}- (L)(Q)(Y′)(R^{a})(R^{b})(R^{c}), wherein L_{A32}- (L1)(Q1)(Y1)(R1)(R1) (R1) to L_{A32}- (L28)(Q56)(Y4)(R120) (R120)(R120) have the structure | 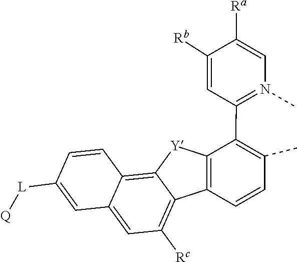 |
| L_{A33}-(L)(Q)(Y′)(R^{a})(R^{b})(R^{c}), wherein L_{A33}- (L1)(Q1)(Y1)(R1)(R1)(R1) to L_{A33}- (L28)(Q56)(Y4)(R120)(R120) (R120) have the structure | 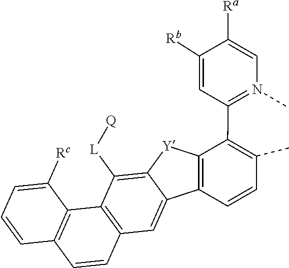 |
| L_{A34}- (L)(Q)(Y′)(R^{a})(R^{b})(R^{c}), wherein L_{A34}- (L1)(Q1)(Y1)(R1)(R1) (R1) to L_{A34}- (L28)(Q56)(Y4)(R120) (R120)(R120) have the structure | 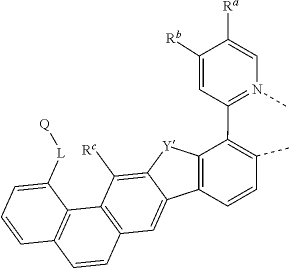 |
| L_{A35}-(L)(Q)(Y′)(R^{a})(R^{b})(R^{c}), wherein L_{A35}- (L1)(Q1)(Y1)(R1)(R1)(R1) to L_{A35}- (L28)(Q56)(Y4)(R120)(R120) (R120) have the structure | 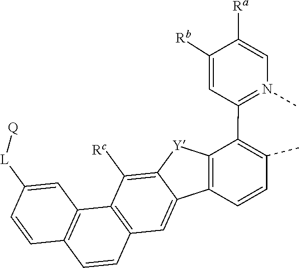 |
| L_{A36}- (L)(Q)(Y′)(R^{a})(R^{b})(R^{c}), wherein L_{A36}- (L1)(Q1)(Y1)(R1)(R1) (R1) to L_{A36}- (L28)(Q56)(Y4)(R120) (R120)(R120) have the structure | 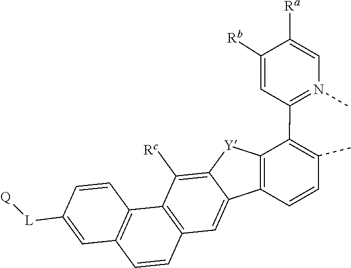 |
| L_{A37}-(L)(Q)(Y′)(R^{a})(R^{b})(R^{c}), wherein L_{A37}- (L1)(Q1)(Y1)(R1)(R1)(R1) to L_{A37}- (L28)(Q56)(Y4)(R120)(R120) (R120) have the structure | 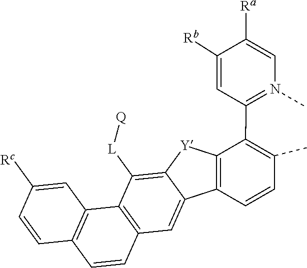 |
| L_{A38}- (L)(Q)(Y′)(R^{a})(R^{b})(R^{c}), wherein L_{A38}- (L1)(Q1)(Y1)(R1)(R1) (R1) to L_{A38}- (L28)(Q56)(Y4)(R120) (R120)(R120) have the structure | 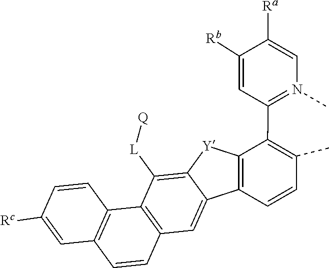 |
| L_{A39}-(L)(Q)(Y′)(R^{a})(R^{b})(R^{c}), wherein L_{A39}- (L1)(Q1)(Y1)(R1)(R1)(R1) to L_{A39}- (L28)(Q56)(Y4)(R120)(R120) (R120) have the structure | 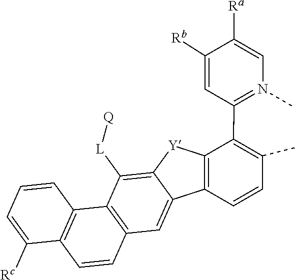 |
| L_{A40}- (L)(Q)(Y′)(R^{a})(R^{b})(R^{c}), wherein L_{A40}- (L1)(Q1)(Y1)(R1)(R1) (R1) to L_{A40}- (L28)(Q56)(Y4)(R120) (R120)(R120) have the structure | 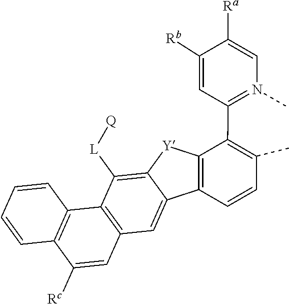 |
| L_{A41}-(L)(Q)(Y′)(R^{a})(R^{b})(R^{c}), wherein L_{A41}- (L1)(Q1)(Y1)(R1)(R1)(R1) to L_{A41}- (L28)(Q56)(Y4)(R120)(R120) (R120) have the structure | 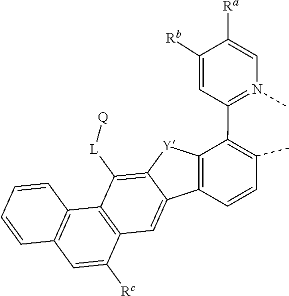 |
| L_{A42}- (L)(Q)(Y′)(R^{a})(R^{b})(R^{c}), wherein L_{A42}- (L1)(Q1)(Y1)(R1)(R1) (R1) to L_{A42}- (L28)(Q56)(Y4)(R120) (R120)(R120) have the structure | 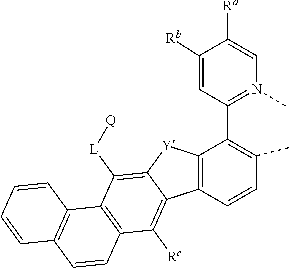 |
| L_{A43}-(L)(Q)(Y′)(R^{a})(R^{b})(R^{c}), wherein L_{A43}- (L1)(Q1)(Y1)(R1)(R1)(R1) to L_{A43}- (L28)(Q56)(Y4)(R120)(R120) (R120) have the structure | 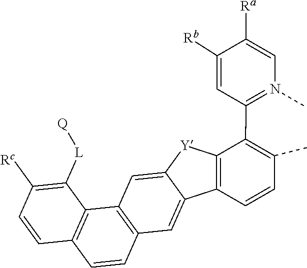 |
| L_{A44}- (L)(Q)(Y′)(R^{a})(R^{b})(R^{c}), wherein L_{A44}- (L1)(Q1)(Y1)(R1)(R1) (R1) to L_{A44}- (L28)(Q56)(Y4)(R120) (R120)(R120) have the structure | 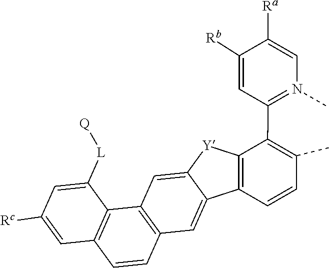 |
| L_{A45}-(L)(Q)(Y′)(R^{a})(R^{b})(R^{c}), wherein L_{A45}- (L1)(Q1)(Y1)(R1)(R1)(R1) to L_{A45}- (L28)(Q56)(Y4)(R120)(R120) (R120) have the structure | 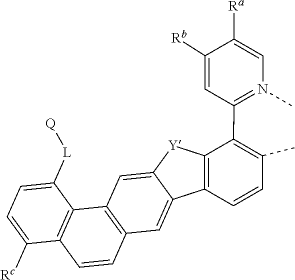 |
| L_{A46}- (L)(Q)(Y′)(R^{a})(R^{b})(R^{c}), wherein L_{A46}- (L1)(Q1)(Y1)(R1)(R1) (R1) to L_{A46}- (L28)(Q56)(Y4)(R120) (R120)(R120) have the structure | 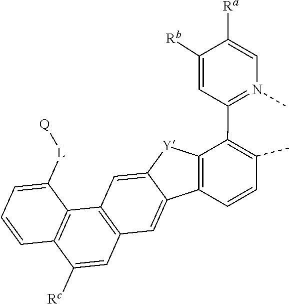 |
| L_{A47}-(L)(Q)(Y′)(R^{a})(R^{b})(R^{c}), wherein L_{A47}- (L1)(Q1)(Y1)(R1)(R1)(R1) to L_{A47}- (L28)(Q56)(Y4)(R120)(R120) (R120) have the structure | 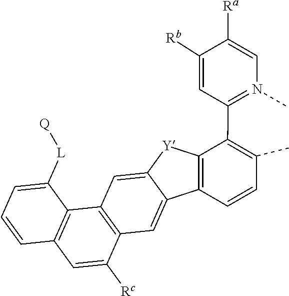 |
| L_{A48}- (L)(Q)(Y′)(R^{a})(R^{b})(R^{c}), wherein L_{A48}- (L1)(Q1)(Y1)(R1)(R1) (R1) to L_{A48}- (L28)(Q56)(Y4)(R120) (R120)(R120) have the structure | 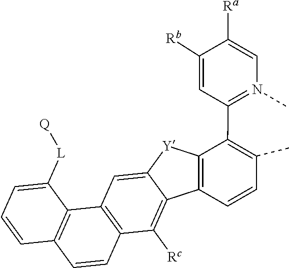 |
| L_{A49}-(L)(Q)(Y′)(R^{a})(R^{b})(R^{c}), wherein L_{A49}- (L1)(Q1)(Y1)(R1)(R1)(R1) to L_{A49}- (L28)(Q56)(Y4)(R120)(R120) (R120) have the structure | 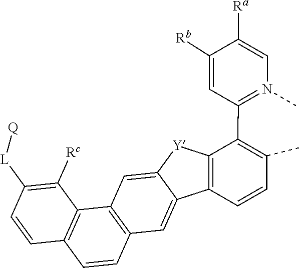 |
| L_{A50}- (L)(Q)(Y′)(R^{a})(R^{b})(R^{c}), wherein L_{A50}- (L1)(Q1)(Y1)(R1)(R1) (R1) to L_{A50}- (L28)(Q56)(Y4)(R120) (R120)(R120) have the structure | 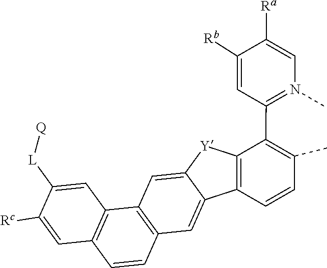 |
| L_{A51}-(L)(Q)(Y′)(R^{a})(R^{b})(R^{c}), wherein L_{A51}- (L1)(Q1)(Y1)(R1)(R1)(R1) to L_{A51}- (L28)(Q56)(Y4)(R120)(R120) (R120) have the structure | 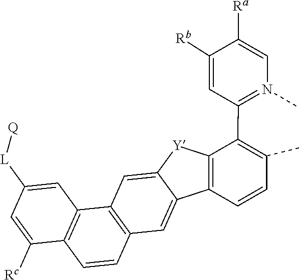 |
| L_{A52}- (L)(Q)(Y′)(R^{a})(R^{b})(R^{c}), wherein L_{A52}- (L1)(Q1)(Y1)(R1)(R1) (R1) to L_{A52}- (L28)(Q56)(Y4)(R120) (R120)(R120) have the structure | 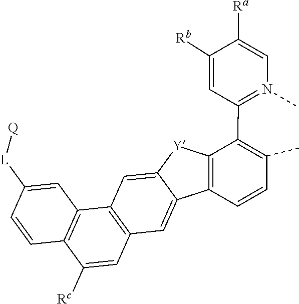 |
| L_{A53}-(L)(Q)(Y′)(R^{a})(R^{b})(R^{c}), wherein L_{A53}- (L1)(Q1)(Y1)(R1)(R1)(R1) to L_{A53}- (L28)(Q56)(Y4)(R120)(R120) (R120) have the structure | 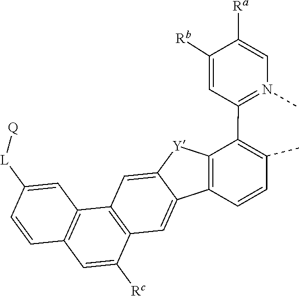 |
| L_{A56}- (L)(Q)(Y′)(R^{a})(R^{b})(R^{c}), wherein L_{A56}- (L1)(Q1)(Y1)(R1)(R1) (R1) to L_{A56}- (L28)(Q56)(Y4)(R120) (R120)(R120) have the structure | 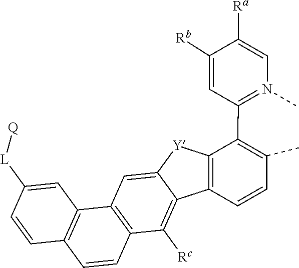 |
| L_{A55}-(L)(Q)(Y′)(R^{a})(R^{b})(R^{c}), wherein L_{A55}- (L1)(Q1)(Y1)(R1)(R1)(R1) to L_{A55}- (L28)(Q56)(Y4)(R120)(R120) (R120) have the structure | 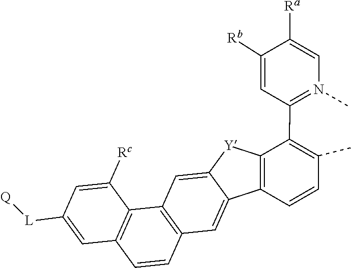 |
| L_{A56}- (L)(Q)(Y′)(R^{a})(R^{b})(R^{c}), wherein L_{A56}- (L1)(Q1)(Y1)(R1)(R1) (R1) to L_{A56}- (L28)(Q56)(Y4)(R120) (R120)(R120) have the structure | 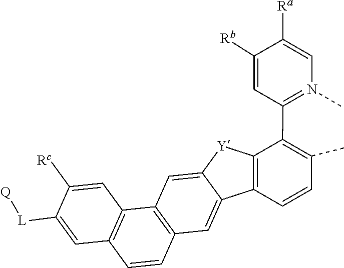 |
| L_{A57}-(L)(Q)(Y′)(R^{a})(R^{b})(R^{c}), wherein L_{A57}- (L1)(Q1)(Y1)(R1)(R1)(R1) to L_{A57}- (L28)(Q56)(Y4)(R120)(R120) (R120) have the structure | 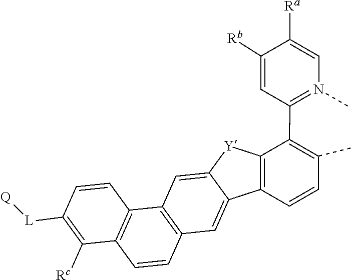 |
| L_{A58}- (L)(Q)(Y′)(R^{a})(R^{b})(R^{c}), wherein L_{A58}- (L1)(Q1)(Y1)(R1)(R1) (R1) to L_{A58}- (L28)(Q56)(Y4)(R120) (R120)(R120) have the structure | 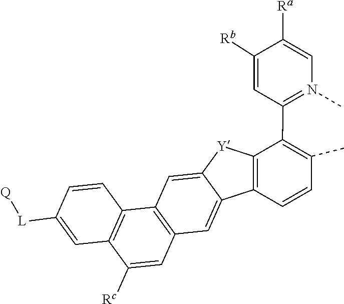 |
| L_{A59}-(L)(Q)(Y′)(R^{a})(R^{b})(R^{c}), wherein L_{A59}- (L1)(Q1)(Y1)(R1)(R1)(R1) to L_{A59}- (L28)(Q56)(Y4)(R120)(R120) (R120) have the structure | 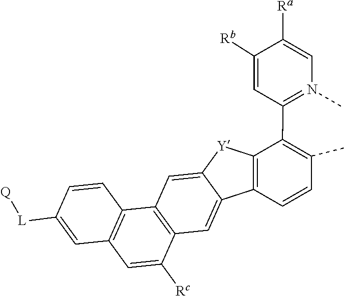 |
| L_{A60}- (L)(Q)(Y′)(R^{a})(R^{b})(R^{c}), wherein L_{A60}- (L1)(Q1)(Y1)(R1)(R1) (R1) to L_{A60}- (L28)(Q56)(Y4)(R120) (R120)(R120) have the structure | 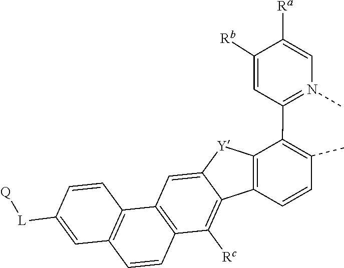 |
| L_{A61}-(L)(Q)(Y′)(R^{a})(R^{b})(R^{c}), wherein L_{A61}- (L1)(Q1)(Y1)(R1)(R1) to L_{A61}- (L28)(Q56)(Y4)(R120)(R120) (R120) have the structure | 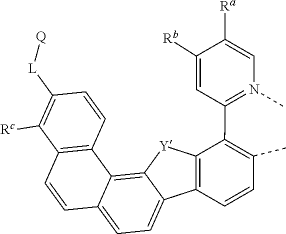 |
| L_{A62}- (L)(Q)(Y′)(R^{a})(R^{b})(R^{c}), wherein L_{A62}- (L1)(Q1)(Y1)(R1)(R1) to L_{A62}- (L28)(Q56)(Y4)(R120) (R120) (R120) have the structure | 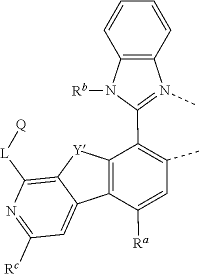 |
| L_{A63}-(L)(Q)(Y′)(R^{a})(R^{b})(R^{c}), wherein L_{A63}- (L1)(Q1)(Y1)(R1)(R1) to L_{A63}- (L28)(Q56)(Y4)(R120)(R120) (R120) have the structure | 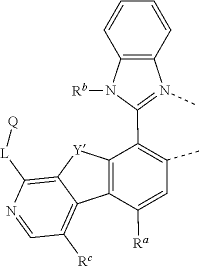 |
| L_{A64}- (L)(Q)(Y′)(R^{a})(R^{b})(R^{c}), wherein L_{A64}- (L1)(Q1)(Y1)(R1)(R1) to L_{A64}- (L28)(Q56)(Y4)(R120) (R120) (R120) have the structure | 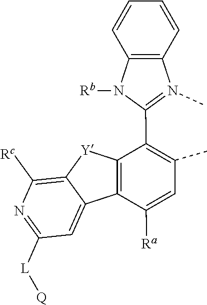 |
| L_{A65}-(L)(Q)(Y′)(R^{a})(R^{b})(R^{c}), wherein L_{A65}- (L1)(Q1)(Y1)(R1)(R1) to L_{A65}- (L28)(Q56)(Y4)(R120)(R120) (R120) have the structure | 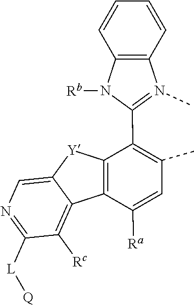 |
| L_{A66}- (L)(Q)(Y′)(R^{a})(R^{b})(R^{c}), wherein L_{A66}- (L1)(Q1)(Y1)(R1)(R1) to L_{A66}- (L28)(Q56)(Y4)(R120) (R120) (R120) have the structure | 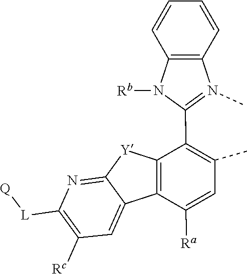 |
| L_{A67}-(L)(Q)(Y′)(R^{a})(R^{b})(R^{c}), wherein L_{A67}- (L1)(Q1)(Y1)(R1)(R1) to L_{A67}- (L28)(Q56)(Y4)(R120)(R120) (R120) have the structure | 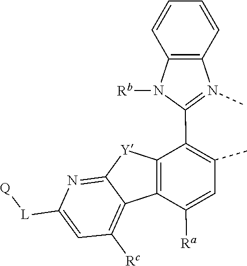 |
| L_{A68}- (L)(Q)(Y′)(R^{a})(R^{b})(R^{c}), wherein L_{A68}- (L1)(Q1)(Y1)(R1)(R1) to L_{A68}- (L28)(Q56)(Y4)(R120) (R120) (R120) have the structure | 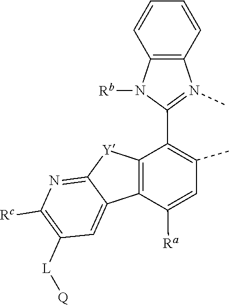 |
| L_{A69}-(L)(Q)(Y′)(R^{a})(R^{b})(R^{c}), wherein L_{A69}- (L1)(Q1)(Y1)(R1)(R1) to L_{A69}- (L28)(Q56)(Y4)(R120)(R120) (R120) have the structure | 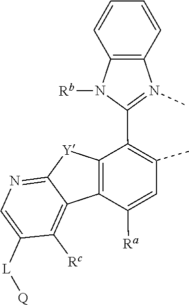 |
| L_{A70}- (L)(Q)(Y′)(R^{a})(R^{b})(R^{c}), wherein L_{A70}- (L1)(Q1)(Y1)(R1)(R1) to L_{A70}- (L28)(Q56)(Y4)(R120) (R120) (R120) have the structure | 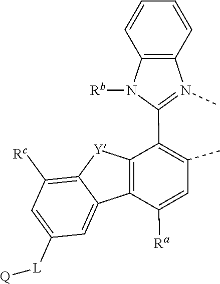 |
| L_{A71}-(L)(Q)(Y′)(R^{a})(R^{b})(R^{c}), wherein L_{A71}- (L1)(Q1)(Y1)(R1)(R1) to L_{A71}- (L28)(Q56)(Y4)(R120)(R120) (R120) have the structure | 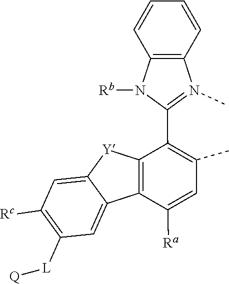 |
| L_{A72}- (L)(Q)(Y′)(R^{a})(R^{b})(R^{c}), wherein L_{A72}- (L1)(Q1)(Y1)(R1)(R1) to L_{A72}- (L28)(Q56)(Y4)(R120) (R120) (R120) have the structure | 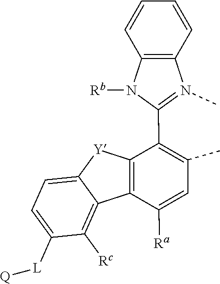 |
| L_{A73}-(L)(Q)(Y′)(R^{a})(R^{b})(R^{c}), wherein L_{A73}- (L1)(Q1)(Y1)(R1)(R1) to L_{A73}- (L28)(Q56)(Y4)(R120)(R120) (R120) have the structure | 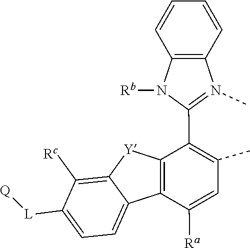 |
| L_{A74}- (L)(Q)(Y′)(R^{a})(R^{b})(R^{c}), wherein L_{A74}- (L1)(Q1)(Y1)(R1)(R1) to L_{A74}- (L28)(Q56)(Y4)(R120) (R120) (R120) have the structure | 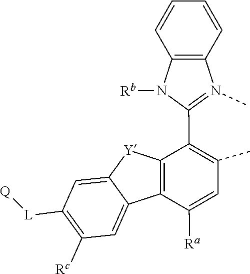 |
| L_{A75}-(L)(Q)(Y′)(R^{a})(R^{b})(R^{c}), wherein L_{A75}- (L1)(Q1)(Y1)(R1)(R1) to L_{A75}- (L28)(Q56)(Y4)(R120)(R120) (R120) have the structure | 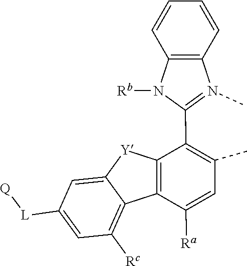 |
| L_{A76}- (L)(Q)(Y′)(R^{a})(R^{b})(R^{c}), wherein L_{A76}- (L1)(Q1)(Y1)(R1)(R1) to L_{A76}- (L28)(Q56)(Y4)(R120) (R120) (R120) have the structure | 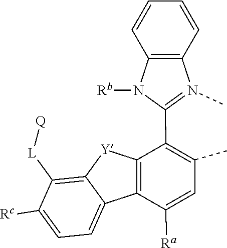 |
| L_{A77}-(L)(Q)(Y′)(R^{a})(R^{b})(R^{c}), wherein L_{A77}- (L1)(Q1)(Y1)(R1)(R1) to L_{A77}- (L28)(Q56)(Y4)(R120)(R120) (R120) have the structure | 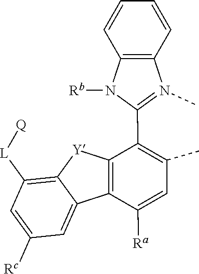 |
| L_{A78}- (L)(Q)(Y′)(R^{a})(R^{b})(R^{c}), wherein L_{A78}- (L1)(Q1)(Y1)(R1)(R1) to L_{A78}- (L28)(Q56)(Y4)(R120) (R120) (R120) have the structure | 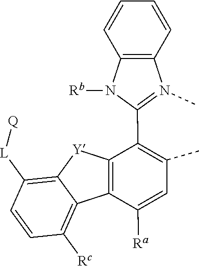 |
| L_{A79}-(L)(Q)(Y′)(R^{a})(R^{b})(R^{c}), wherein L_{A79}- (L1)(Q1)(Y1)(R1)(R1) to L_{A79}- (L28)(Q56)(Y4)(R120)(R120) (R120) have the structure | 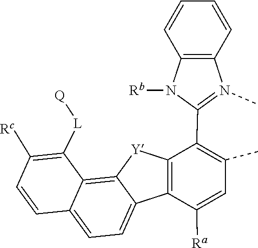 |
| L_{A80}- (L)(Q)(Y′)(R^{a})(R^{b})(R^{c}), wherein L_{A80}- (L1)(Q1)(Y1)(R1)(R1) to L_{A80}- (L28)(Q56)(Y4)(R120) (R120) (R120) have the structure | 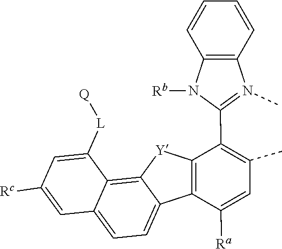 |
| L_{A81}-(L)(Q)(Y′)(R^{a})(R^{b})(R^{c}), wherein L_{A81}- (L1)(Q1)(Y1)(R1)(R1) to L_{A81}- (L28)(Q56)(Y4)(R120)(R120) (R120) have the structure | 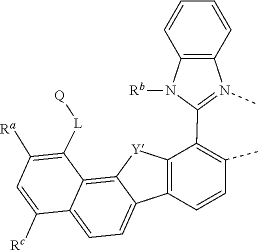 |
| L_{A82}- (L)(Q)(Y′)(R^{a})(R^{b})(R^{c}), wherein L_{A82}- (L1)(Q1)(Y1)(R1)(R1) to L_{A82}- (L28)(Q56)(Y4)(R120) (R120) (R120) have the structure | 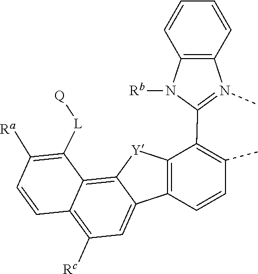 |
| L_{A83}-(L)(Q)(Y′)(R^{a})(R^{b})(R^{c}), wherein L_{A83}- (L1)(Q1)(Y1)(R1)(R1) to L_{A83}- (L28)(Q56)(Y4)(R120)(R120) (R120) have the structure | 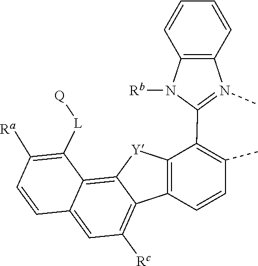 |
| L_{A84}- (L)(Q)(Y′)(R^{a})(R^{b})(R^{c}), wherein L_{A84}- (L1)(Q1)(Y1)(R1)(R1) to L_{A84}- (L28)(Q56)(Y4)(R120) (R120) (R120) have the structure | 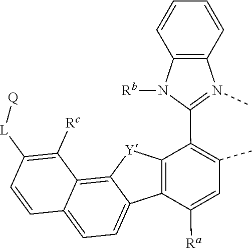 |
| L_{A85}-(L)(Q)(Y′)(R^{a})(R^{b})(R^{c}), wherein L_{A85}- (L1)(Q1)(Y1)(R1)(R1) to L_{A85}- (L28)(Q56)(Y4)(R120)(R120) (R120) have the structure | 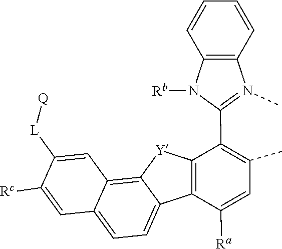 |
| L_{A86}- (L)(Q)(Y′)(R^{a})(R^{b})(R^{c}), wherein L_{A86}- (L1)(Q1)(Y1)(R1)(R1) to L_{A86}- (L28)(Q56)(Y4)(R120) (R120) (R120) have the structure | 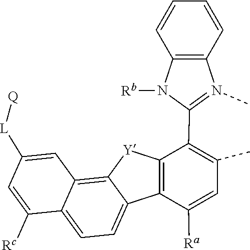 |
| L_{A87}-(L)(Q)(Y′)(R^{a})(R^{b})(R^{c}), wherein L_{A87}- (L1)(Q1)(Y1)(R1)(R1) to L_{A87}- (L28)(Q56)(Y4)(R120)(R120) (R120) have the structure | 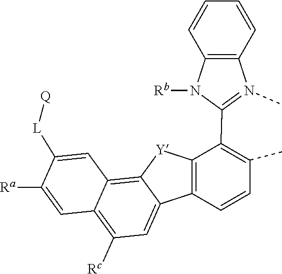 |
| L_{A88}- (L)(Q)(Y′)(R^{a})(R^{b})(R^{c}), wherein L_{A88}- (L1)(Q1)(Y1)(R1)(R1) to L_{A88}- (L28)(Q56)(Y4)(R120) (R120) (R120) have the structure | 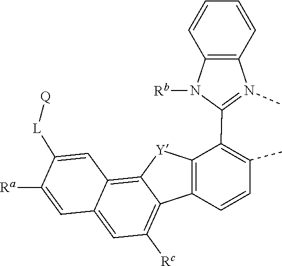 |
| L_{A89}-(L)(Q)(Y′)(R^{a})(R^{b})(R^{c}), wherein L_{A89}- (L1)(Q1)(Y1)(R1)(R1) to L_{A89}- (L28)(Q56)(Y4)(R120)(R120) (R120) have the structure | 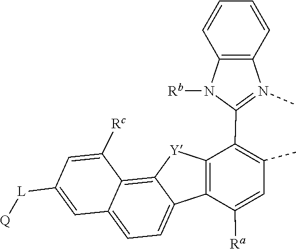 |
| L_{A90}- (L)(Q)(Y′)(R^{a})(R^{b})(R^{c}), wherein L_{A90}- (L1)(Q1)(Y1)(R1)(R1) to L_{A90}- (L28)(Q56)(Y4)(R120) (R120) (R120) have the structure | 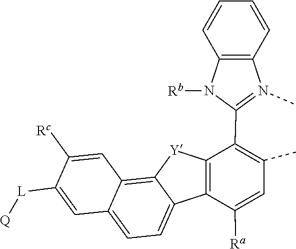 |
| L_{A91}-(L)(Q)(Y′)(R^{a})(R^{b})(R^{c}), wherein L_{A91}- (L1)(Q1)(Y1)(R1)(R1) to L_{A91}- (L28)(Q56)(Y4)(R120)(R120) (R120) have the structure | 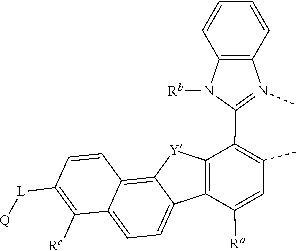 |
| L_{A92}- (L)(Q)(Y′)(R^{a})(R^{b})(R^{c}), wherein L_{A92}- (L1)(Q1)(Y1)(R1)(R1) to L_{A92}- (L28)(Q56)(Y4)(R120) (R120) (R120) have the structure | 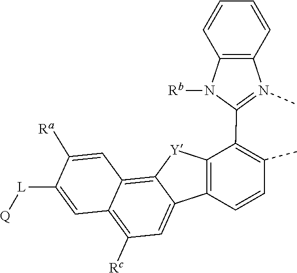 |
| L_{A93}-(L)(Q)(Y′)(R^{a})(R^{b})(R^{c}), wherein L_{A93}- (L1)(Q1)(Y1)(R1)(R1) to L_{A93}- (L28)(Q56)(Y4)(R120)(R120) (R120) have the structure | 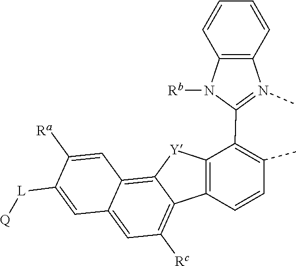 |
| L_{A94}- (L)(Q)(Y′)(R^{a})(R^{b})(R^{c}), wherein L_{A94}- (L1)(Q1)(Y1)(R1)(R1) to L_{A94}- (L28)(Q56)(Y4)(R120) (R120) (R120) have the structure | 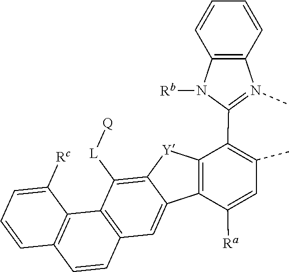 |
| L_{A95}-(L)(Q)(Y′)(R^{a})(R^{b})(R^{c}), wherein L_{A95}- (L1)(Q1)(Y1)(R1)(R1) to L_{A95}- (L28)(Q56)(Y4)(R120)(R120) (R120) have the structure | 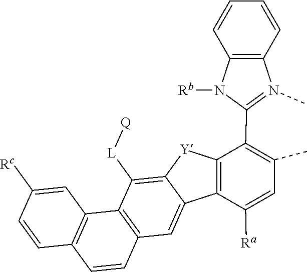 |
| L_{A96}- (L)(Q)(Y′)(R^{a})(R^{b})(R^{c}), wherein L_{A96}- (L1)(Q1)(Y1)(R1)(R1) to L_{A96}- (L28)(Q56)(Y4)(R120) (R120) (R120) have the structure | 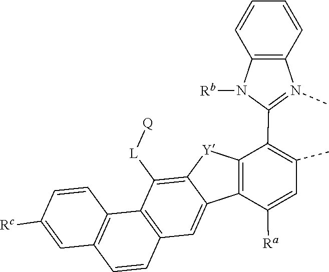 |
| L_{A97}-(L)(Q)(Y′)(R^{a})(R^{b})(R^{c}), wherein L_{A97}- (L1)(Q1)(Y1)(R1)(R1) to L_{A97}- (L28)(Q56)(Y4)(R120)(R120) (R120) have the structure | 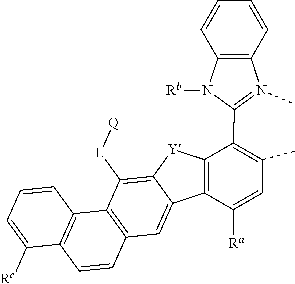 |
| L_{A98}- (L)(Q)(Y′)(R^{a})(R^{b})(R^{c}), wherein L_{A98}- (L1)(Q1)(Y1)(R1)(R1) to L_{A98}- (L28)(Q56)(Y4)(R120) (R120) (R120) have the structure | 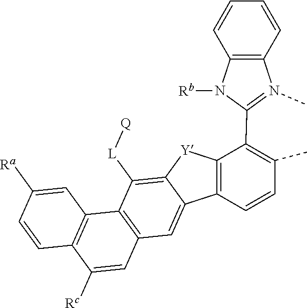 |
| L_{A99}-(L)(Q)(Y′)(R^{a})(R^{b})(R^{c}), wherein L_{A99}- (L1)(Q1)(Y1)(R1)(R1) to L_{A99}- (L28)(Q56)(Y4)(R120)(R120) (R120) have the structure | 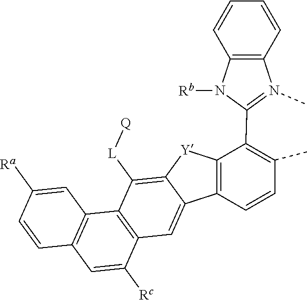 |
| L_{A100}- (L)(Q)(Y′)(R^{a})(R^{b})(R^{c}), wherein L_{A100}- (L1)(Q1)(Y1)(R1)(R1) to L_{A100}- (L28)(Q56)(Y4)(R120) (R120) (R120) have the structure | 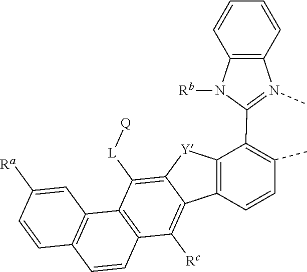 |
| L_{A101}-(L)(Q)(Y′)(R^{a})(R^{b})(R^{c}), wherein L_{A101}- (L1)(Q1)(Y1)(R1)(R1) to L_{A101}- (L28)(Q56)(Y4)(R120)(R120) (R120) have the structure | 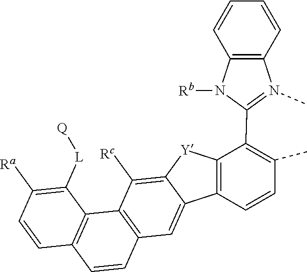 |
| L_{A102}- (L)(Q)(Y′)(R^{a})(R^{b})(R^{c}), wherein L_{A102}- (L1)(Q1)(Y1)(R1)(R1) to L_{A102}- (L28)(Q56)(Y4)(R120) (R120) (R120) have the structure | 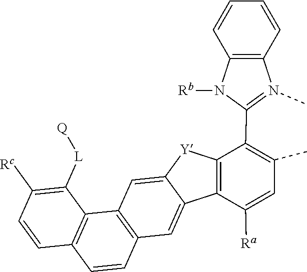 |
| L_{A103}-(L)(Q)(Y′)(R^{a})(R^{b})(R^{c}), wherein L_{A103}- (L1)(Q1)(Y1)(R1)(R1) to L_{A103}- (L28)(Q56)(Y4)(R120)(R120) (R120) have the structure | 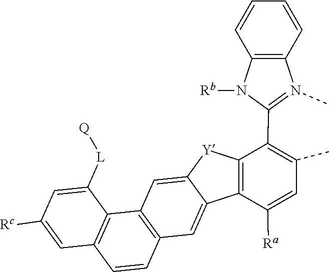 |
| L_{A104}- (L)(Q)(Y′)(R^{a})(R^{b})(R^{c}), wherein L_{A104}- (L1)(Q1)(Y1)(R1)(R1) to L_{A104}- (L28)(Q56)(Y4)(R120) (R120) (R120) have the structure | 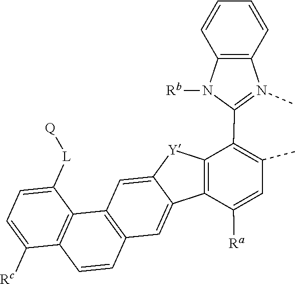 |
| L_{A105}-(L)(Q)(Y′)(R^{a})(R^{b})(R^{c}), wherein L_{A105}- (L1)(Q1)(Y1)(R1)(R1) to L_{A105}- (L28)(Q56)(Y4)(R120)(R120) (R120) have the structure | 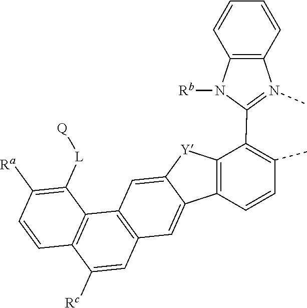 |
| L_{A106}- (L)(Q)(Y′)(R^{a})(R^{b})(R^{c}), wherein L_{A106}- (L1)(Q1)(Y1)(R1)(R1) to L_{A106}- (L28)(Q56)(Y4)(R120) (R120) (R120) have the structure | 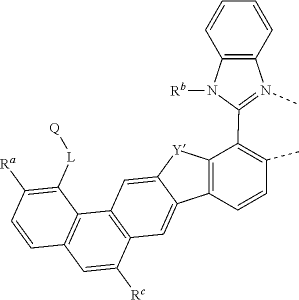 |
| L_{A107}-(L)(Q)(Y′)(R^{a})(R^{b})(R^{c}), wherein L_{A107}- (L1)(Q1)(Y1)(R1)(R1) to L_{A107}- (L28)(Q56)(Y4)(R120)(R120) (R120) have the structure | 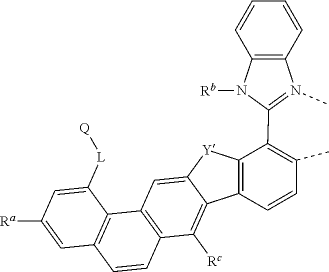 |
| L_{A108}- (L)(Q)(Y′)(R^{a})(R^{b})(R^{c}), wherein L_{A108}- (L1)(Q1)(Y1)(R1)(R1) to L_{A108}- (L28)(Q56)(Y4)(R120) (R120) (R120) have the structure | 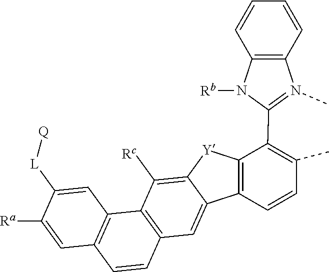 |
| L_{A109}-(L)(Q)(Y′)(R^{a})(R^{b})(R^{c}), wherein L_{A109}- (L1)(Q1)(Y1)(R1)(R1) to L_{A109}- (L28)(Q56)(Y4)(R120)(R120) (R120) have the structure | 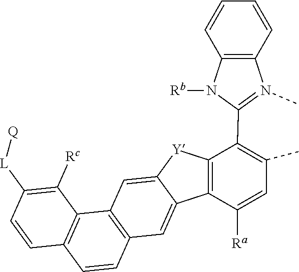 |
| L_{A110}- (L)(Q)(Y′)(R^{a})(R^{b})(R^{c}), wherein L_{A110}- (L1)(Q1)(Y1)(R1)(R1) to L_{A110}- (L28)(Q56)(Y4)(R120) (R120) (R120) have the structure | 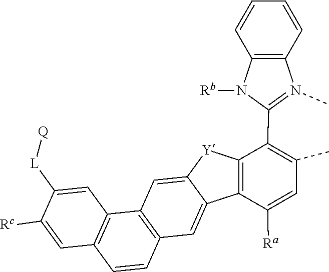 |
| L_{A111}-(L)(Q)(Y′)(R^{a})(R^{b})(R^{c}), wherein L_{A111}- (L1)(Q1)(Y1)(R1)(R1) to L_{A111}- (L28)(Q56)(Y4)(R120)(R120) (R120) have the structure | 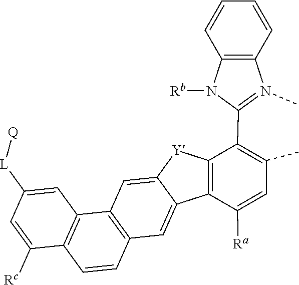 |
| L_{A112}- (L)(Q)(Y′)(R^{a})(R^{b})(R^{c}), wherein L_{A112}- (L1)(Q1)(Y1)(R1)(R1) to L_{A112}- (L28)(Q56)(Y4)(R120) (R120) (R120) have the structure | 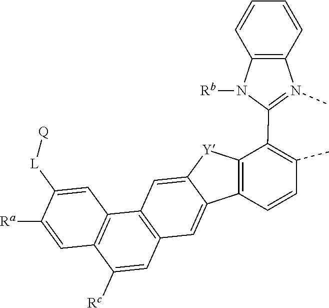 |
| L_{A113}-(L)(Q)(Y′)(R^{a})(R^{b})(R^{c}), wherein L_{A113}- (L1)(Q1)(Y1)(R1)(R1) to L_{A113}- (L28)(Q56)(Y4)(R120)(R120) (R120) have the structure | 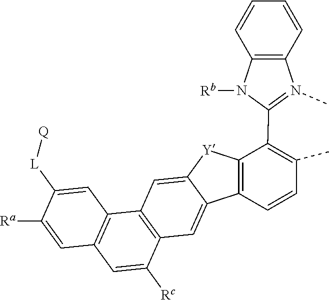 |
| L_{A114}- (L)(Q)(Y′)(R^{a})(R^{b})(R^{c}), wherein L_{A114}- (L1)(Q1)(Y1)(R1)(R1) to L_{A114}- (L28)(Q56)(Y4)(R120) (R120) (R120) have the structure | 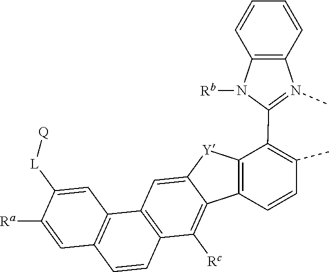 |
| L_{A115}-(L)(Q)(Y′)(R^{a})(R^{b})(R^{c}), wherein L_{A115}- (L1)(Q1)(Y1)(R1)(R1) to L_{A115}- (L28)(Q56)(Y4)(R120)(R120) (R120) have the structure | 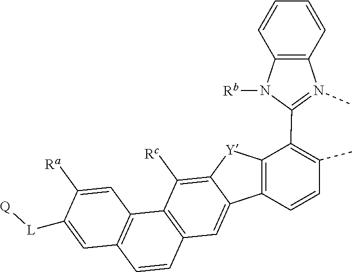 |
| L_{A116}- (L)(Q)(Y′)(R^{a})(R^{b})(R^{c}), wherein L_{A116}- (L1)(Q1)(Y1)(R1)(R1) to L_{A116}- (L28)(Q56)(Y4)(R120) (R120) (R120) have the structure | 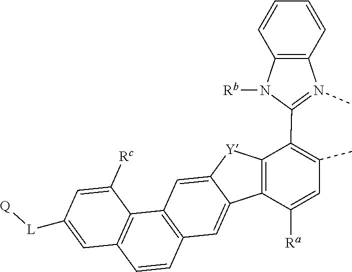 |
| L_{A117}-(L)(Q)(Y′)(R^{a})(R^{b})(R^{c}), wherein L_{A117}- (L1)(Q1)(Y1)(R1)(R1) to L_{A117}- (L28)(Q56)(Y4)(R120)(R120) (R120) have the structure | 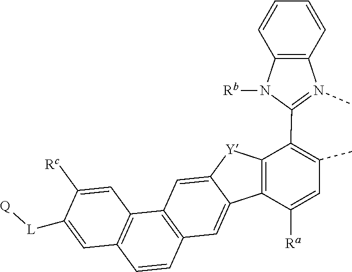 |
| L_{A118}- (L)(Q)(Y′)(R^{a})(R^{b})(R^{c}), wherein L_{A118}- (L1)(Q1)(Y1)(R1)(R1) to L_{A118}- (L28)(Q56)(Y4)(R120) (R120) (R120) have the structure | 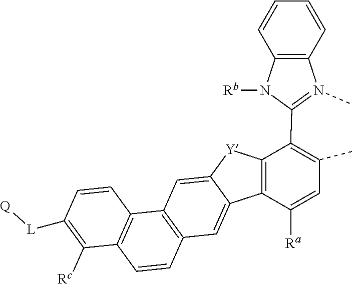 |
| L_{A119}-(L)(Q)(Y′)(R^{a})(R^{b})(R^{c}), wherein L_{A119}- (L1)(Q1)(Y1)(R1)(R1) to L_{A119}- (L28)(Q56)(Y4)(R120)(R120) (R120) have the structure | 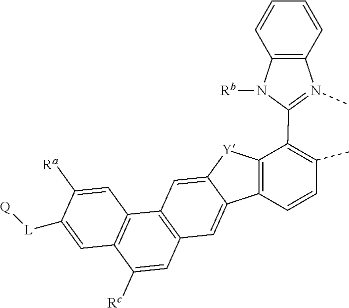 |
| L_{A120}- (L)(Q)(Y′)(R^{a})(R^{b})(R^{c}), wherein L_{A120}- (L1)(Q1)(Y1)(R1)(R1) to L_{A120}- (L28)(Q56)(Y4)(R120) (R120) (R120) have the structure | 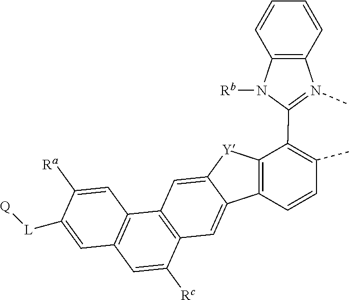 |
| L_{A121}-(L)(Q)(Y′)(R^{a})(R^{b})(R^{c}), wherein L_{A121}- (L1)(Q1)(Y1)(R1)(R1) to L_{A121}- (L28)(Q56)(Y4)(R120)(R120) (R120) have the structure | 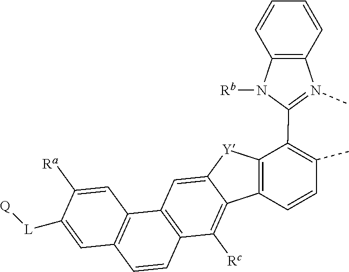 |
| L_{A122}- (L)(Q)(Y′)(R^{a})(R^{b})(R^{c}), wherein L_{A122}- (L1)(Q1)(Y1)(R1) to L_{A122}- (L28)(Q56)(Y4)(R120) (R120) have the structure | 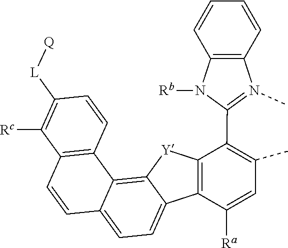 |
| L_{A123}-(L)(Q)(Y′)(R^{a})(R^{b})(R^{c}), wherein L_{A123}- (L1)(Q1)(Y1)(R1)(R1) to L_{A123}- (L28)(Q56)(Y4)(R120)(R120) (R120) have the structure | 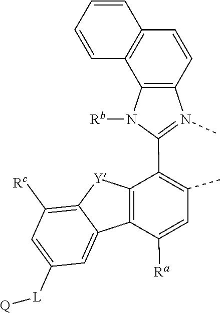 |
| L_{A124}- (L)(Q)(Y′)(R^{a})(R^{b})(R^{c}), wherein L_{A124}- (L1)(Q1)(Y1)(R1)(R1) to L_{A124}- (L28)(Q56)(Y4)(R120) (R120) (R120) have the structure | 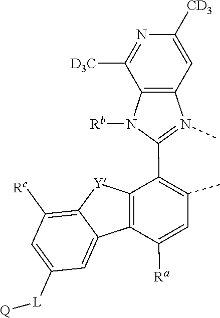 |
| L_{A125}-(L)(Q)(Y′)(R^{a})(R^{b})(R^{c}), wherein L_{A125}- (L1)(Q1)(Y1)(R1)(R1) to L_{A125}- (L28)(Q56)(Y4)(R120)(R120) (R120) have the structure | 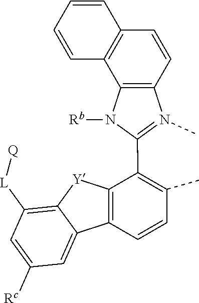 |
| L_{A126}- (L)(Q)(Y′)(R^{a})(R^{b})(R^{c}), wherein L_{A126}- (L1)(Q1)(Y1)(R1)(R1) to L_{A126}- (L28)(Q56)(Y4)(R120) (R120) (R120) have the structure | 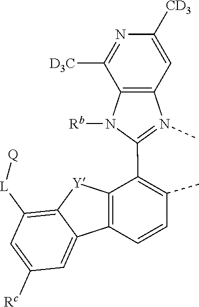 |
| L_{A127}-(L)(Q)(Y′)(R^{a})(R^{b})(R^{c}), wherein L_{A127}- (L1)(Q1)(Y1)(R1)(R1) to L_{A127}- (L28)(Q56)(Y4)(R120)(R120) (R120) have the structure | 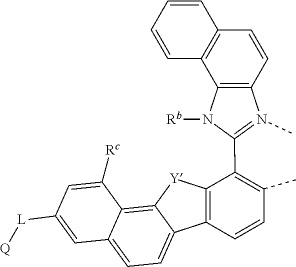 |
| L_{A128}- (L)(Q)(Y′)(R^{a})(R^{b})(R^{c}), wherein L_{A128}- (L1)(Q1)(Y1)(R1)(R1) to L_{A128}- (L28)(Q56)(Y4)(R120) (R120) (R120) have the structure | 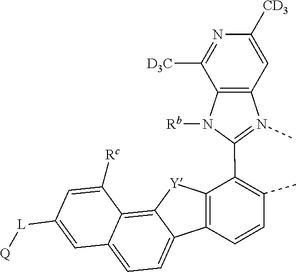 |
| L_{A129}-(L)(Q)(Y′)(R^{a})(R^{b})(R^{c}), wherein L_{A129}- (L1)(Q1)(Y1)(R1)(R1) to L_{A129}- (L28)(Q56)(Y4)(R120)(R120) (R120) have the structure | 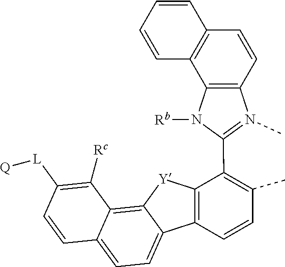 |
| L_{A130}- (L)(Q)(Y′)(R^{a})(R^{b})(R^{c}), wherein L_{A130}- (L1)(Q1)(Y1)(R1)(R1) to L_{A130}- (L28)(Q56)(Y4)(R120) (R120) (R120) have the structure | 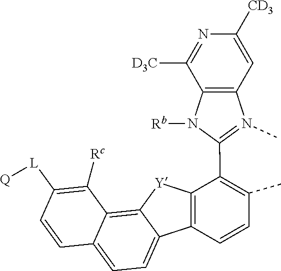 |
| L_{A131}-(L)(Q)(Y′)(R^{a})(R^{b})(R^{c}), wherein L_{A131}- (L1)(Q1)(Y1)(R1)(R1) to L_{A131}- (L28)(Q56)(Y4)(R120)(R120) (R120) have the structure | 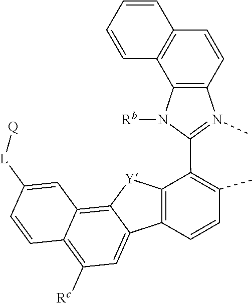 |
| L_{A132}- (L)(Q)(Y′)(R^{a})(R^{b})(R^{c}), wherein L_{A132}- (L1)(Q1)(Y1)(R1)(R1) to L_{A132}- (L28)(Q56)(Y4)(R120) (R120) (R120) have the structure | 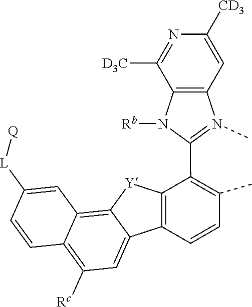 |
| L_{A133}-(L)(Q)(Y′)(R^{a})(R^{b})(R^{c}), wherein L_{A133}- (L1)(Q1)(Y1)(R1)(R1) to L_{A133}- (L28)(Q56)(Y4)(R120)(R120) (R120) have the structure | 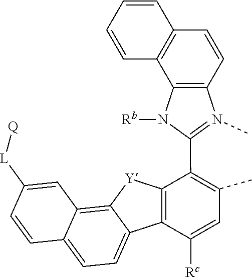 |
| L_{A134}- (L)(Q)(Y′)(R^{a})(R^{b})(R^{c}), wherein L_{A134}- (L1)(Q1)(Y1)(R1)(R1) to L_{A134}- (L28)(Q56)(Y4)(R120) (R120) (R120) have the structure | 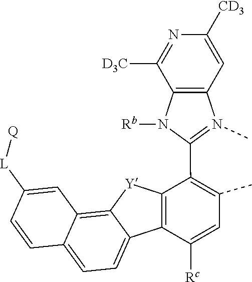 |
| L_{A135}-(L)(Q)(Y′)(R^{a})(R^{b})(R^{c}), wherein L_{A135}- (L1)(Q1)(Y1)(R1)(R1) to L_{A135}- (L28)(Q56)(Y4)(R120)(R120) (R120) have the structure | 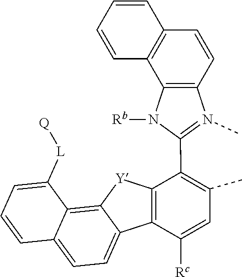 |
| L_{A136}- (L)(Q)(Y′)(R^{a})(R^{b})(R^{c}), wherein L_{A136}- (L1)(Q1)(Y1)(R1)(R1) to L_{A136}- (L28)(Q56)(Y4)(R120) (R120) (R120) have the structure | 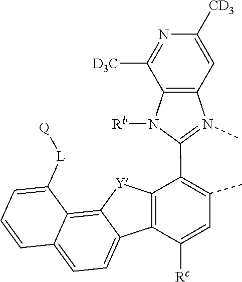 |
| L_{A137}-(L)(Q)(Y′)(R^{a})(R^{b})(R^{c}), wherein L_{A137}- (L1)(Q1)(Y1)(R1)(R1) to L_{A137}- (L28)(Q56)(Y4)(R120)(R120) (R120) have the structure | 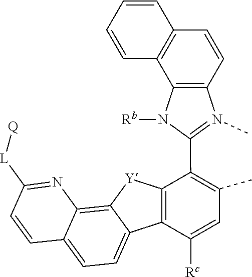 |
| L_{A138}- (L)(Q)(Y′)(R^{a})(R^{b})(R^{c}), wherein L_{A138}- (L1)(Q1)(Y1)(R1)(R1) to L_{A138}- (L28)(Q56)(Y4)(R120) (R120) (R120) have the structure | 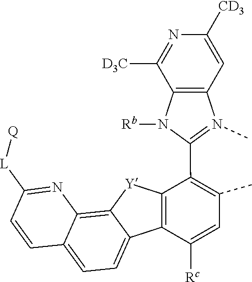 |
| L_{A139}-(L)(Q)(Y′)(R^{a})(R^{b})(R^{c}), wherein L_{A139}- (L1)(Q1)(Y1)(R1)(R1) to L_{A139}- (L28)(Q56)(Y4)(R120)(R120) (R120) have the structure | 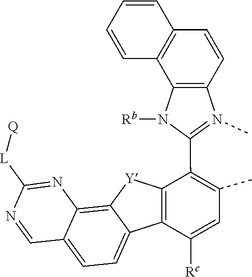 |
| L_{A140}- (L)(Q)(Y′)(R^{a})(R^{b})(R^{c}), wherein L_{A140}- (L1)(Q1)(Y1)(R1)(R1) to L_{A140}- (L28)(Q56)(Y4)(R120) (R120) (R120) have the structure | 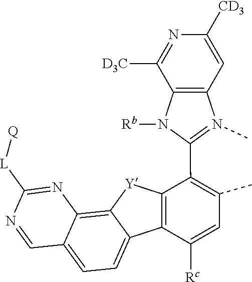 |

wherein R1 to R120 each have the structures defined in the following LIST 11:

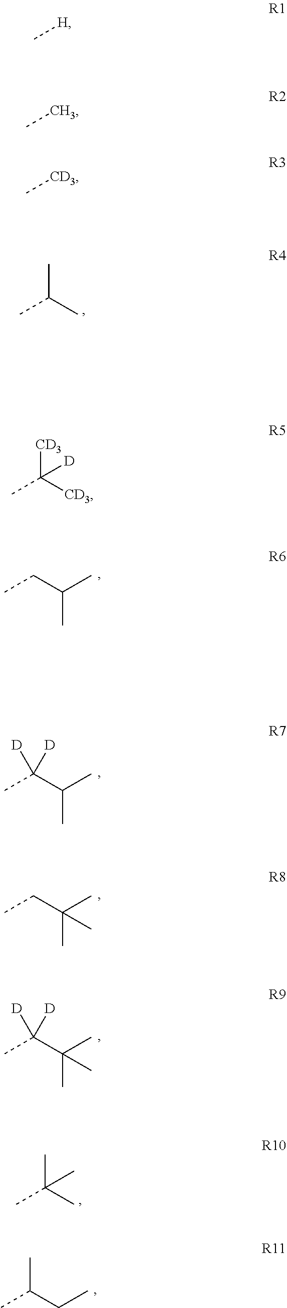

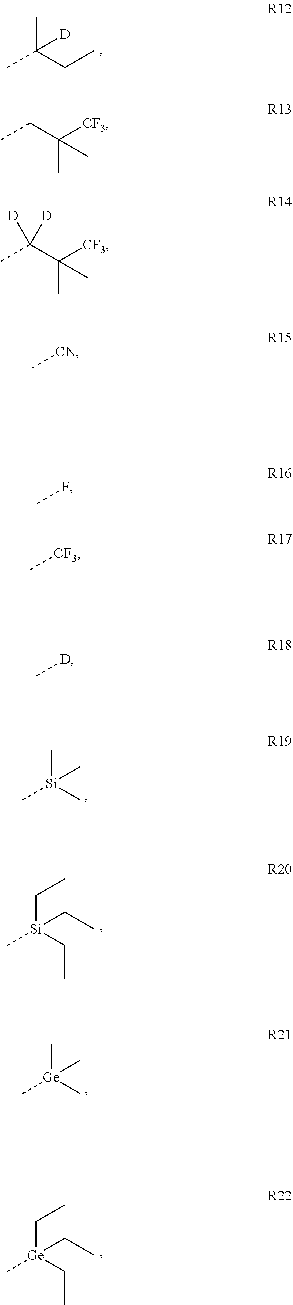

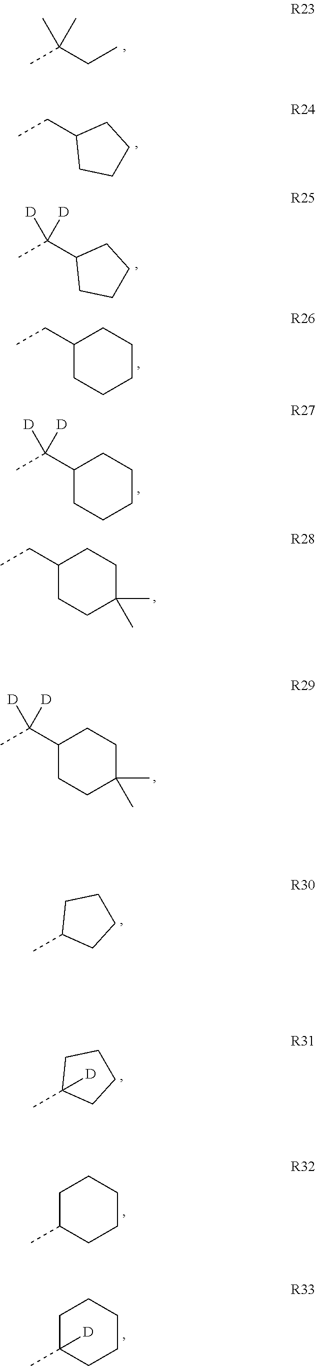

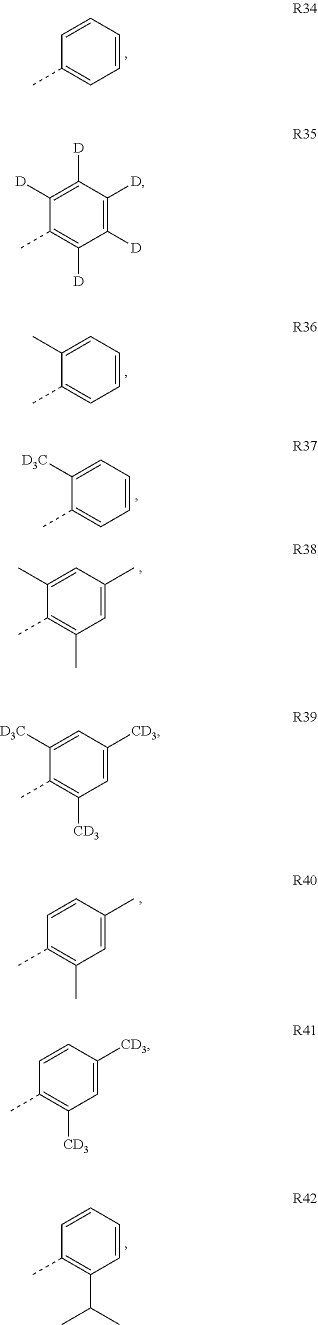

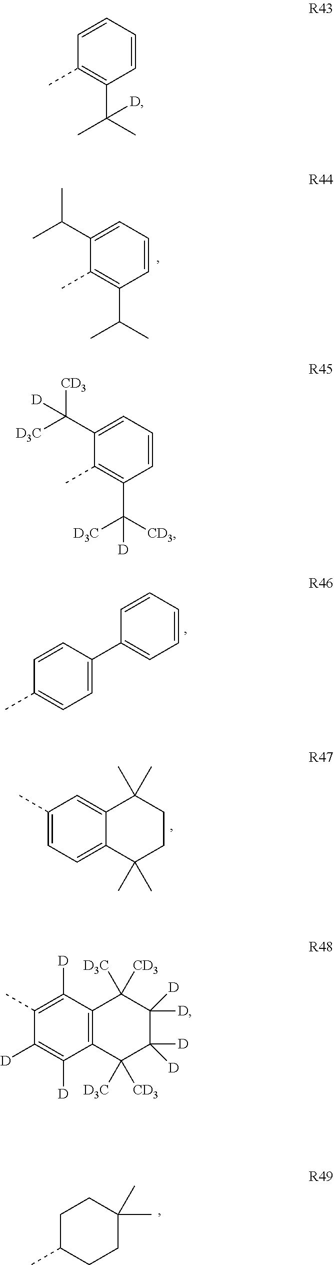

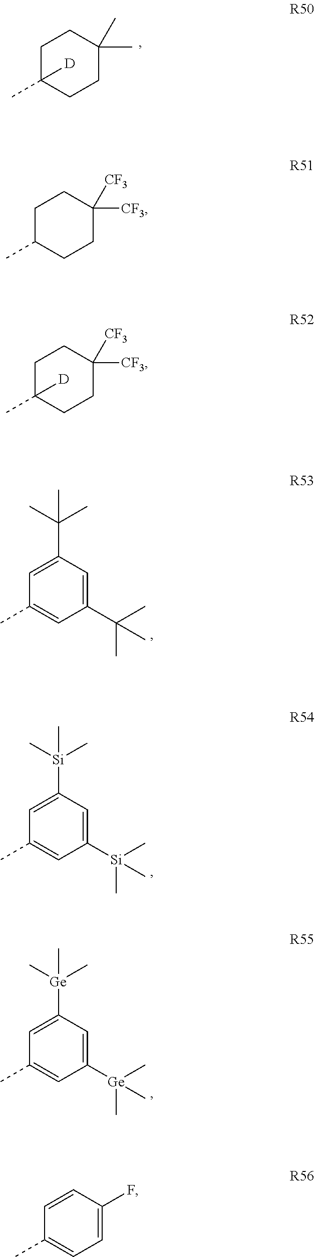

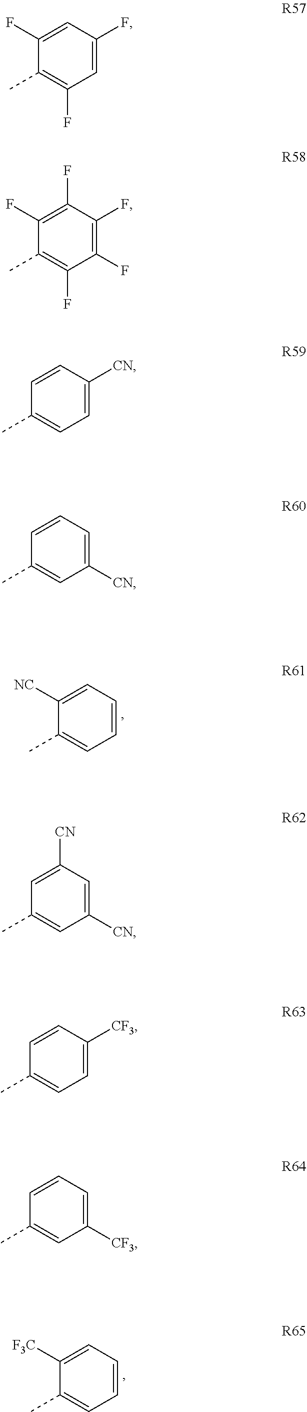

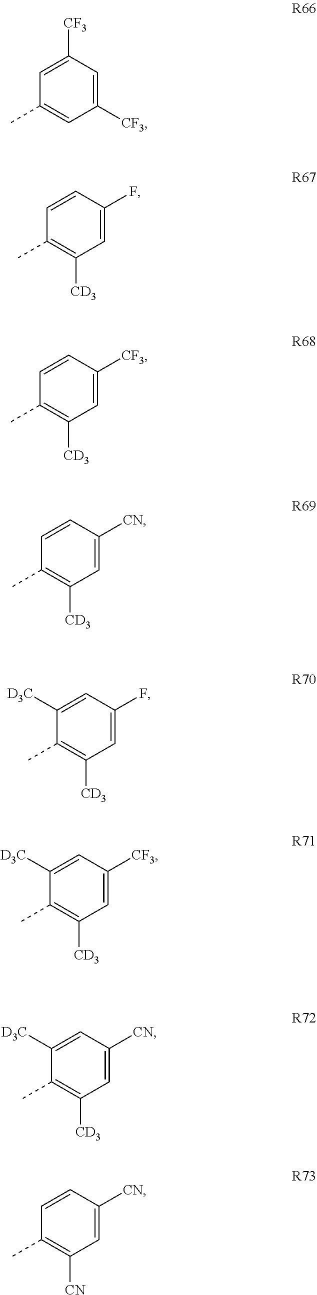

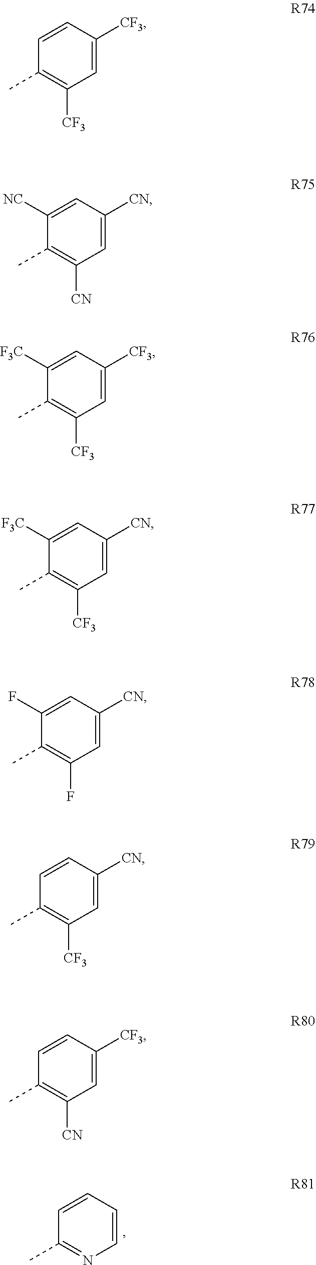

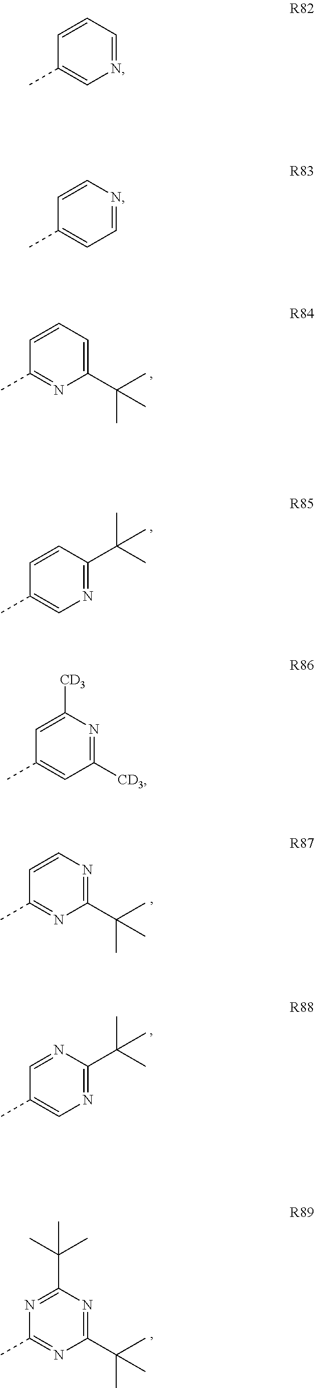

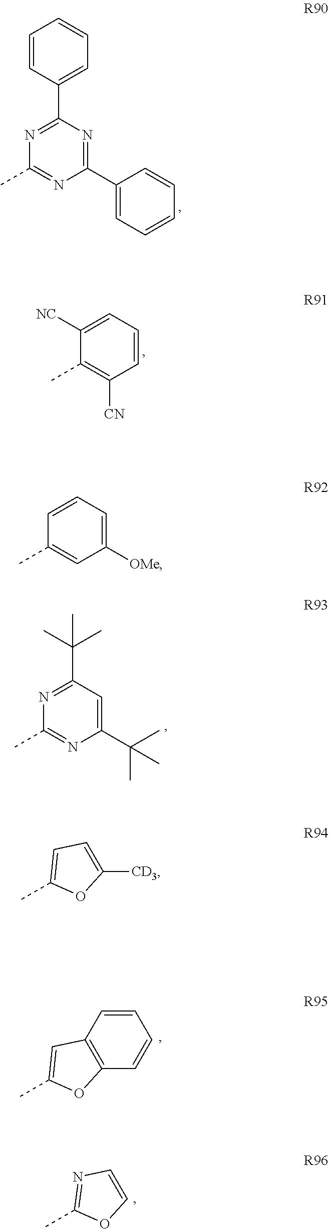

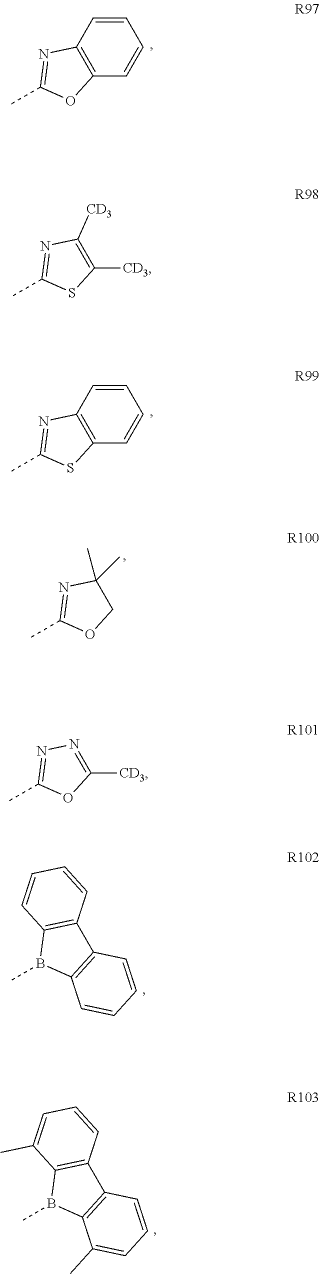

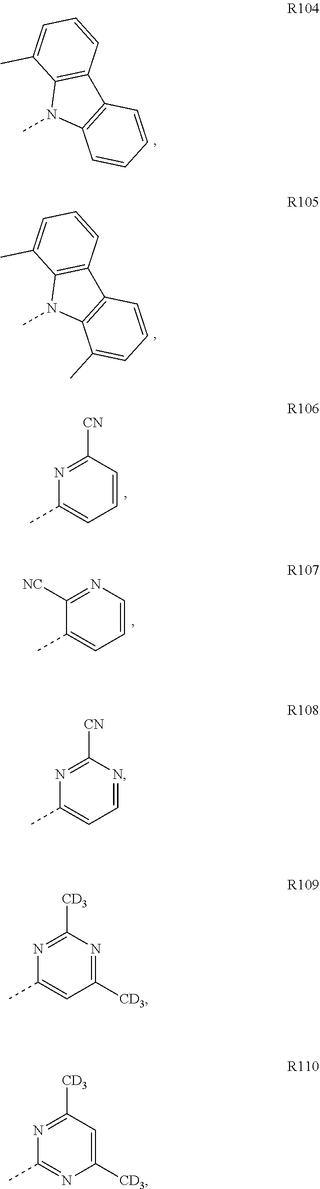

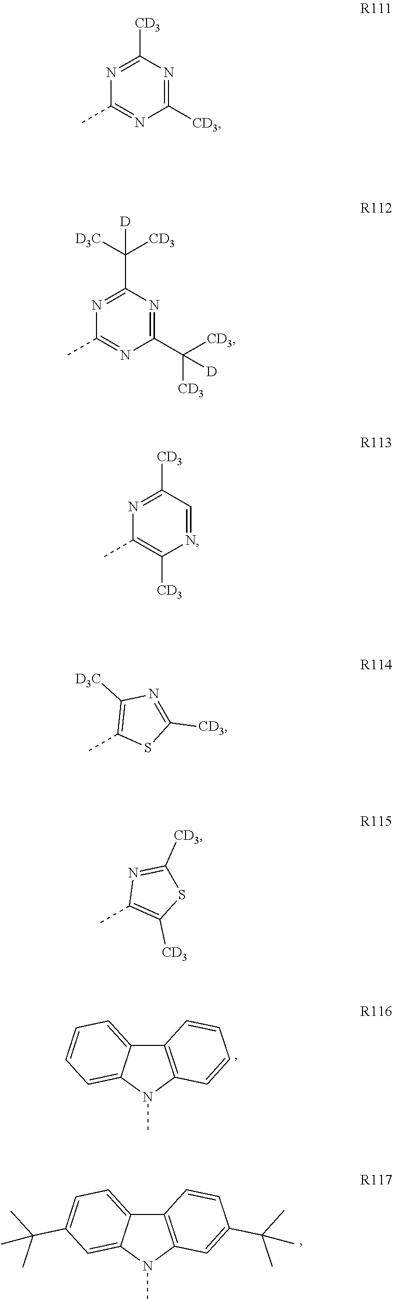

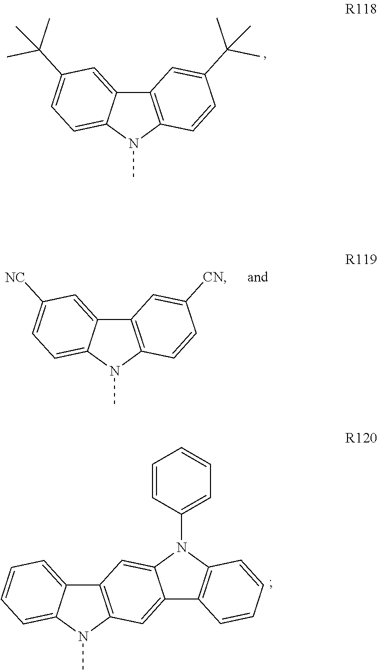

wherein Y1 to Y4 have the following structures:

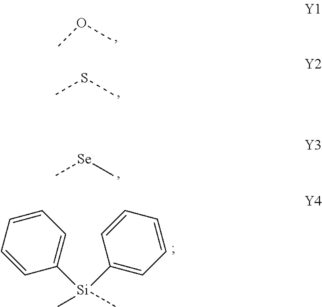

where in L1 to L28 have the structure defined in the following LIST 12:

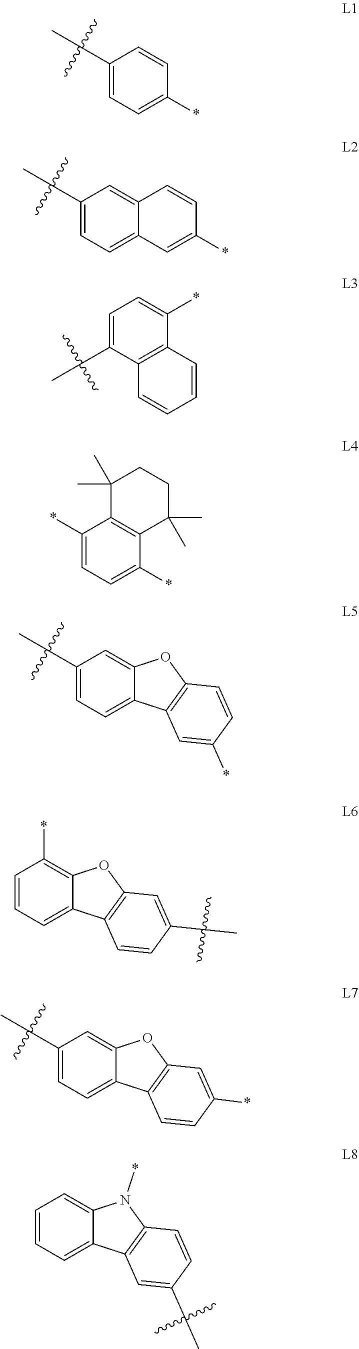

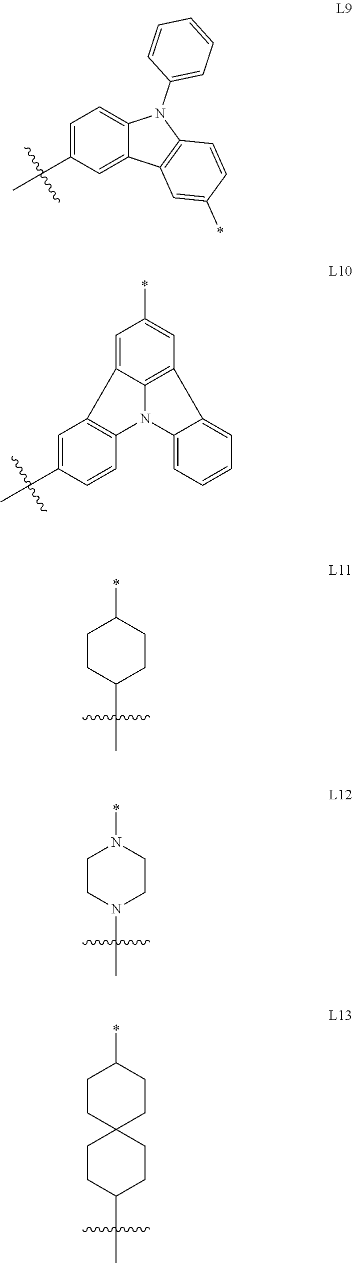

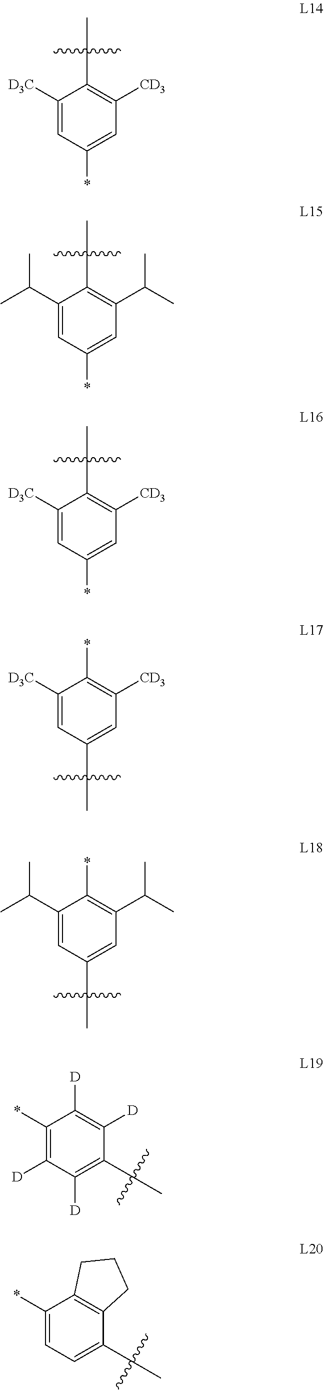

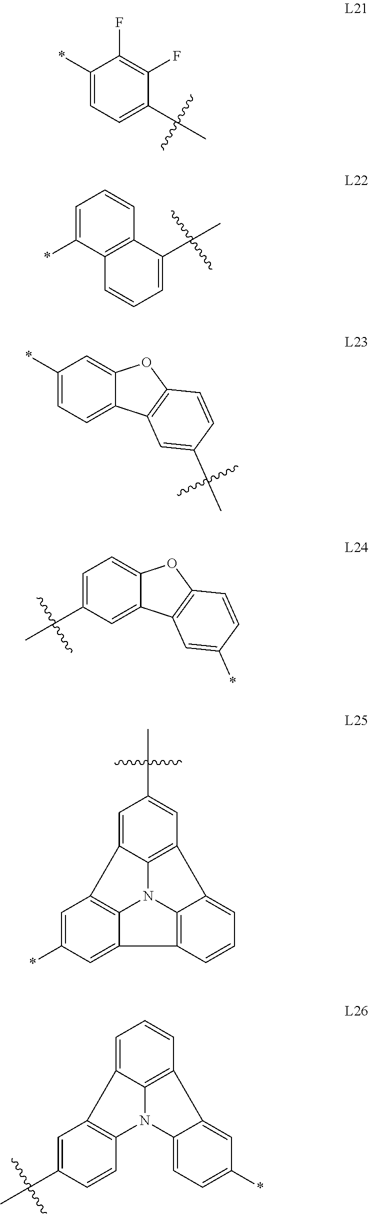

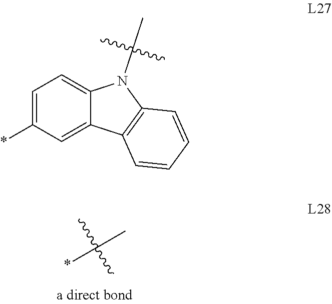

wherein, in LIST 12

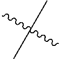

represents attachment to ring B or moiety C and * represents attachment to Q; and
wherein Q1 to Q56 have the structures defined in the following LIST 13:

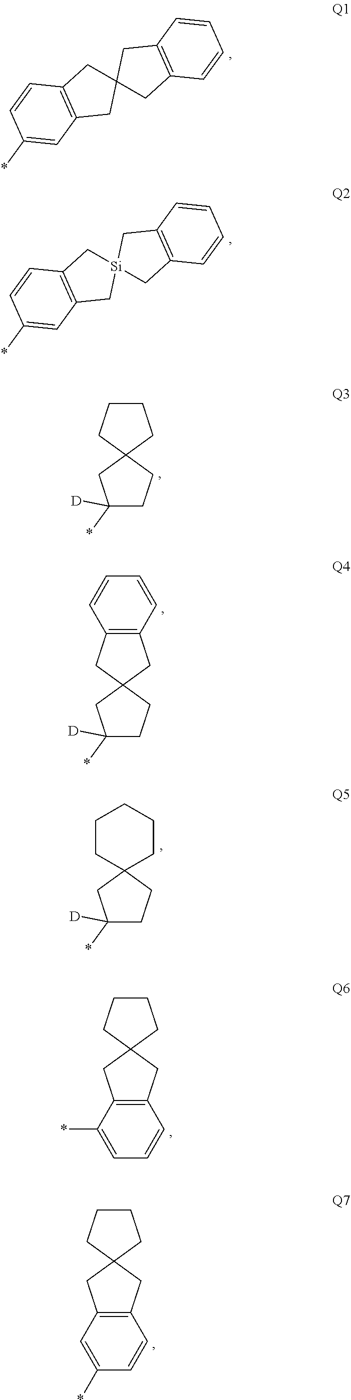

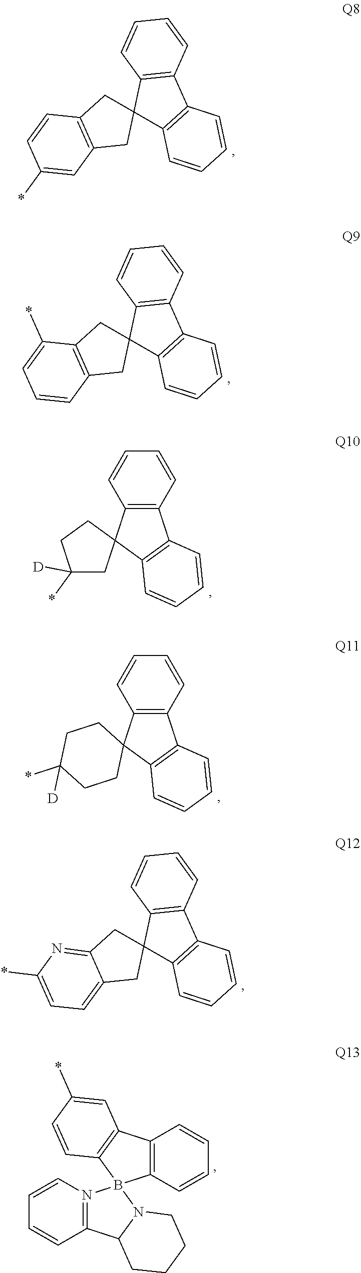

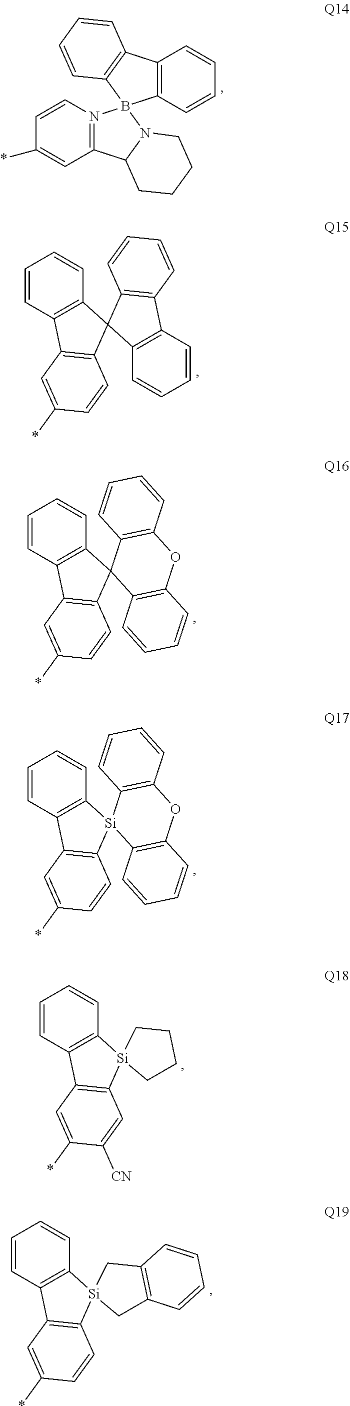

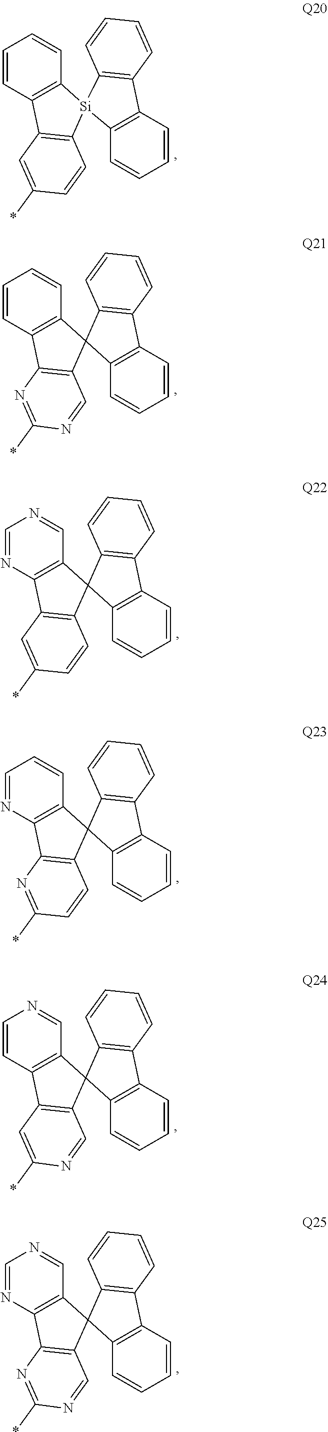 [SMILES: *c1ccc2c(c1)-c1ccccc1[Si]21c2ccccc2-c2ccccc21 ; *c1ncc2c(n1)-c1ccccc1C21c2ccccc2-c2ccccc21 ; *c1ccc2c(c1)-c1ncncc1C21c2ccccc2-c2ccccc21 ; *c1ccc2c(n1)-c1ncccc1C21c2ccccc2-c2ccccc21 ; *c1cc2c(cn1)C1(c3ccccc3-c3ccccc31)c1cnccc1-2 ; *c1ncc2c(n1)-c1ncncc1C21c2ccccc2-c2ccccc21]

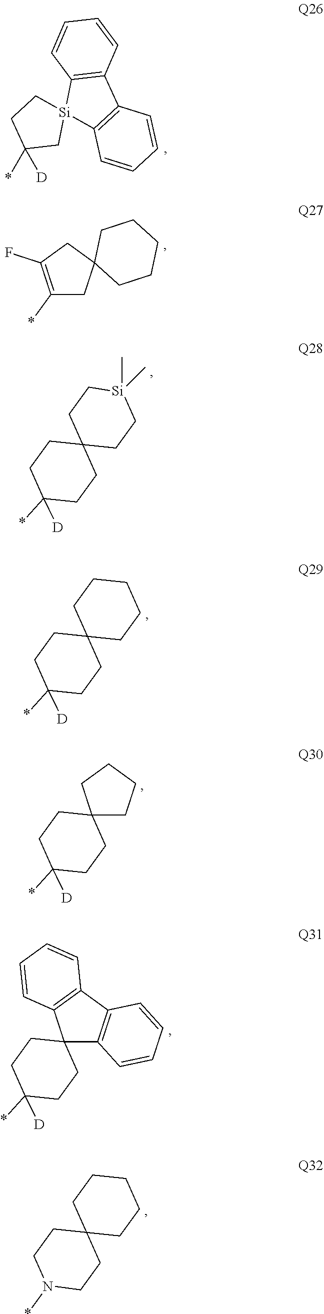

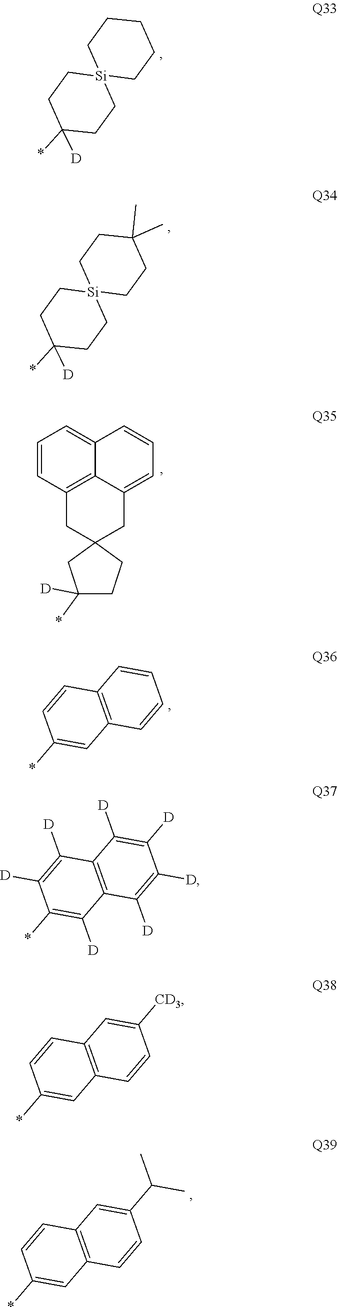

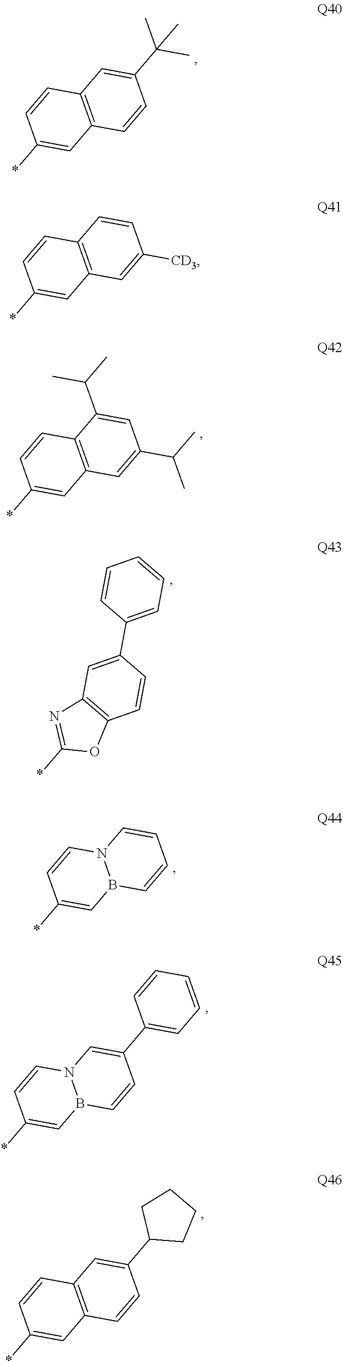

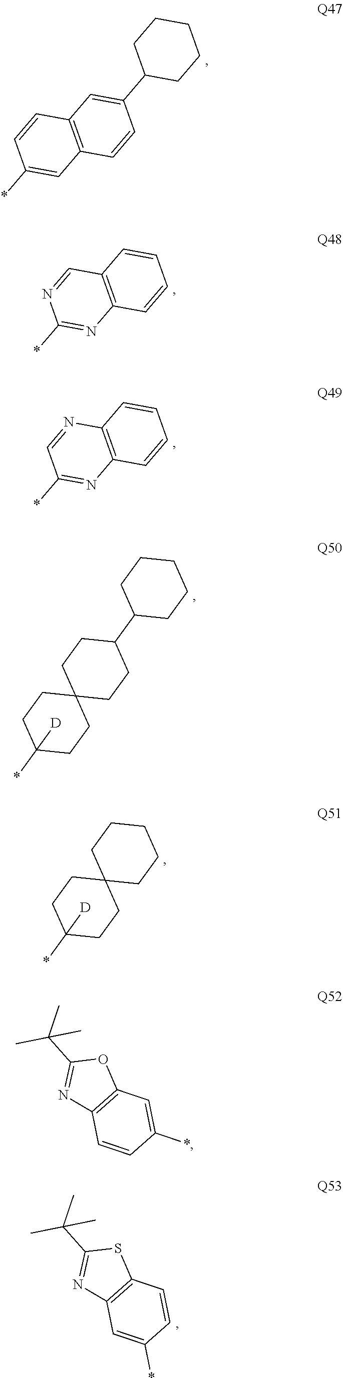

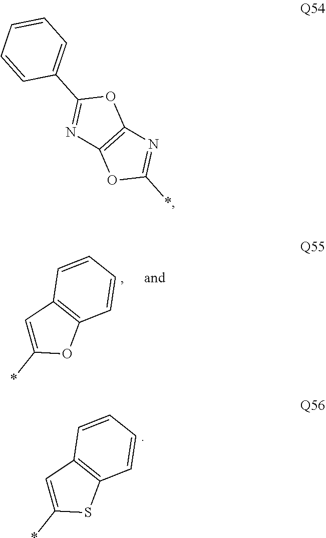

In some embodiments, L_{B} comprises an electron-withdrawing group from the EWG1 LIST as defined herein. In some embodiments, L_{B} comprises an electron-withdrawing group from the EWG2 LIST as defined herein. In some embodiments, L_{B} comprises an electron-withdrawing group from the EWG3 LIST as defined herein. In some embodiments, L_{B} comprises an electron-withdrawing group from the EWG4 LIST as defined herein. In some embodiments, L_{B} comprises an electron-withdrawing group from the Pi-EWG LIST as defined herein.

In some embodiments, L_{C} comprises an electron-withdrawing group from the EWG1 LIST as defined herein. In some embodiments, L_{C} comprises an electron-withdrawing group from the EWG2 LIST as defined herein. In some embodiments, L_{C} comprises an electron-withdrawing group from the EWG3 LIST as defined herein. In some embodiments, L_{C} comprises an electron-withdrawing group from the EWG4 LIST as defined herein. In some embodiments, L_{C} comprises an electron-withdrawing group from the Pi-EWG LIST as defined herein.

In some embodiments, the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound has a formula of Pt(L_{A})(L_{B}); and wherein L_{A} and L_{B} can be same or different. In some embodiments, L_{A} and L_{B} are connected to form a tetradentate ligand.

What is claimed:

1. A compound having a first ligand L_{A} comprising a structure of Formula I: 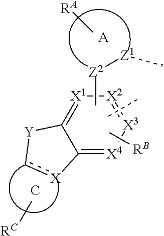
wherein:
at least one R^{B} or R^{C} is a substituent comprising a structure of Formula II 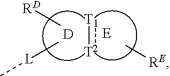
or Formula III, 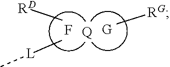
each of moiety A, moiety C, moiety D, moiety E, moiety F, and moiety G is independently a monocyclic ring or a polycyclic fused ring system, wherein the monocyclic ring or each ring of the polycyclic fused ring system is independently a 5-membered to 10-membered carbocyclic or heterocyclic ring.
Q is selected from the group consisting of B, C, Si, and Ge;
each of X, X¹ to X⁴, Z¹, and Z² is independently C or N;
each of T¹ and T² is independently C, N, or B;
the rings of moiety D and moiety E that contain T¹ and T² are both aromatic rings;
each [symbol] represents a single bond or a double bond;
Y is selected from the group consisting of BR, BRR′, NR, PR, P(O)R, O, S, Se, C═O, C═S, C═Se, C═NR′, C═CRR′, S═O, SO₂, CRR′, SiRR′, and GeRR′;
L is a direct bond or a substituted or unsubstituted monocyclic or polycyclic ring system;
each of R^{A}, R^{B}, R^{C}, R^{D}, R^{E}, R^{F}, and R^{G} independently represents mono to the maximum allowable substitution, or no substitution;
each R, R′, R^{A}, R^{B}, R^{C}, R^{D}, R^{E}, R^{F}, and R^{G} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M, having an atomic mass of at least 40;
metal M can be coordinated to other ligands;
L_{A} can be joined with other ligands to comprise a bidentate, tridentate, tetradentate, pentadentate, or hexadentate ligand; and
any two substituents can be joined or fused to form a ring;
with the provisos that:
(1) if moiety C is a 6-membered monocyclic ring, then
(a) at least one of R^{D} and R^{E} comprises a cyclic or heterocyclic group; and
(b) if Formula II is present and the combination of moieties D and E is a substituted 9-phenanthrene or a substituted 9-carbazole, then at least one of R^{D} and R^{E} is not phenyl; and
(2) if moiety C comprises at least three fused 6-membered rings and Formula III is present, then formula III is not

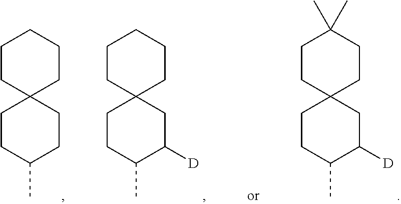

2. The compound of claim 1, wherein each R, R′, R^{A}, R^{B}, R^{C}, R^{D}, R^{E}, R^{F}, and R^{G} is independently hydrogen, or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

3. The compound of claim 1, wherein each of moiety A and moiety C is independently selected from the group consisting of the following Cyclic Moiety Group: benzene, pyridine, pyrimidine, pyridazine, pyrazine, triazine, imidazole, imidazole derived carbene, pyrazole, pyrrole, oxazole, furan, thiophene, thiazole, triazole, naphthalene, quinoline, isoquinoline, quinazoline, benzofuran, aza-benzofuran, phenanthro[3,2-b]benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene; and/or wherein each of moiety D and moiety E is independently selected from the group consisting of the following Cyclic Moiety Group: benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene; and/or wherein L is a direct bond, a substituted or unsubstituted monocyclic or polycyclic ring system; and/or wherein X is C; and/or wherein each of X¹ to X⁴ is C or wherein at least one of X¹ to X⁴ is N; and/or wherein Z¹ is N and Z² is C or wherein Z¹ is carbene carbon C and Z² is N; and/or wherein Y is selected from the group consisting of O, NR, CRR′, SiRR′, S, and Se.

4. The compound of claim 1, wherein at least one R^{A} comprises a substituent selected from the group consisting of alkyl, cycloalkyl, silyl, germyl, aryl, heteroaryl, and combinations thereof; and/or wherein at least one R^{B} comprises a substituent selected from the group consisting of alkyl, cycloalkyl, silyl, germyl, aryl, heteroaryl, and combinations thereof; and/or wherein at least one R^{C} comprises a substituent selected from the group consisting of alkyl, cycloalkyl, silyl, germyl, aryl, heteroaryl, and combinations thereof; and/or wherein at least one R^{F} comprises a substituent selected from the group consisting of alkyl, cycloalkyl, heterocycloalkyl, silyl, germyl, aryl, heteroaryl, and combinations thereof; and/or wherein at least one R^{G} comprises a substituent selected from the group consisting of alkyl, cycloalkyl, heterocycloalkyl, silyl, germyl, aryl, heteroaryl, and combinations thereof; and/or wherein L is a direct bond, a substituted or unsubstituted monocyclic or polycyclic ring system; and/or wherein the first ligand L_{A} comprises at least one electron-withdrawing group selected from the group consisting of LIST EWG1 defined herein; and/or wherein metal M is selected from the group consisting of Ir, Rh, Re, Ru, Os, Pt, Pd, Ag, Au, and Cu.

5. The compound of claim 1, wherein at least one R^{B} or R^{C} is a substituent comprising a structure of Formula II,

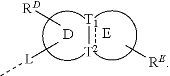

6. The compound of claim 1, wherein at least one R^{B} or R^{C} is a substituent comprises a structure of Formula III,

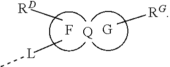

7. The compound of claim 6, wherein the structure of Formula III is selected from the group consisting of: 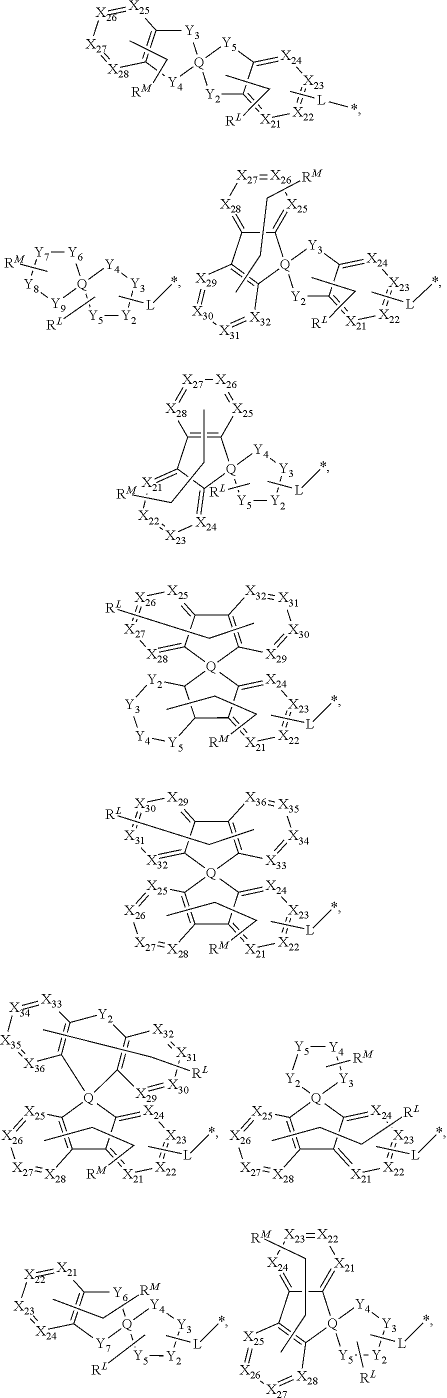 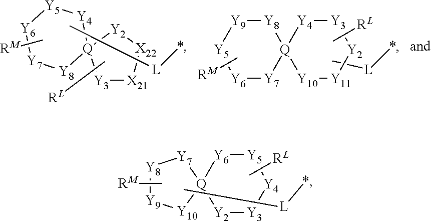
wherein:
X₂₁ to X₃₆ are each independently C or N;
each of Y₁ to Y₁₁ is selected from the group consisting of B, N, P, P(O), O, S, Se, C═O, C═S, C═Se, C═NR′, C═CRR′, S═O, SO₂, C, Si, and Ge;
each of R^{L} and R^{N} independently represents mono to the maximum allowable substitution, or no substitution;
each R, R′, R^{L}, and R^{M} is independently hydrogen, or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents can be joined or fused to form a ring.

8. The compound of claim 1, wherein the ligand L_{A} is selected from the group consisting of: 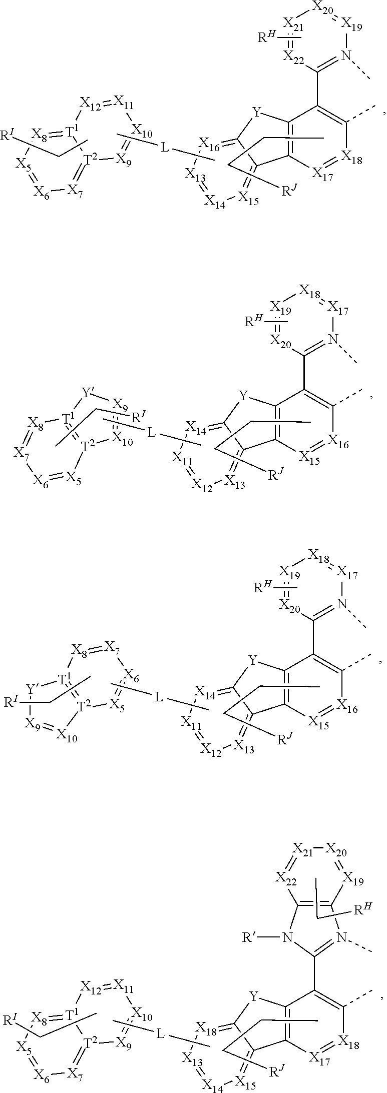 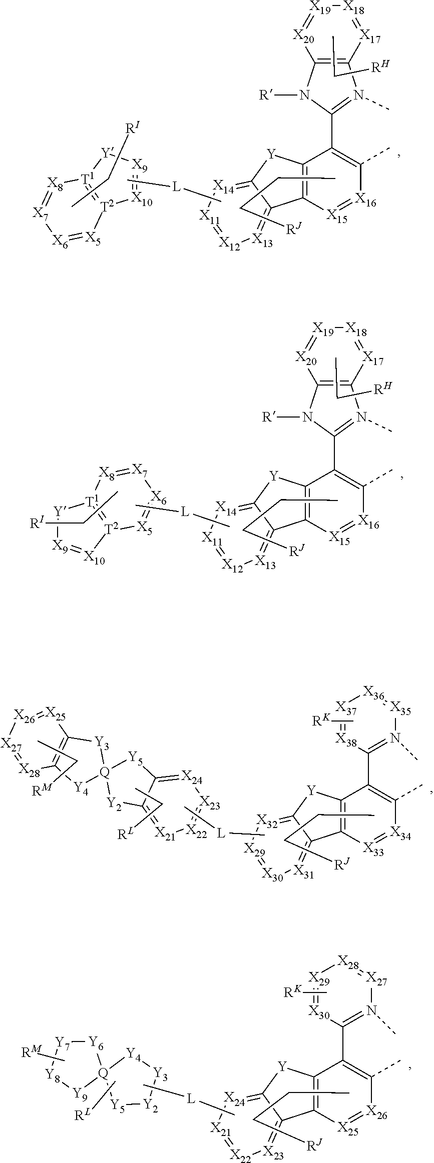 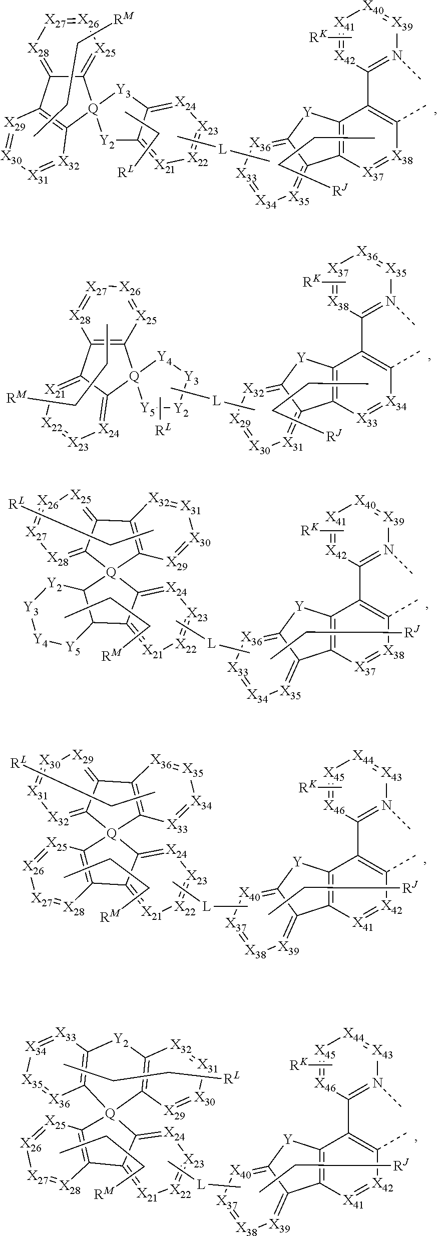 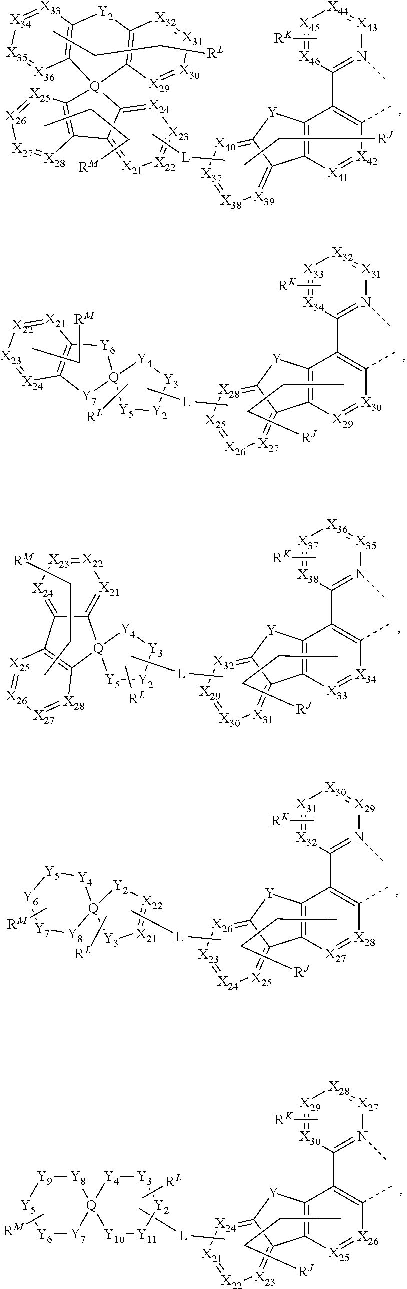 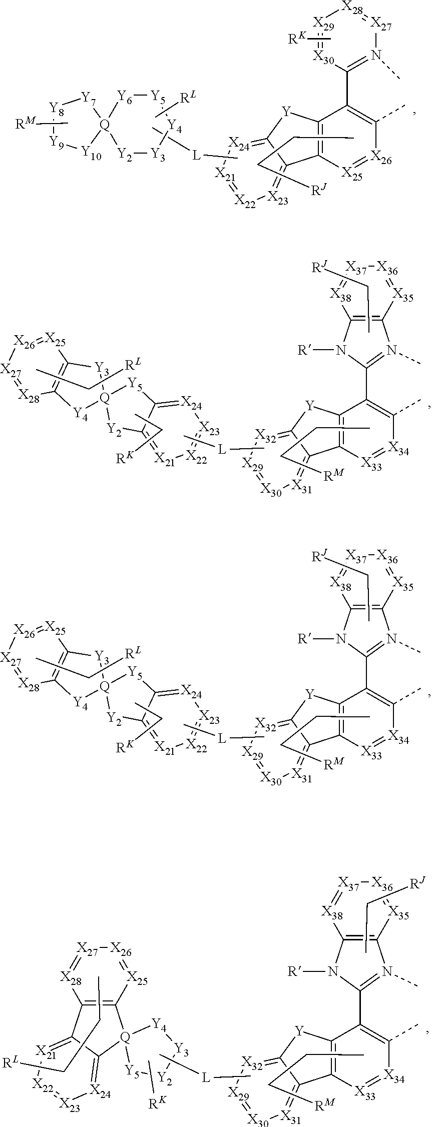 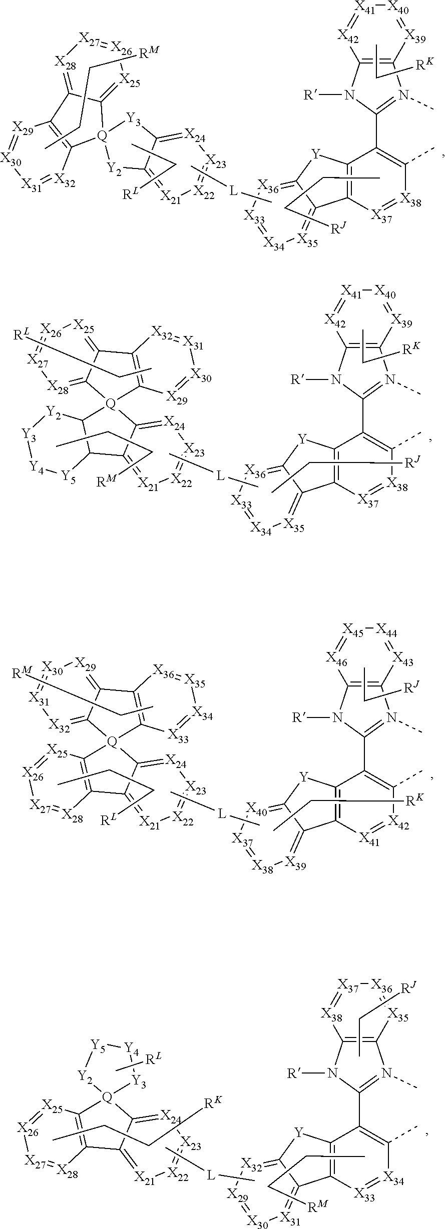 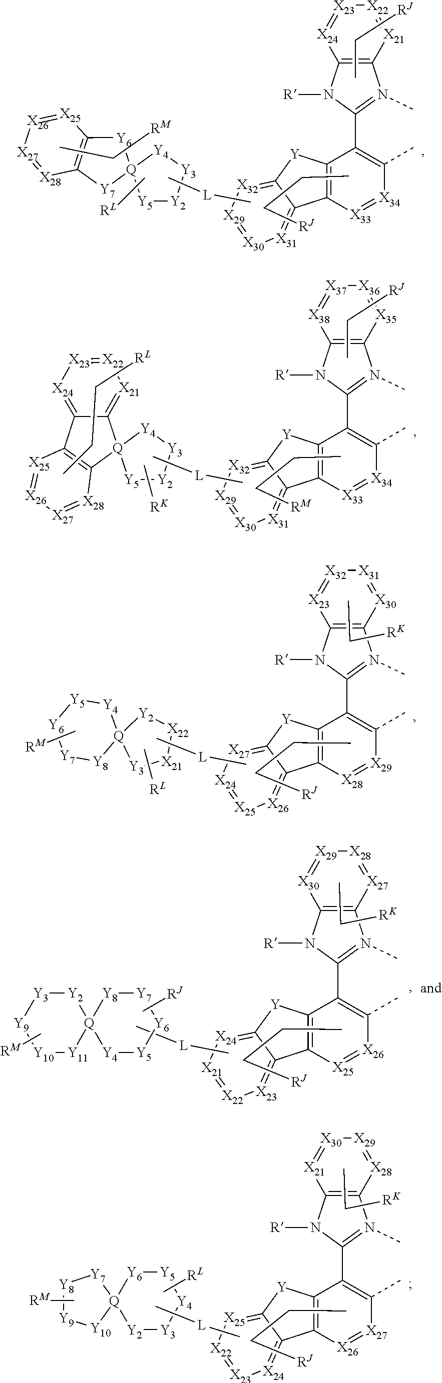
wherein
each of X₅ to X₄₆ is independently C or N;
each of Y₁ to Y₁₁ is independently selected from the group consisting of B, N, P, P(O), O, S, Se, C═O, C═S, C═Se, C═NR′, C═CRR′, S═O, SO₂, C, Si, and Ge;
each of R^{H}, R^{I}, R^{J}, R^{K}, R^{L}, and R^{M} independently represents mono to the maximum allowable substitution, or no substitution;
each R, R′, R^{H}, R^{I}, R^{J}, R^{K}, R^{L}, and R^{M} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
the remaining variables are the same as previously defined; and
any two substituents can be joined or fused to form a ring.

9. The compound of claim 1, wherein the ligand L_{A} is selected from the group consisting of: 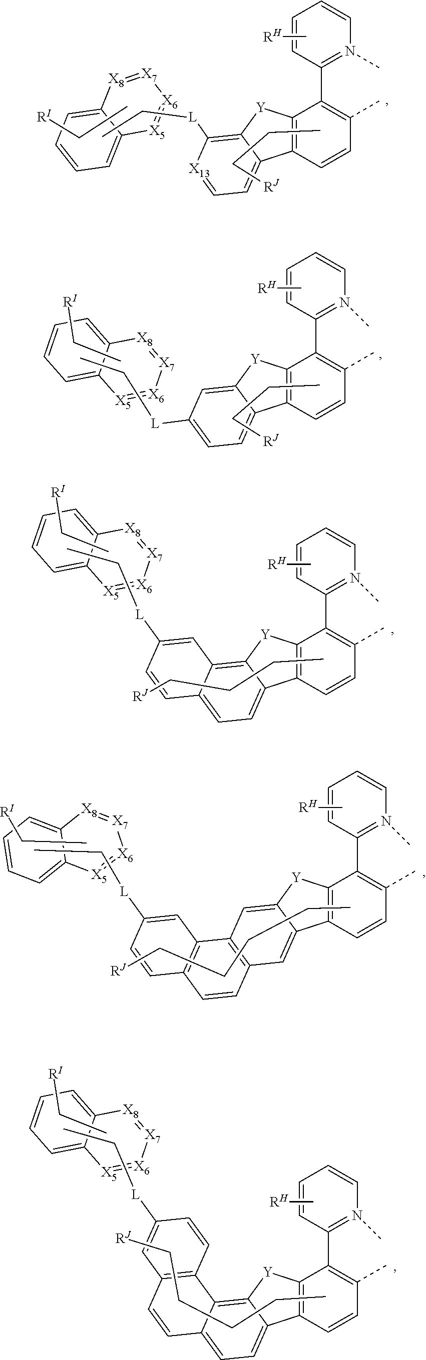 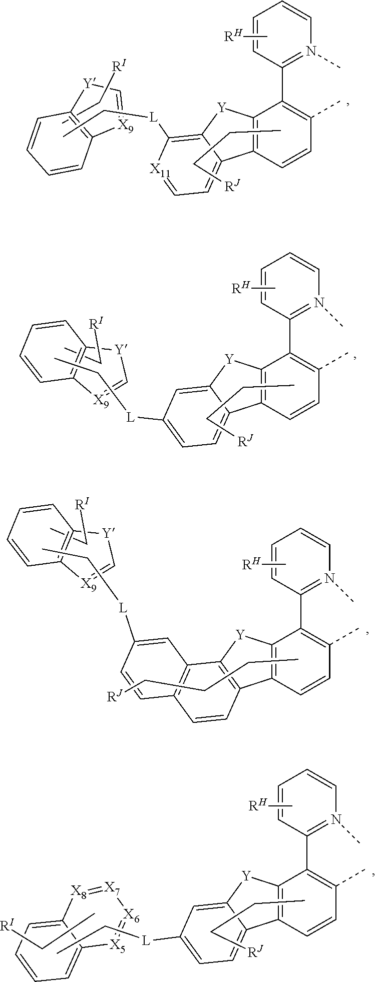 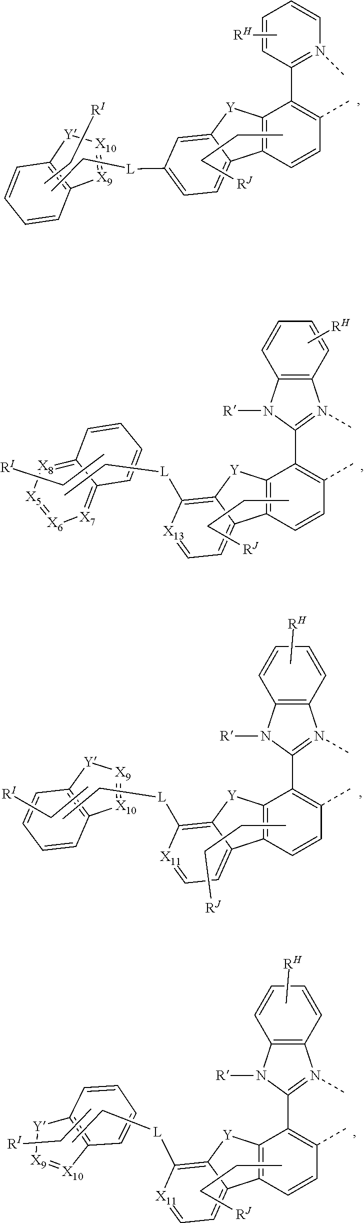 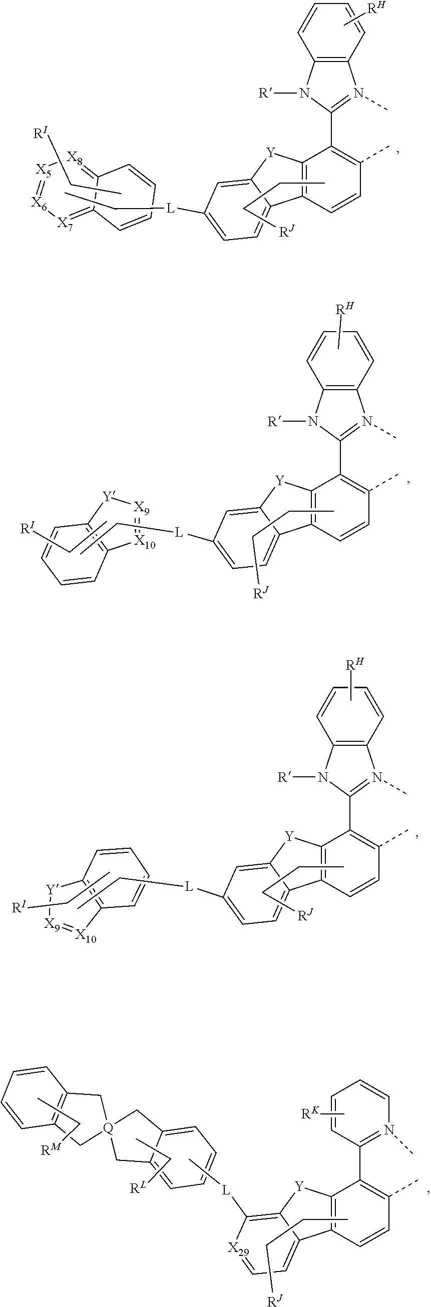 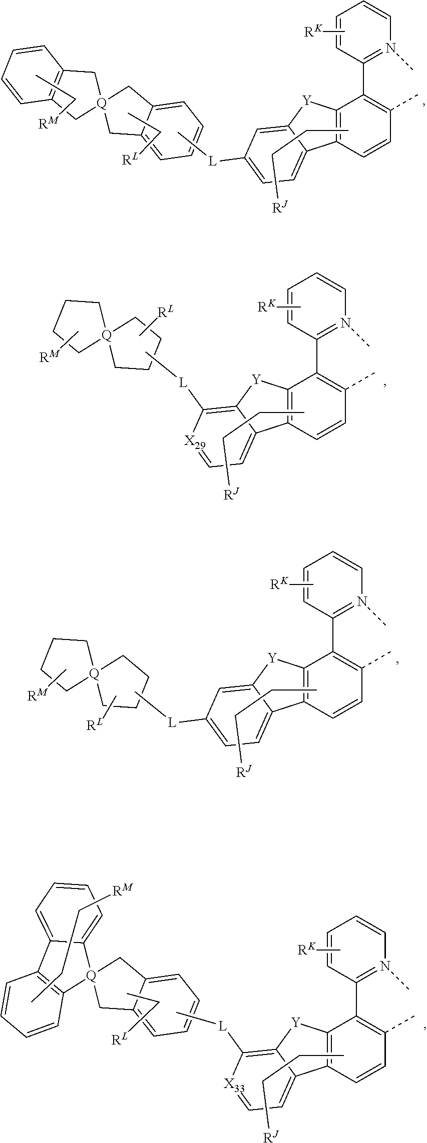 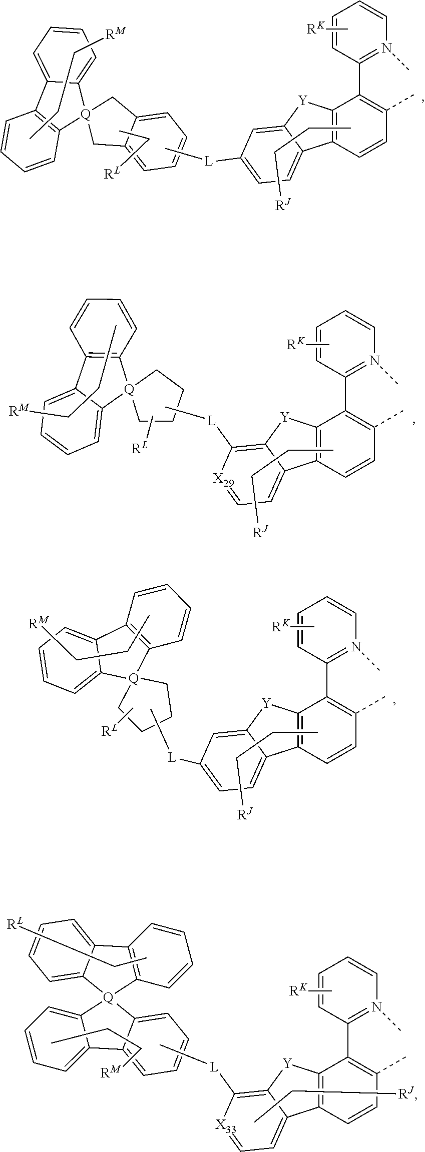 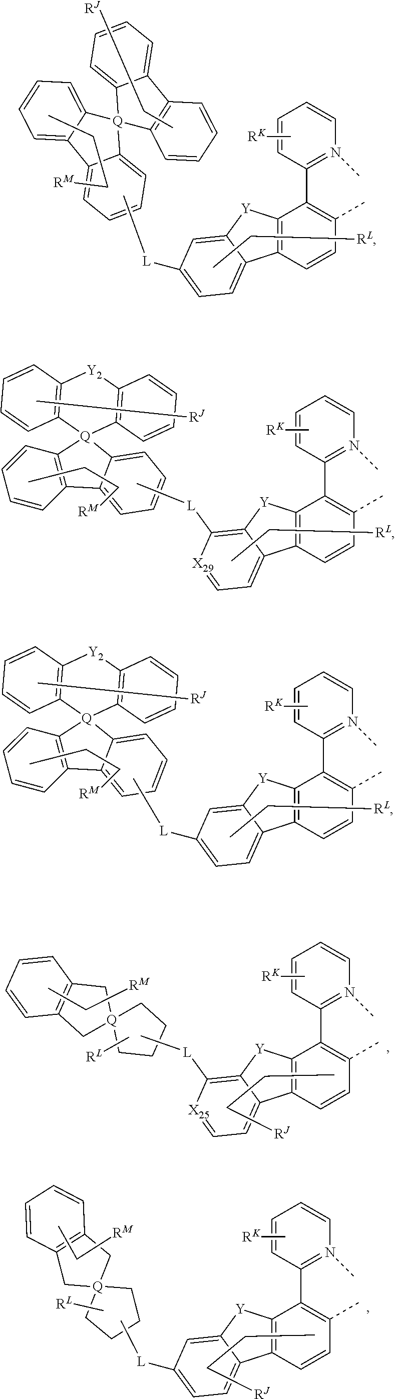 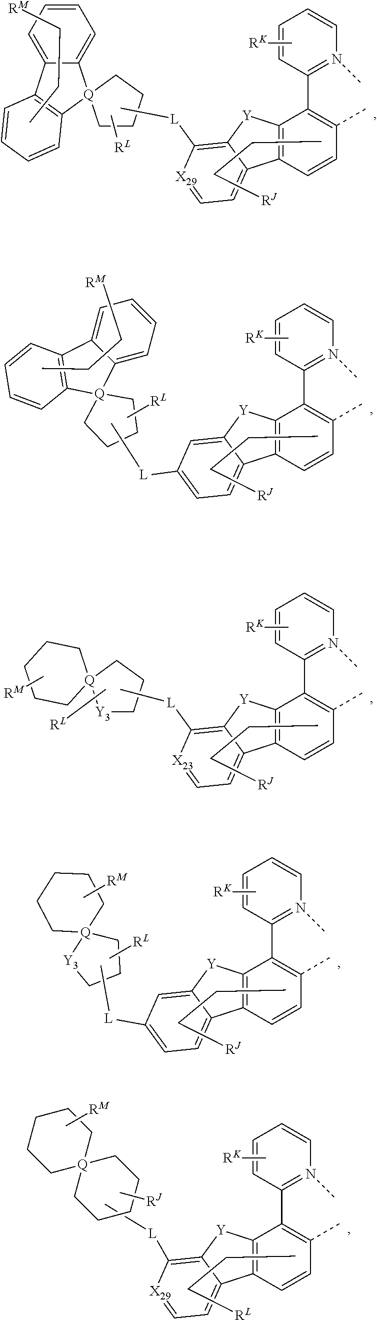 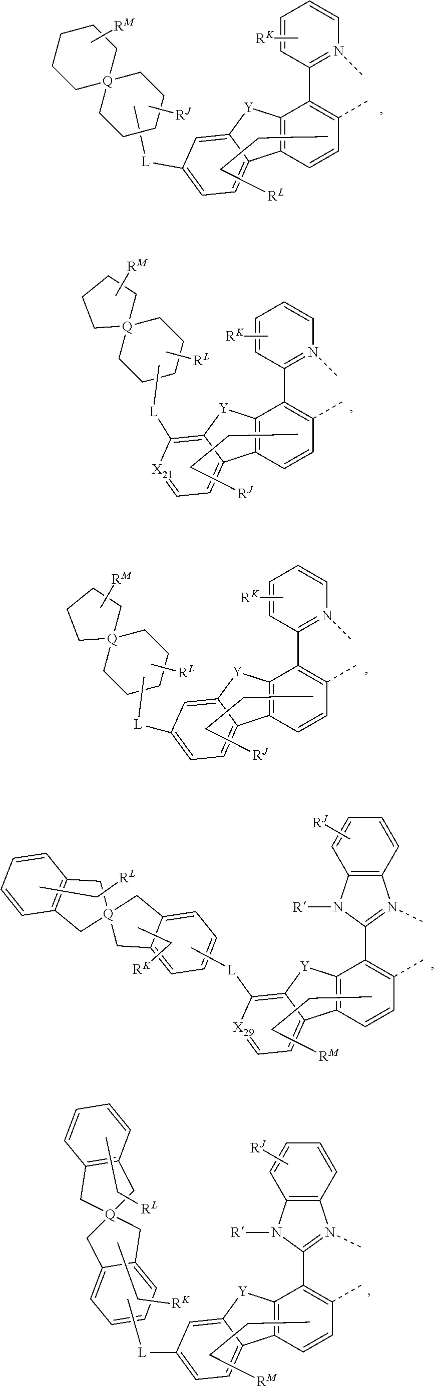 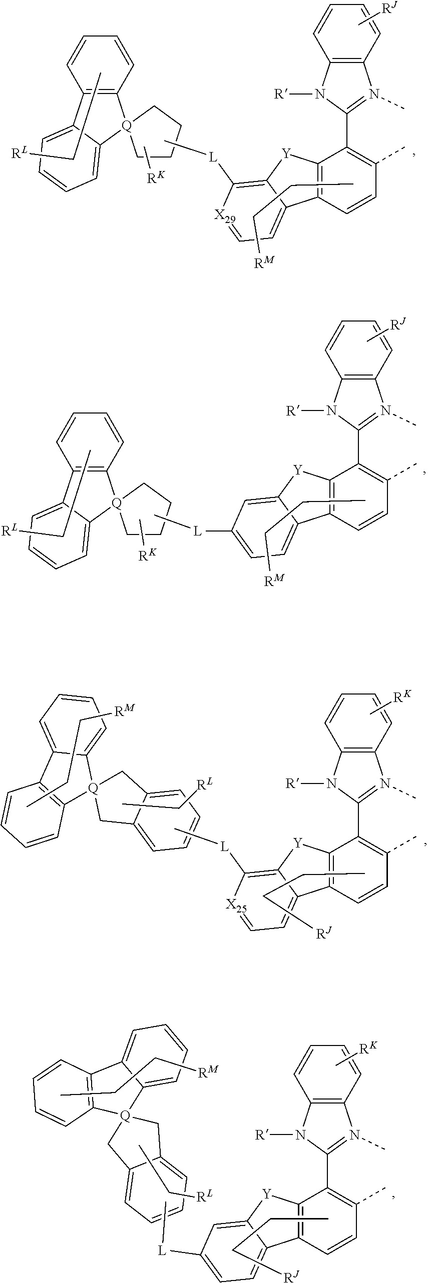 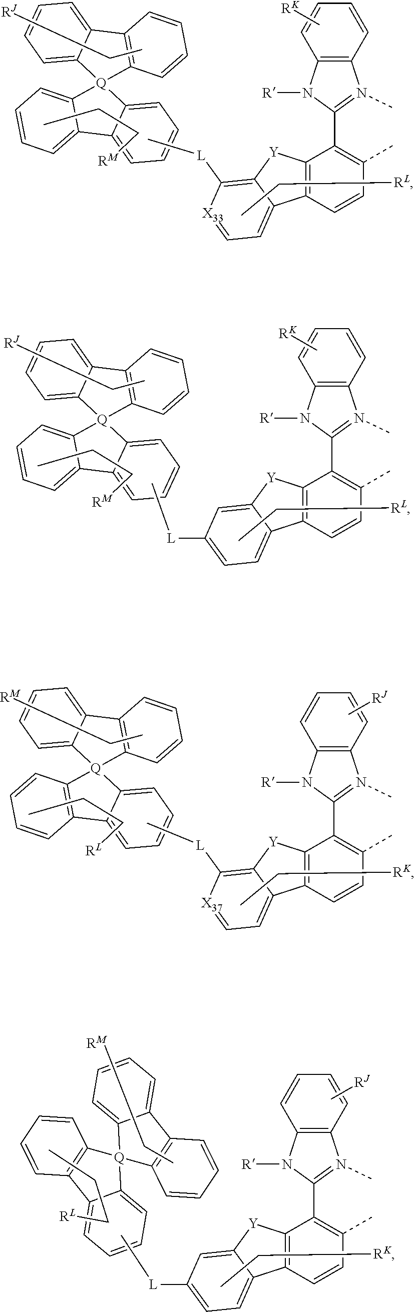 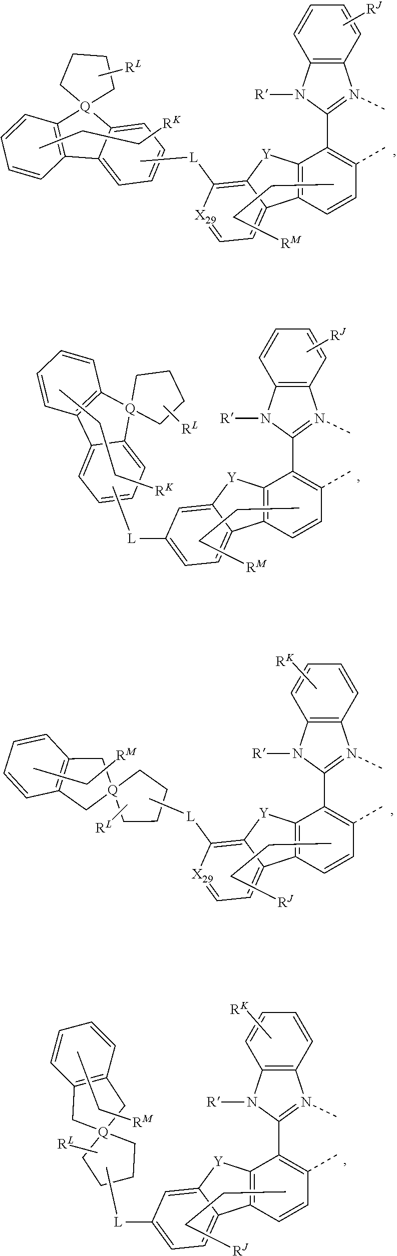 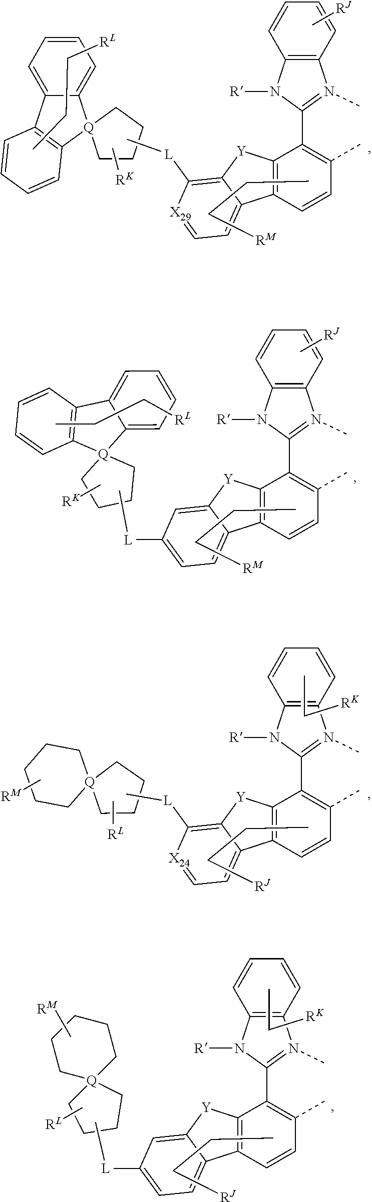 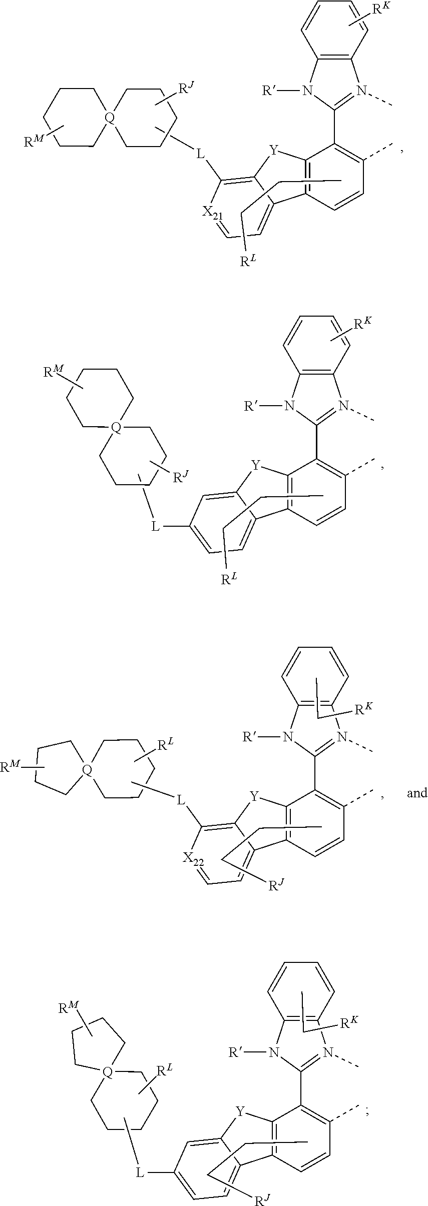
wherein
each of X₅ to X₃₃ is independently C or N;
each of Y₂ to Y₃ is independently selected from the group consisting of B, N, P, P(O), O, S, Se, C═O, C═S, C═Se, C═NR′, C═CRR′, S═O, SO₂, C, Si, and Ge;
each of R^{H}, R^{I}, R^{J}, R^{K}, R^{L}, and R^{M} independently represents mono to the maximum allowable substitution, or no substitution;
each R, R′, R^{H}, R^{I}, R^{J}, R^{K}, R^{L}, and R^{M} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
the remaining variables are the same as previously defined; and
any two substituents can be joined or fused to form a ring.

10. The compound of claim 1, wherein the ligand L_{A} is selected from L_{Ai}-(L)(Q)(Y′)(R^{a})(R^{b})(R^{c}), wherein i is an integer from 1 to 140, each of R³, R^{b}, and R^{o}, is independently selected from the group consisting of R1 to R120; L is selected from the group consisting of L1 to L28, Q is selected from the group consisting of Q1 to Q56, Y′ is selected from the group consisting of Y1 to Y4, wherein each of L_{A1}-(L1)(Q1)(Y1)(R1)(R1)(R1) to L_{A140}-(L28)(Q56)(Y4)(R120)(R120)(R120) is defined as follows:

| Compound | Structure of compound |
|---|---|
| L_{A1}- (L)(Q)(Y′)(R^{a})(R^{b})(R^{c}), wherein L_{A1}- (L1)(Q1)(Y1)(R1)(R1)(R1) to L_{A1}- (L28)(Q56)(Y4)(R120) (R120)(R120) have the structure | 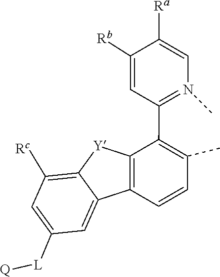 |
| L_{A2}- (L)(Q)(Y′)(R^{a})(R^{b})(R^{c}), wherein L_{A2}- (L1)(Q1)(Y1)(R1)(R1)(R1) to L_{A2}- (L28)(Q56)(Y4)(R120) (R120)(R120) have the structure | 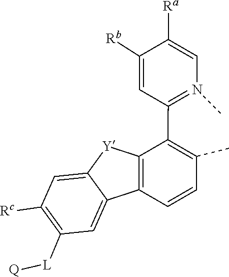 |
| L_{A3}- (L)(Q)(Y′)(R^{a})(R^{b})(R^{c}), wherein L_{A3}- (L1)(Q1)(Y1)(R1)(R1)(R1) to L_{A3}- (L28)(Q56)(Y4)(R120) (R120)(R120) have the structure | 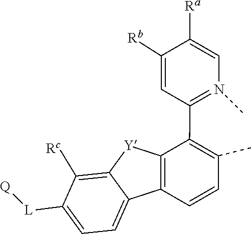 |
| L_{A4}- (L)(Q)(Y′)(R^{a})(R^{b})(R^{c}), wherein L_{A4}- (L1)(Q1)(Y1)(R1)(R1)(R1) to L_{A4}- (L28)(Q56)(Y4)(R120) (R120)(R120) have the structure | 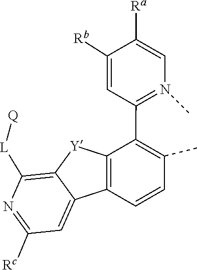 |
| L_{A5}- (L)(Q)(Y′)(R^{a})(R^{b})(R^{c}), wherein L_{A5}- (L1)(Q1)(Y1)(R1)(R1)(R1) to L_{A5}- (L28)(Q56)(Y4)(R120) (R120)(R120) have the structure | 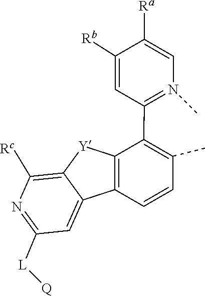 |
| L_{A6}- (L)(Q)(Y′)(R^{a})(R^{b})(R^{c}), wherein L_{A6}- (L1)(Q1)(Y1)(R1)(R1)(R1) to L_{A6}- (L28)(Q56)(Y4)(R120) (R120)(R120) have the structure | 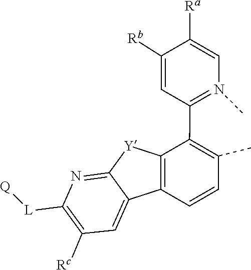 |
| L_{A7}- (L)(Q)(Y′)(R^{a})(R^{b})(R^{c}), wherein L_{A7}- (L1)(Q1)(Y1)(R1)(R1)(R1) to L_{A7}- (L28)(Q56)(Y4)(R120) (R120)(R120) have the structure | 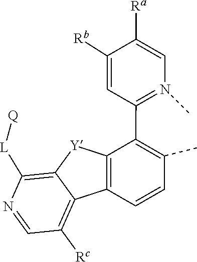 |
| L_{A8}- (L)(Q)(Y′)(R^{a})(R^{b})(R^{c}), wherein L_{A8}- (L1)(Q1)(Y1)(R1)(R1)(R1) to L_{A8}- (L28)(Q56)(Y4)(R120) (R120)(R120) have the structure | 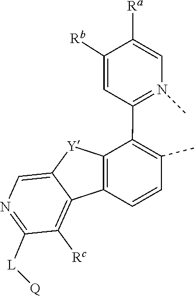 |
| L_{A9}- (L)(Q)(Y′)(R^{a})(R^{b})(R^{c}), wherein L_{A9}- (L1)(Q1)(Y1)(R1)(R1)(R1) to L_{A9}- (L28)(Q56)(Y4)(R120) (R120)(R120) have the structure | 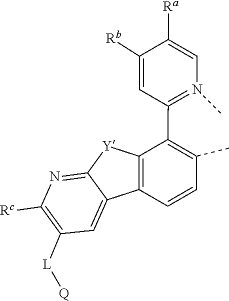 |
| L_{A10}- (L)(Q)(Y′)(R^{a})(R^{b})(R^{c}), wherein L_{A10}- (L1)(Q1)(Y1)(R1)(R1)(R1) to L_{A10}- (L28)(Q56)(Y4)(R120) (R120)(R120) have the structure | 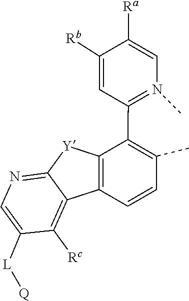 |
| L_{A11}- (L)(Q)(Y′)(R^{a})(R^{b})(R^{c}), wherein L_{A11}- (L1)(Q1)(Y1)(R1)(R1)(R1) to L_{A11}- (L28)(Q56)(Y4)(R120) (R120)(R120) have the structure | 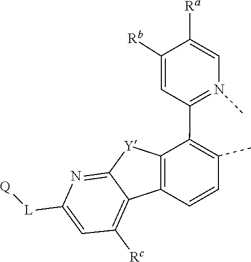 |
| L_{A12}- (L)(Q)(Y′)(R^{a})(R^{b})(R^{c}), wherein L_{A12}- (L1)(Q1)(Y1)(R1)(R1)(R1) to L_{A12}- (L28)(Q56)(Y4)(R120) (R120)(R120) have the structure | 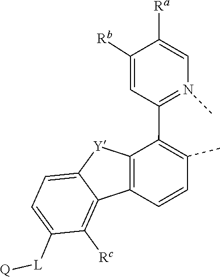 |
| L_{A13}- (L)(Q)(Y′)(R^{a})(R^{b})(R^{c}), wherein L_{A13}- (L1)(Q1)(Y1)(R1)(R1)(R1) to L_{A13}- (L28)(Q56)(Y4)(R120) (R120)(R120) have the structure | 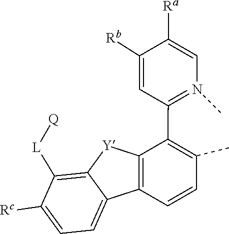 |
| L_{A14}- (L)(Q)(Y′)(R^{a})(R^{b})(R^{c}), wherein L_{A14}- (L1)(Q1)(Y1)(R1)(R1)(R1) to L_{A14}- (L28)(Q56)(Y4)(R120) (R120)(R120) have the structure | 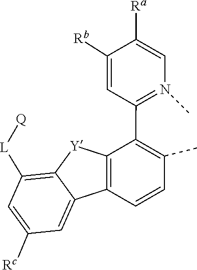 |
| L_{A15}- (L)(Q)(Y′)(R^{a})(R^{b})(R^{c}), wherein L_{A15}- (L1)(Q1)(Y1)(R1)(R1)(R1) to L_{A15}- (L28)(Q56)(Y4)(R120) (R120)(R120) have the structure | 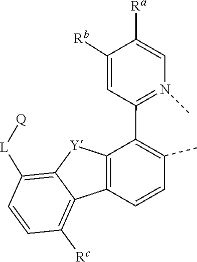 |
| L_{A16}- (L)(Q)(Y′)(R^{a})(R^{b})(R^{c}), wherein L_{A16}- (L1)(Q1)(Y1)(R1)(R1)(R1) to L_{A16}- (L28)(Q56)(Y4)(R120) (R120)(R120) have the structure | 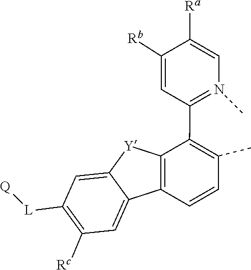 |
| L_{A17}- (L)(Q)(Y′)(R^{a})(R^{b})(R^{c}), wherein L_{A17}- (L1)(Q1)(Y1)(R1)(R1)(R1) to L_{A17}- (L28)(Q56)(Y4)(R120) (R120)(R120) have the structure | 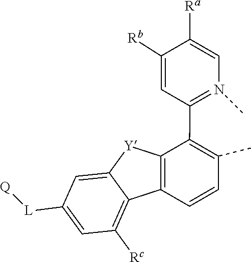 |
| L_{A18}- (L)(Q)(Y′)(R^{a})(R^{b})(R^{c}), wherein L_{A18}- (L1)(Q1)(Y1)(R1)(R1)(R1) to L_{A18}- (L28)(Q56)(Y4)(R120) (R120)(R120) have the structure | 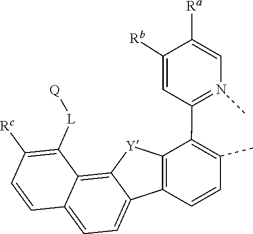 |
| L_{A19}- (L)(Q)(Y′)(R^{a})(R^{b})(R^{c}), wherein L_{A19}- (L1)(Q1)(Y1)(R1)(R1)(R1) to L_{A19}- (L28)(Q56)(Y4)(R120) (R120)(R120) have the structure | 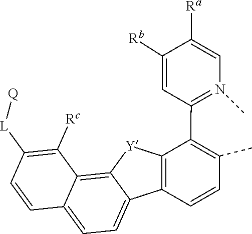 |
| L_{A20}- (L)(Q)(Y′)(R^{a})(R^{b})(R^{c}), wherein L_{A20}- (L1)(Q1)(Y1)(R1)(R1)(R1) to L_{A20}- (L28)(Q56)(Y4)(R120) (R120)(R120) have the structure | 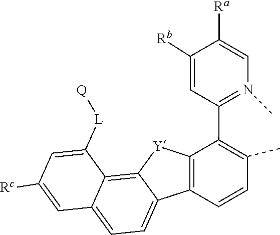 |
| L_{A21}- (L)(Q)(Y′)(R^{a})(R^{b})(R^{c}), wherein L_{A21}- (L1)(Q1)(Y1)(R1)(R1)(R1) to L_{A21}- (L28)(Q56)(Y4)(R120) (R120)(R120) have the structure | 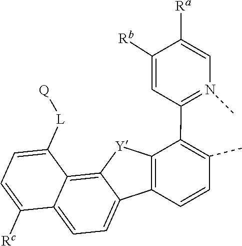 |
| L_{A22}- (L)(Q)(Y′)(R^{a})(R^{b})(R^{c}), wherein L_{A22}- (L1)(Q1)(Y1)(R1)(R1)(R1) to L_{A22}- (L28)(Q56)(Y4)(R120) (R120)(R120) have the structure | 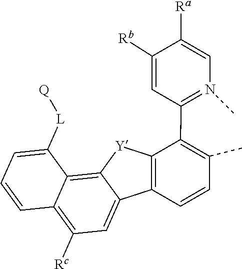 |
| L_{A23}- (L)(Q)(Y′)(R^{a})(R^{b})(R^{c}), wherein L_{A23}- (L1)(Q1)(Y1)(R1)(R1)(R1) to L_{A23}- (L28)(Q56)(Y4)(R120) (R120)(R120) have the structure | 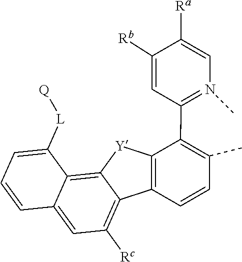 |
| L_{A24}- (L)(Q)(Y′)(R^{a})(R^{b})(R^{c}), wherein L_{A24}- (L1)(Q1)(Y1)(R1)(R1)(R1) to L_{A24}- (L28)(Q56)(Y4)(R120) (R120)(R120) have the structure | 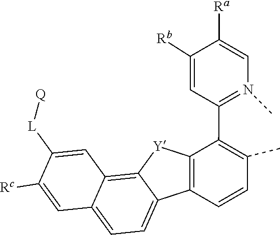 |
| L_{A25}- (L)(Q)(Y′)(R^{a})(R^{b})(R^{c}), wherein L_{A25}- (L1)(Q1)(Y1)(R1)(R1)(R1) to L_{A25}- (L28)(Q56)(Y4)(R120) (R120)(R120) have the structure | 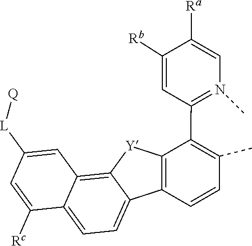 |
| L_{A26}- (L)(Q)(Y′)(R^{a})(R^{b})(R^{c}), wherein L_{A26}- (L1)(Q1)(Y1)(R1)(R1)(R1) to L_{A26}- (L28)(Q56)(Y4)(R120) (R120)(R120) have the structure | 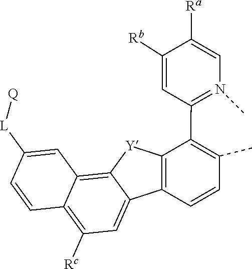 |
| L_{A27}- (L)(Q)(Y′)(R^{a})(R^{b})(R^{c}), wherein L_{A27}- (L1)(Q1)(Y1)(R1)(R1)(R1) to L_{A27}- (L28)(Q56)(Y4)(R120) (R120)(R120) have the structure | 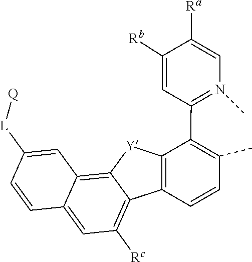 |
| L_{A28}- (L)(Q)(Y′)(R^{a})(R^{b})(R^{c}), wherein L_{A28}- (L1)(Q1)(Y1)(R1)(R1)(R1) to L_{A28}- (L28)(Q56)(Y4)(R120) (R120)(R120) have the structure | 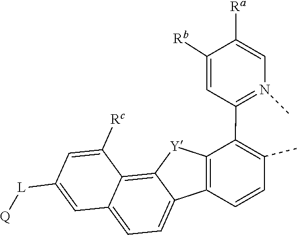 |
| L_{A29}- (L)(Q)(Y′)(R^{a})(R^{b})(R^{c}), wherein L_{A29}- (L1)(Q1)(Y1)(R1)(R1)(R1) to L_{A29}- (L28)(Q56)(Y4)(R120) (R120)(R120) have the structure | 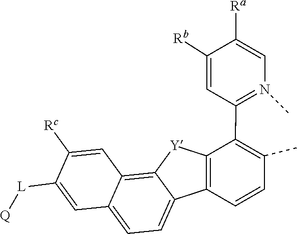 |
| L_{A30}- (L)(Q)(Y′)(R^{a})(R^{b})(R^{c}), wherein L_{A30}- (L1)(Q1)(Y1)(R1)(R1)(R1) to L_{A30}- (L28)(Q56)(Y4)(R120) (R120)(R120) have the structure | 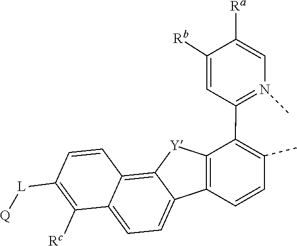 |
| L_{A31}- (L)(Q)(Y′)(R^{a})(R^{b})(R^{c}), wherein L_{A31}- (L1)(Q1)(Y1)(R1)(R1)(R1) to L_{A31}- (L28)(Q56)(Y4)(R120) (R120)(R120) have the structure | 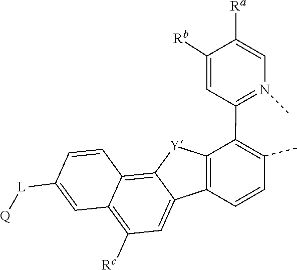 |
| L_{A32}- (L)(Q)(Y′)(R^{a})(R^{b})(R^{c}), wherein L_{A32}- (L1)(Q1)(Y1)(R1)(R1)(R1) to L_{A32}- (L28)(Q56)(Y4)(R120) (R120)(R120) have the structure | 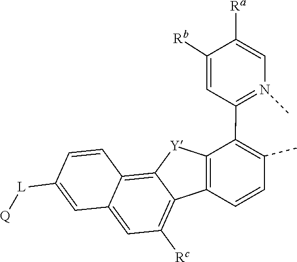 |
| L_{A33}- (L)(Q)(Y′)(R^{a})(R^{b})(R^{c}), wherein L_{A33}- (L1)(Q1)(Y1)(R1)(R1)(R1) to L_{A33}- (L28)(Q56)(Y4)(R120) (R120)(R120) have the structure | 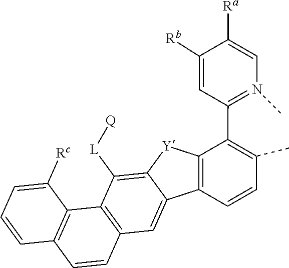 |
| L_{A34}- (L)(Q)(Y′)(R^{a})(R^{b})(R^{c}), wherein L_{A34}- (L1)(Q1)(Y1)(R1)(R1)(R1) to L_{A34}- (L28)(Q56)(Y4)(R120) (R120)(R120) have the structure | 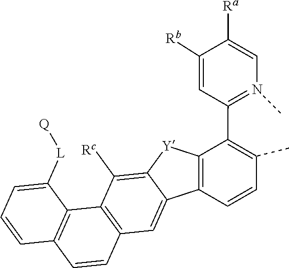 |
| L_{A35}- (L)(Q)(Y′)(R^{a})(R^{b})(R^{c}), wherein L_{A35}- (L1)(Q1)(Y1)(R1)(R1)(R1) to L_{A35}- (L28)(Q56)(Y4)(R120) (R120)(R120) have the structure | 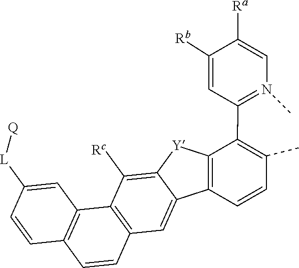 |
| L_{A36}- (L)(Q)(Y′)(R^{a})(R^{b})(R^{c}), wherein L_{A36}- (L1)(Q1)(Y1)(R1)(R1)(R1) to L_{A36}- (L28)(Q56)(Y4)(R120) (R120)(R120) have the structure | 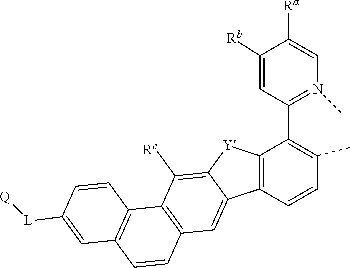 |
| L_{A37}- (L)(Q)(Y′)(R^{a})(R^{b})(R^{c}), wherein L_{A37}- (L1)(Q1)(Y1)(R1)(R1)(R1) to L_{A37}- (L28)(Q56)(Y4)(R120) (R120)(R120) have the structure | 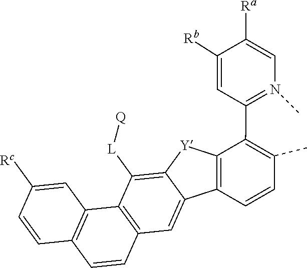 |
| L_{A38}- (L)(Q)(Y′)(R^{a})(R^{b})(R^{c}), wherein L_{A38}- (L1)(Q1)(Y1)(R1)(R1)(R1) to L_{A38}- (L28)(Q56)(Y4)(R120) (R120)(R120) have the structure | 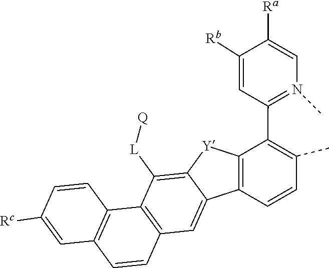 |
| L_{A39}- (L)(Q)(Y′)(R^{a})(R^{b})(R^{c}), wherein L_{A39}- (L1)(Q1)(Y1)(R1)(R1)(R1) to L_{A39}- (L28)(Q56)(Y4)(R120) (R120)(R120) have the structure | 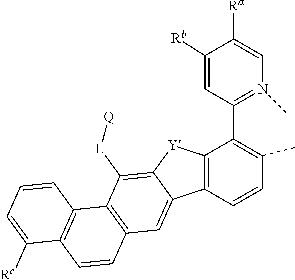 |
| L_{A40}- (L)(Q)(Y′)(R^{a})(R^{b})(R^{c}), wherein L_{A40}- (L1)(Q1)(Y1)(R1)(R1)(R1) to L_{A40}- (L28)(Q56)(Y4)(R120) (R120)(R120) have the structure | 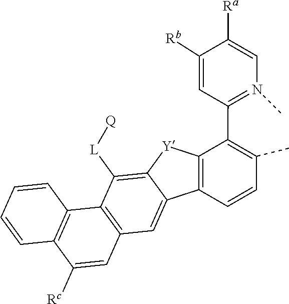 |
| L_{A41}- (L)(Q)(Y′)(R^{a})(R^{b})(R^{c}), wherein L_{A41}- (L1)(Q1)(Y1)(R1)(R1)(R1) to L_{A41}- (L28)(Q56)(Y4)(R120) (R120)(R120) have the structure | 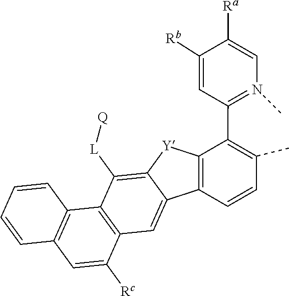 |
| L_{A42}- (L)(Q)(Y′)(R^{a})(R^{b})(R^{c}), wherein L_{A42}- (L1)(Q1)(Y1)(R1)(R1)(R1) to L_{A42}- (L28)(Q56)(Y4)(R120) (R120)(R120) have the structure | 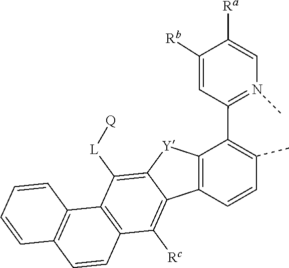 |
| L_{A43}- (L)(Q)(Y′)(R^{a})(R^{b})(R^{c}), wherein L_{A43}- (L1)(Q1)(Y1)(R1)(R1)(R1) to L_{A43}- (L28)(Q56)(Y4)(R120) (R120)(R120) have the structure | 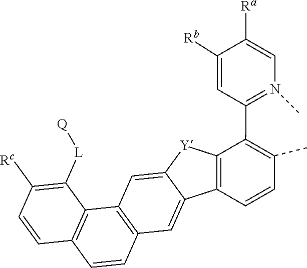 |
| L_{A44}- (L)(Q)(Y′)(R^{a})(R^{b})(R^{c}), wherein L_{A44}- (L1)(Q1)(Y1)(R1)(R1)(R1) to L_{A44}- (L28)(Q56)(Y4)(R120) (R120)(R120) have the structure | 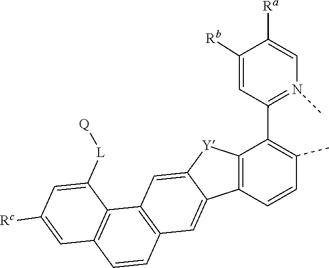 |
| L_{A45}- (L)(Q)(Y′)(R^{a})(R^{b})(R^{c}), wherein L_{A45}- (L1)(Q1)(Y1)(R1)(R1)(R1) to L_{A45}- (L28)(Q56)(Y4)(R120) (R120)(R120) have the structure | 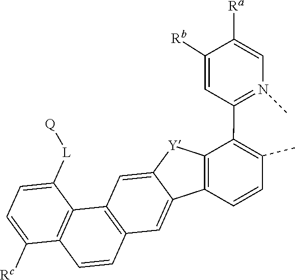 |
| L_{A46}- (L)(Q)(Y′)(R^{a})(R^{b})(R^{c}), wherein L_{A46}- (L1)(Q1)(Y1)(R1)(R1)(R1) to L_{A46}- (L28)(Q56)(Y4)(R120) (R120)(R120) have the structure | 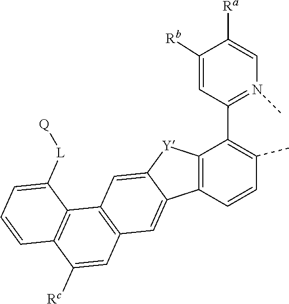 |
| L_{A47}- (L)(Q)(Y′)(R^{a})(R^{b})(R^{c}), wherein L_{A47}- (L1)(Q1)(Y1)(R1)(R1)(R1) to L_{A47}- (L28)(Q56)(Y4)(R120) (R120)(R120) have the structure | 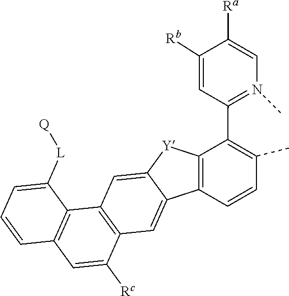 |
| L_{A48}- (L)(Q)(Y′)(R^{a})(R^{b})(R^{c}), wherein L_{A48}- (L1)(Q1)(Y1)(R1)(R1)(R1) to L_{A48}- (L28)(Q56)(Y4)(R120) (R120)(R120) have the structure | 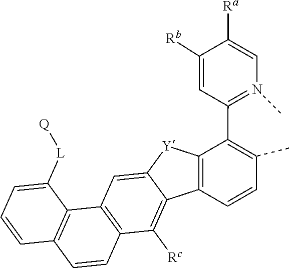 |
| L_{A49}- (L)(Q)(Y′)(R^{a})(R^{b})(R^{c}), wherein L_{A49}- (L1)(Q1)(Y1)(R1)(R1)(R1) to L_{A49}- (L28)(Q56)(Y4)(R120) (R120)(R120) have the structure | 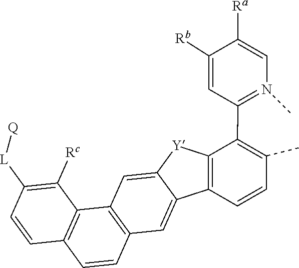 |
| L_{A50}- (L)(Q)(Y′)(R^{a})(R^{b})(R^{c}), wherein L_{A50}- (L1)(Q1)(Y1)(R1)(R1)(R1) to L_{A50}- (L28)(Q56)(Y4)(R120) (R120)(R120) have the structure | 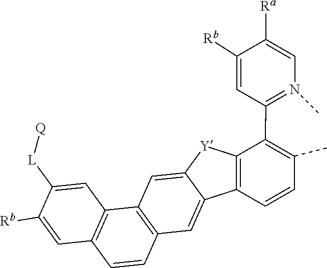 |
| L_{A51}- (L)(Q)(Y′)(R^{a})(R^{b})(R^{c}), wherein L_{A51}- (L1)(Q1)(Y1)(R1)(R1)(R1) to L_{A51}- (L28)(Q56)(Y4)(R120) (R120)(R120) have the structure | 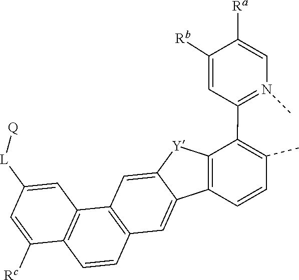 |
| L_{A52}- (L)(Q)(Y′)(R^{a})(R^{b})(R^{c}), wherein L_{A52}- (L1)(Q1)(Y1)(R1)(R1)(R1) to L_{A52}- (L28)(Q56)(Y4)(R120) (R120)(R120) have the structure | 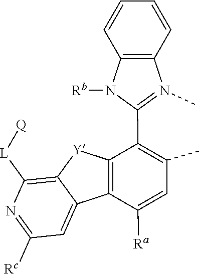 |
| L_{A53}- (L)(Q)(Y′)(R^{a})(R^{b})(R^{c}), wherein L_{A53}- (L1)(Q1)(Y1)(R1)(R1)(R1) to L_{A53}- (L28)(Q56)(Y4)(R120) (R120)(R120) have the structure | 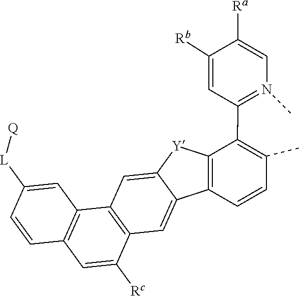 |
| L_{A54}- (L)(Q)(Y′)(R^{a})(R^{b})(R^{c}), wherein L_{A54}- (L1)(Q1)(Y1)(R1)(R1)(R1) to L_{A54}- (L28)(Q56)(Y4)(R120) (R120)(R120) have the structure | 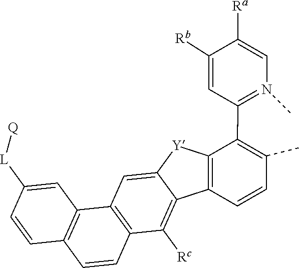 |
| L_{A55}- (L)(Q)(Y′)(R^{a})(R^{b})(R^{c}), wherein L_{A55}- (L1)(Q1)(Y1)(R1)(R1)(R1) to L_{A55}- (L28)(Q56)(Y4)(R120) (R120)(R120) have the structure | 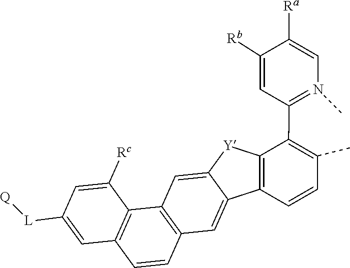 |
| L_{A56}- (L)(Q)(Y′)(R^{a})(R^{b})(R^{c}), wherein L_{A56}- (L1)(Q1)(Y1)(R1)(R1)(R1) to L_{A56}- (L28)(Q56)(Y4)(R120) (R120)(R120) have the structure | 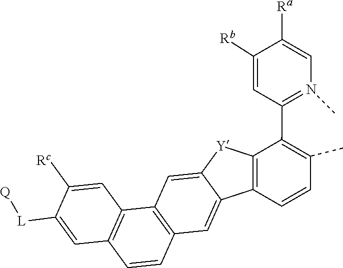 |
| L_{A57}- (L)(Q)(Y′)(R^{a})(R^{b})(R^{c}), wherein L_{A57}- (L1)(Q1)(Y1)(R1)(R1)(R1) to L_{A57}- (L28)(Q56)(Y4)(R120) (R120)(R120) have the structure | 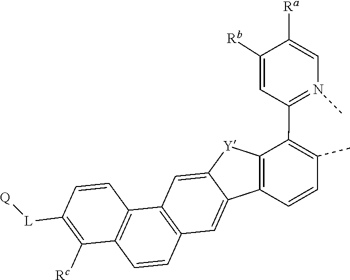 |
| L_{A58}- (L)(Q)(Y′)(R^{a})(R^{b})(R^{c}), wherein L_{A58}- (L1)(Q1)(Y1)(R1)(R1)(R1) to L_{A58}- (L28)(Q56)(Y4)(R120) (R120)(R120) have the structure | 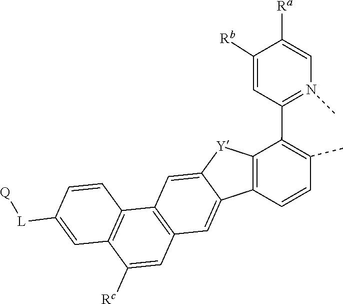 |
| L_{A59}- (L)(Q)(Y′)(R^{a})(R^{b})(R^{c}), wherein L_{A59}- (L1)(Q1)(Y1)(R1)(R1)(R1) to L_{A59}- (L28)(Q56)(Y4)(R120) (R120)(R120) have the structure | 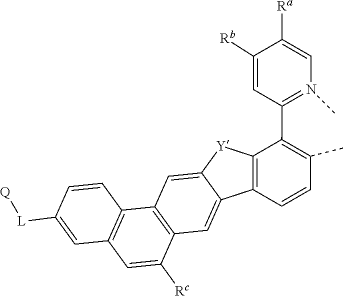 |
| L_{A60}- (L)(Q)(Y′)(R^{a})(R^{b})(R^{c}), wherein L_{A60}- (L1)(Q1)(Y1)(R1)(R1)(R1) to L_{A60}- (L28)(Q56)(Y4)(R120) (R120)(R120) have the structure | 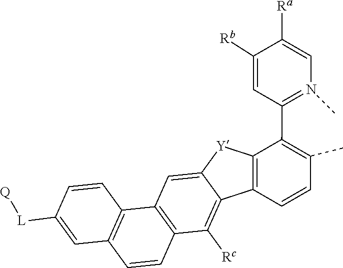 |
| L_{A61}- (L)(Q)(Y′)(R^{a})(R^{b})(R^{c}), wherein L_{A61}- (L1)(Q1)(Y1)(R1)(R1) to L_{A61}- (L28)(Q56)(Y4)(R120) (R120)(R120) have the structure | 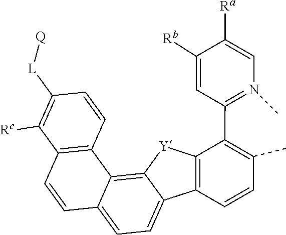 |
| L_{A62}- (L)(Q)(Y′)(R^{a})(R^{b})(R^{c}), wherein L_{A62}- (L1)(Q1)(Y1)(R1)(R1) to L_{A62}- (L28)(Q56)(Y4)(R120) (R120)(R120) have the structure | 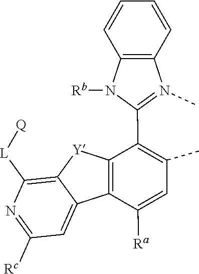 |
| L_{A63}- (L)(Q)(Y′)(R^{a})(R^{b})(R^{c}), wherein L_{A63}- (L1)(Q1)(Y1)(R1)(R1) to L_{A63}- (L28)(Q56)(Y4)(R120) (R120)(R120) have the structure | 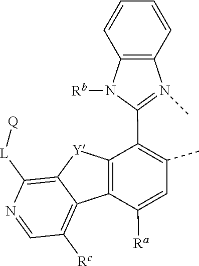 |
| L_{A64}- (L)(Q)(Y′)(R^{a})(R^{b})(R^{c}), wherein L_{A64}- (L1)(Q1)(Y1)(R1)(R1) to L_{A64}- (L28)(Q56)(Y4)(R120) (R120)(R120) have the structure | 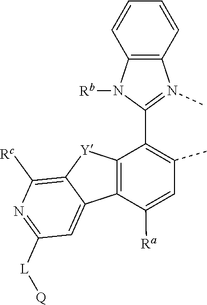 |
| L_{A65}- (L)(Q)(Y′)(R^{a})(R^{b})(R^{c}), wherein L_{A65}- (L1)(Q1)(Y1)(R1)(R1) to L_{A65}- (L28)(Q56)(Y4)(R120) (R120)(R120) have the structure | 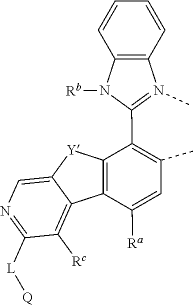 |
| L_{A66}- (L)(Q)(Y′)(R^{a})(R^{b})(R^{c}), wherein L_{A66}- (L1)(Q1)(Y1)(R1)(R1) to L_{A66}- (L28)(Q56)(Y4)(R120) (R120)(R120) have the structure | 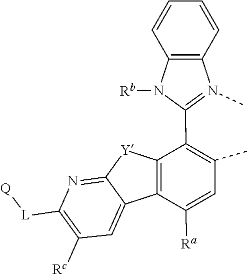 |
| L_{A67}- (L)(Q)(Y′)(R^{a})(R^{b})(R^{c}), wherein L_{A67}- (L1)(Q1)(Y1)(R1)(R1) to L_{A67}- (L28)(Q56)(Y4)(R120) (R120)(R120) have the structure | 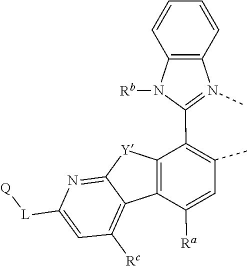 |
| L_{A68}- (L)(Q)(Y′)(R^{a})(R^{b})(R^{c}), wherein L_{A68}- (L1)(Q1)(Y1)(R1)(R1) to L_{A68}- (L28)(Q56)(Y4)(R120) (R120)(R120) have the structure | 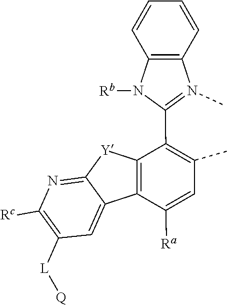 |
| L_{A69}- (L)(Q)(Y′)(R^{a})(R^{b})(R^{c}), wherein L_{A69}- (L1)(Q1)(Y1)(R1)(R1) to L_{A69}- (L28)(Q56)(Y4)(R120) (R120)(R120) have the structure | 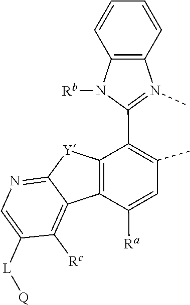 |
| L_{A70}- (L)(Q)(Y′)(R^{a})(R^{b})(R^{c}), wherein L_{A70}- (L1)(Q1)(Y1)(R1)(R1) to L_{A70}- (L28)(Q56)(Y4)(R120) (R120)(R120) have the structure | 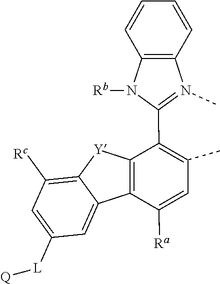 |
| L_{A71}- (L)(Q)(Y′)(R^{a})(R^{b})(R^{c}), wherein L_{A71}- (L1)(Q1)(Y1)(R1)(R1) to L_{A71}- (L28)(Q56)(Y4)(R120) (R120)(R120) have the structure | 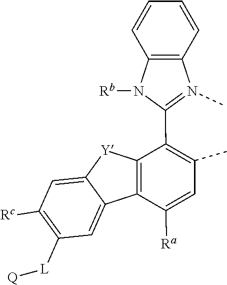 |
| L_{A72}- (L)(Q)(Y′)(R^{a})(R^{b})(R^{c}), wherein L_{A72}- (L1)(Q1)(Y1)(R1)(R1) to L_{A72}- (L28)(Q56)(Y4)(R120) (R120)(R120) have the structure | 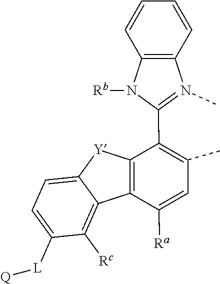 |
| L_{A73}- (L)(Q)(Y′)(R^{a})(R^{b})(R^{c}), wherein L_{A73}- (L1)(Q1)(Y1)(R1)(R1) to L_{A73}- (L28)(Q56)(Y4)(R120) (R120)(R120) have the structure | 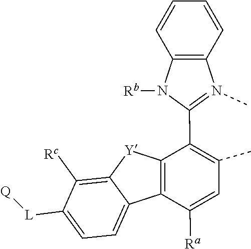 |
| L_{A74}- (L)(Q)(Y′)(R^{a})(R^{b})(R^{c}), wherein L_{A74}- (L1)(Q1)(Y1)(R1)(R1) to L_{A74}- (L28)(Q56)(Y4)(R120) (R120)(R120) have the structure | 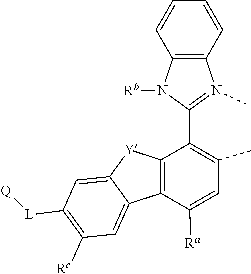 |
| L_{A75}- (L)(Q)(Y′)(R^{a})(R^{b})(R^{c}), wherein L_{A75}- (L1)(Q1)(Y1)(R1)(R1) to L_{A75}- (L28)(Q56)(Y4)(R120) (R120)(R120) have the structure | 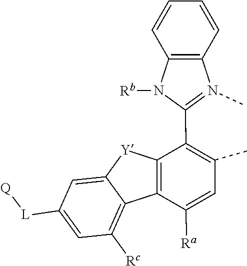 |
| L_{A76}- (L)(Q)(Y′)(R^{a})(R^{b})(R^{c}), wherein L_{A76}- (L1)(Q1)(Y1)(R1)(R1) to L_{A76}- (L28)(Q56)(Y4)(R120) (R120)(R120) have the structure | 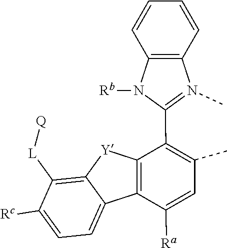 |
| L_{A77}- (L)(Q)(Y′)(R^{a})(R^{b})(R^{c}), wherein L_{A77}- (L1)(Q1)(Y1)(R1)(R1) to L_{A77}- (L28)(Q56)(Y4)(R120) (R120)(R120) have the structure | 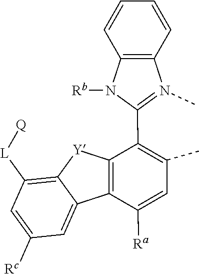 |
| L_{A78}- (L)(Q)(Y′)(R^{a})(R^{b})(R^{c}), wherein L_{A78}- (L1)(Q1)(Y1)(R1)(R1) to L_{A78}- (L28)(Q56)(Y4)(R120) (R120)(R120) have the structure | 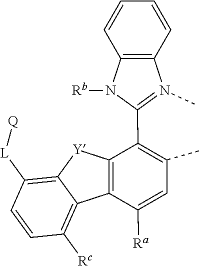 |
| L_{A79}- (L)(Q)(Y′)(R^{a})(R^{b})(R^{c}), wherein L_{A79}- (L1)(Q1)(Y1)(R1)(R1) to L_{A79}- (L28)(Q56)(Y4)(R120) (R120)(R120) have the structure | 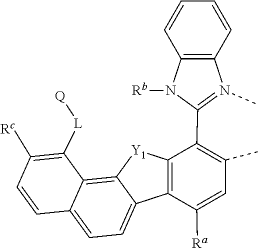 |
| L_{A80}- (L)(Q)(Y′)(R^{a})(R^{b})(R^{c}), wherein L_{A80}- (L1)(Q1)(Y1)(R1)(R1) to L_{A80}- (L28)(Q56)(Y4)(R120) (R120)(R120) have the structure | 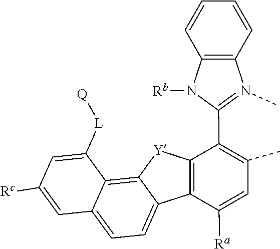 |
| L_{A81}- (L)(Q)(Y′)(R^{a})(R^{b})(R^{c}), wherein L_{A81}- (L1)(Q1)(Y1)(R1)(R1) to L_{A81}- (L28)(Q56)(Y4)(R120) (R120)(R120) have the structure | 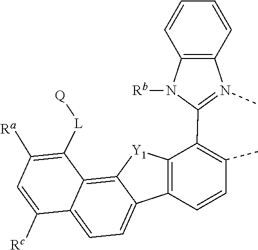 |
| L_{A82}- (L)(Q)(Y′)(R^{a})(R^{b})(R^{c}), wherein L_{A82}- (L1)(Q1)(Y1)(R1)(R1) to L_{A82}- (L28)(Q56)(Y4)(R120) (R120)(R120) have the structure | 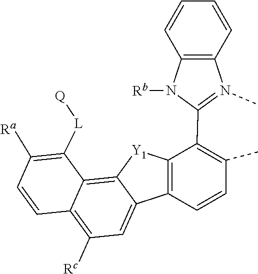 |
| L_{A83}- (L)(Q)(Y′)(R^{a})(R^{b})(R^{c}), wherein L_{A83}- (L1)(Q1)(Y1)(R1)(R1) to L_{A83}- (L28)(Q56)(Y4)(R120) (R120)(R120) have the structure | 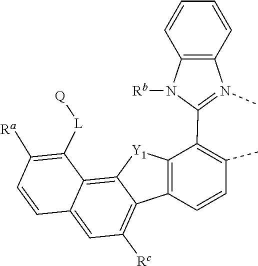 |
| L_{A84}- (L)(Q)(Y′)(R^{a})(R^{b})(R^{c}), wherein L_{A84}- (L1)(Q1)(Y1)(R1)(R1) to L_{A84}- (L28)(Q56)(Y4)(R120) (R120)(R120) have the structure | 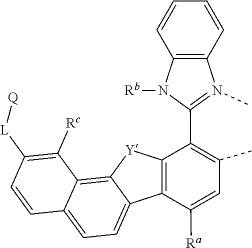 |
| L_{A85}- (L)(Q)(Y′)(R^{a})(R^{b})(R^{c}), wherein L_{A85}- (L1)(Q1)(Y1)(R1)(R1) to L_{A85}- (L28)(Q56)(Y4)(R120) (R120)(R120) have the structure | 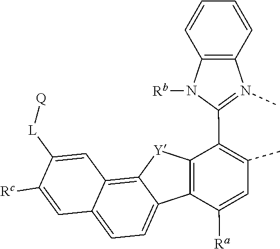 |
| L_{A86}- (L)(Q)(Y′)(R^{a})(R^{b})(R^{c}), wherein L_{A86}- (L1)(Q1)(Y1)(R1)(R1) to L_{A86}- (L28)(Q56)(Y4)(R120) (R120)(R120) have the structure | 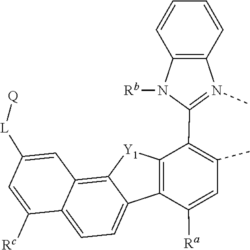 |
| L_{A87}- (L)(Q)(Y′)(R^{a})(R^{b})(R^{c}), wherein L_{A87}- (L1)(Q1)(Y1)(R1)(R1) to L_{A87}- (L28)(Q56)(Y4)(R120) (R120)(R120) have the structure | 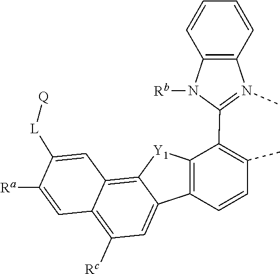 |
| L_{A88}- (L)(Q)(Y′)(R^{a})(R^{b})(R^{c}), wherein L_{A88}- (L1)(Q1)(Y1)(R1)(R1) to L_{A88}- (L28)(Q56)(Y4)(R120) (R120)(R120) have the structure | 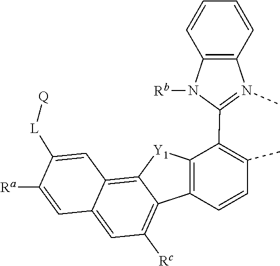 |
| L_{A89}- (L)(Q)(Y′)(R^{a})(R^{b})(R^{c}), wherein L_{A89}- (L1)(Q1)(Y1)(R1)(R1) to L_{A89}- (L28)(Q56)(Y4)(R120) (R120)(R120) have the structure | 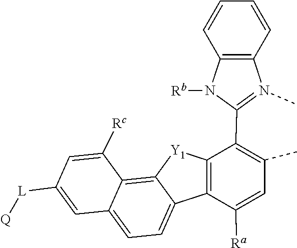 |
| L_{A90}- (L)(Q)(Y′)(R^{a})(R^{b})(R^{c}), wherein L_{A90}- (L1)(Q1)(Y1)(R1)(R1) to L_{A90}- (L28)(Q56)(Y4)(R120) (R120)(R120) have the structure | 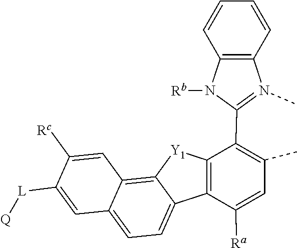 |
| L_{A91}- (L)(Q)(Y′)(R^{a})(R^{b})(R^{c}), wherein L_{A91}- (L1)(Q1)(Y1)(R1)(R1) to L_{A91}- (L28)(Q56)(Y4)(R120) (R120)(R120) have the structure | 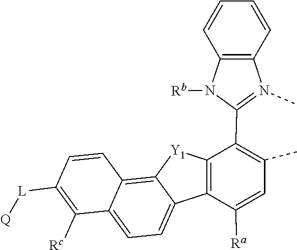 |
| L_{A92}- (L)(Q)(Y′)(R^{a})(R^{b})(R^{c}), wherein L_{A92}- (L1)(Q1)(Y1)(R1)(R1) to L_{A92}- (L28)(Q56)(Y4)(R120) (R120)(R120) have the structure | 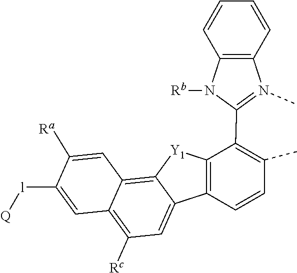 |
| L_{A93}- (L)(Q)(Y′)(R^{a})(R^{b})(R^{c}), wherein L_{A93}- (L1)(Q1)(Y1)(R1)(R1) to L_{A93}- (L28)(Q56)(Y4)(R120) (R120)(R120) have the structure | 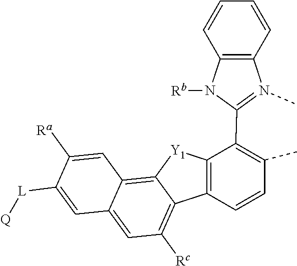 |
| L_{A94}- (L)(Q)(Y′)(R^{a})(R^{b})(R^{c}), wherein L_{A94}- (L1)(Q1)(Y1)(R1)(R1) to L_{A94}- (L28)(Q56)(Y4)(R120) (R120)(R120) have the structure | 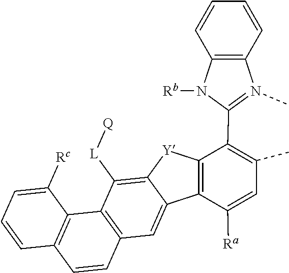 |
| L_{A95}- (L)(Q)(Y′)(R^{a})(R^{b})(R^{c}), wherein L_{A95}- (L1)(Q1)(Y1)(R1)(R1) to L_{A95}- (L28)(Q56)(Y4)(R120) (R120)(R120) have the structure | 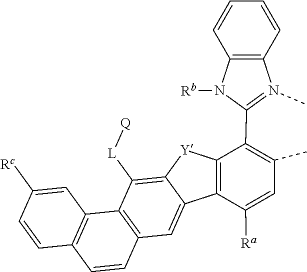 |
| L_{A96}- (L)(Q)(Y′)(R^{a})(R^{b})(R^{c}), wherein L_{A96}- (L1)(Q1)(Y1)(R1)(R1) to L_{A96}- (L28)(Q56)(Y4)(R120) (R120)(R120) have the structure | 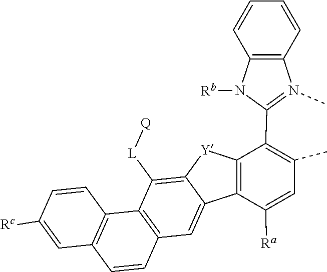 |
| L_{A97}- (L)(Q)(Y′)(R^{a})(R^{b})(R^{c}), wherein L_{A97}- (L1)(Q1)(Y1)(R1)(R1) to L_{A97}- (L28)(Q56)(Y4)(R120) (R120)(R120) have the structure | 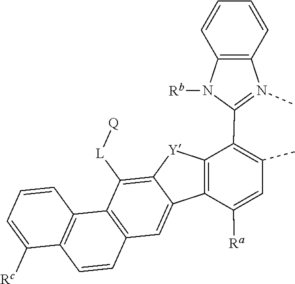 |
| L_{A98}- (L)(Q)(Y′)(R^{a})(R^{b})(R^{c}), wherein L_{A98}- (L1)(Q1)(Y1)(R1)(R1) to L_{A98}- (L28)(Q56)(Y4)(R120) (R120)(R120) have the structure | 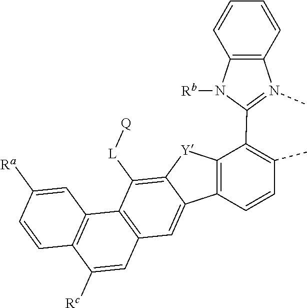 |
| L_{A99}- (L)(Q)(Y′)(R^{a})(R^{b})(R^{c}), wherein L_{A99}- (L1)(Q1)(Y1)(R1)(R1) to L_{A99}- (L28)(Q56)(Y4)(R120) (R120)(R120) have the structure | 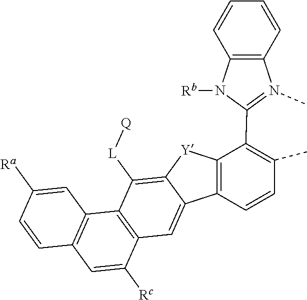 |
| L_{A100}- (L)(Q)(Y′)(R^{a})(R^{b})(R^{c}), wherein L_{A100}- (L1)(Q1)(Y1)(R1)(R1) to L_{A100}- (L28)(Q56)(Y4)(R120) (R120)(R120) have the structure | 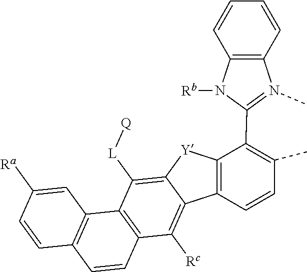 |
| L_{A101}- (L)(Q)(Y′)(R^{a})(R^{b})(R^{c}), wherein L_{A101}- (L1)(Q1)(Y1)(R1)(R1) to L_{A101}- (L28)(Q56)(Y4)(R120) (R120)(R120) have the structure | 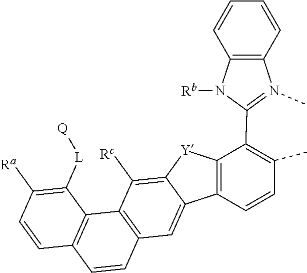 |
| L_{A102}- (L)(Q)(Y′)(R^{a})(R^{b})(R^{c}), wherein L_{A102}- (L1)(Q1)(Y1)(R1)(R1) to L_{A102}- (L28)(Q56)(Y4)(R120) (R120)(R120) have the structure | 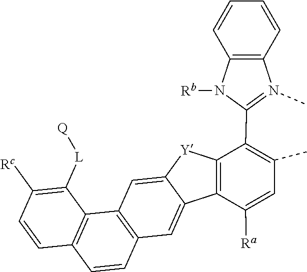 |
| L_{A103}- (L)(Q)(Y′)(R^{a})(R^{b})(R^{c}), wherein L_{A103}- (L1)(Q1)(Y1)(R1)(R1) to L_{A103}- (L28)(Q56)(Y4)(R120) (R120)(R120) have the structure | 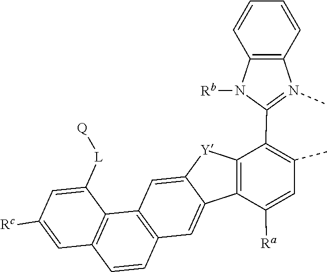 |
| L_{A104}- (L)(Q)(Y′)(R^{a})(R^{b})(R^{c}), wherein L_{A104}- (L1)(Q1)(Y1)(R1)(R1) to L_{A104}- (L28)(Q56)(Y4)(R120) (R120)(R120) have the structure | 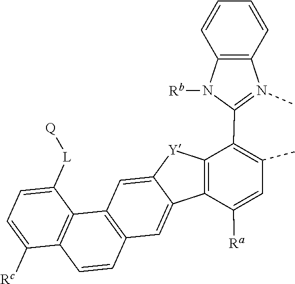 |
| L_{A105}- (L)(Q)(Y′)(R^{a})(R^{b})(R^{c}), wherein L_{A105}- (L1)(Q1)(Y1)(R1)(R1) to L_{A105}- (L28)(Q56)(Y4)(R120) (R120)(R120) have the structure | 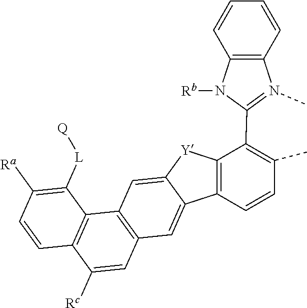 |
| L_{A106}- (L)(Q)(Y′)(R^{a})(R^{b})(R^{c}), wherein L_{A106}- (L1)(Q1)(Y1)(R1)(R1) to L_{A106}- (L28)(Q56)(Y4)(R120) (R120)(R120) have the structure | 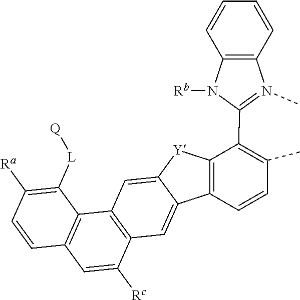 |
| L_{A107}- (L)(Q)(Y′)(R^{a})(R^{b})(R^{c}), wherein L_{A107}- (L1)(Q1)(Y1)(R1)(R1) to L_{A107}- (L28)(Q56)(Y4)(R120) (R120)(R120) have the structure | 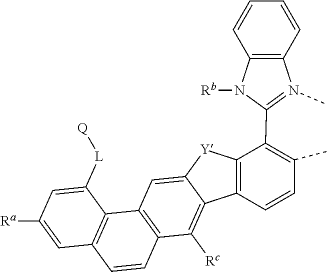 |
| L_{A108}- (L)(Q)(Y′)(R^{a})(R^{b})(R^{c}), wherein L_{A108}- (L1)(Q1)(Y1)(R1)(R1) to L_{A108}- (L28)(Q56)(Y4)(R120) (R120)(R120) have the structure | 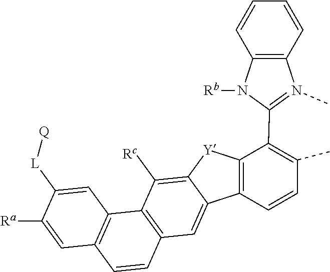 |
| L_{A109}- (L)(Q)(Y′)(R^{a})(R^{b})(R^{c}), wherein L_{A109}- (L1)(Q1)(Y1)(R1)(R1) to L_{A109}- (L28)(Q56)(Y4)(R120) (R120)(R120) have the structure | 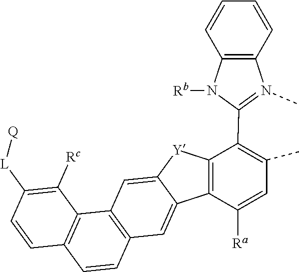 |
| L_{A110}- (L)(Q)(Y′)(R^{a})(R^{b})(R^{c}), wherein L_{A110}- (L1)(Q1)(Y1)(R1)(R1) to L_{A110}- (L28)(Q56)(Y4)(R120) (R120)(R120) have the structure | 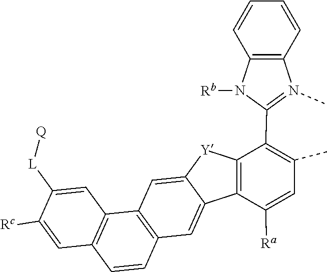 |
| L_{A111}- (L)(Q)(Y′)(R^{a})(R^{b})(R^{c}), wherein L_{A111}- (L1)(Q1)(Y1)(R1)(R1) to L_{A111}- (L28)(Q56)(Y4)(R120) (R120)(R120) have the structure | 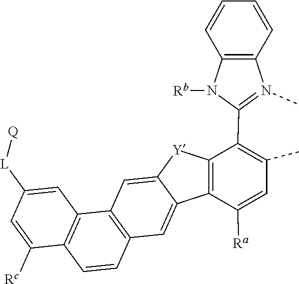 |
| L_{A112}- (L)(Q)(Y′)(R^{a})(R^{b})(R^{c}), wherein L_{A112}- (L1)(Q1)(Y1)(R1)(R1) to L_{A112}- (L28)(Q56)(Y4)(R120) (R120)(R120) have the structure | 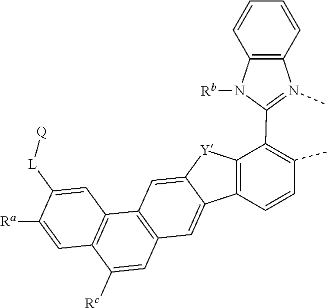 |
| L_{A113}- (L)(Q)(Y′)(R^{a})(R^{b})(R^{c}), wherein L_{A113}- (L1)(Q1)(Y1)(R1)(R1) to L_{A113}- (L28)(Q56)(Y4)(R120) (R120)(R120) have the structure | 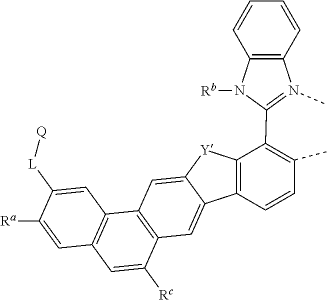 |
| L_{A114}- (L)(Q)(Y′)(R^{a})(R^{b})(R^{c}), wherein L_{A114}- (L1)(Q1)(Y1)(R1)(R1) to L_{A114}- (L28)(Q56)(Y4)(R120) (R120)(R120) have the structure | 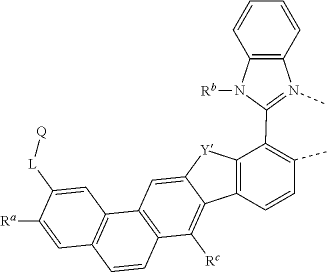 |
| L_{A115}- (L)(Q)(Y′)(R^{a})(R^{b})(R^{c}), wherein L_{A115}- (L1)(Q1)(Y1)(R1)(R1) to L_{A115}- (L28)(Q56)(Y4)(R120) (R120)(R120) have the structure | 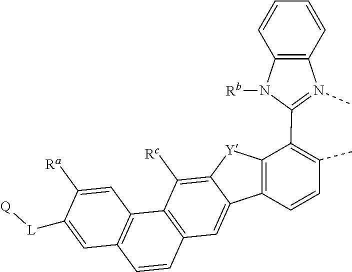 |
| L_{A116}- (L)(Q)(Y′)(R^{a})(R^{b})(R^{c}), wherein L_{A116}- (L1)(Q1)(Y1)(R1)(R1) to L_{A116}- (L28)(Q56)(Y4)(R120) (R120)(R120) have the structure | 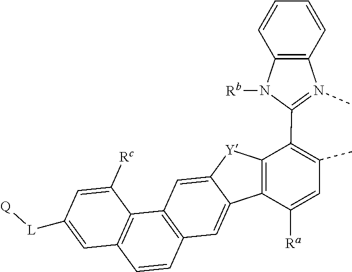 |
| L_{A117}- (L)(Q)(Y′)(R^{a})(R^{b})(R^{c}), wherein L_{A117}- (L1)(Q1)(Y1)(R1)(R1) to L_{A117}- (L28)(Q56)(Y4)(R120) (R120)(R120) have the structure | 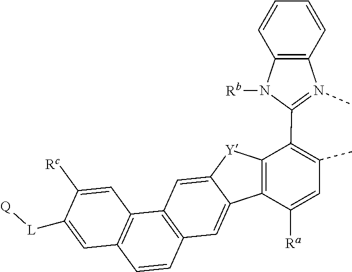 |
| L_{A118}- (L)(Q)(Y′)(R^{a})(R^{b})(R^{c}), wherein L_{A118}- (L1)(Q1)(Y1)(R1)(R1) to L_{A118}- (L28)(Q56)(Y4)(R120) (R120)(R120) have the structure | 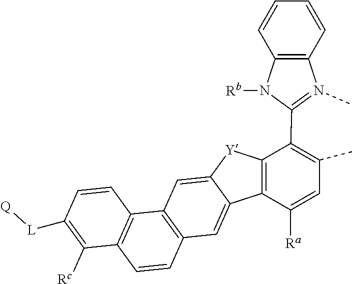 |
| L_{A119}- (L)(Q)(Y′)(R^{a})(R^{b})(R^{c}), wherein L_{A119}- (L1)(Q1)(Y1)(R1)(R1) to L_{A119}- (L28)(Q56)(Y4)(R120) (R120)(R120) have the structure | 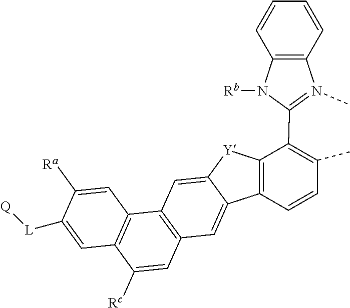 |
| L_{A120}- (L)(Q)(Y′)(R^{a})(R^{b})(R^{c}), wherein L_{A120}- (L1)(Q1)(Y1)(R1)(R1) to L_{A120}- (L28)(Q56)(Y4)(R120) (R120)(R120) have the structure | 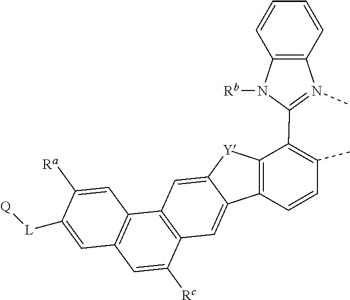 |
| L_{A121}- (L)(Q)(Y′)(R^{a})(R^{b})(R^{c}), wherein L_{A121}- (L1)(Q1)(Y1)(R1)(R1) to L_{A121}- (L28)(Q56)(Y4)(R120) (R120)(R120) have the structure | 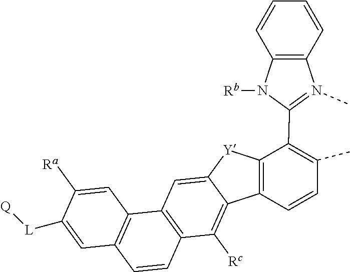 |
| L_{A122}- (L)(Q)(Y′)(R^{a})(R^{b})(R^{c}), wherein L_{A122}- (L1)(Q1)(Y1)(R1) to L_{A122}- (L28)(Q56)(Y4)(R120) (R120)(R120) have the structure | 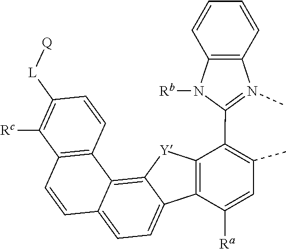 |
| L_{A123}- (L)(Q)(Y′)(R^{a})(R^{b})(R^{c}), wherein L_{A123}- (L1)(Q1)(Y1)(R1)(R1)(R1) to L_{A123}- (L28)(Q56)(Y4)(R120) (R120) have the structure | 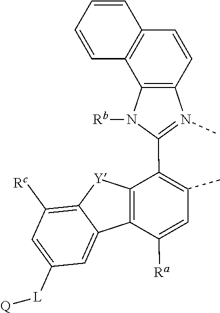 |
| L_{A124}- (L)(Q)(Y′)(R^{a})(R^{b})(R^{c}), wherein L_{A124}- (L1)(Q1)(Y1)(R1)(R1) to L_{A124}- (L28)(Q56)(Y4)(R120) (R120)(R120) have the structure | 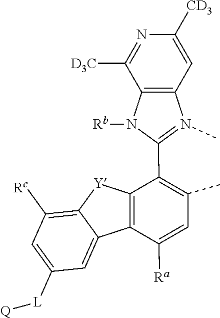 |
| L_{A125}- (L)(Q)(Y′)(R^{a})(R^{b})(R^{c}), wherein L_{A125}- (L1)(Q1)(Y1)(R1)(R1) to L_{A125}- (L28)(Q56)(Y4)(R120) (R120)(R120) have the structure | 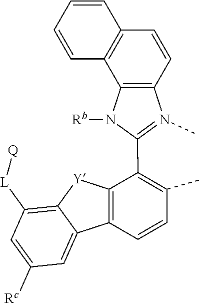 |
| L_{A126}- (L)(Q)(Y′)(R^{a})(R^{b})(R^{c}), wherein L_{A126}- (L1)(Q1)(Y1)(R1)(R1) to L_{A126}- (L28)(Q56)(Y4)(R120) (R120)(R120) have the structure | 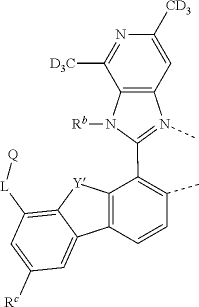 |
| L_{A127}- (L)(Q)(Y′)(R^{a})(R^{b})(R^{c}), wherein L_{A127}- (L1)(Q1)(Y1)(R1)(R1) to L_{A127}- (L28)(Q56)(Y4)(R120) (R120)(R120) have the structure | 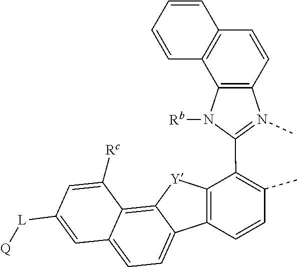 |
| L_{A128}- (L)(Q)(Y′)(R^{a})(R^{b})(R^{c}), wherein L_{A128}- (L1)(Q1)(Y1)(R1)(R1) to L_{A128}- (L28)(Q56)(Y4)(R120) (R120)(R120) have the structure | 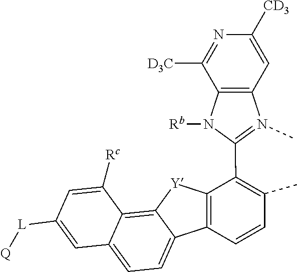 |
| L_{A129}- (L)(Q)(Y′)(R^{a})(R^{b})(R^{c}), wherein L_{A129}- (L1)(Q1)(Y1)(R1)(R1) to L_{A129}- (L28)(Q56)(Y4)(R120) (R120)(R120) have the structure | 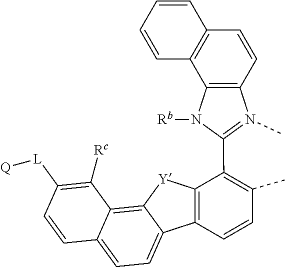 |
| L_{A130}- (L)(Q)(Y′)(R^{a})(R^{b})(R^{c}), wherein L_{A130}- (L1)(Q1)(Y1)(R1)(R1) to L_{A130}- (L28)(Q56)(Y4)(R120) (R120)(R120) have the structure | 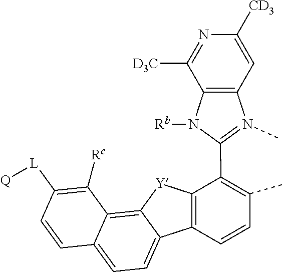 |
| L_{A131}- (L)(Q)(Y′)(R^{a})(R^{b})(R^{c}), wherein L_{A131}- (L1)(Q1)(Y1)(R1)(R1) to L_{A131}- (L28)(Q56)(Y4)(R120) (R120)(R120) have the structure | 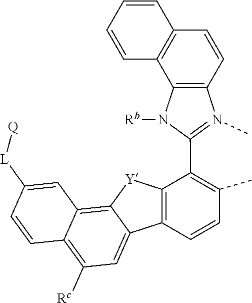 |
| L_{A132}- (L)(Q)(Y′)(R^{a})(R^{b})(R^{c}), wherein L_{A132}- (L1)(Q1)(Y1)(R1)(R1) to L_{A132}- (L28)(Q56)(Y4)(R120) (R120)(R120) have the structure | 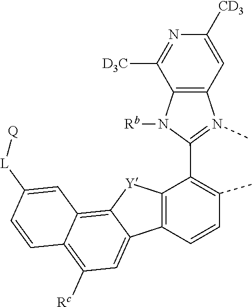 |
| L_{A133}- (L)(Q)(Y′)(R^{a})(R^{b})(R^{c}), wherein L_{A133}- (L1)(Q1)(Y1)(R1)(R1) to L_{A133}- (L28)(Q56)(Y4)(R120) (R120)(R120) have the structure | 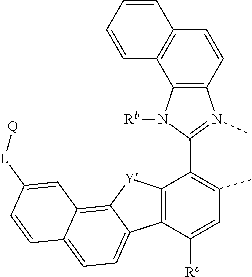 |
| L_{A134}- (L)(Q)(Y′)(R^{a})(R^{b})(R^{c}), wherein L_{A134}- (L1)(Q1)(Y1)(R1)(R1) to L_{A134}- (L28)(Q56)(Y4)(R120) (R120)(R120) have the structure | 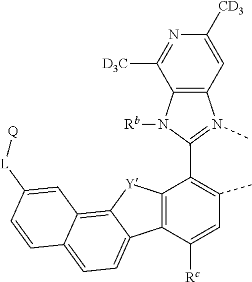 |
| L_{A135}- (L)(Q)(Y′)(R^{a})(R^{b})(R^{c}), wherein L_{A135}- (L1)(Q1)(Y1)(R1)(R1) to L_{A135}- (L28)(Q56)(Y4)(R120) (R120)(R120) have the structure | 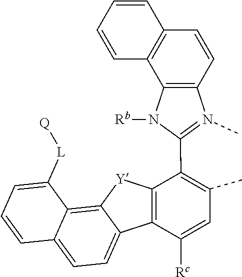 |
| L_{A136}- (L)(Q)(Y′)(R^{a})(R^{b})(R^{c}), wherein L_{A136}- (L1)(Q1)(Y1)(R1)(R1) to L_{A136}- (L28)(Q56)(Y4)(R120) (R120)(R120) have the structure | 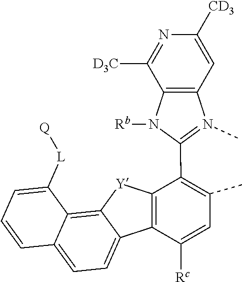 |
| L_{A137}- (L)(Q)(Y′)(R^{a})(R^{b})(R^{c}), wherein L_{A137}- (L1)(Q1)(Y1)(R1)(R1) to L_{A137}- (L28)(Q56)(Y4)(R120) (R120)(R120) have the structure | 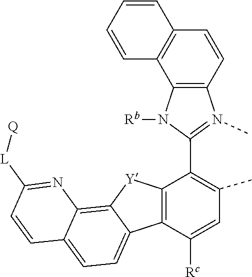 |
| L_{A138}- (L)(Q)(Y′)(R^{a})(R^{b})(R^{c}), wherein L_{A138}- (L1)(Q1)(Y1)(R1)(R1) to L_{A138}- (L28)(Q56)(Y4)(R120) (R120)(R120) have the structure | 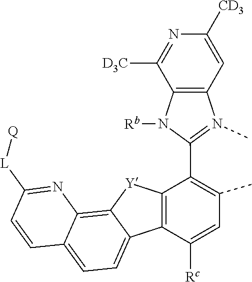 |
| L_{A139}- (L)(Q)(Y′)(R^{a})(R^{b})(R^{c}), wherein L_{A139}- (L1)(Q1)(Y1)(R1)(R1) to L_{A139}- (L28)(Q56)(Y4)(R120) (R120)(R120) have the structure | 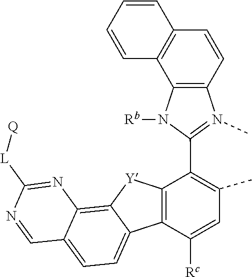 |
| L_{A140}- (L)(Q)(Y′)(R^{a})(R^{b})(R^{c}), wherein L_{A140}- (L1)(Q1)(Y1)(R1)(R1) to L_{A140}- (L28)(Q56)(Y4)(R120) (R120)(R120) have the structure | 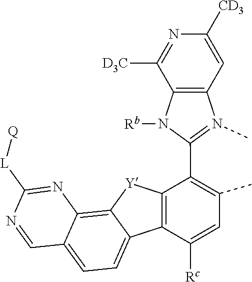 |

wherein R1 to R120 each have the structures defined as follows: 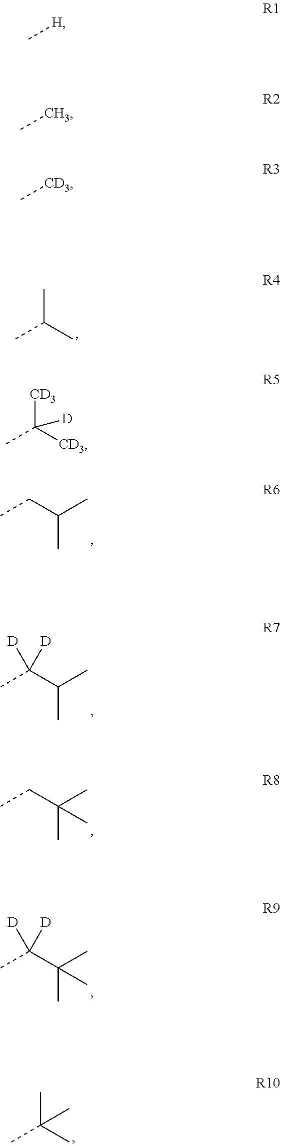 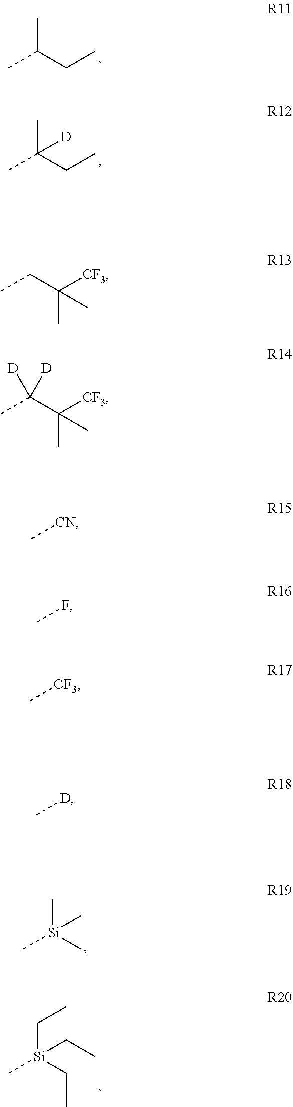 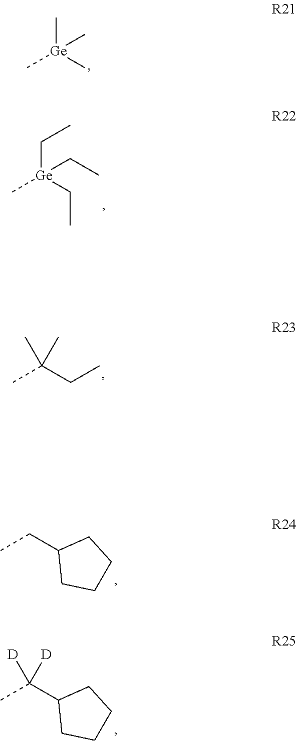 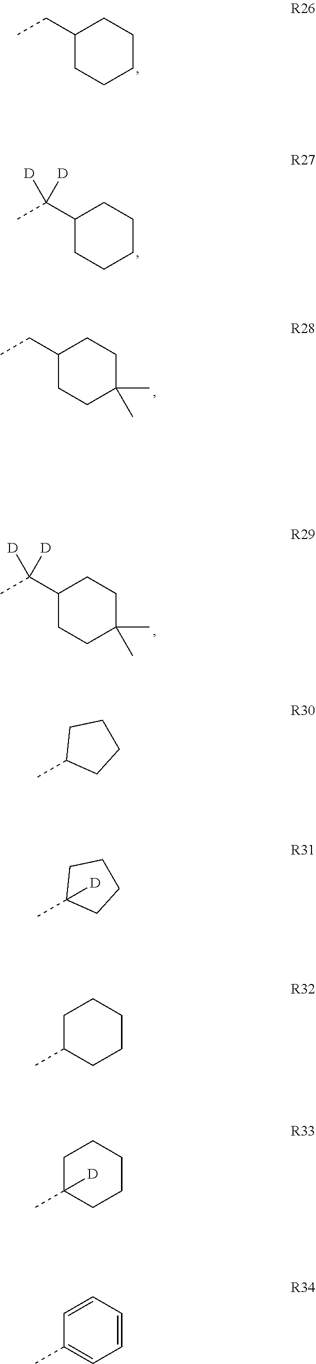 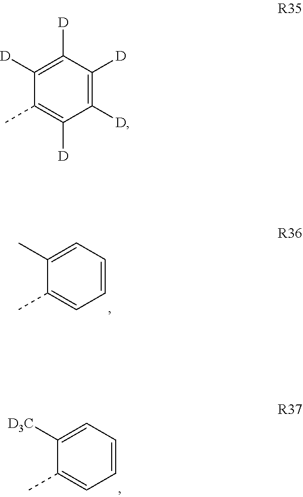 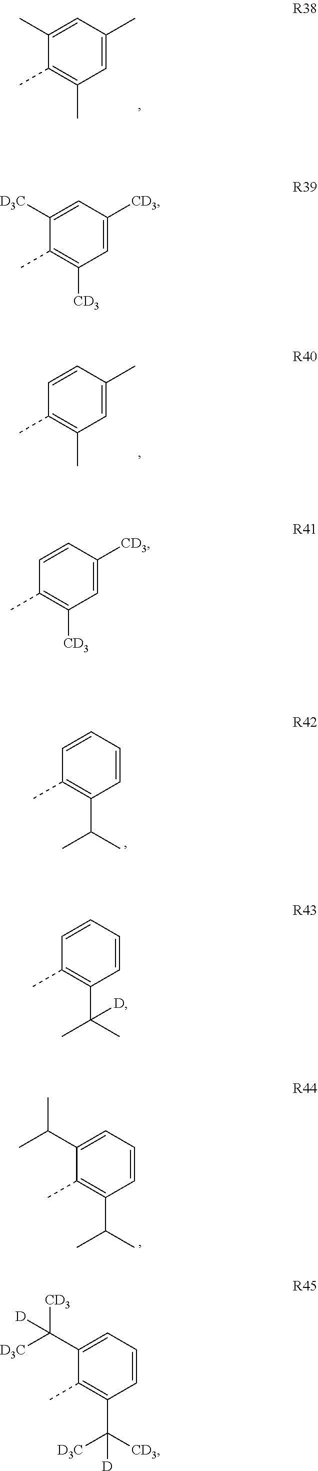 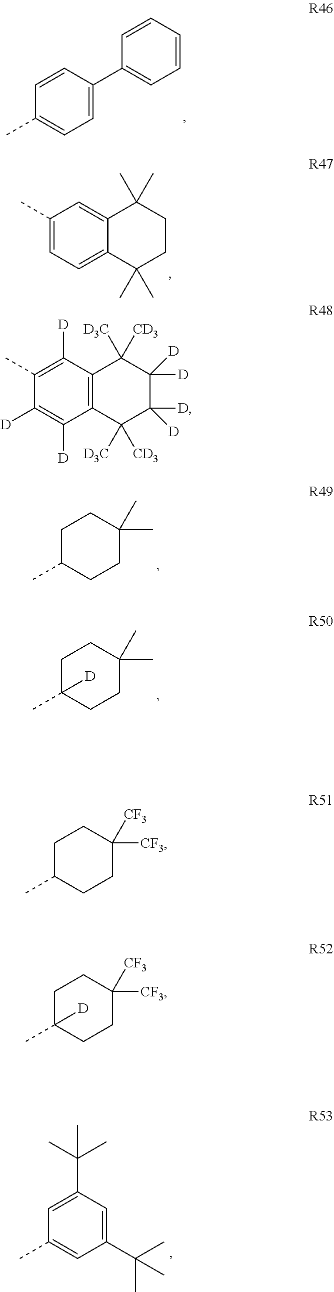 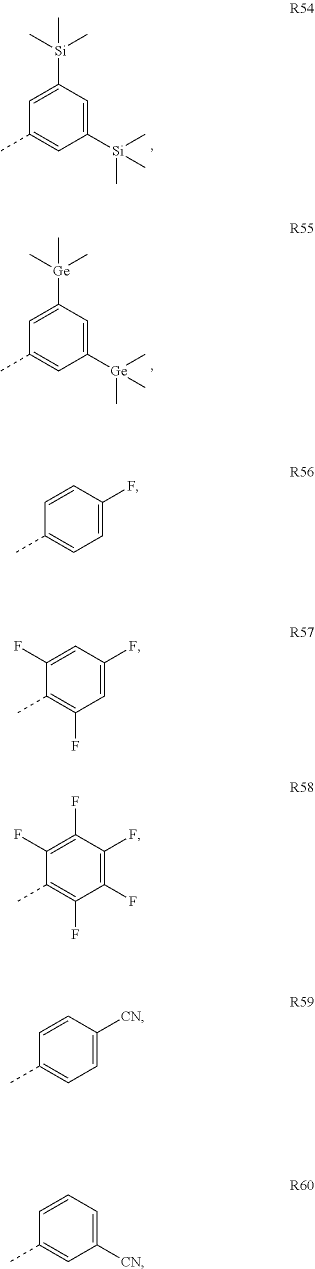 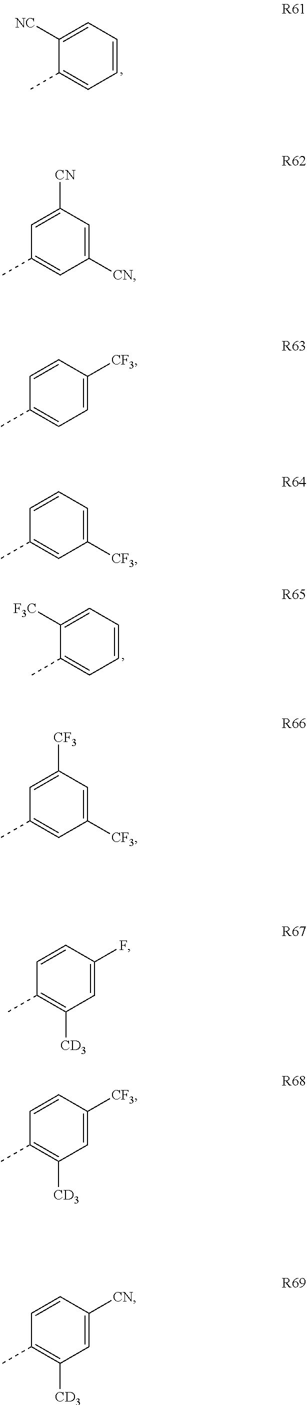 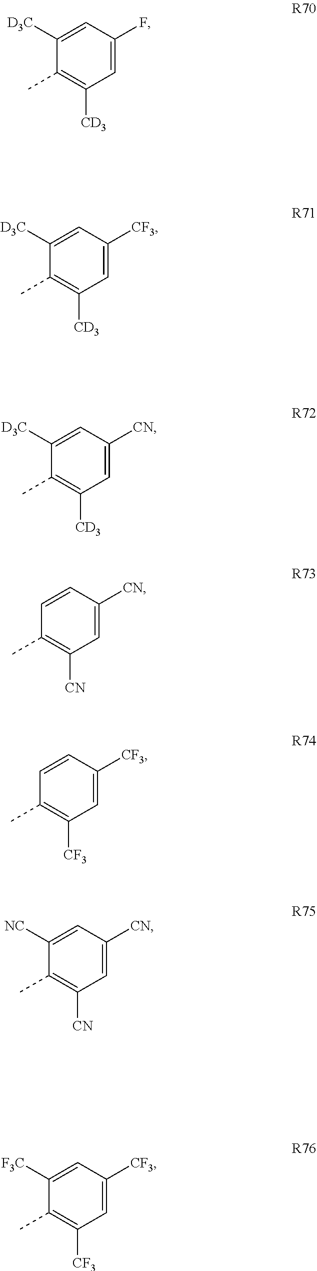 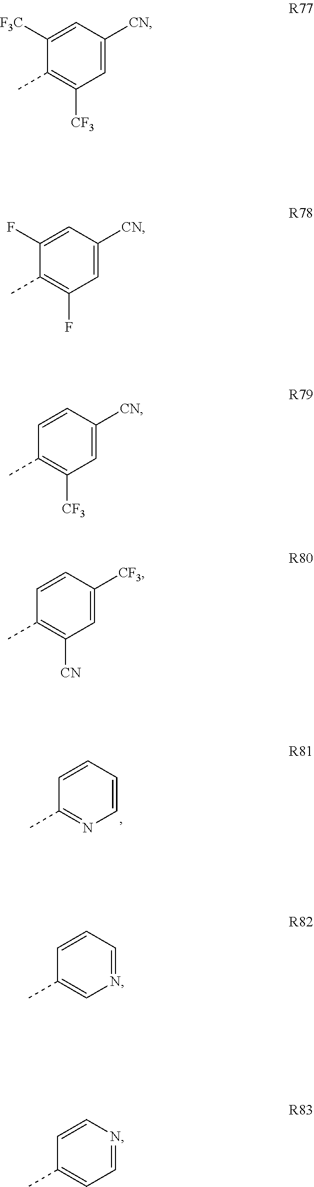 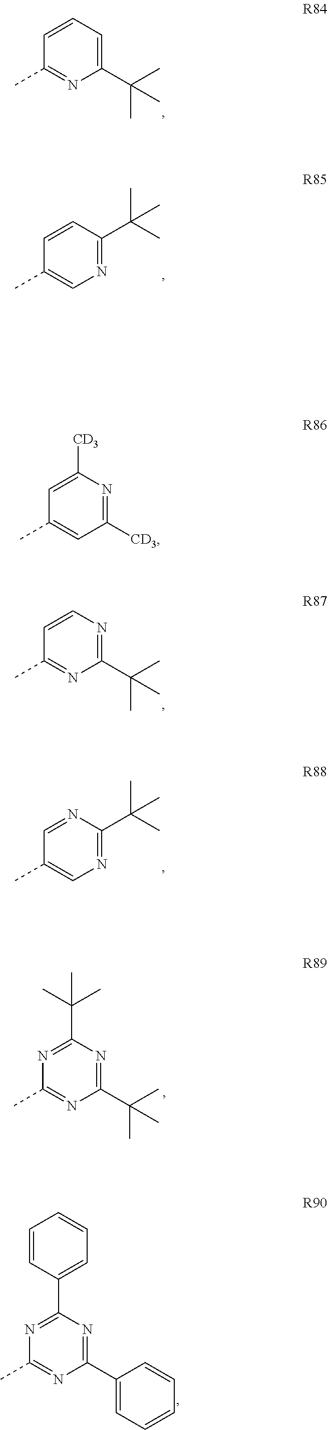 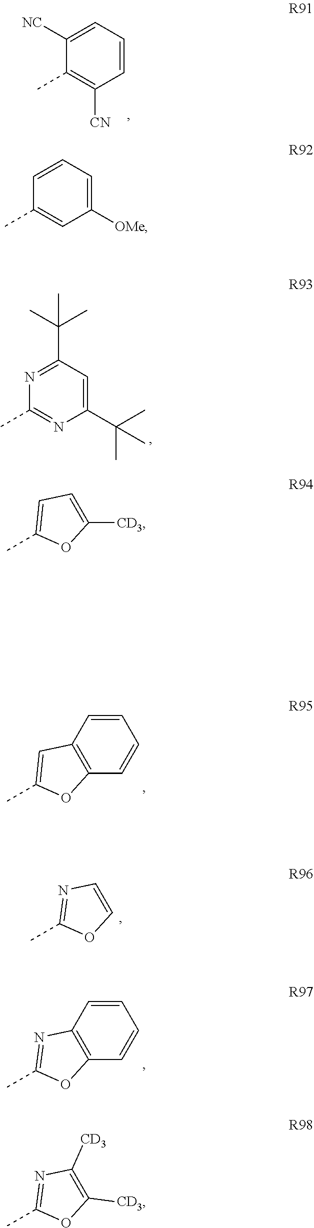 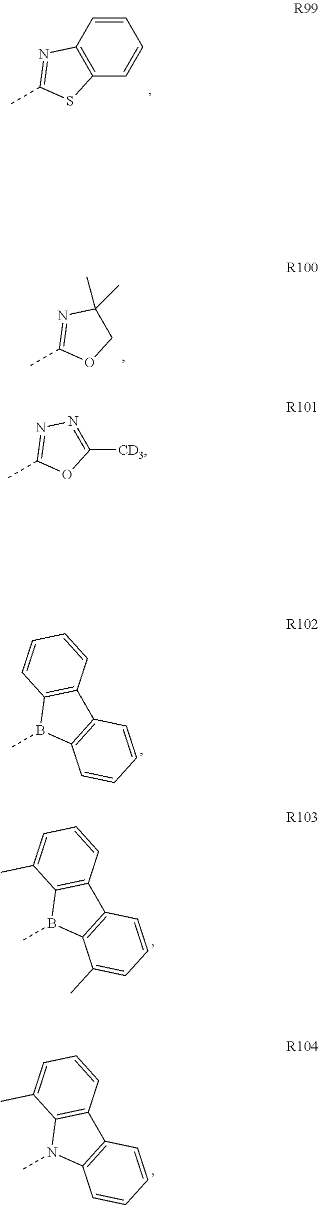 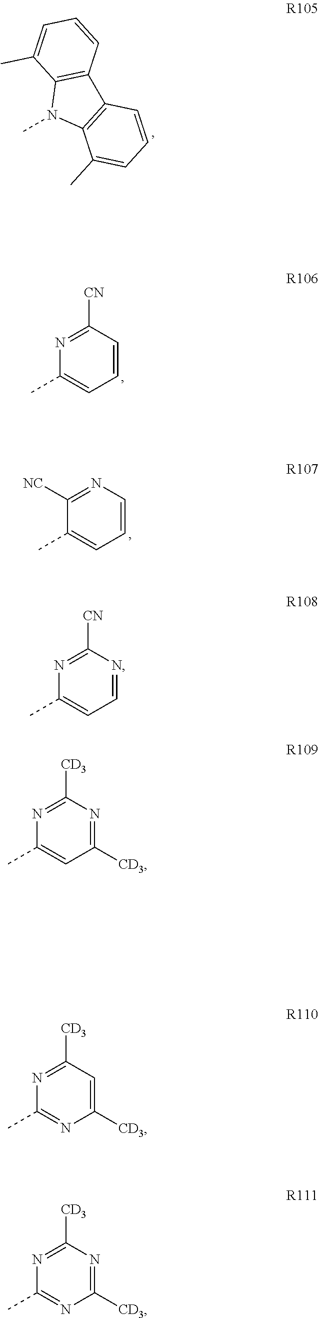 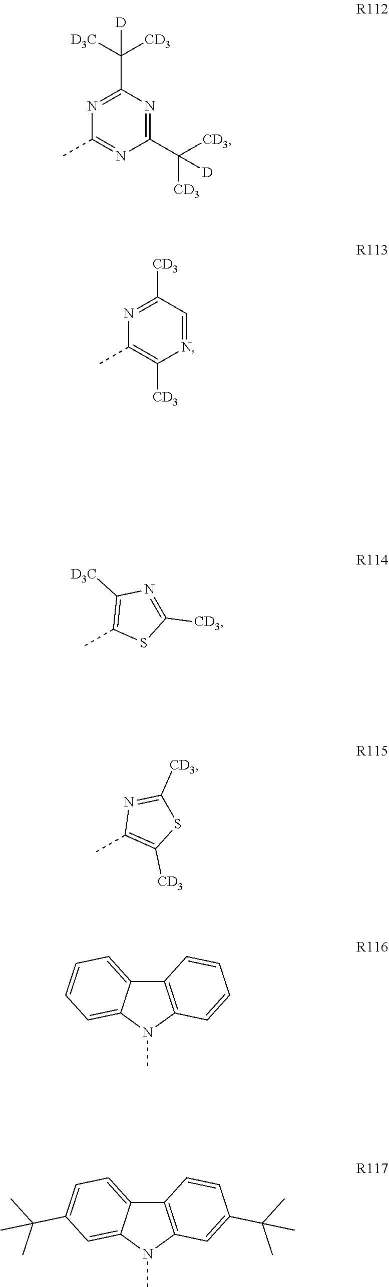 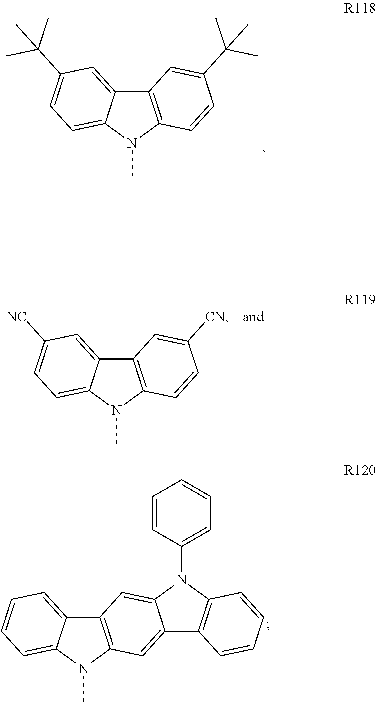
wherein Y1 to Y4 have the following structures: 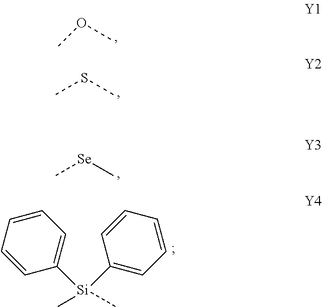
where in L1 to L28 have the following structures: 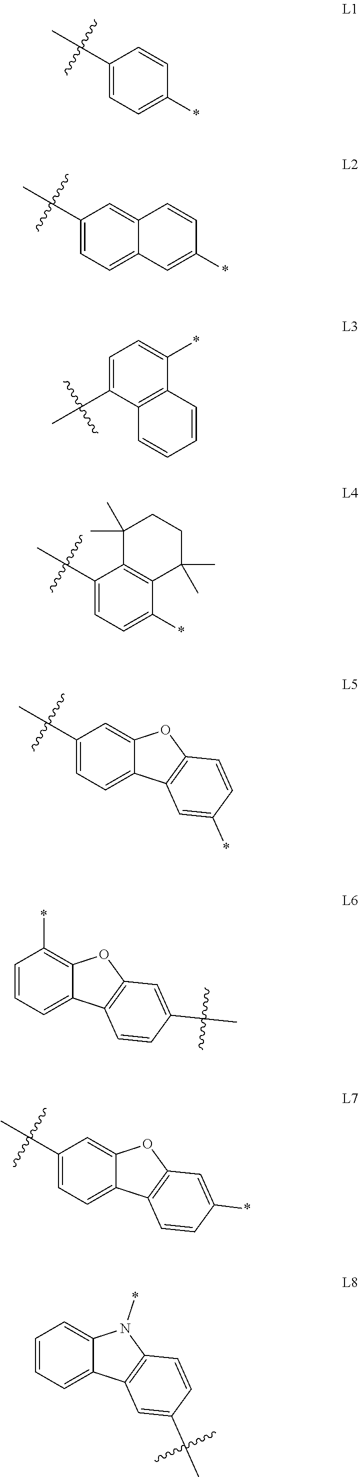 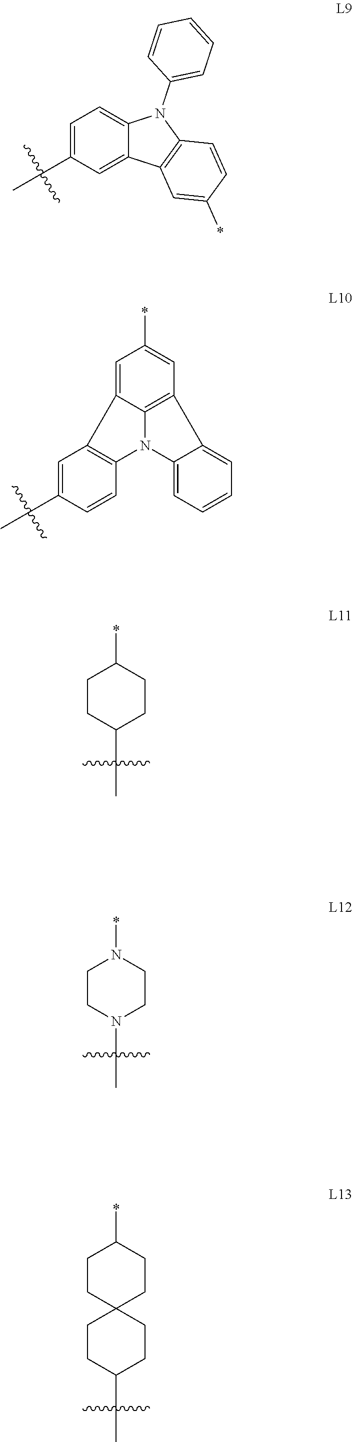 [SMILES: *c1ccc2c(c1)c1cc(*)ccc1n2-c1ccccc1 ; *c1ccc2c(c1)c1cc(*)cc3c4ccccc4n2c31 ; *C1CCC(*)CC1 ; *N1CCN(*)CC1 ; *C1CCC2(CC1)CCC(*)CC2] 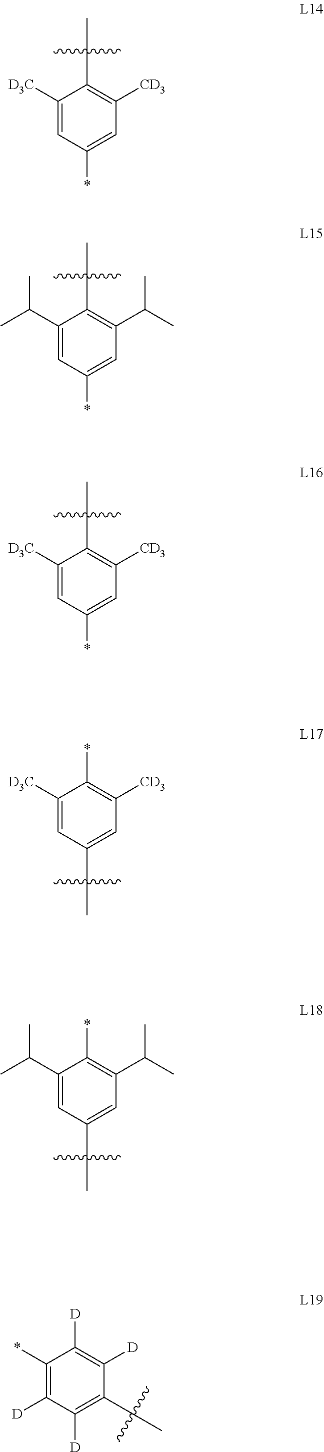 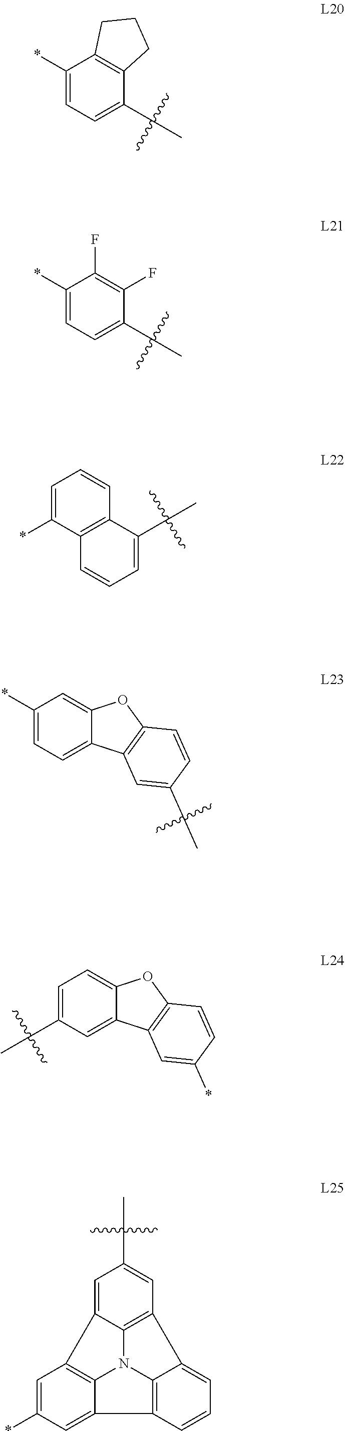 [SMILES: *c1ccc(*)c2c1CCC2 ; *c1ccc(*)c(F)c1F ; *c1cccc2c(*)cccc12 ; *c1ccc2c(c1)oc1ccc(*)cc12 ; *c1ccc2oc3ccc(*)cc3c2c1 ; *c1cc2c3cccc4c5cc(*)cc6c(c1)c2n(c34)c56] 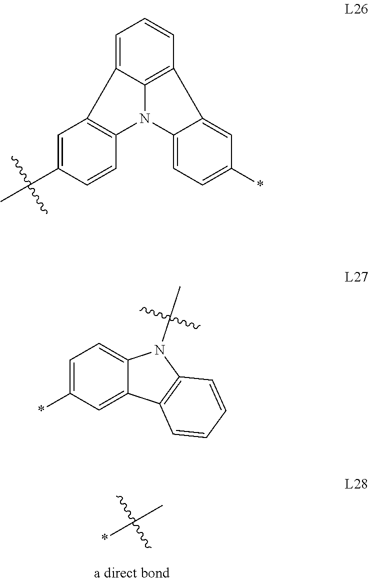
wherein 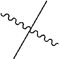
represents attachment to ring B or moiety C and * represents attachment to Q; and
wherein Q1 to Q56 have the following structures:

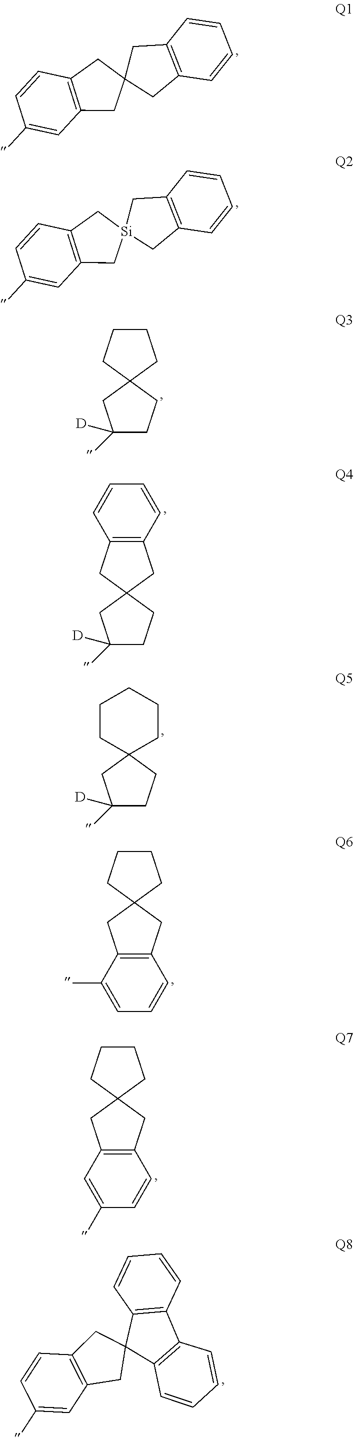

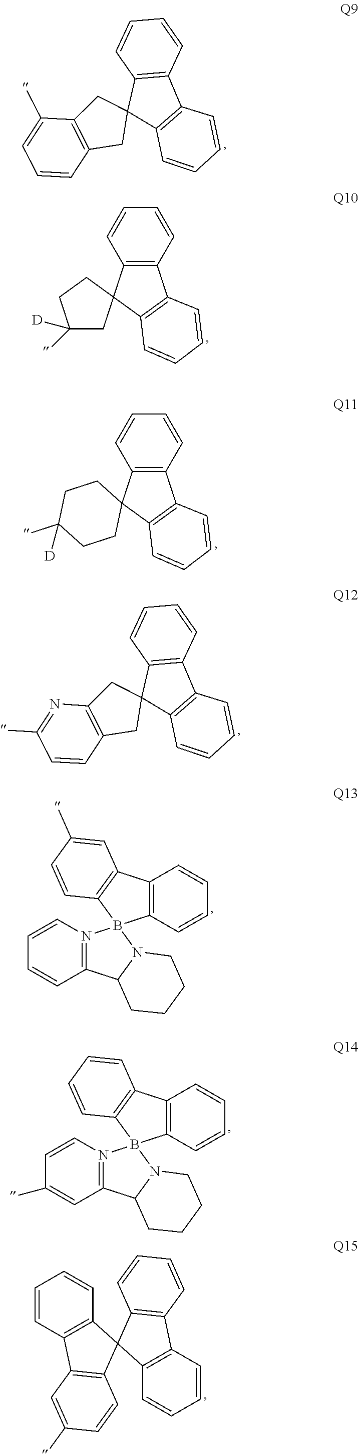

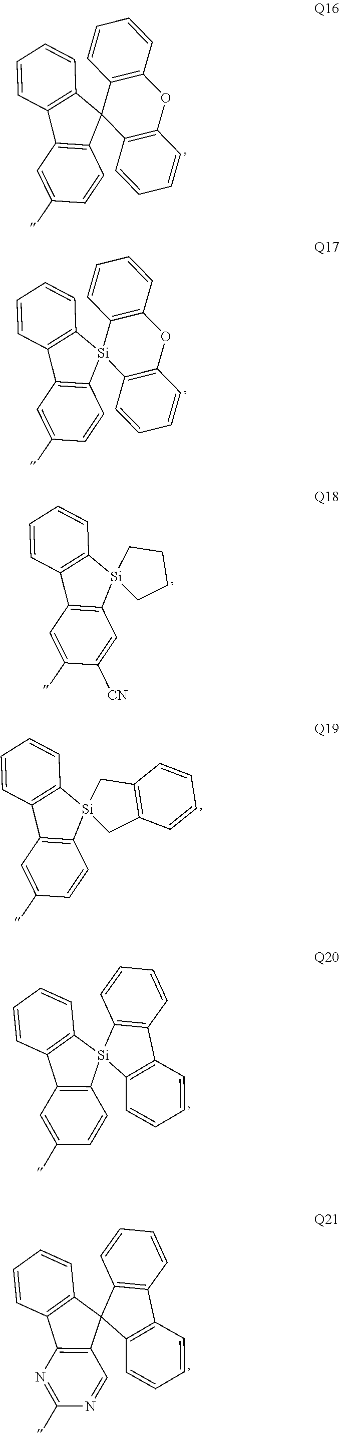

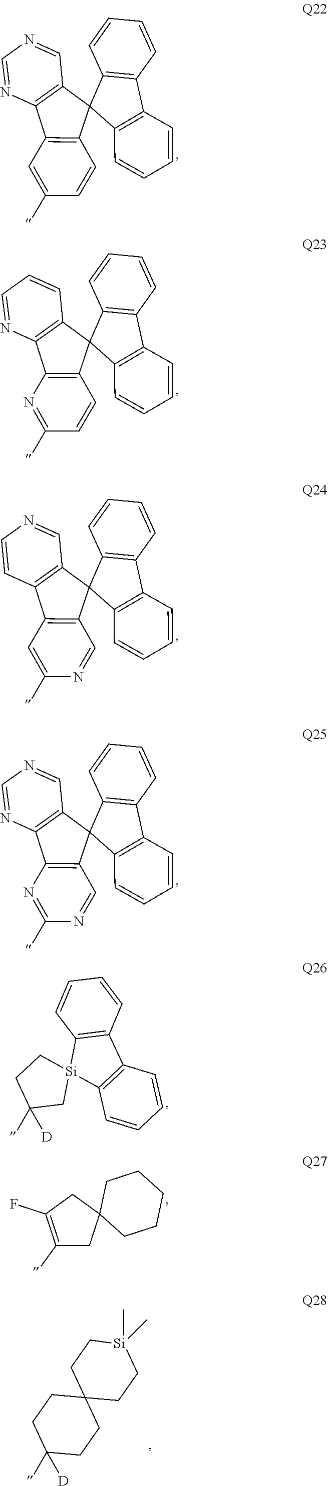

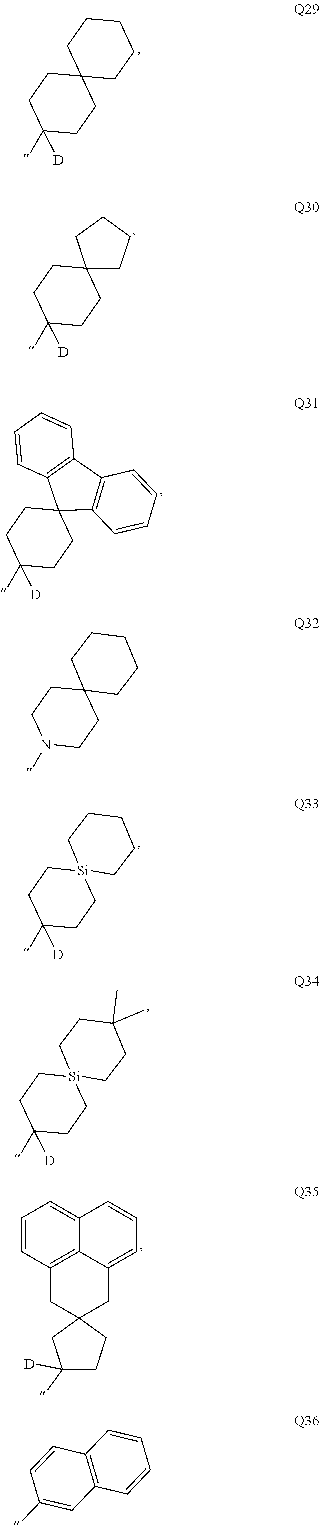

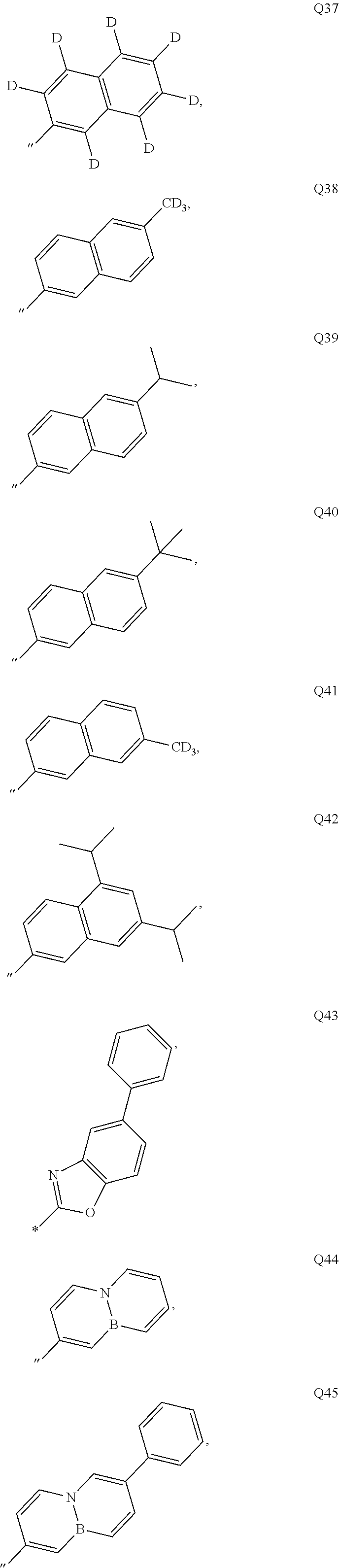

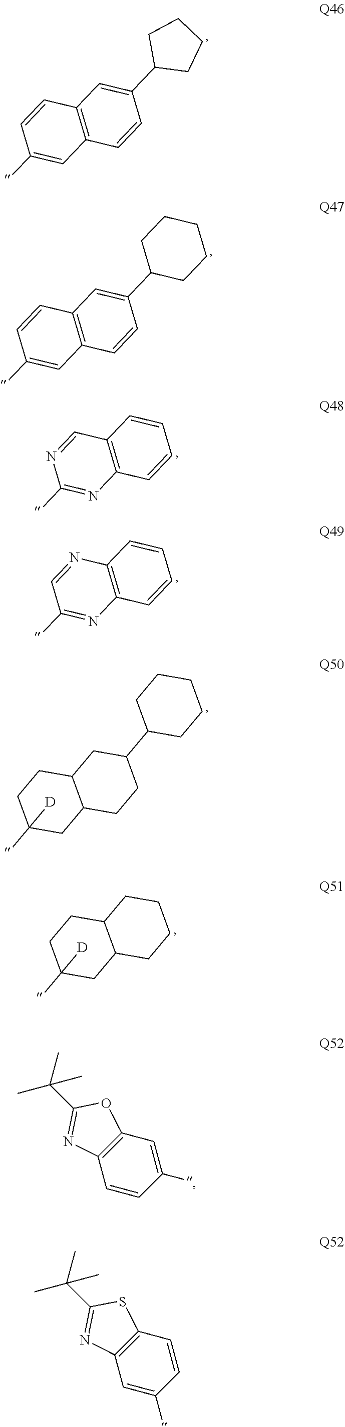

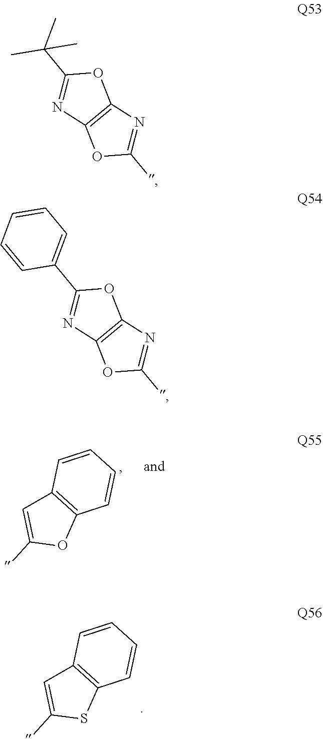

11. The compound of claim 1, wherein the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

12. The compound of claim 11, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other; or a formula of Pt(L_{A})(L_{B}); and wherein L_{A} and L_{B} can be same or different.

13. The compound of claim 11, wherein L_{B} and L_{C} are each independently selected from the group consisting of: 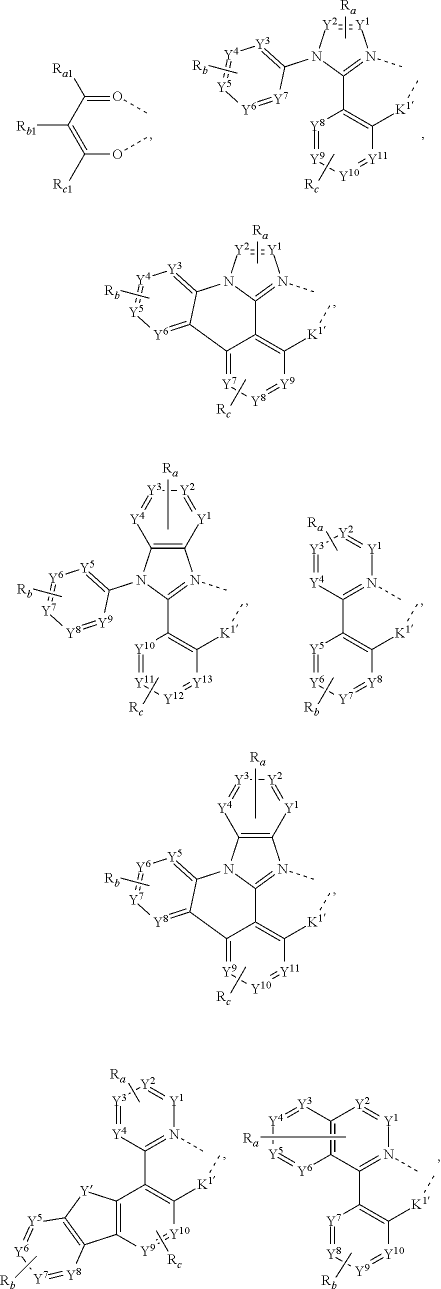 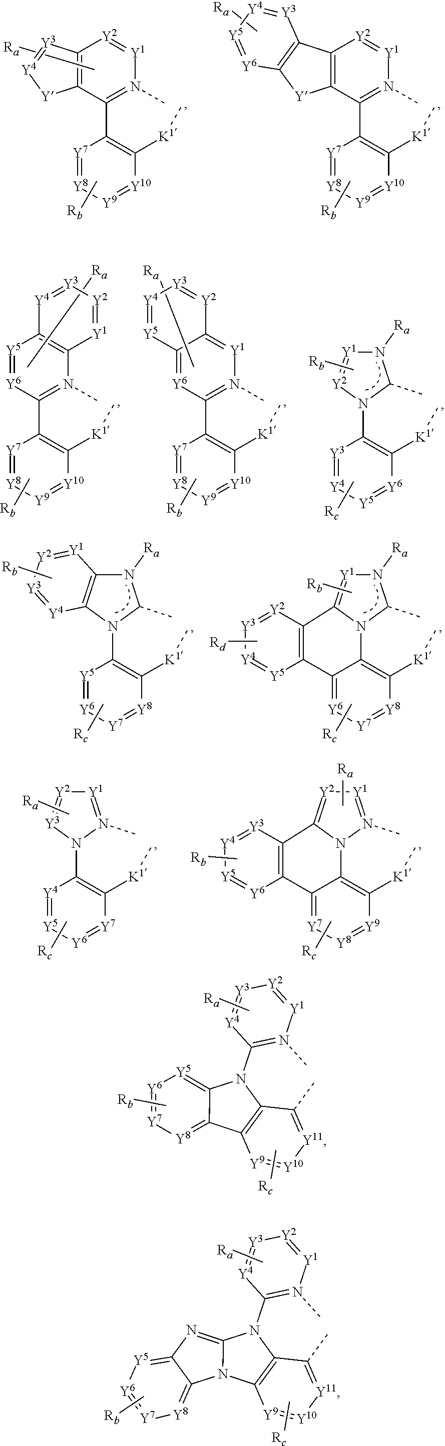 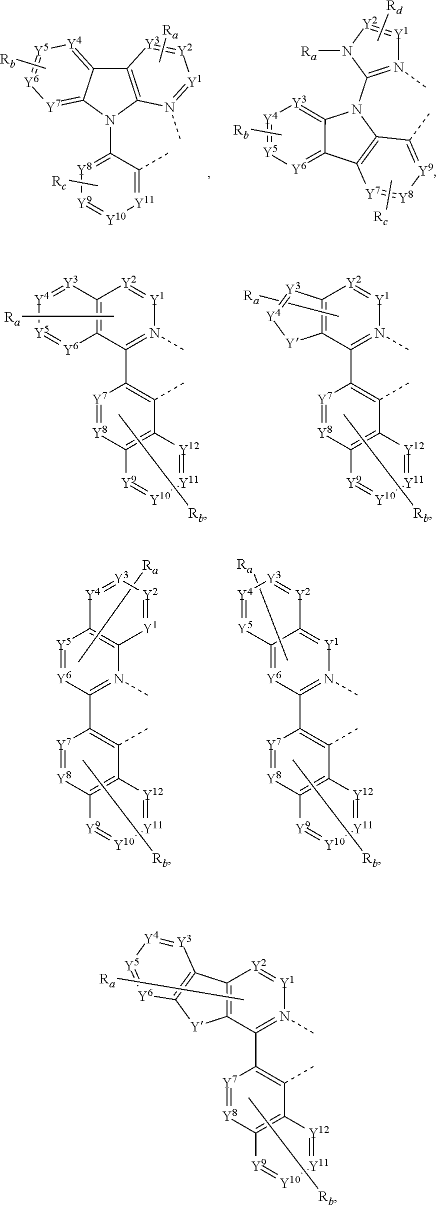 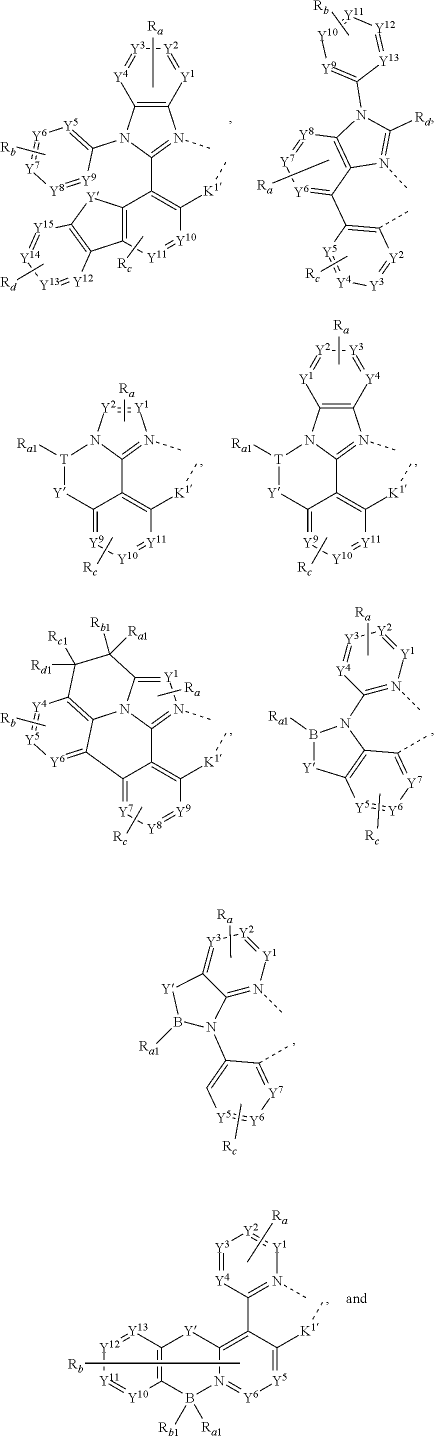 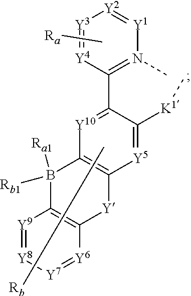
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f}, each of Y¹ to Y¹³ is independently selected from the group consisting of C and N;
Y¹ is selected from the group consisting of BRₑ, BRₑR_{f}, NRₑ, PRₑ, P(O)Rₑ, O, S, Se, C═O, C═S, C═Se, C═NRₑ, C═CReR_{f}, S═O, SO₂, CReR_{f}, SiReR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a subsituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

14. The compound of claim 10, wherein the compound has formula Ir(L_{A})₃, formula Ir(L_{A})(L_{Bk})₂, formula Ir(L_{A})₂(L_{Bk}), formula Ir(L_{A})₂(L_{Cj-I}), or Ir(L_{A})₂(L_{Cj-II});
wherein k is an integer from 1 to 541, and each L_{Bk} has the structure defined as follows: 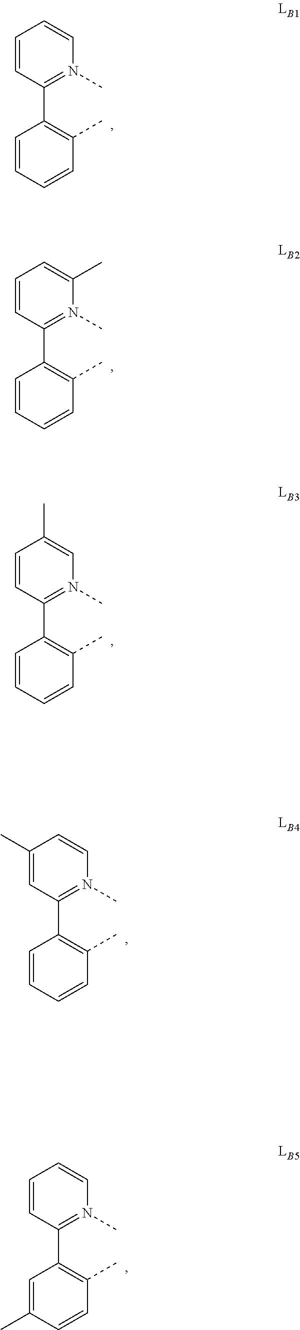 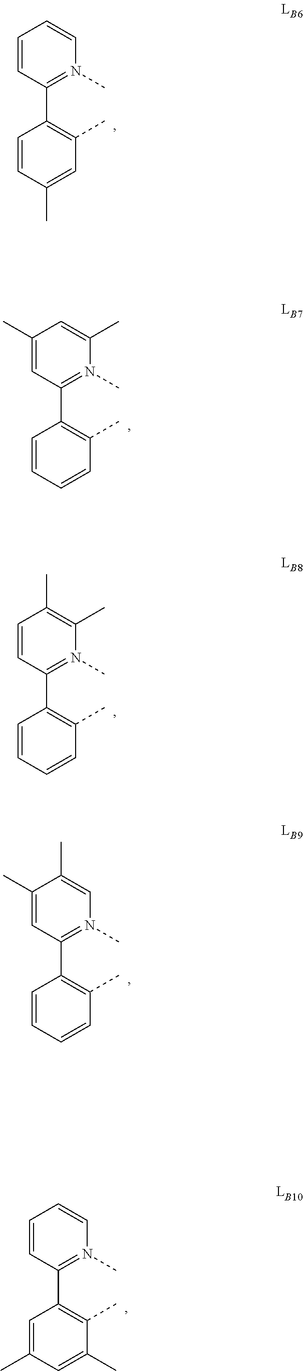 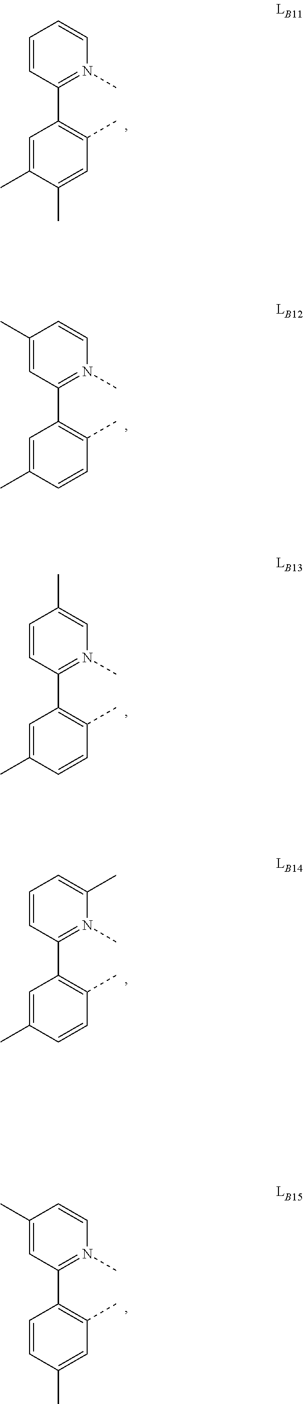 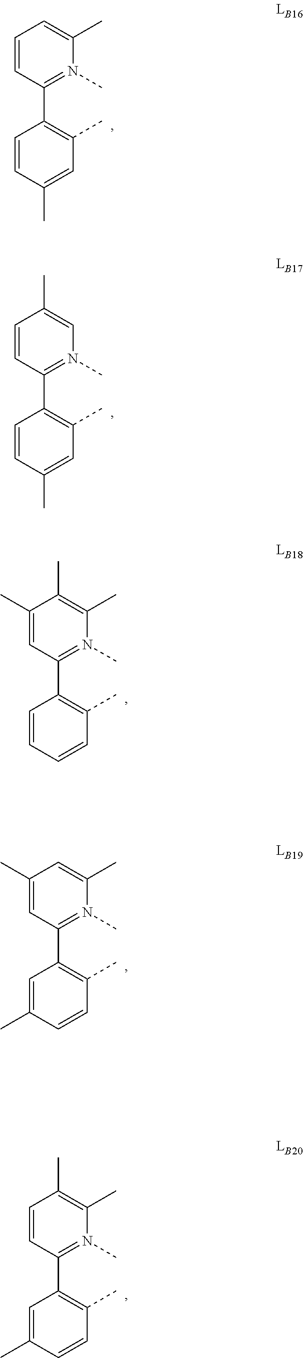 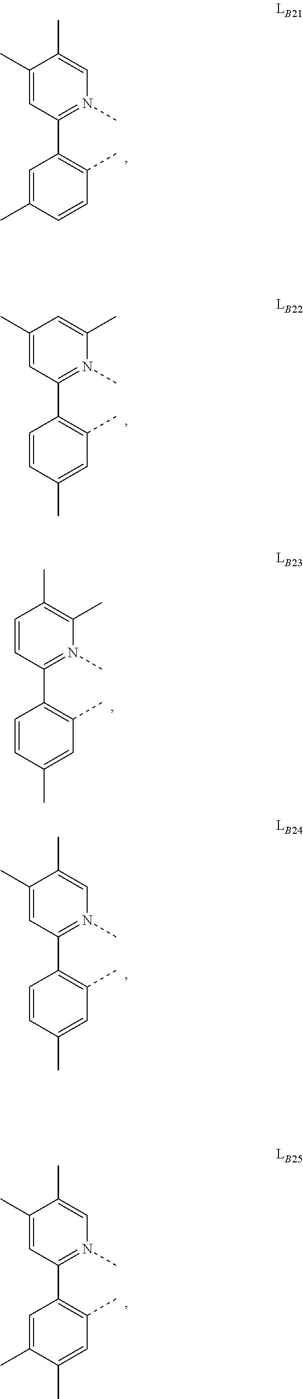 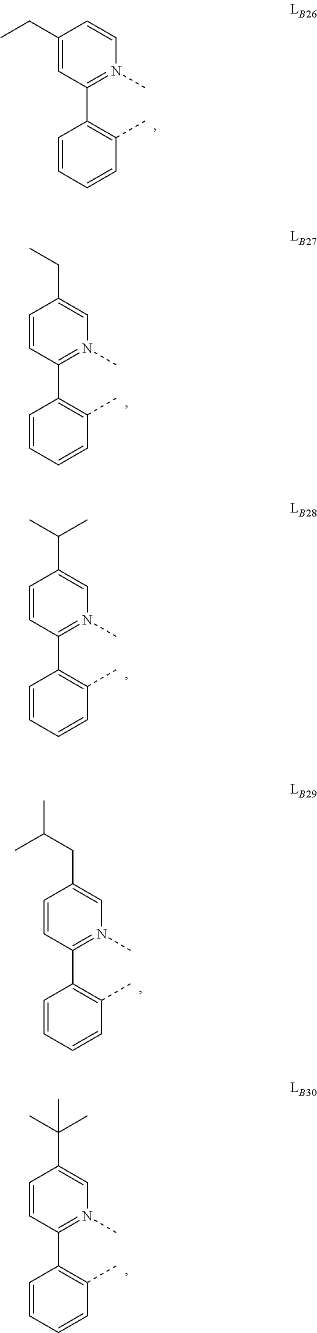 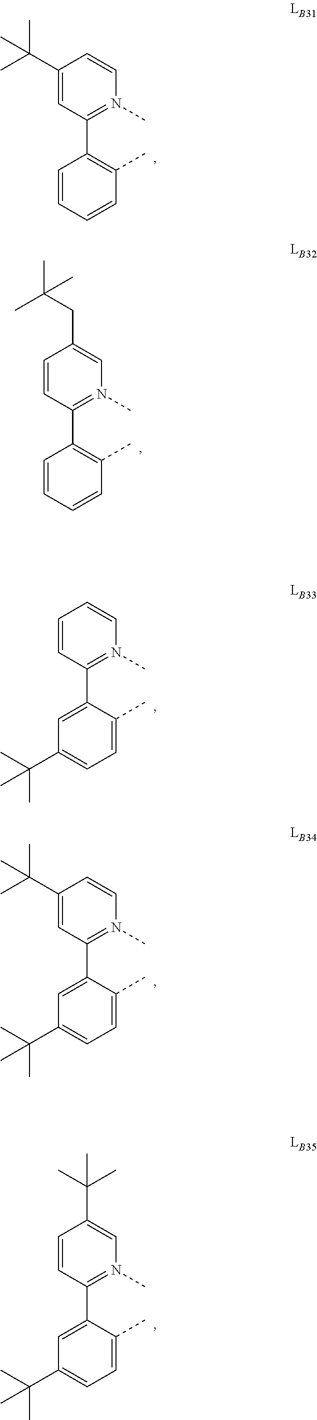 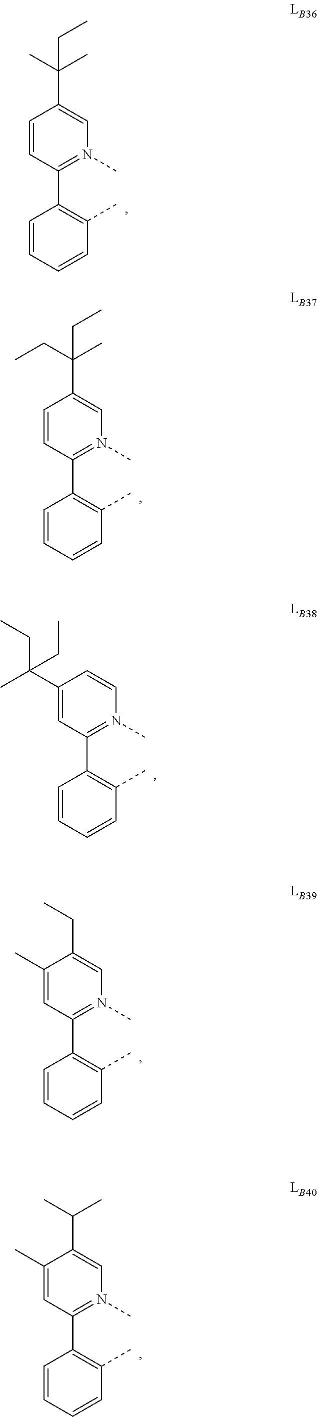 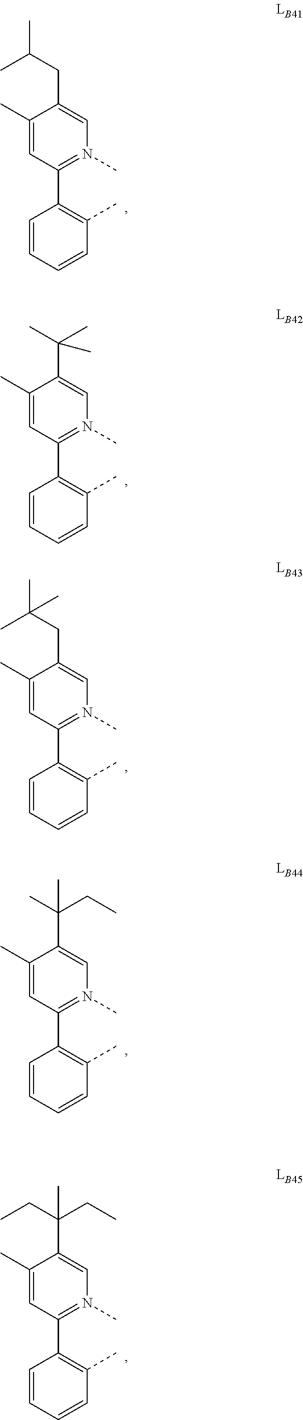 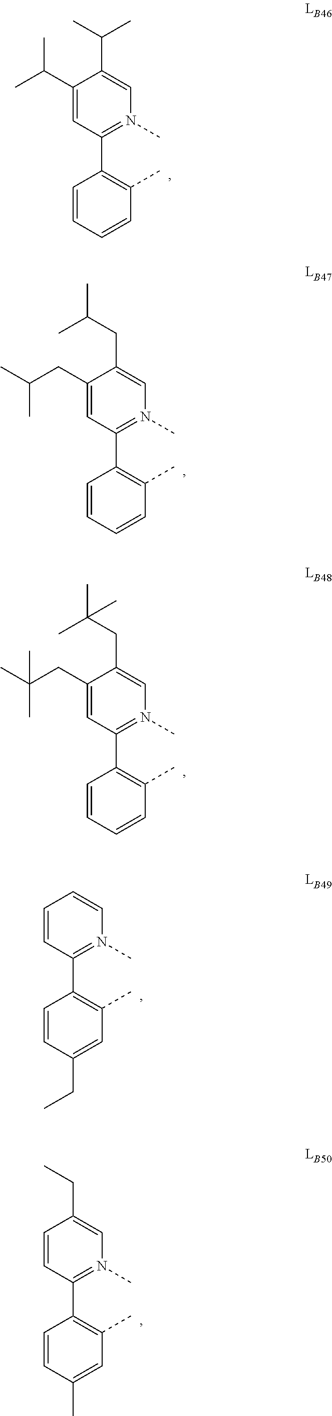 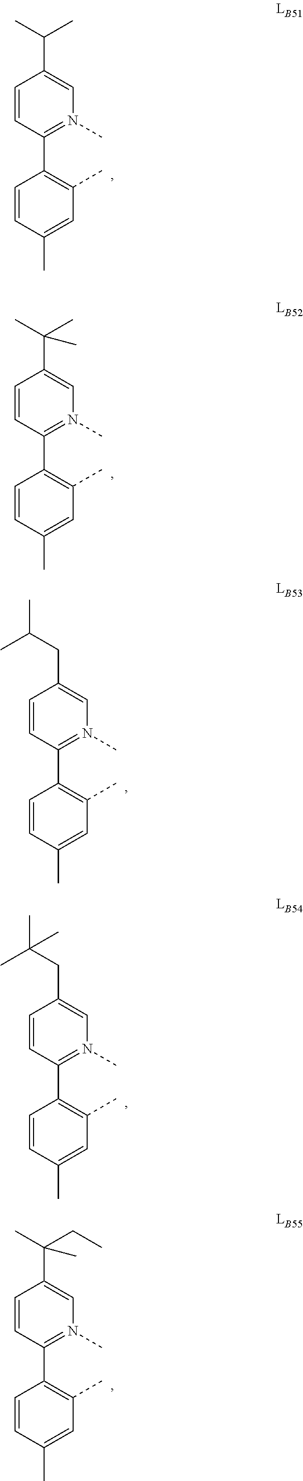 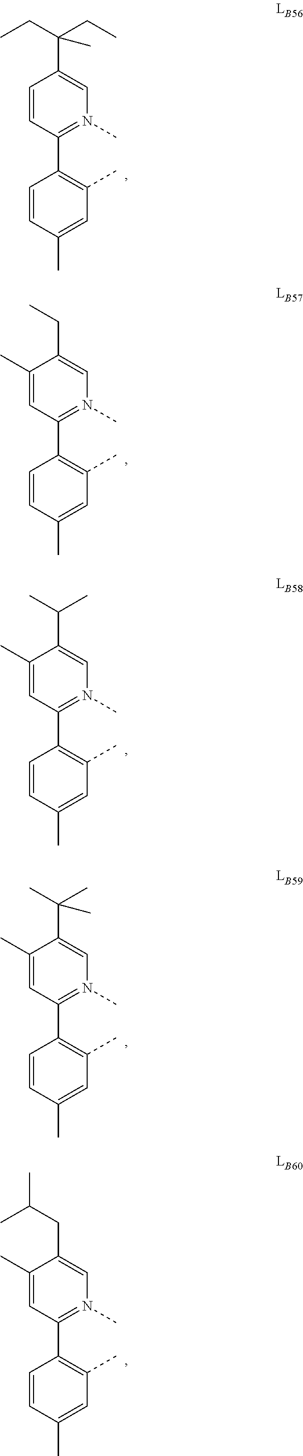 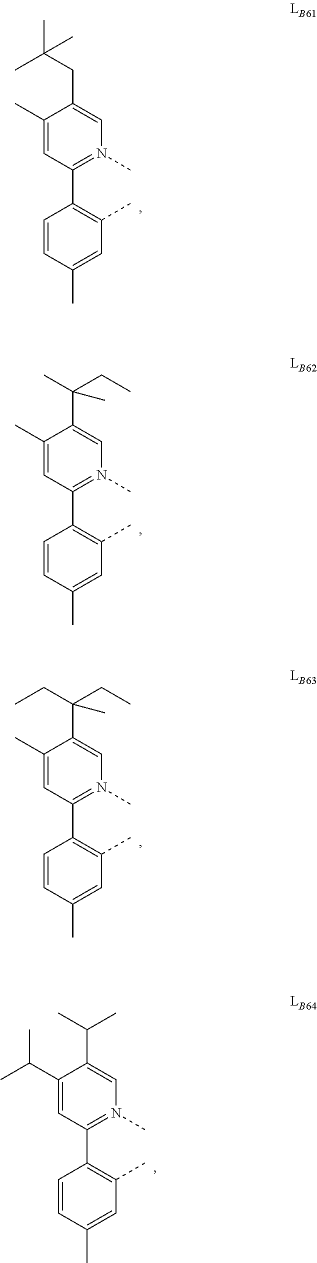 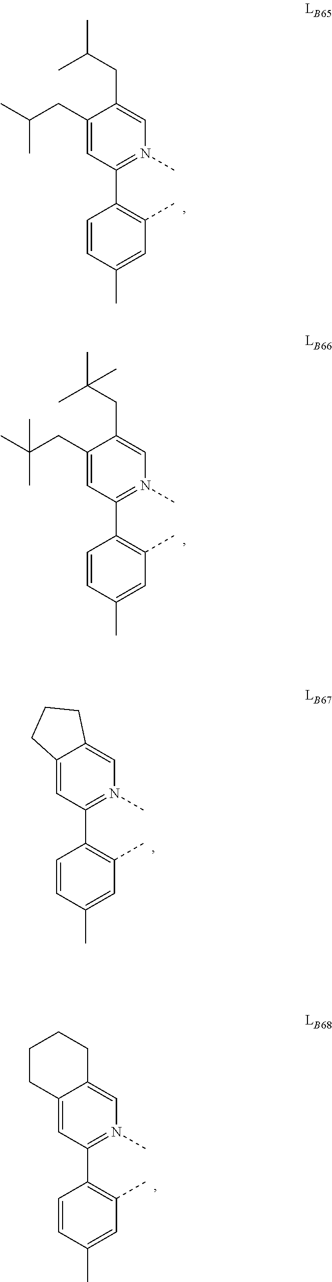 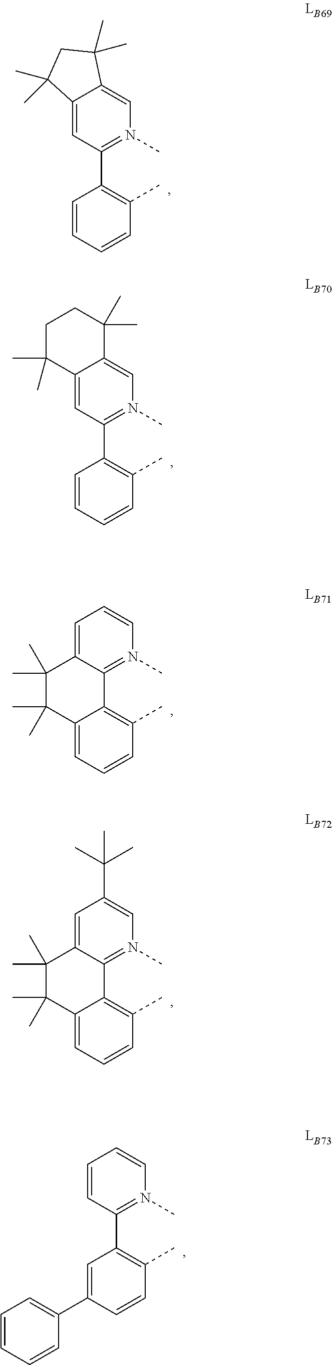 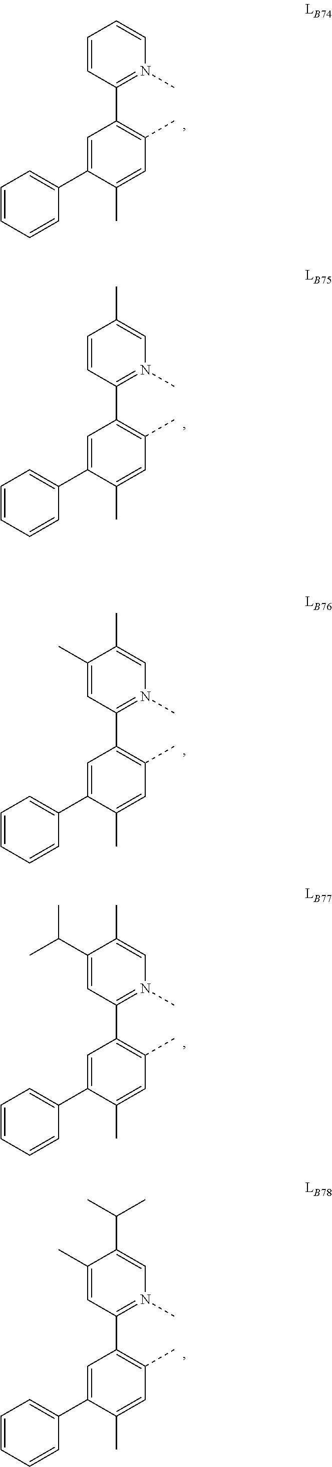 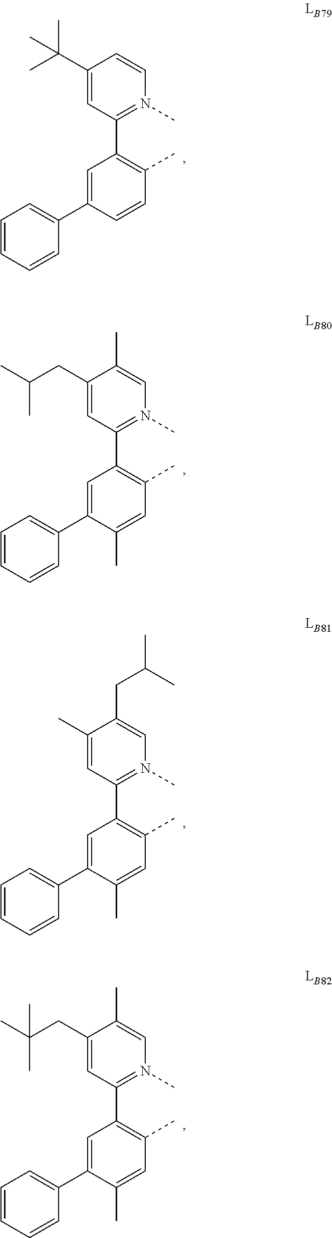 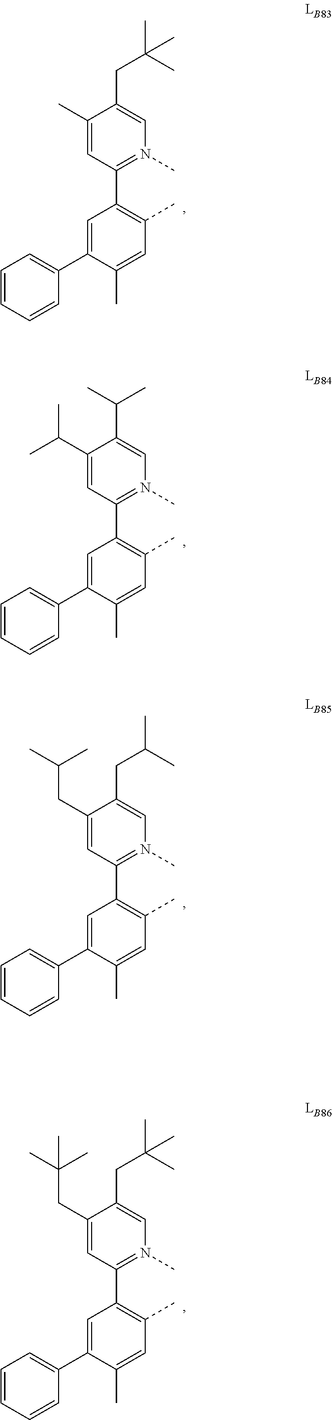 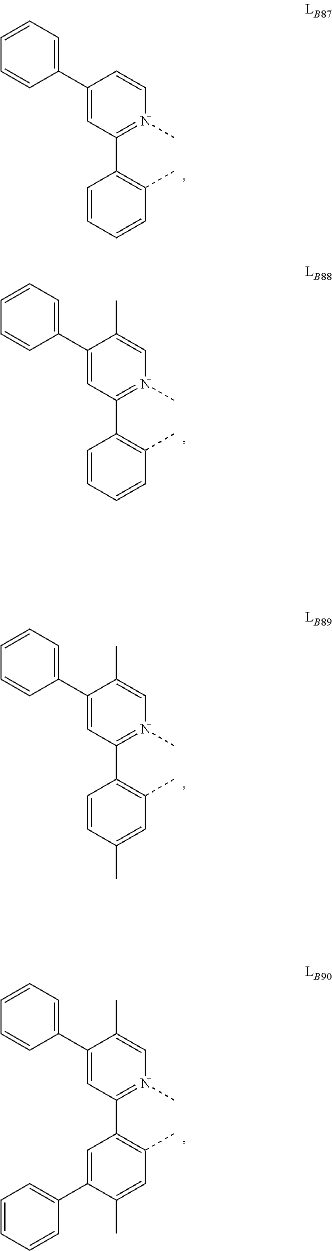 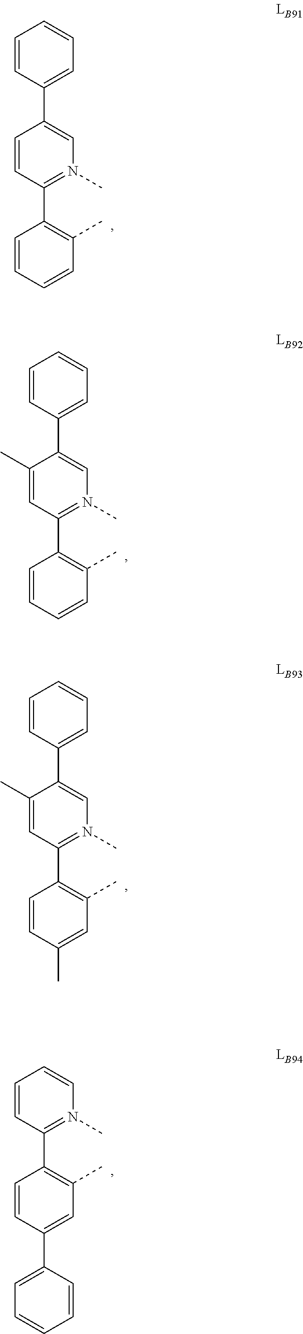 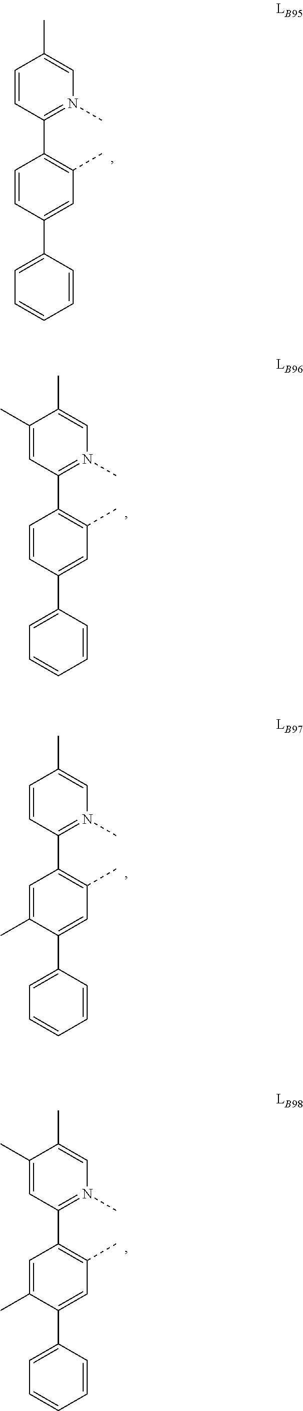 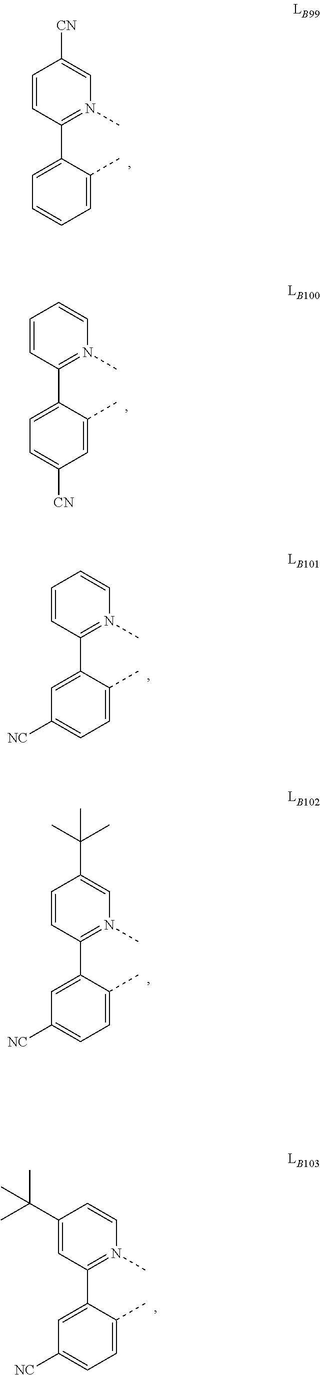 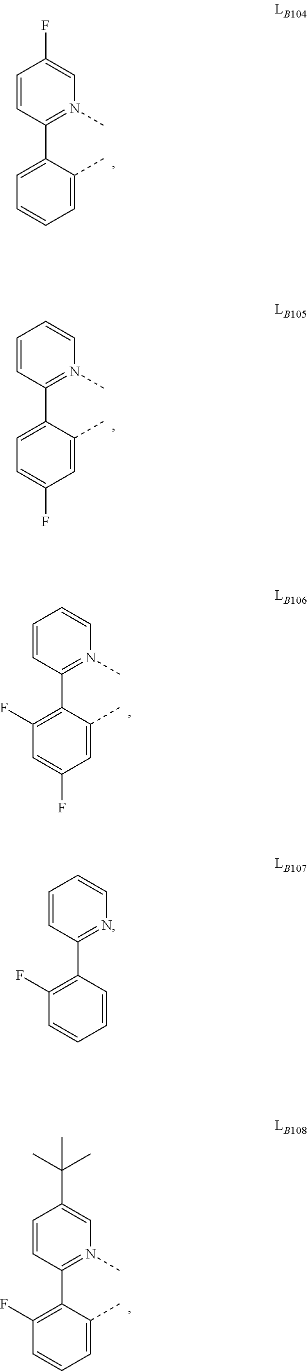 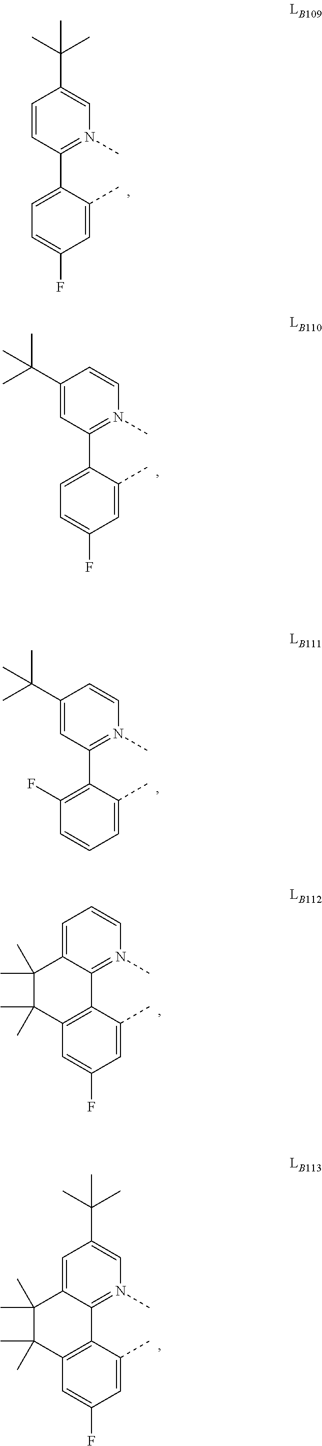 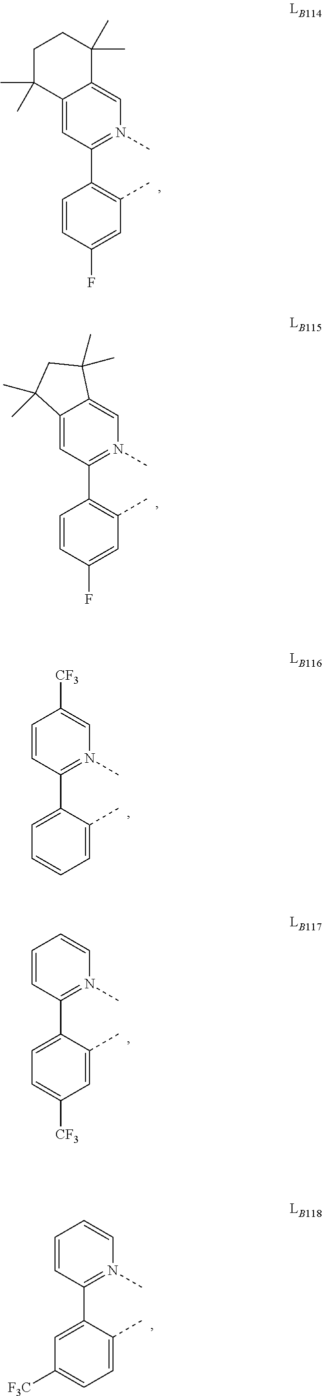 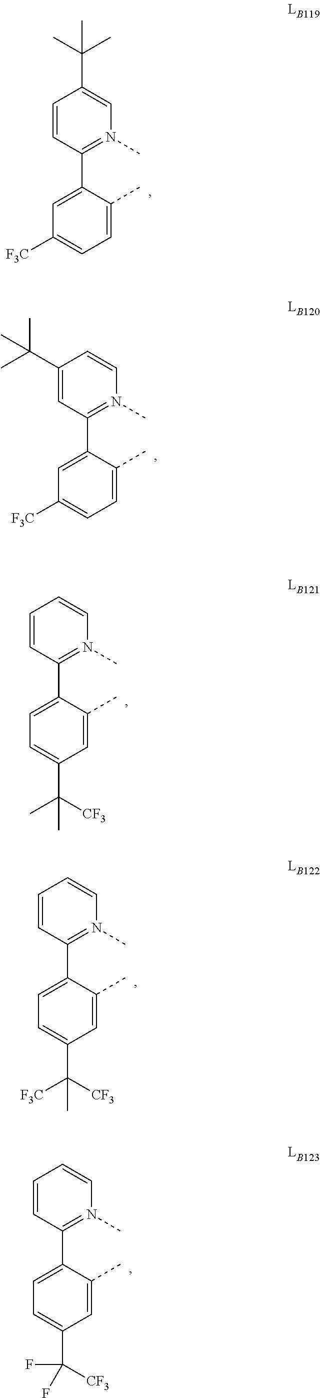 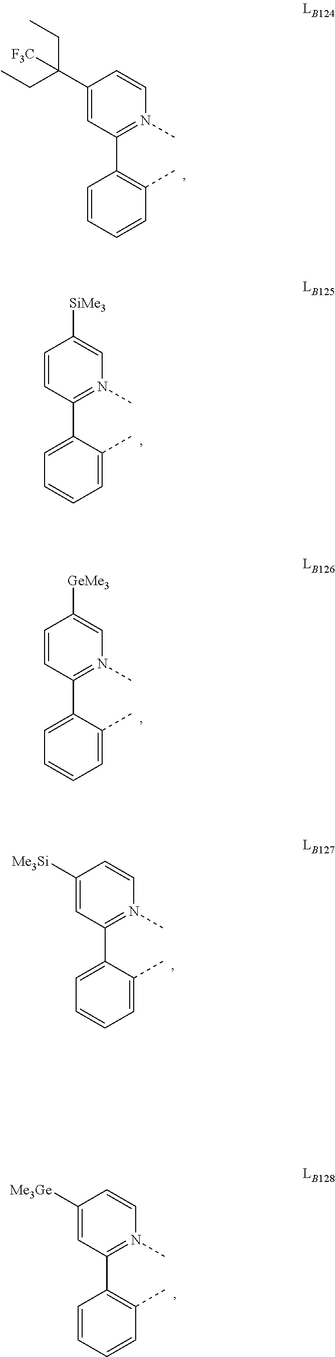 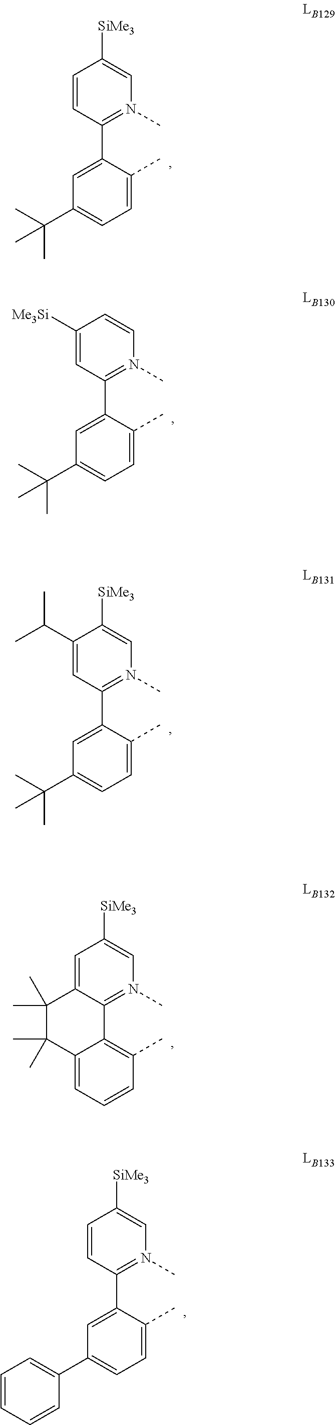 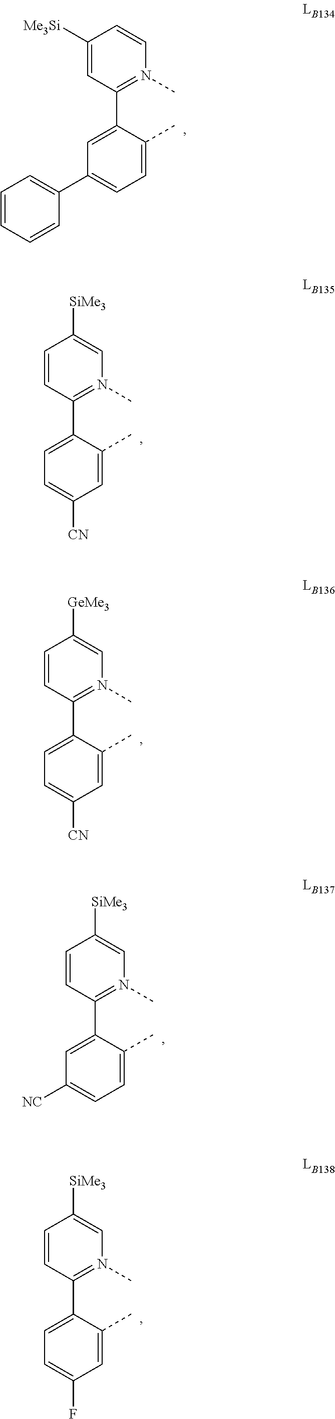 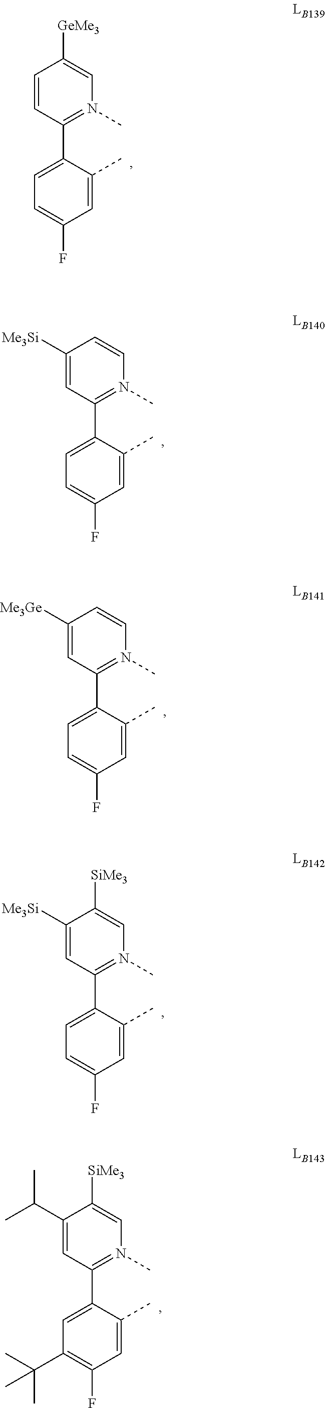 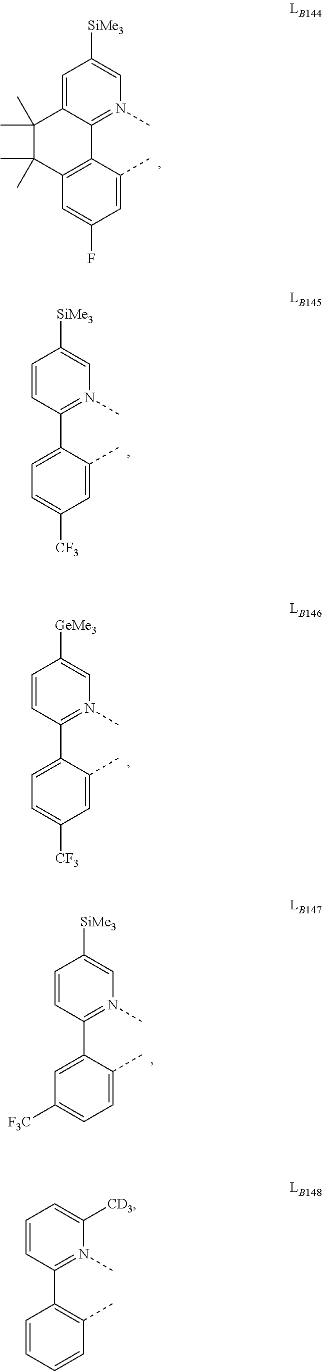 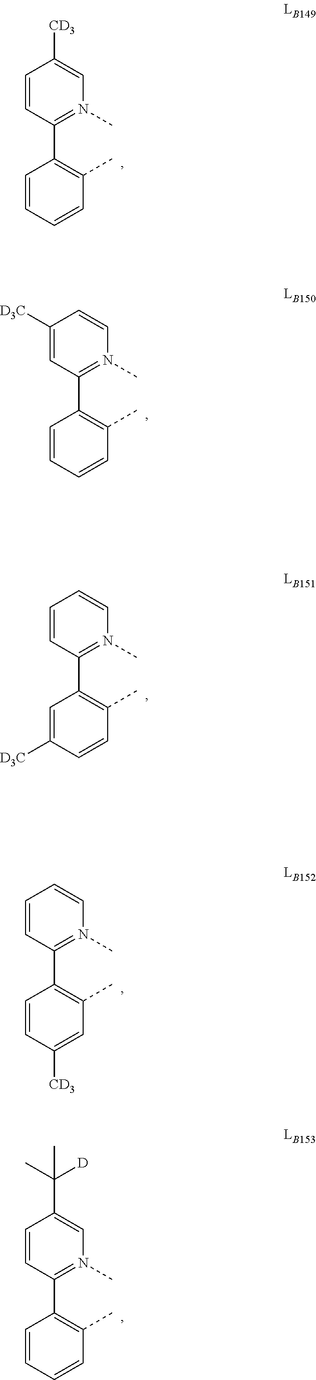 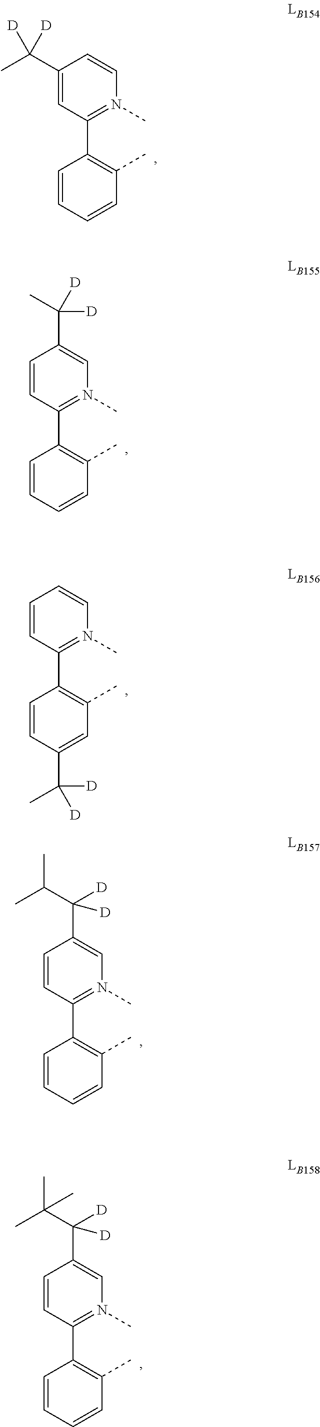 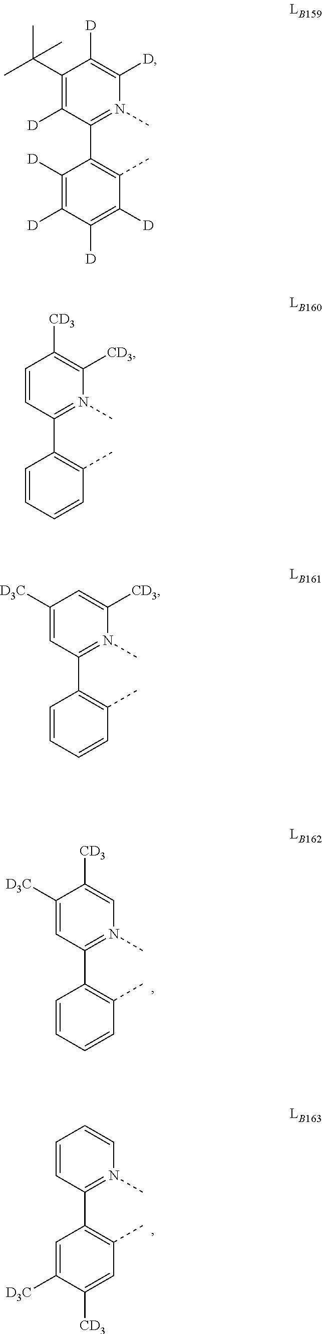 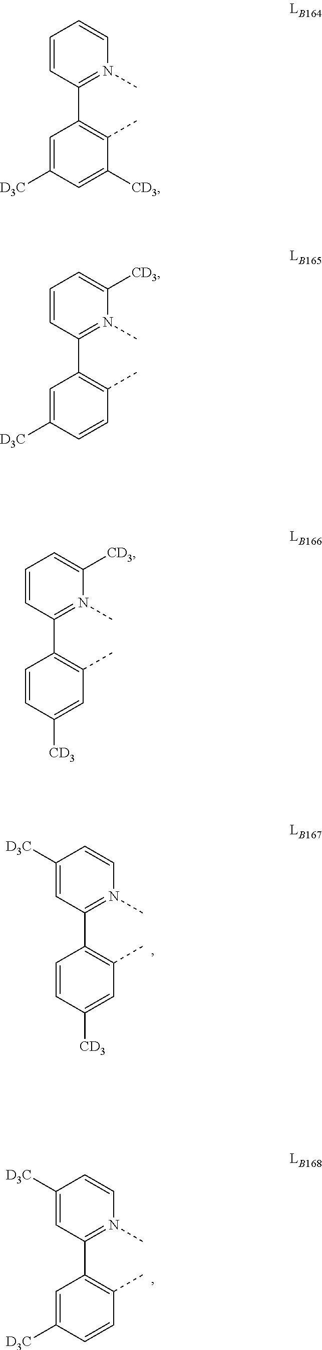 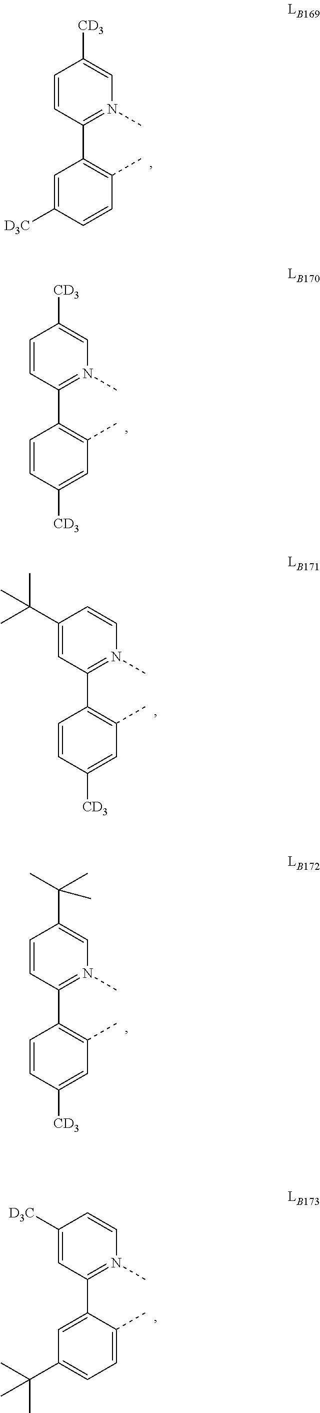 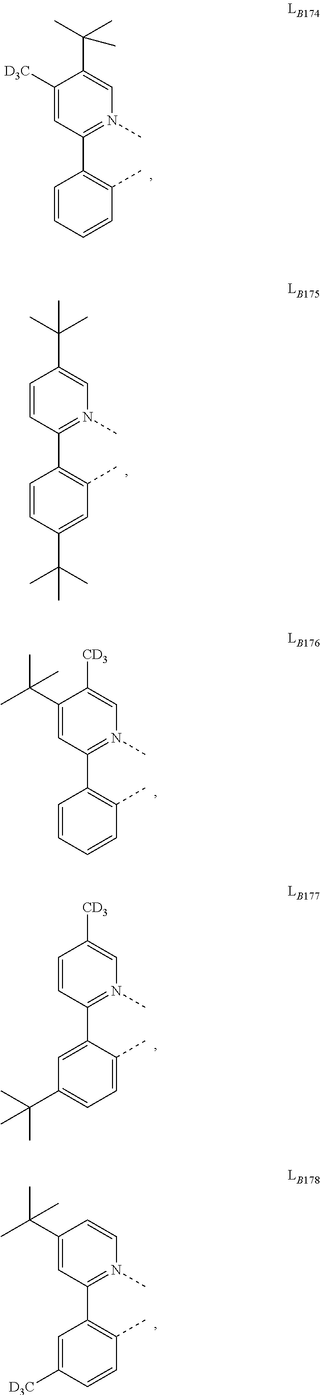 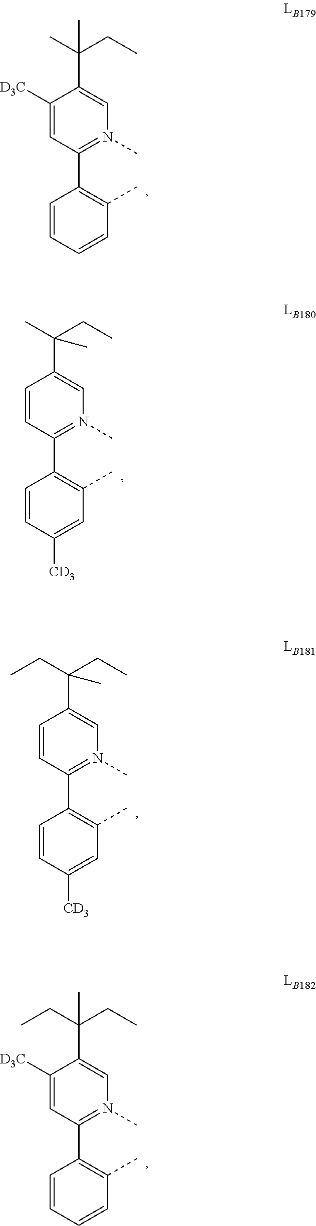 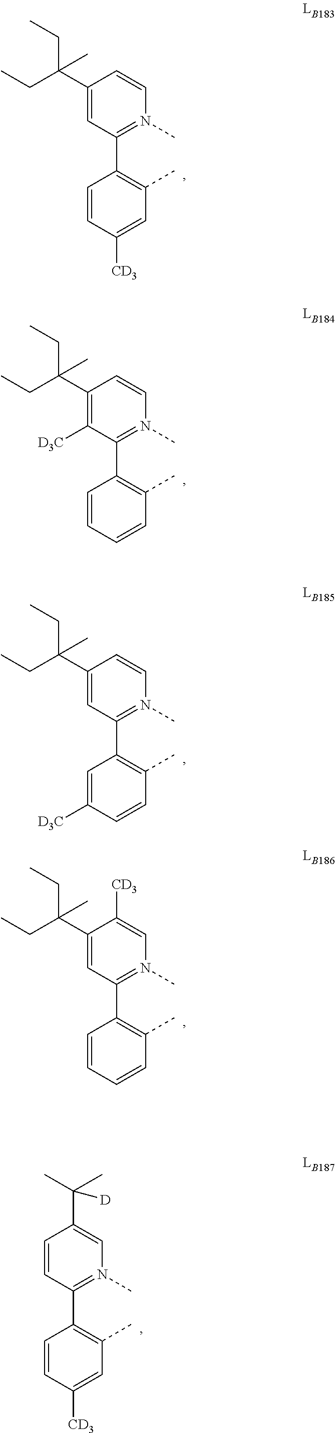 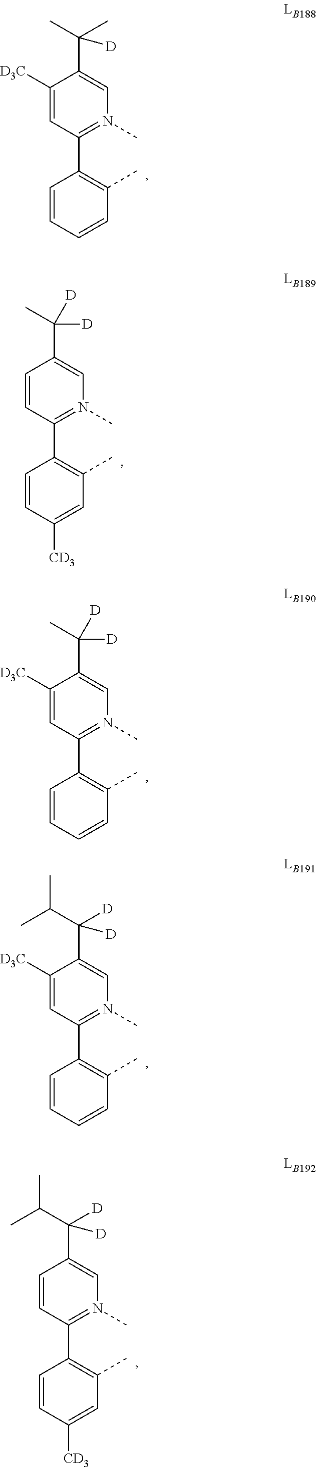 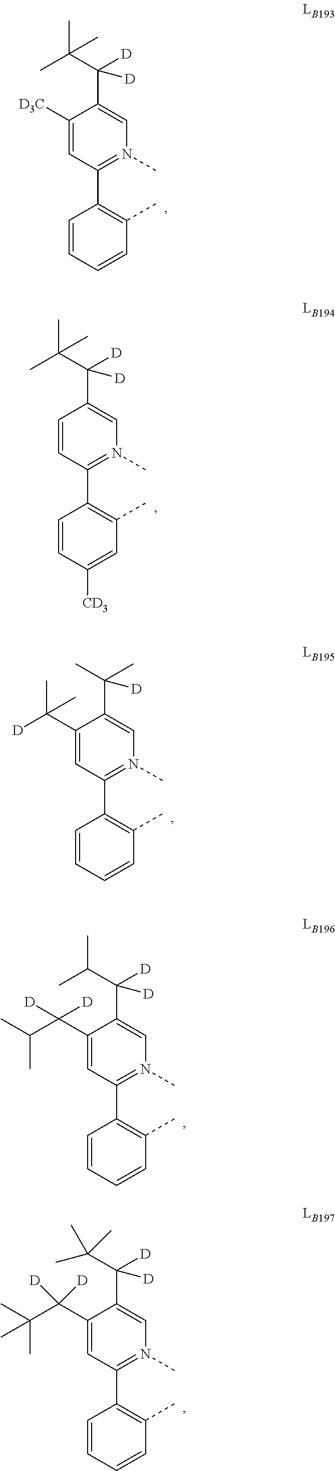 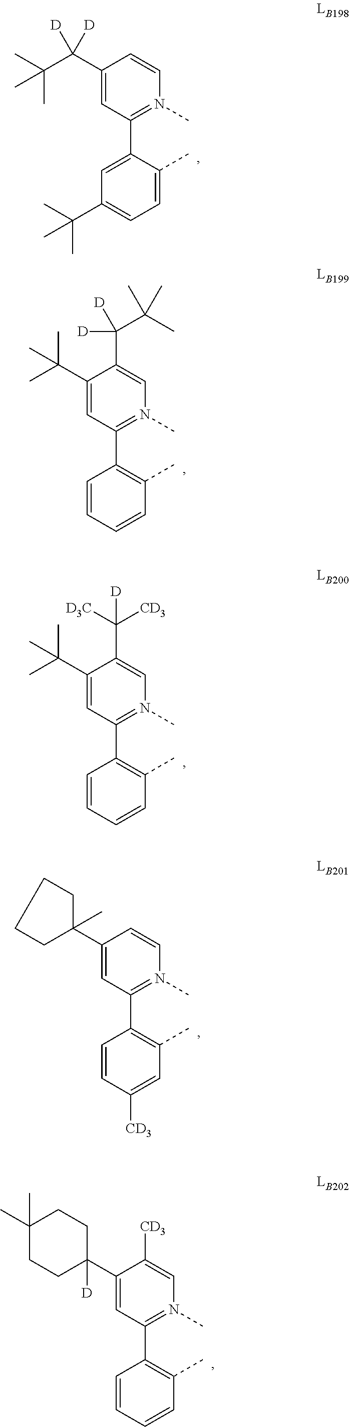 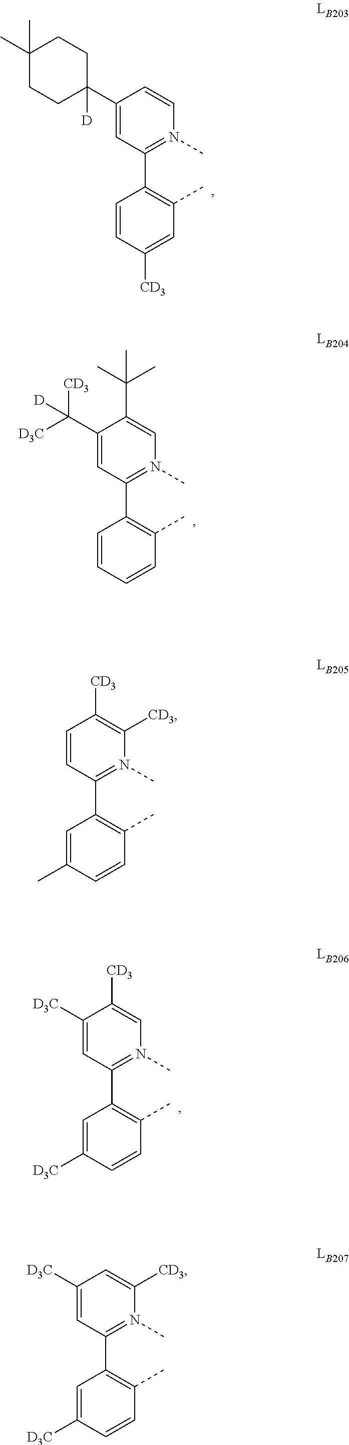 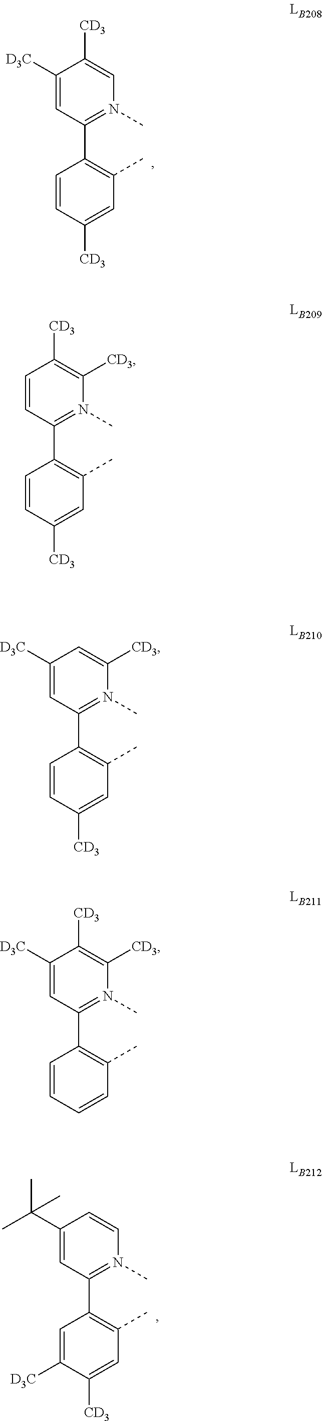 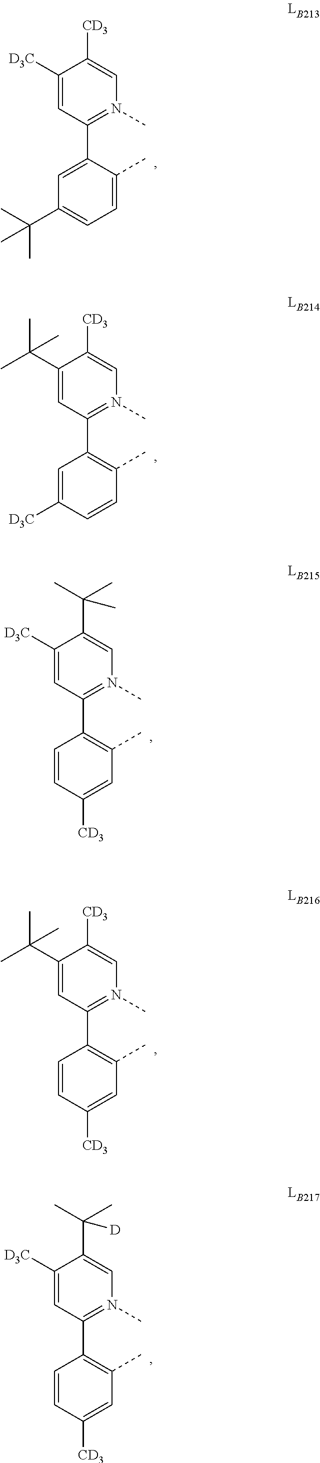 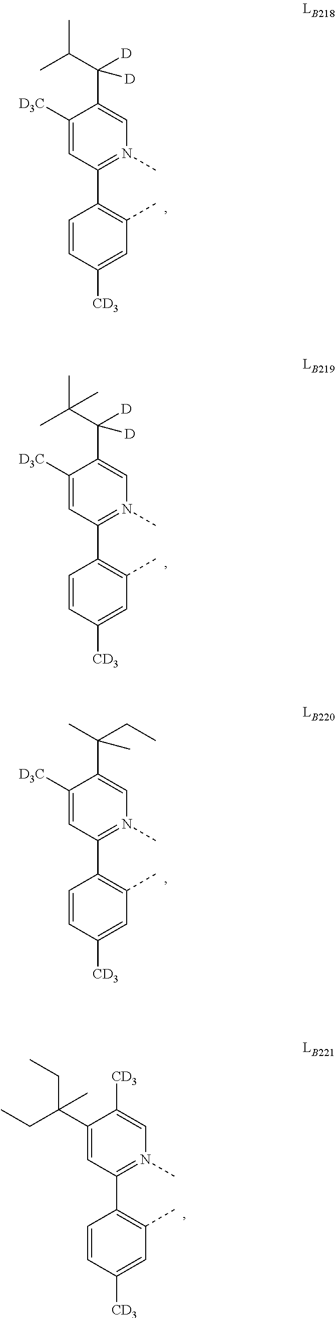 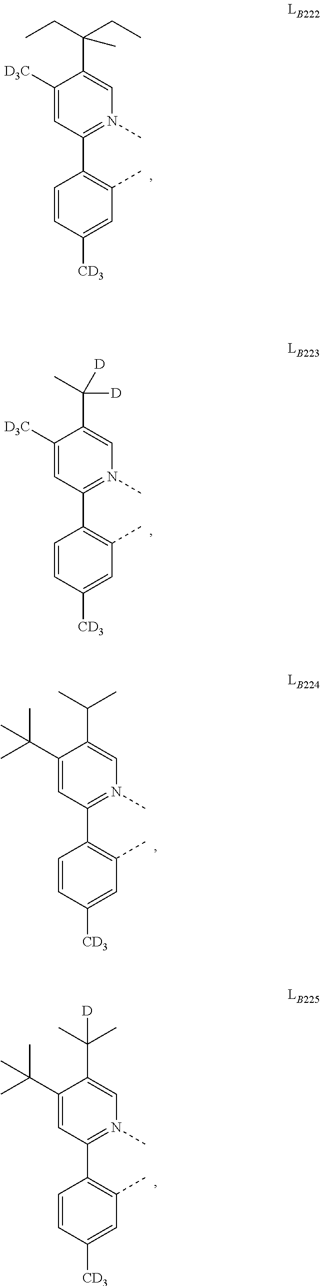 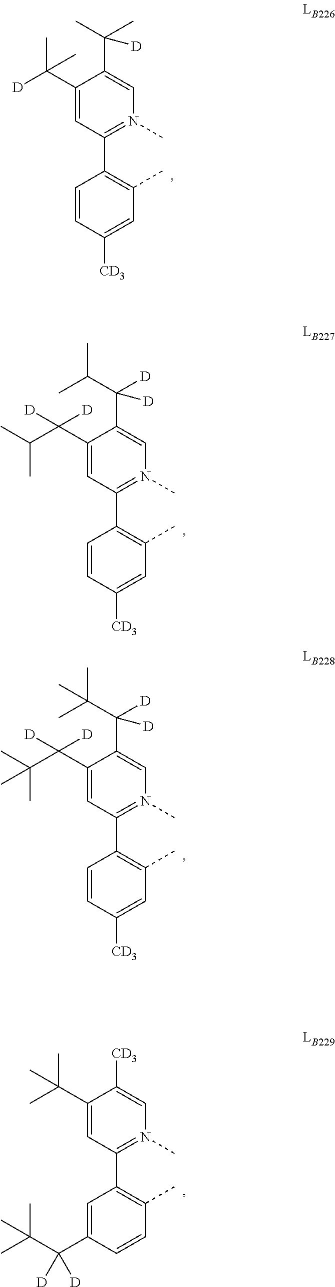 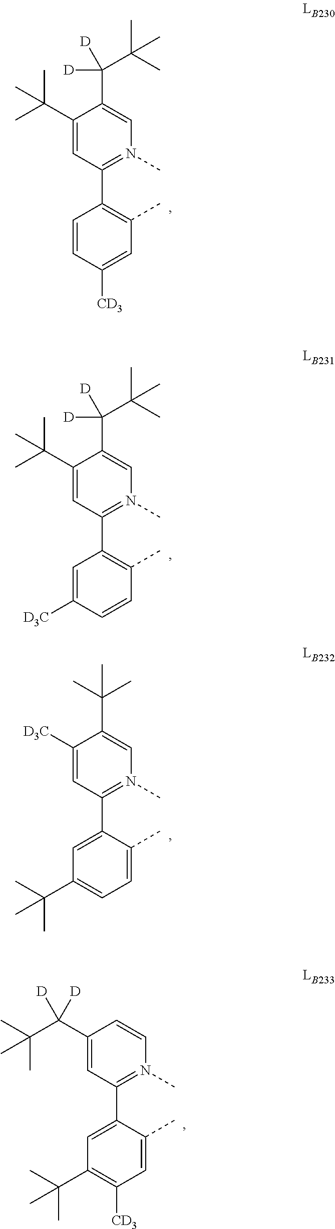 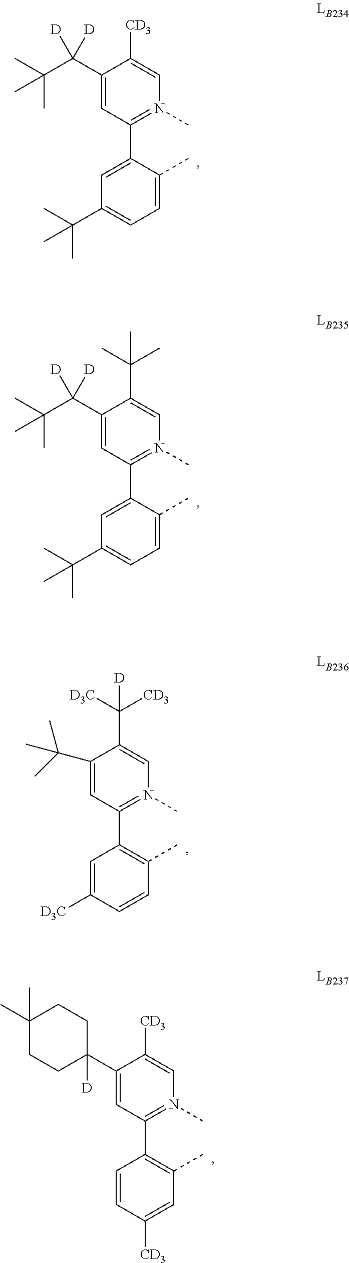 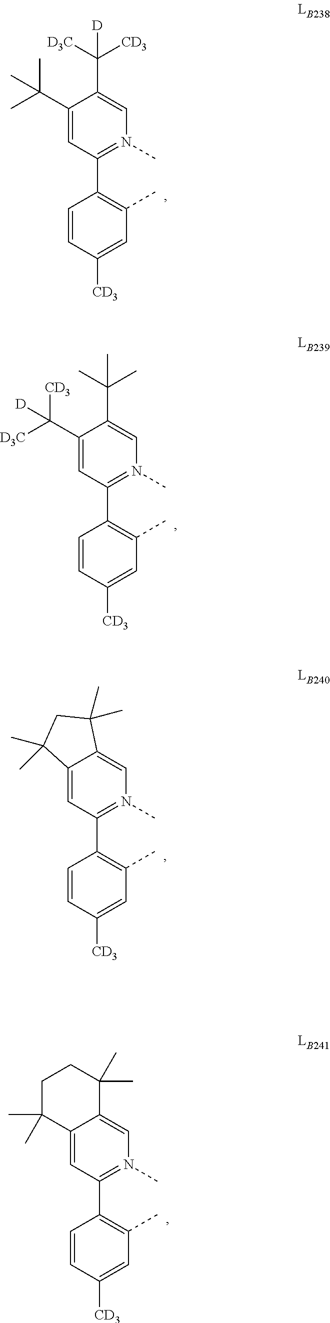 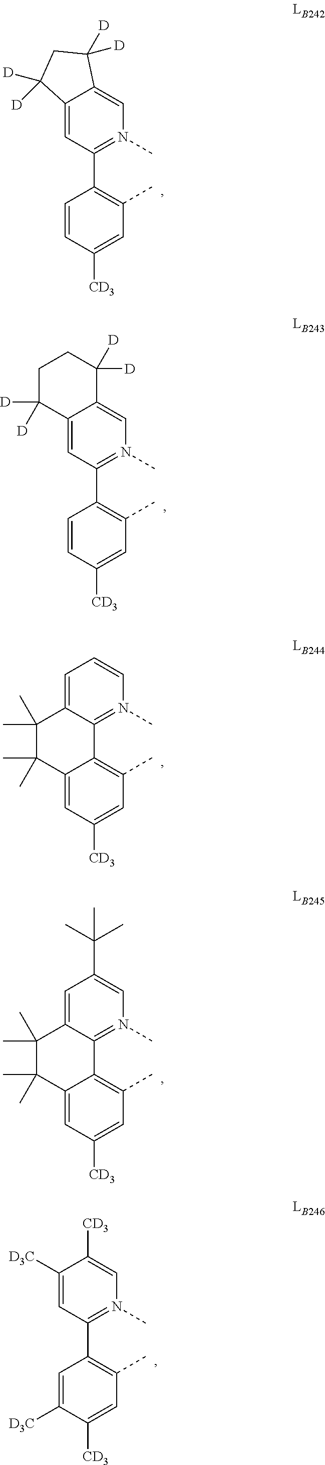 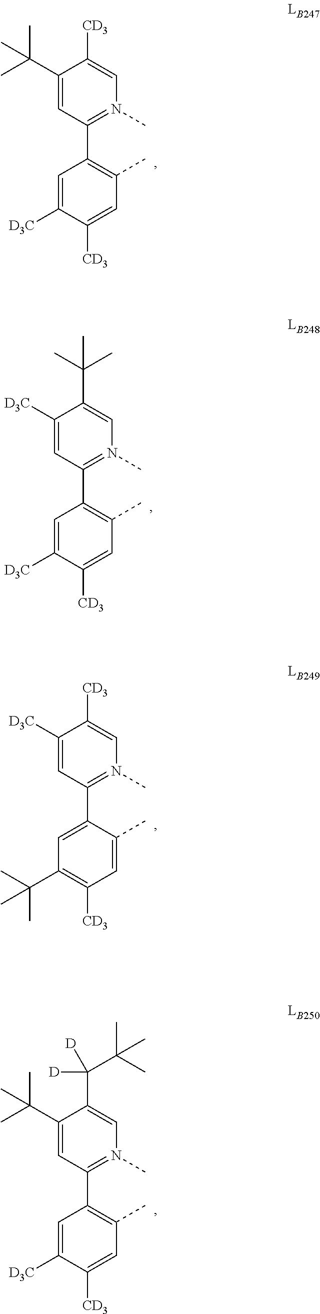 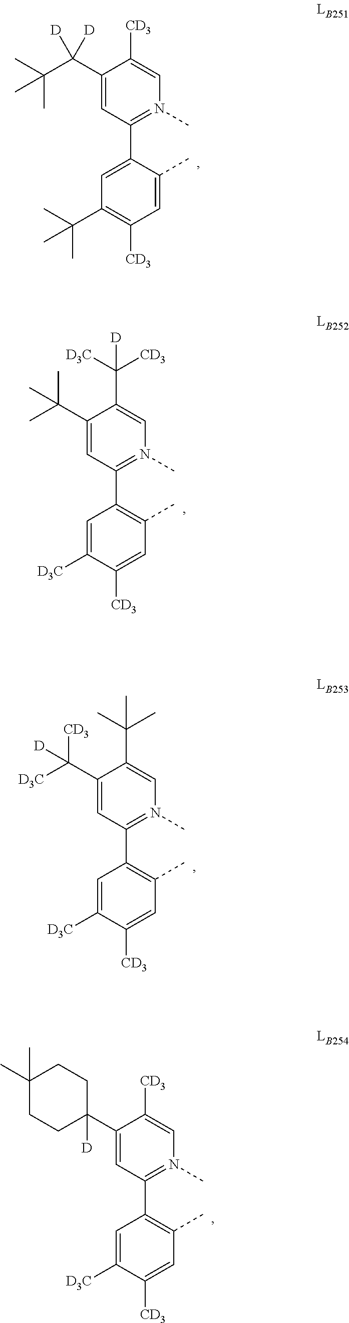 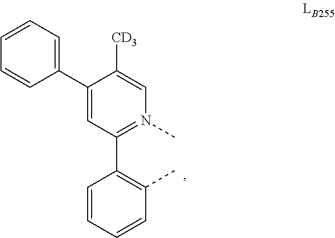 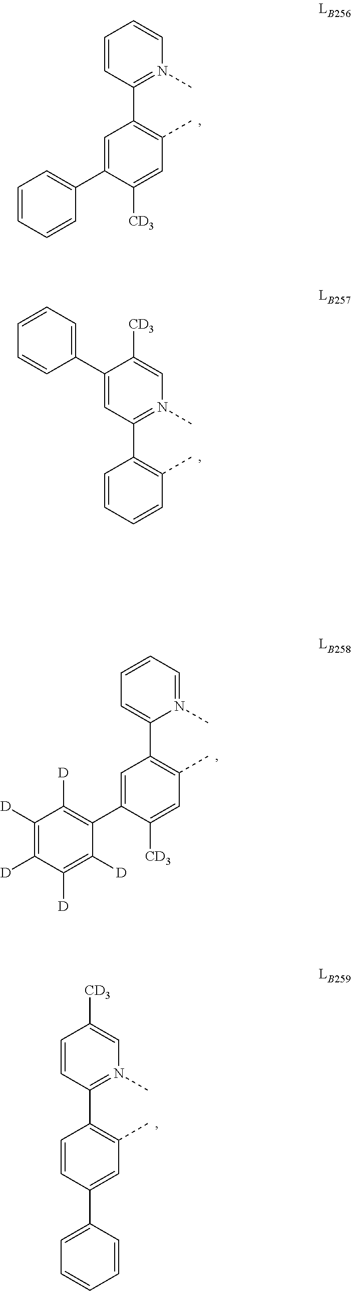 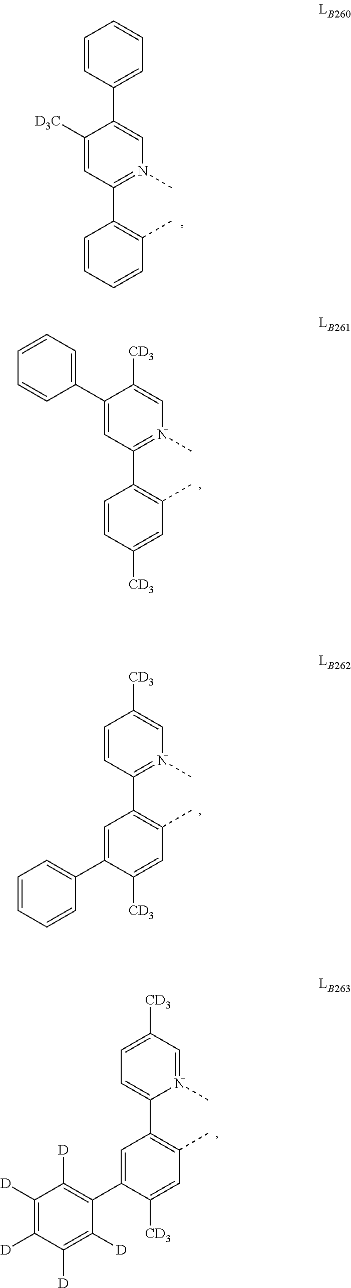 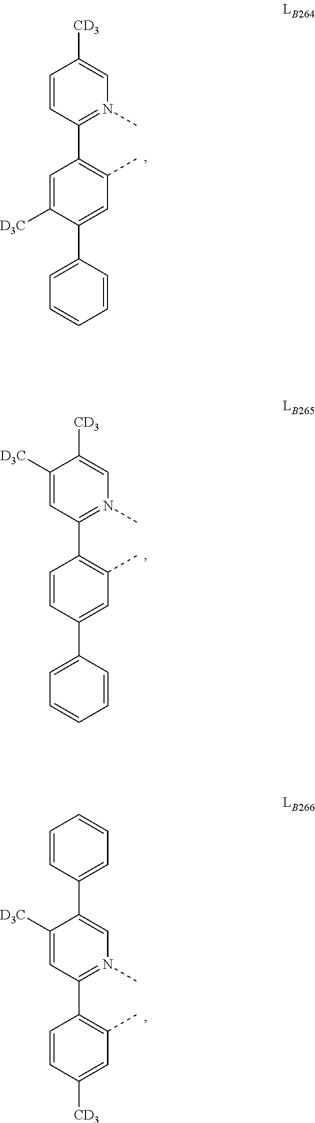 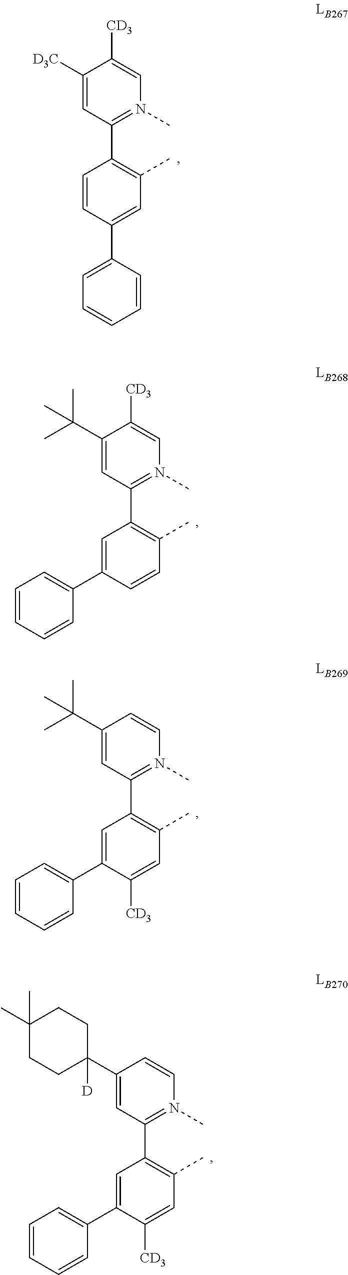 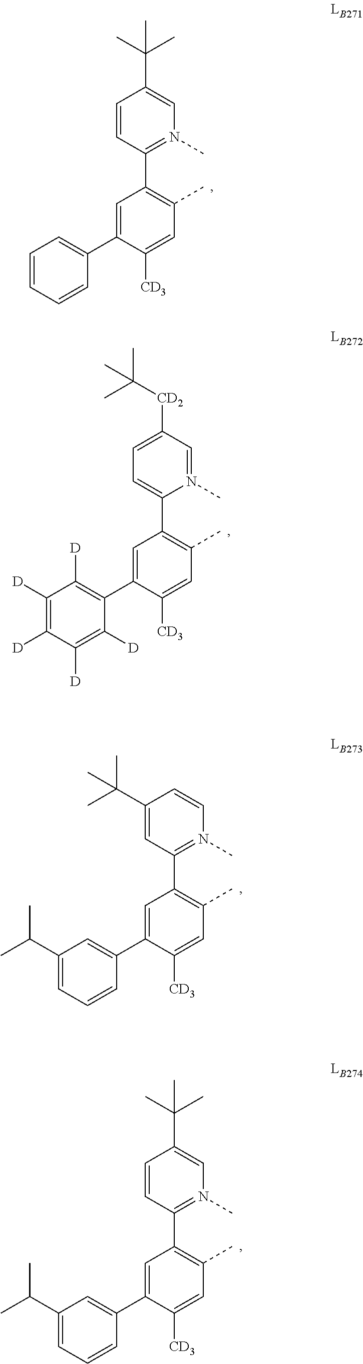 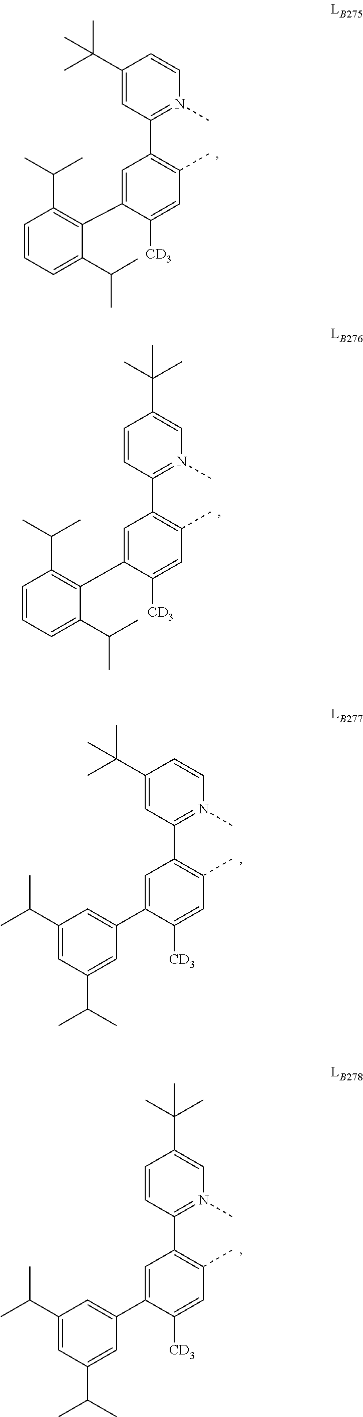 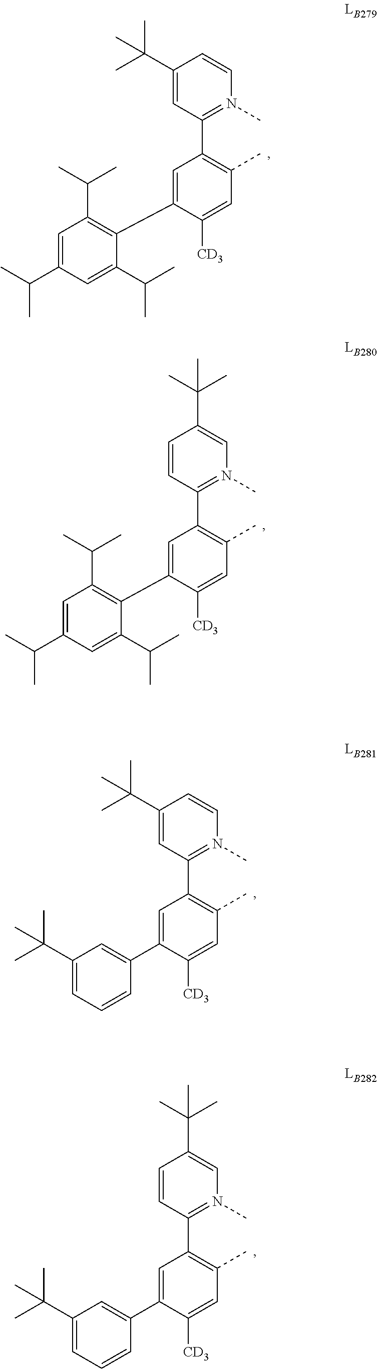 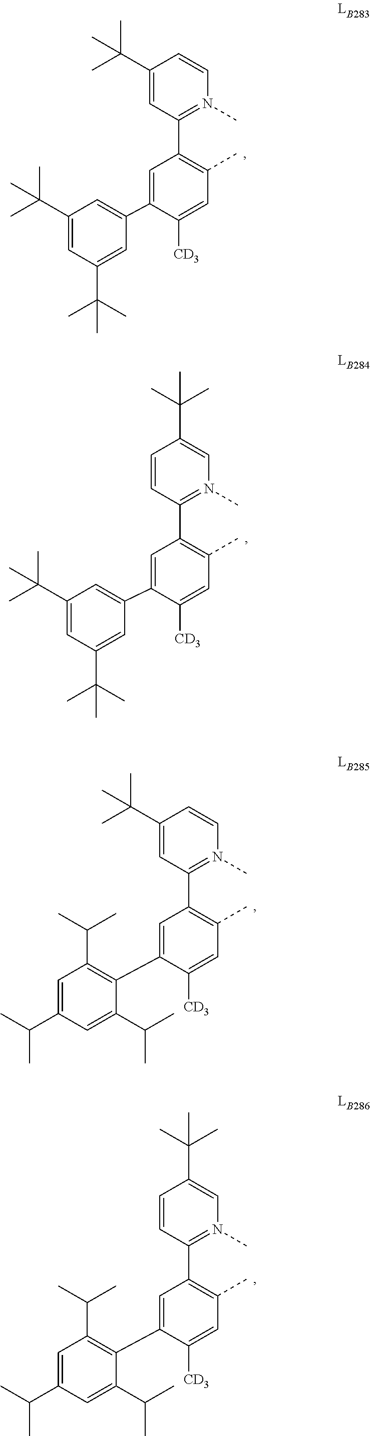 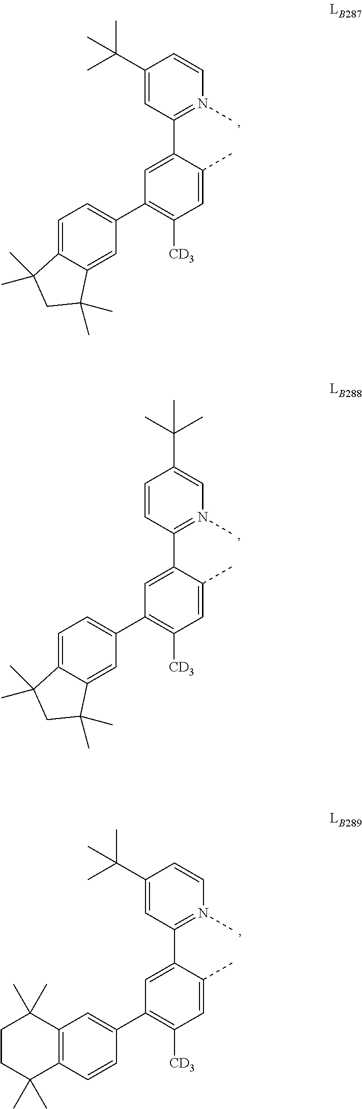 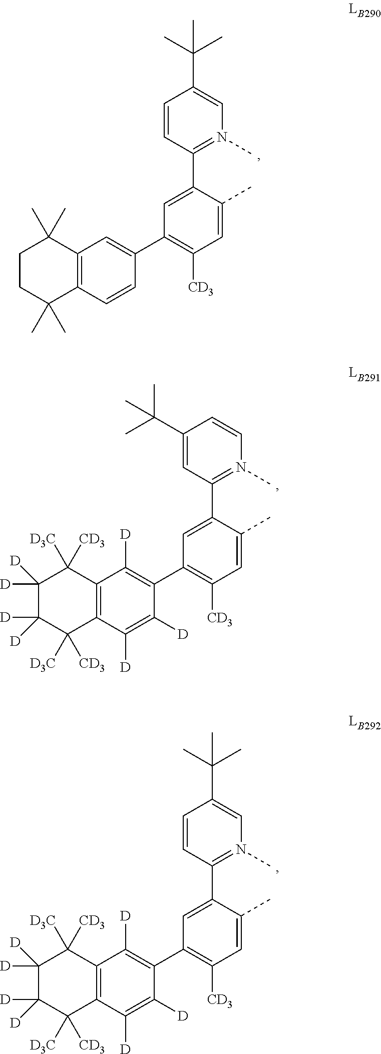 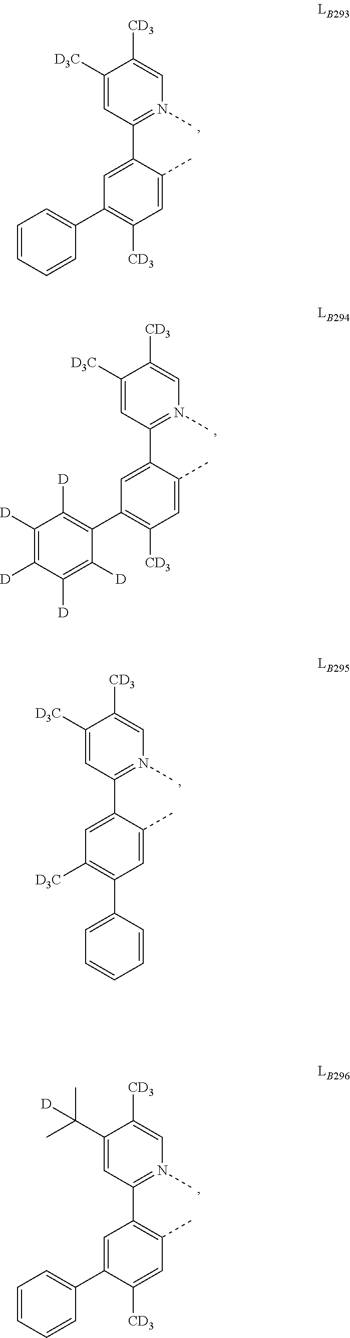 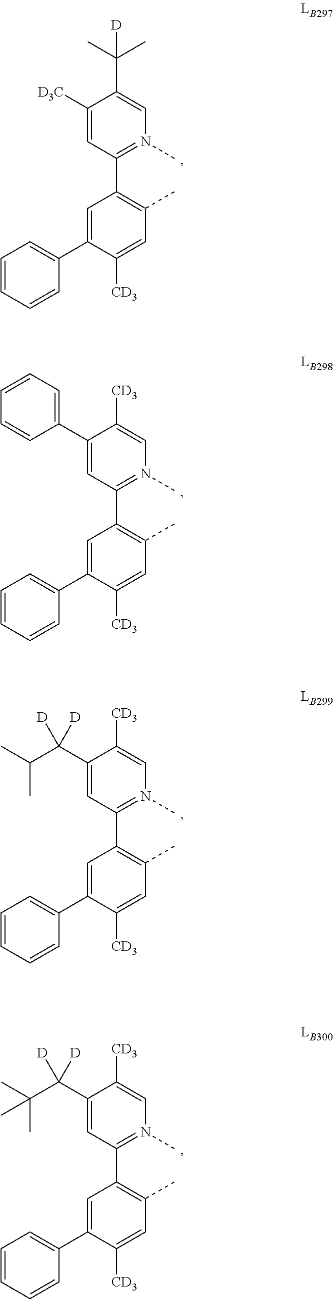 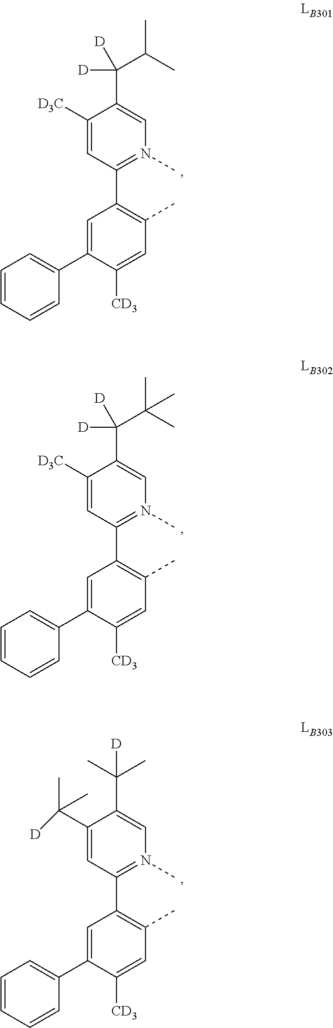 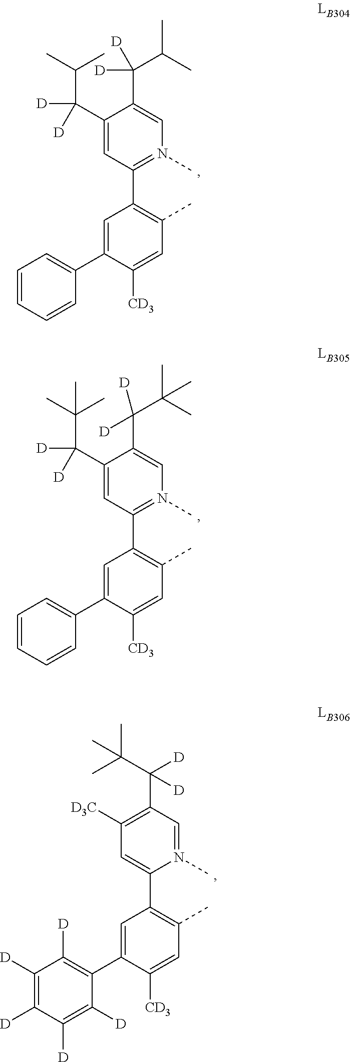 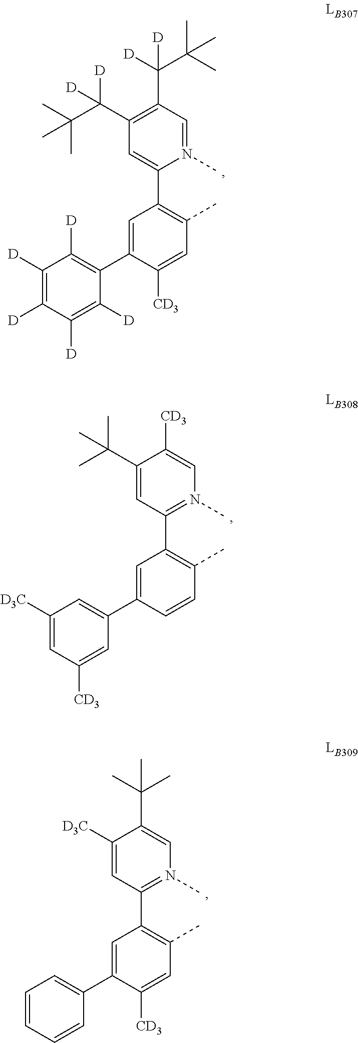 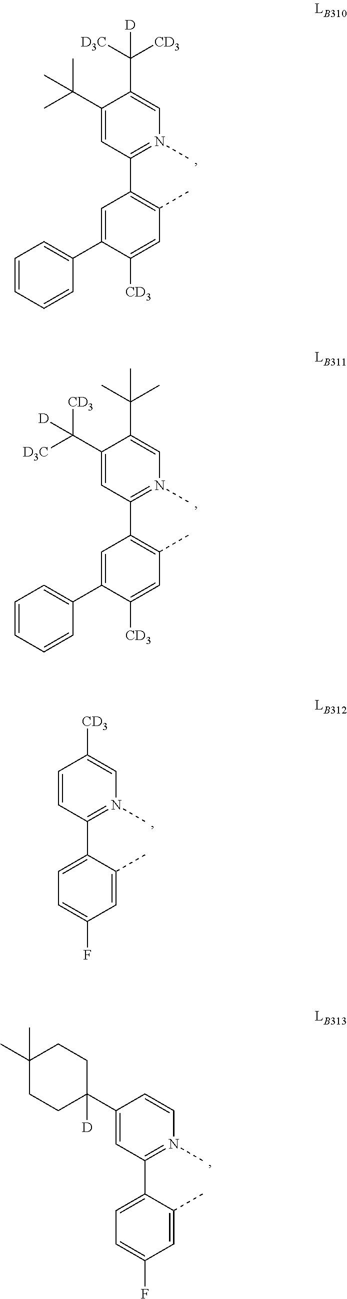 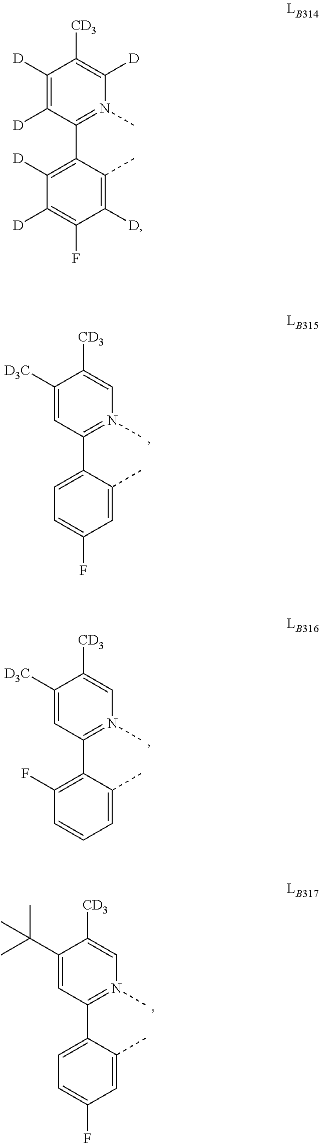 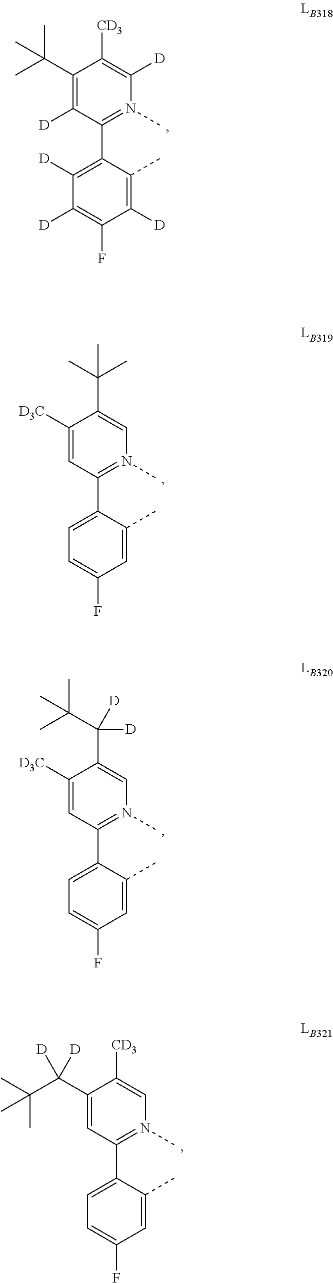 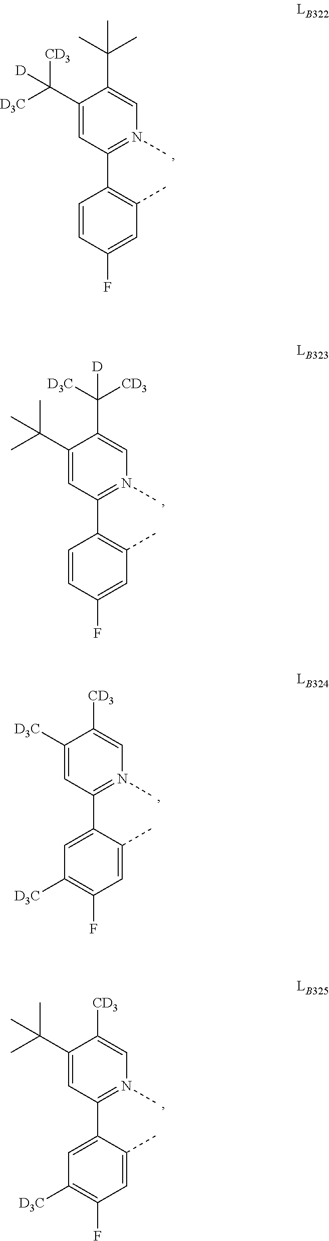 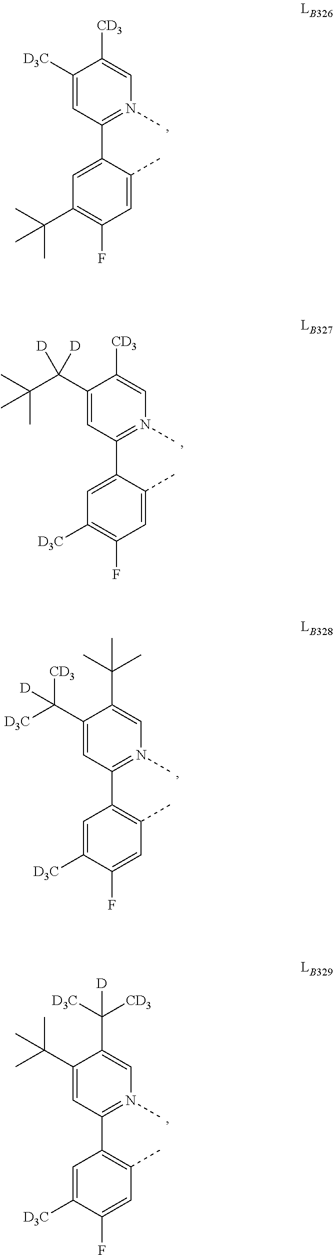 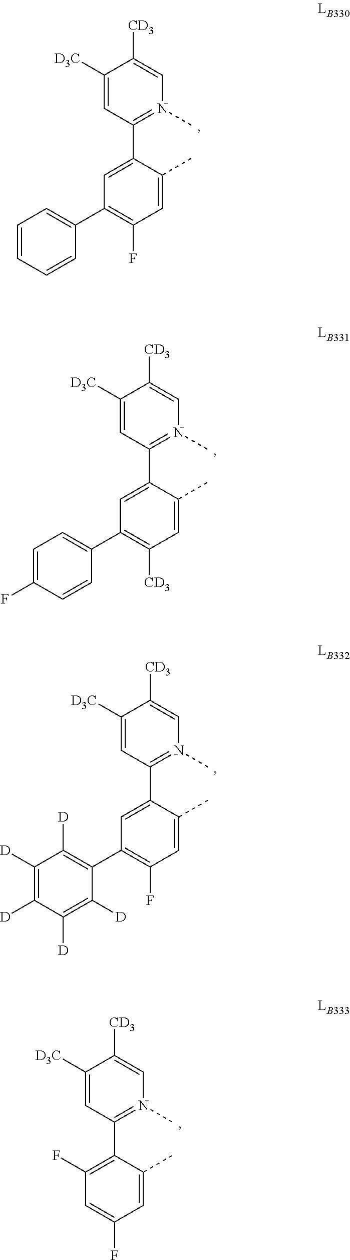 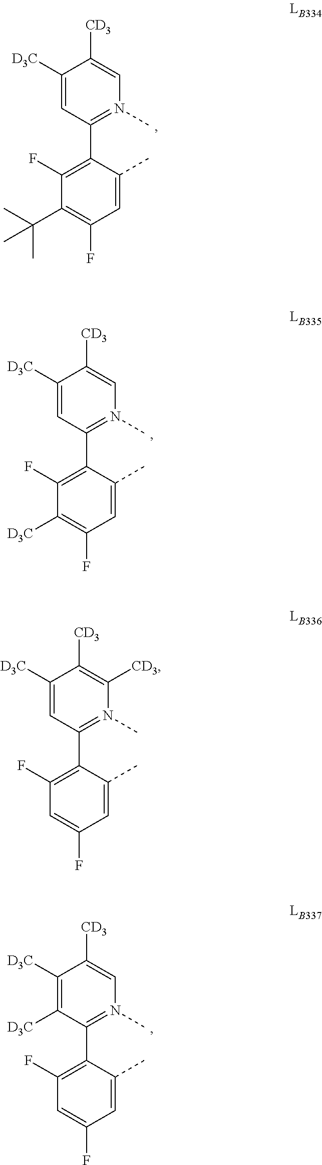 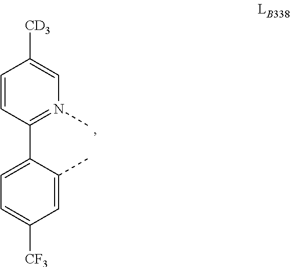 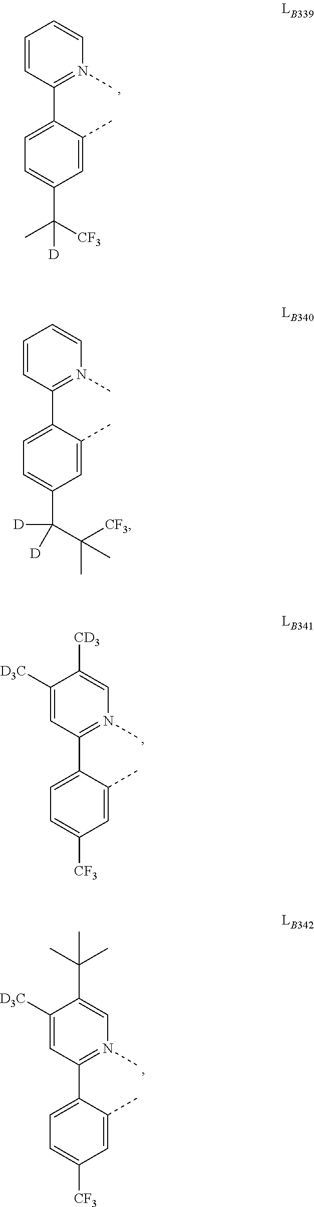 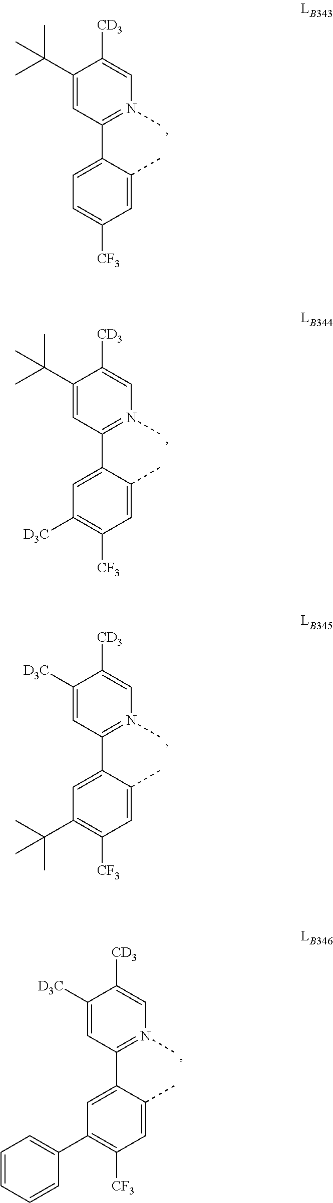 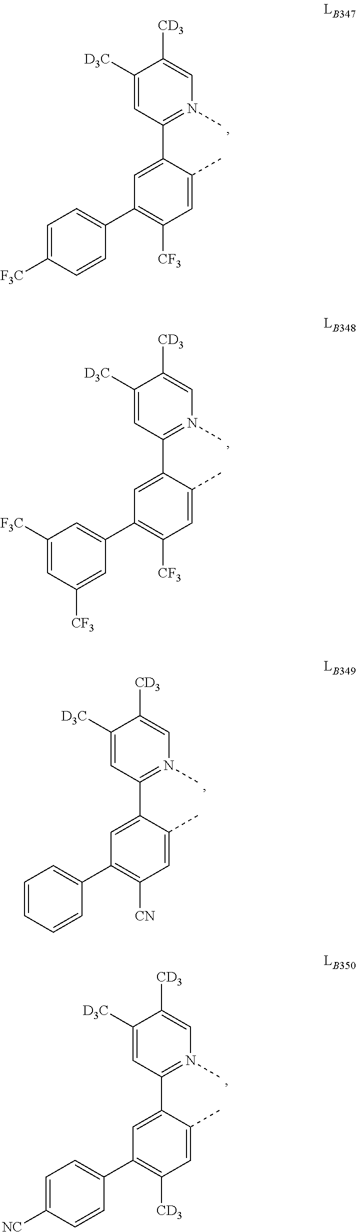 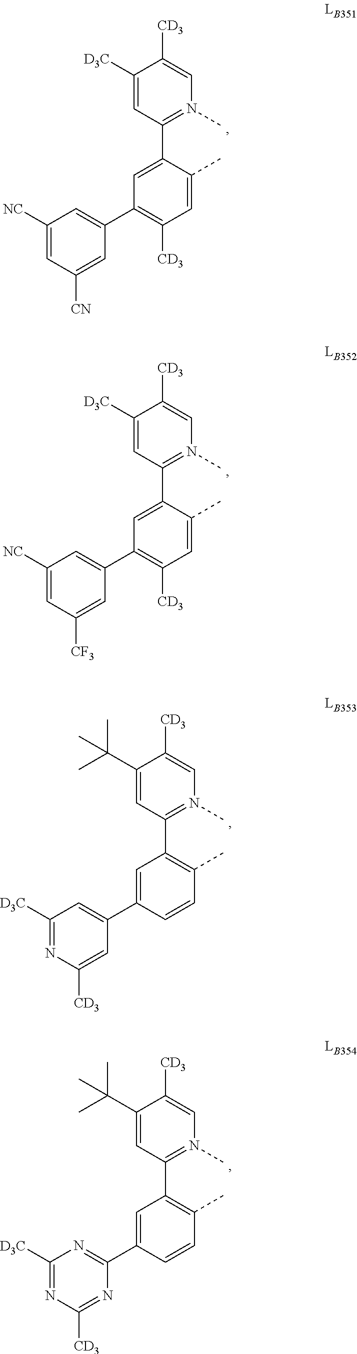 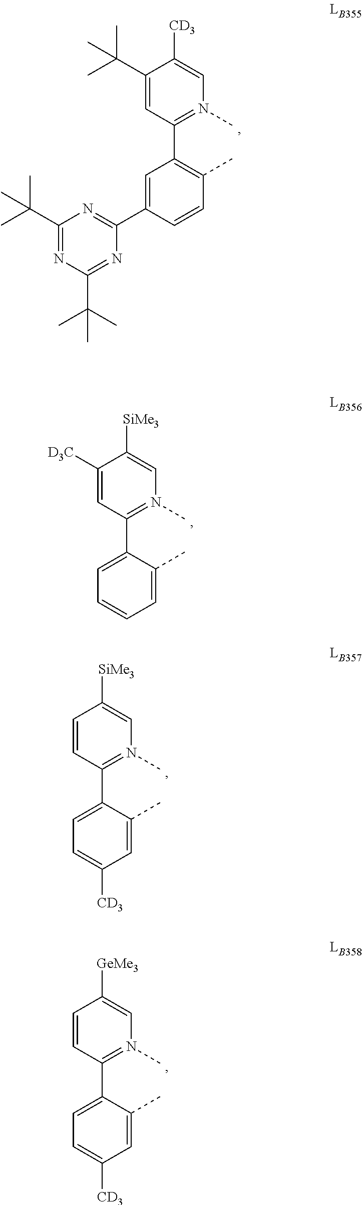 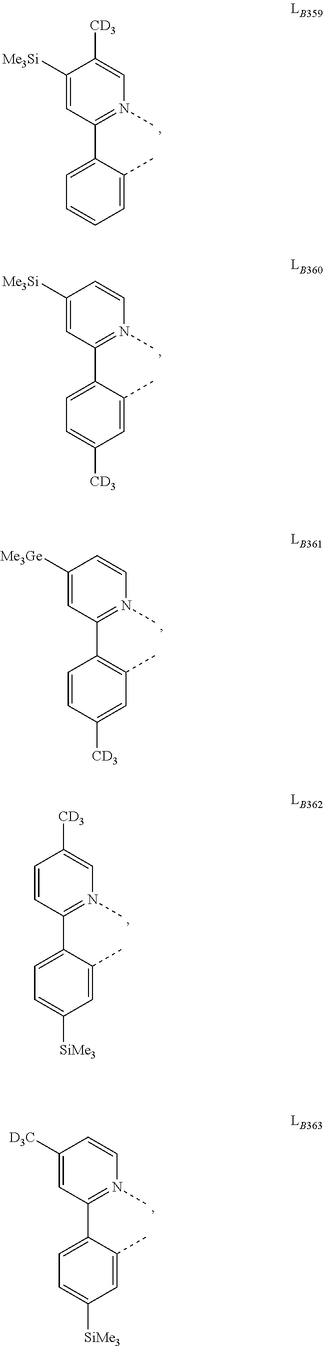 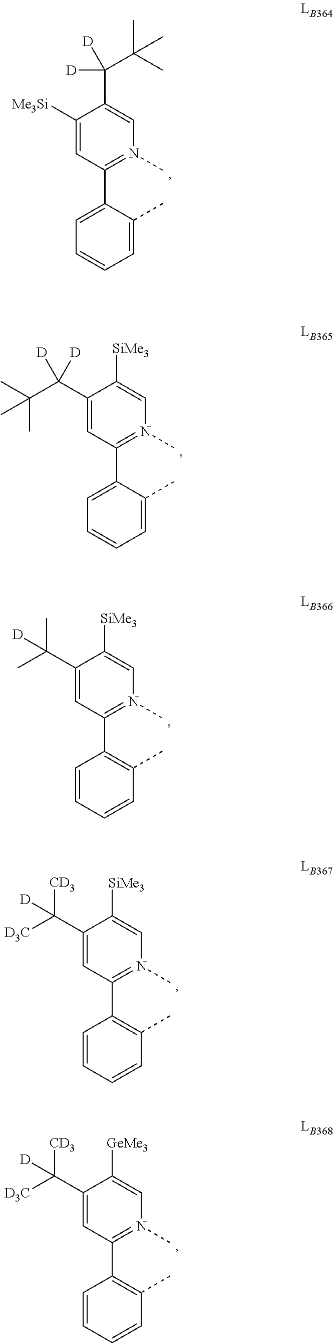 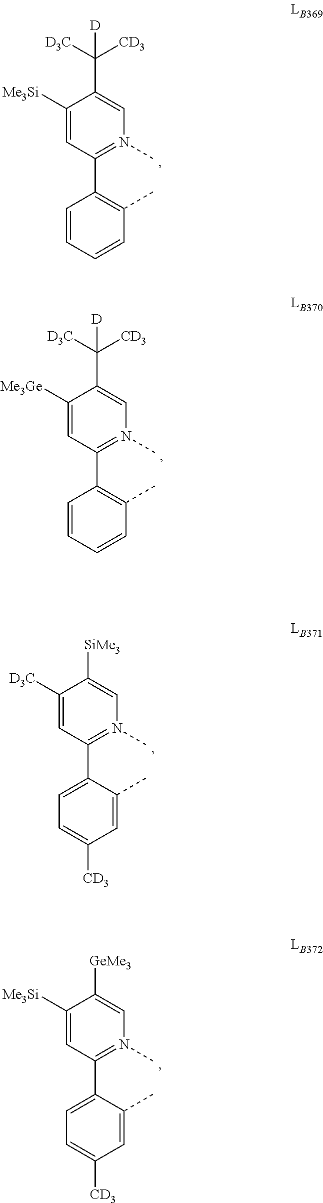 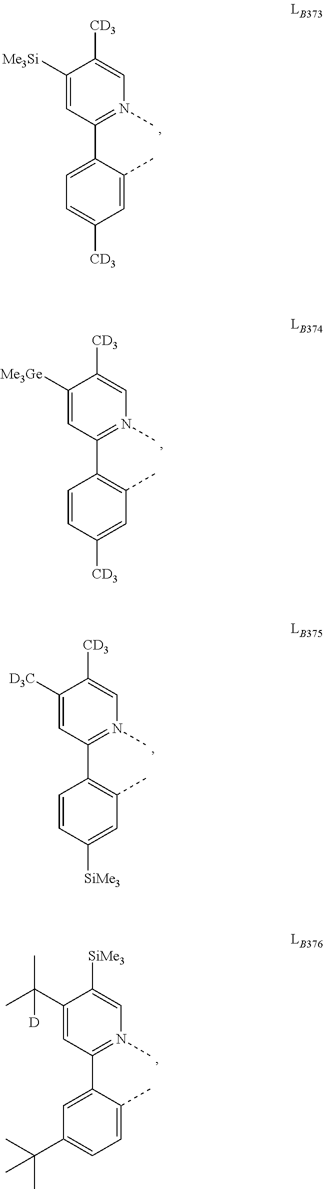 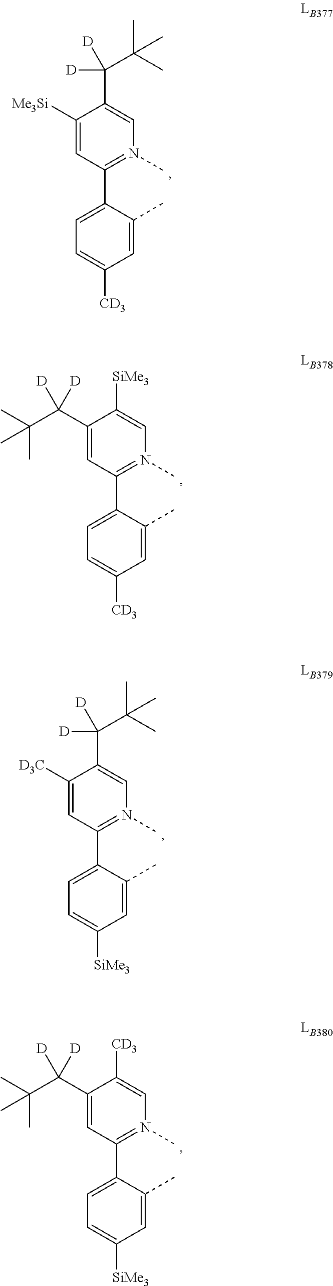 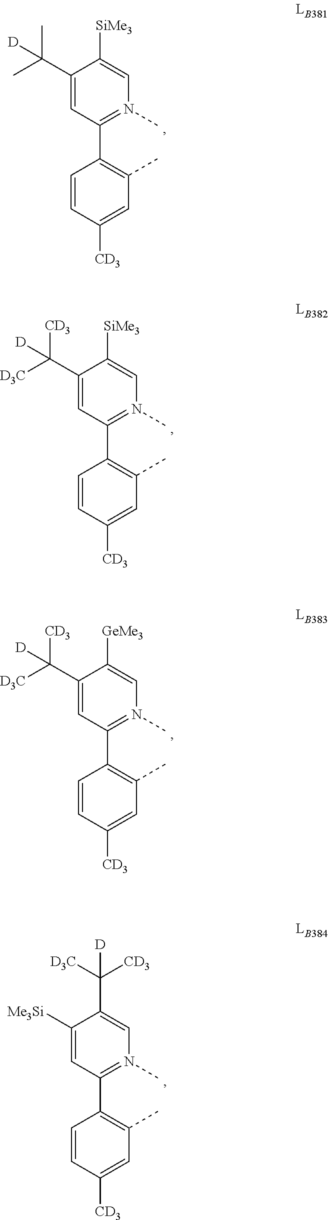 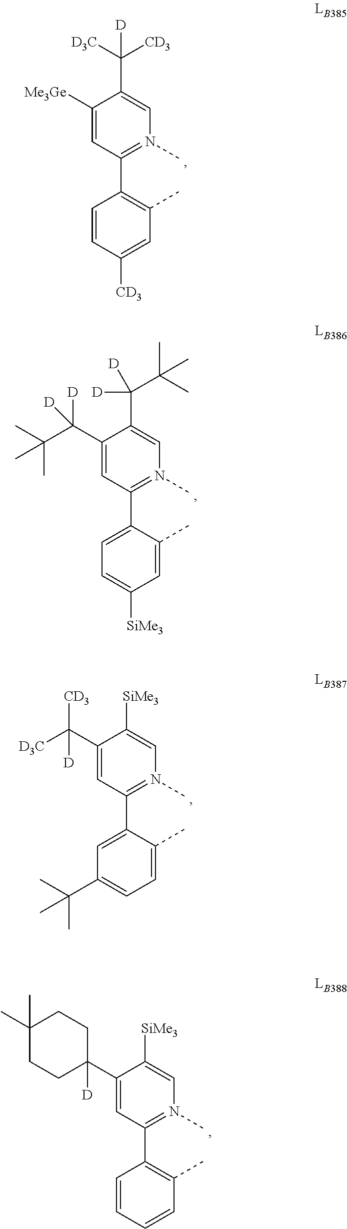 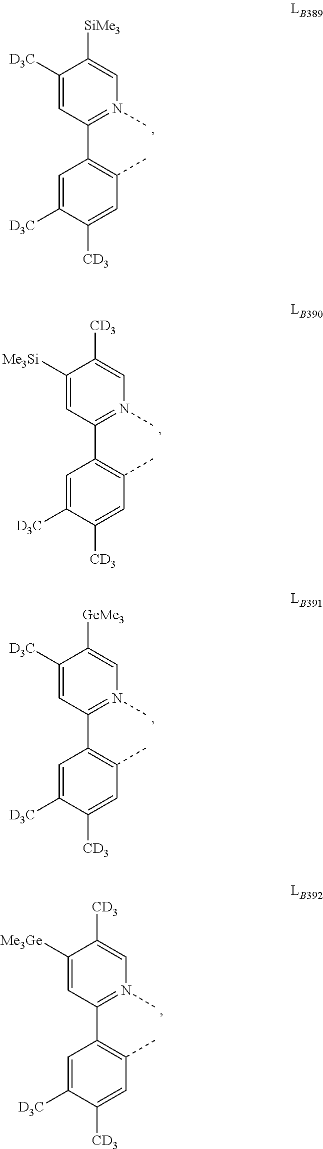 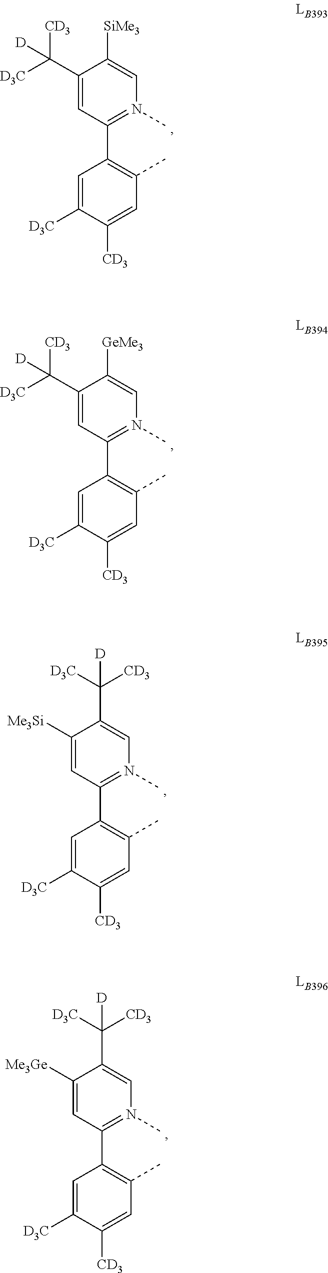 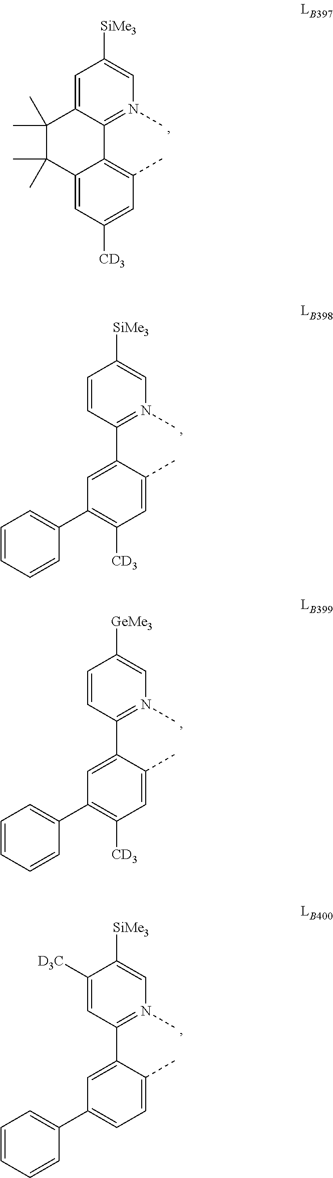 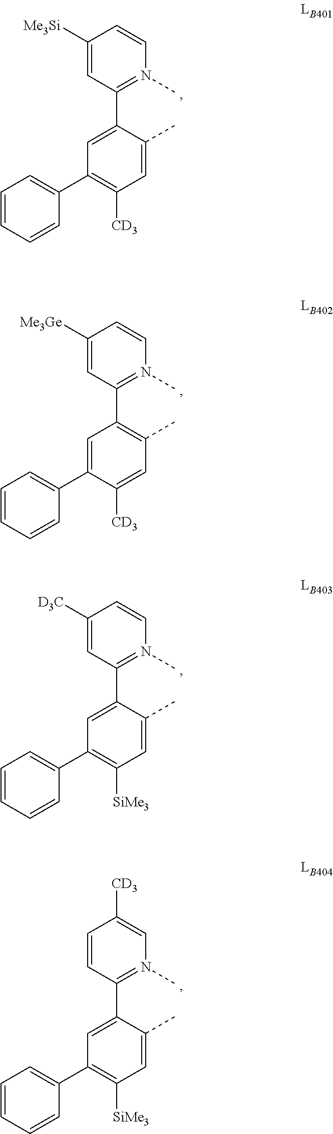 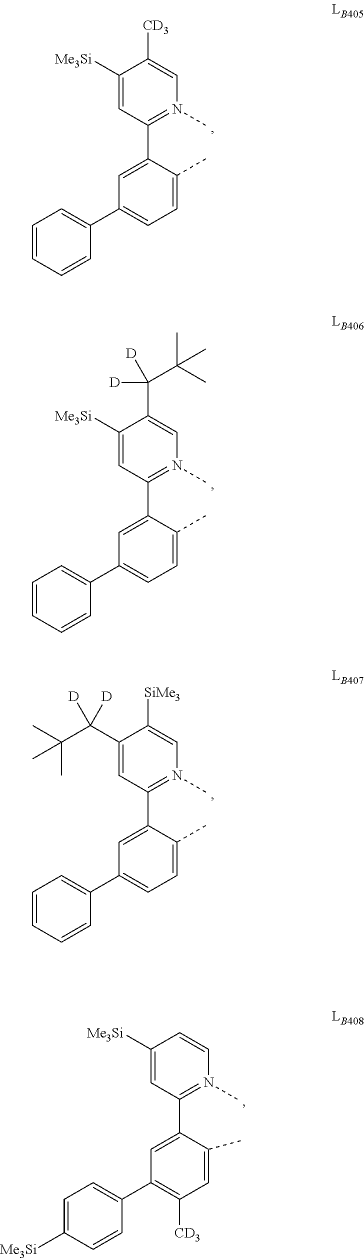 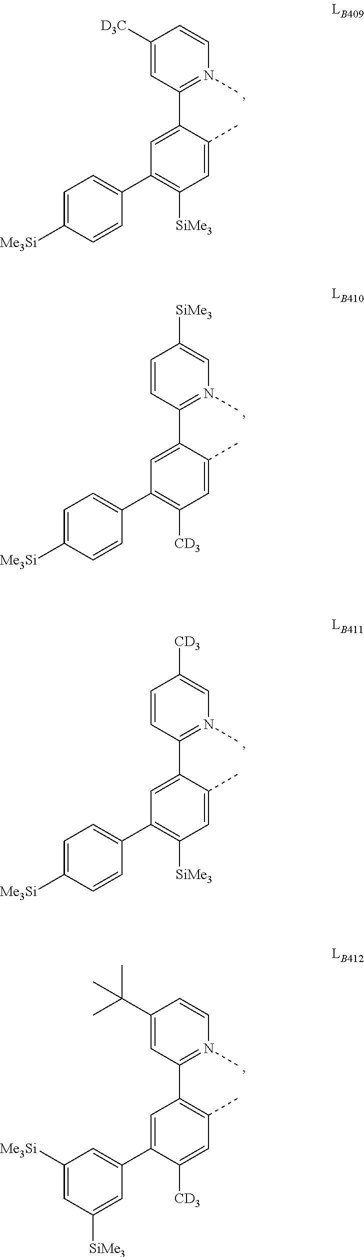 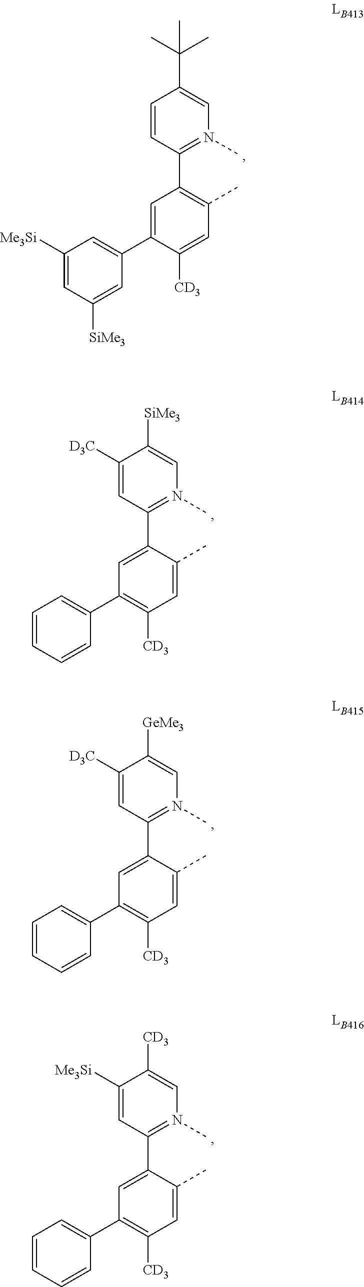 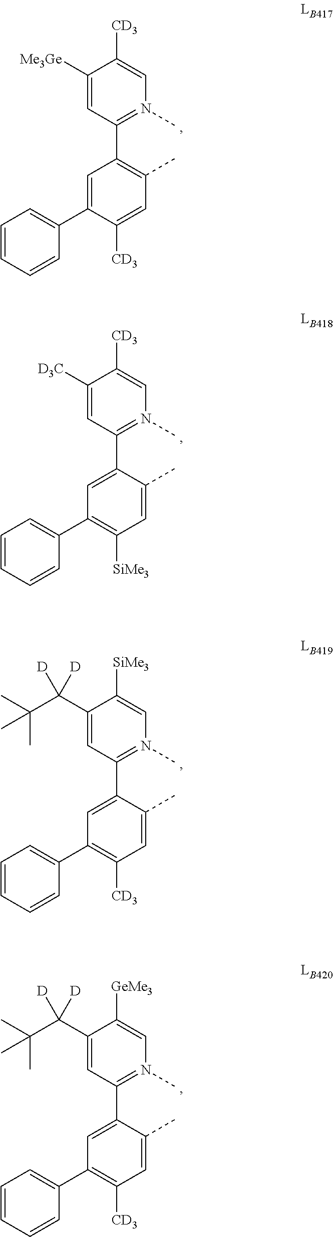 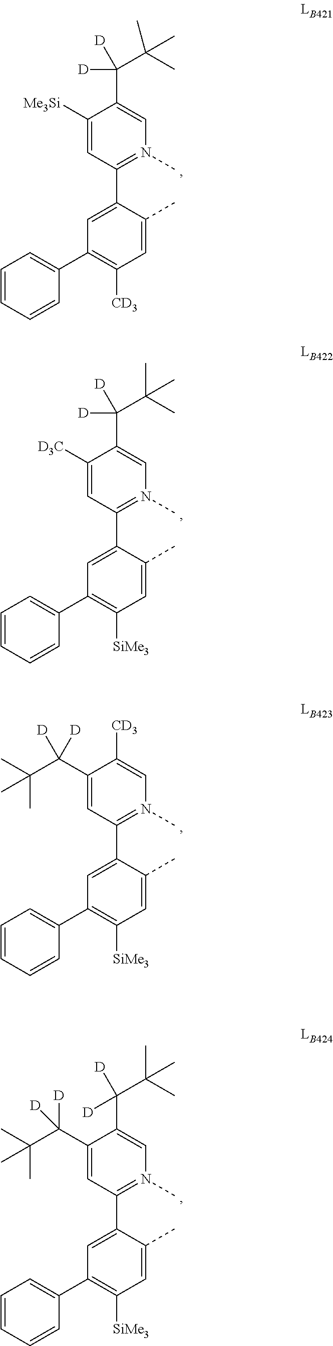 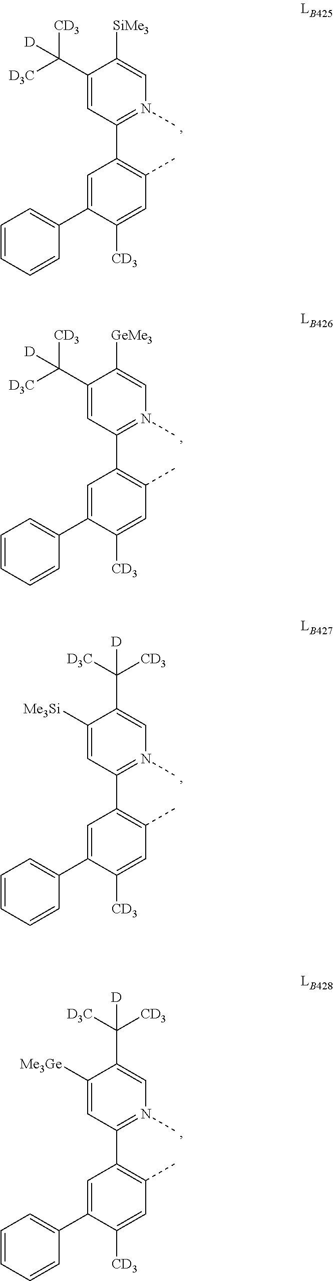 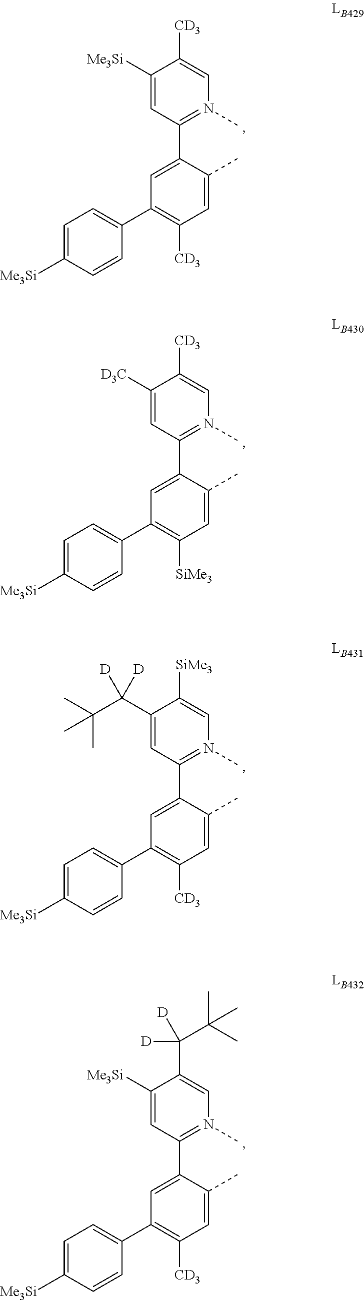 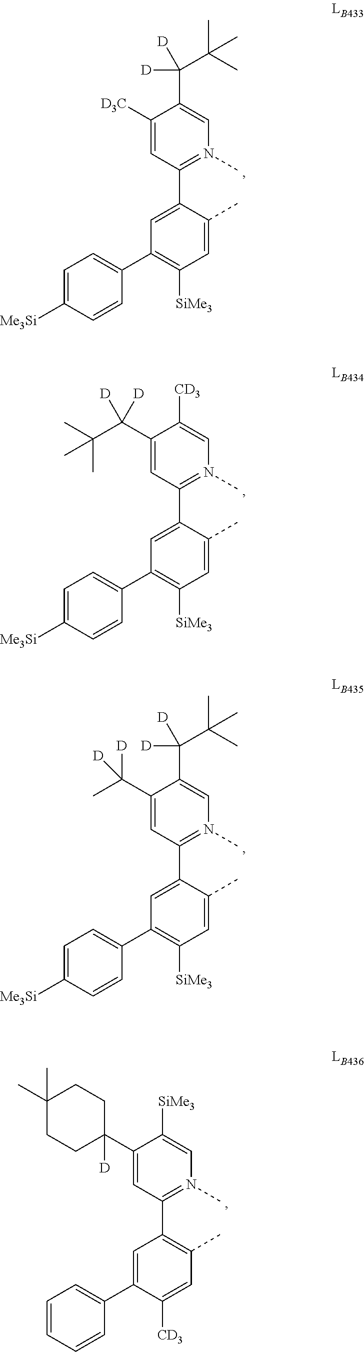 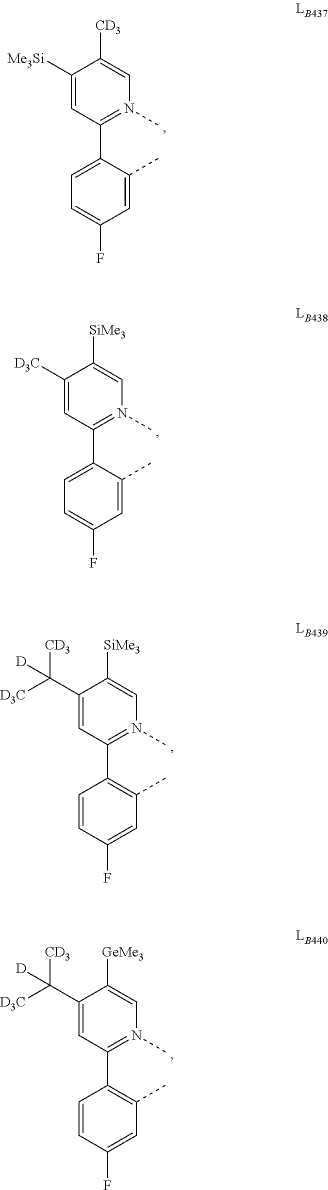 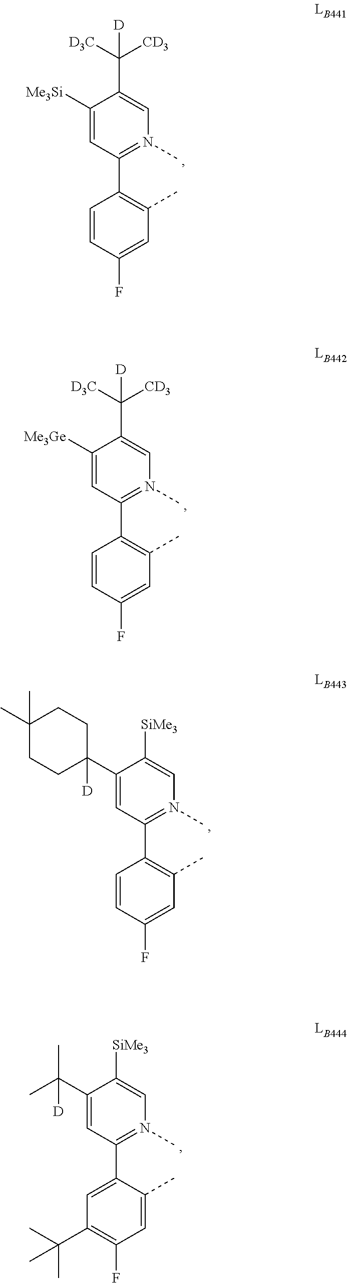 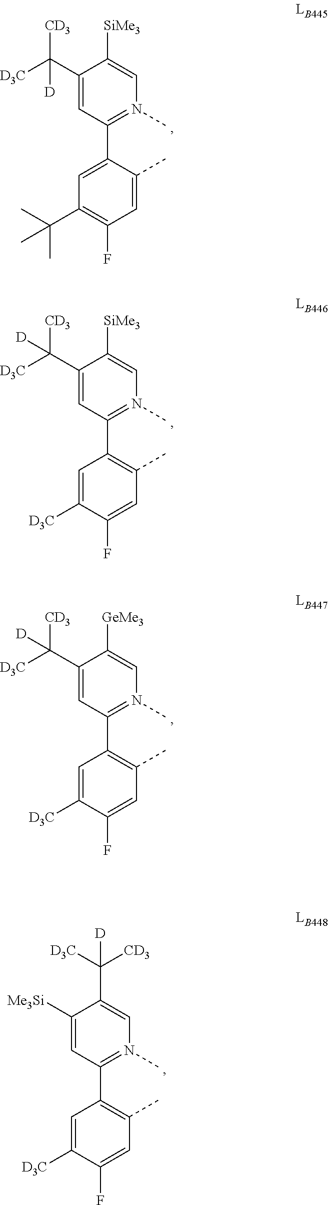 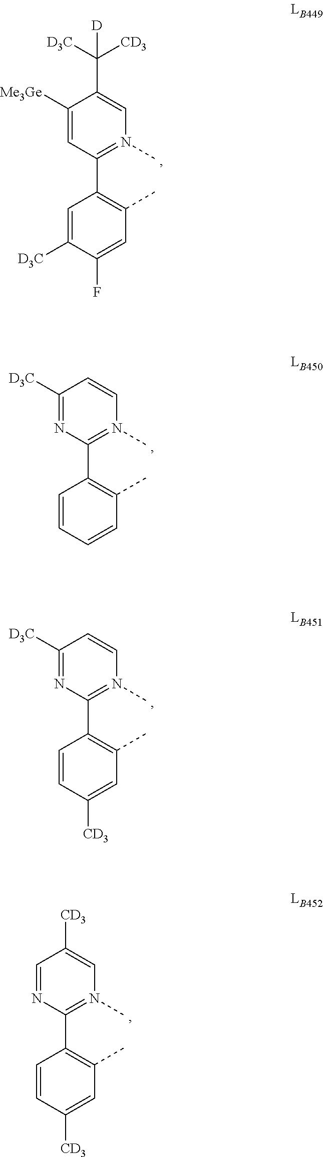 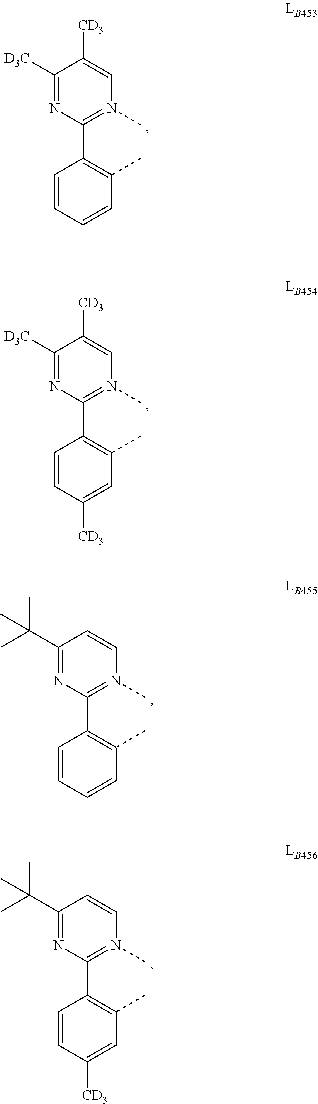 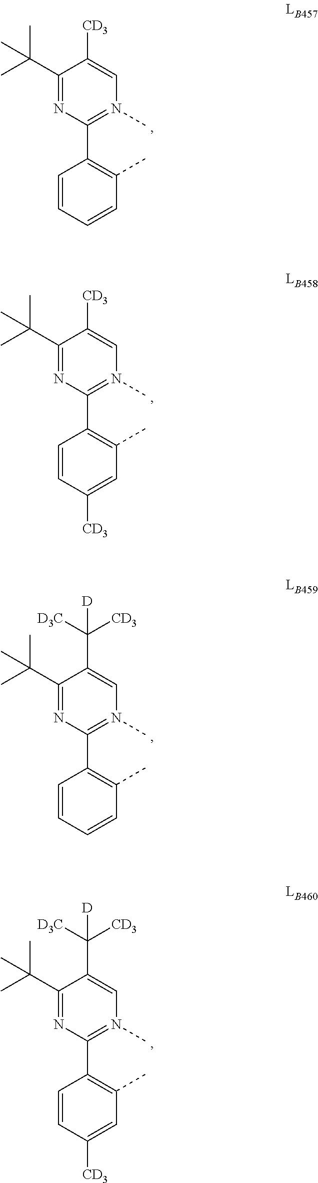 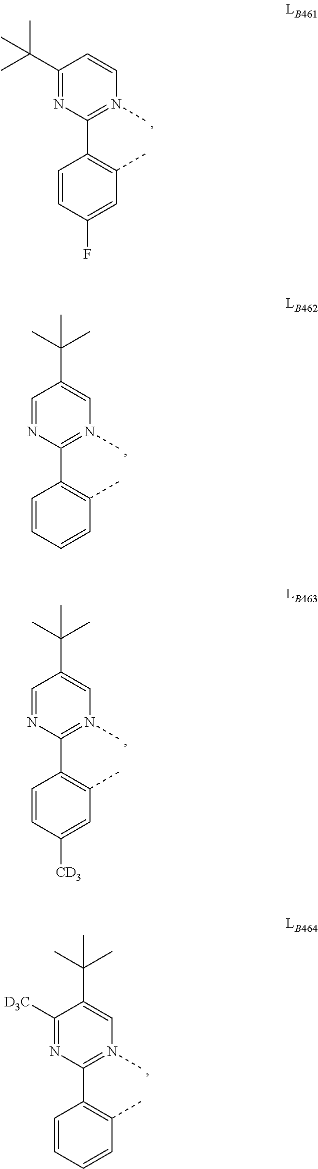 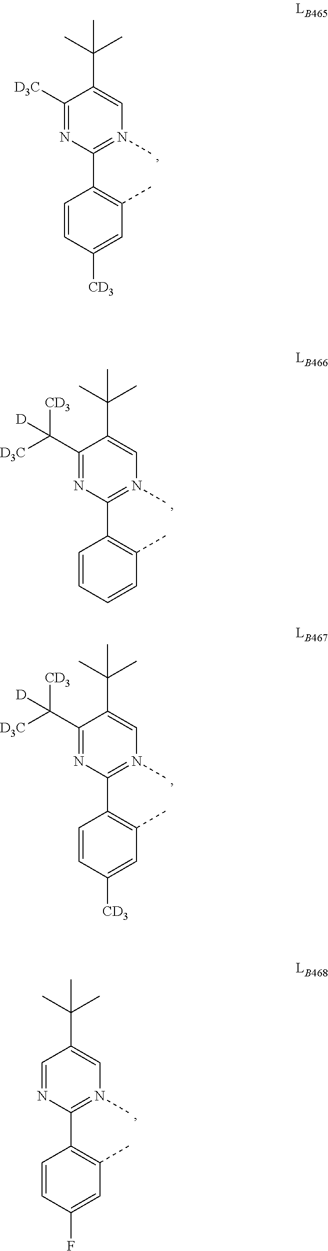 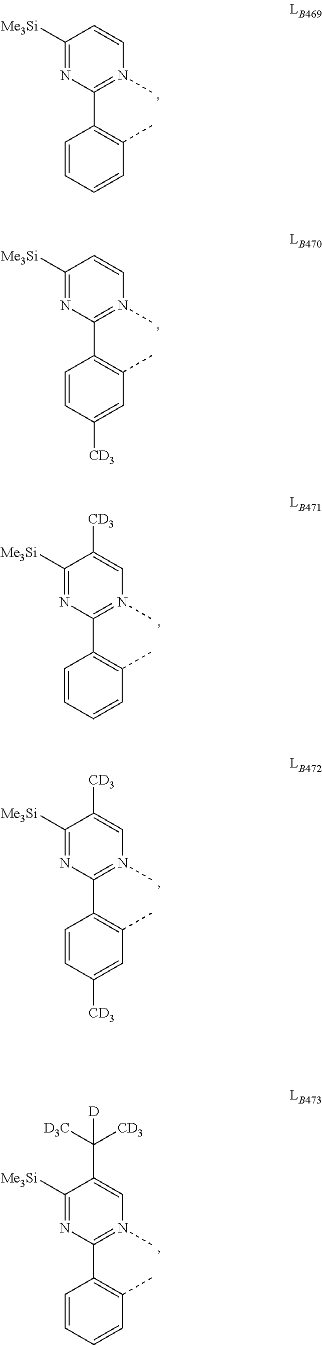 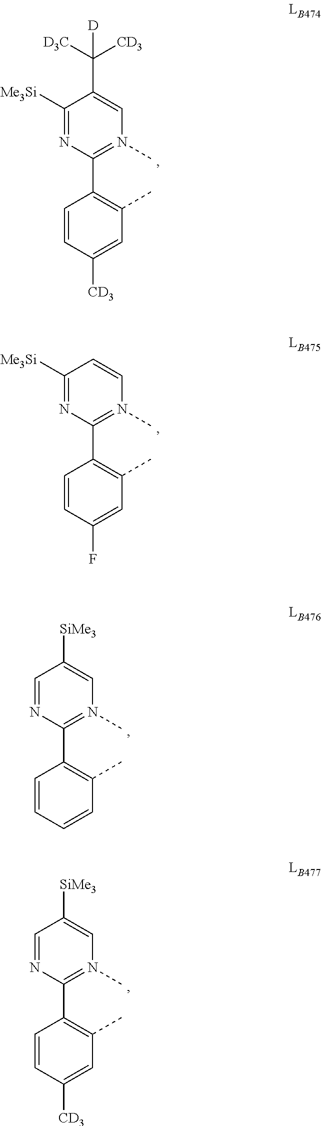 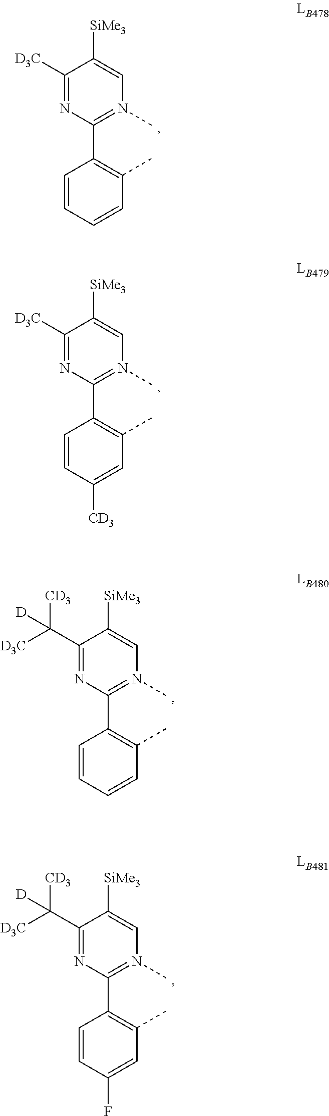 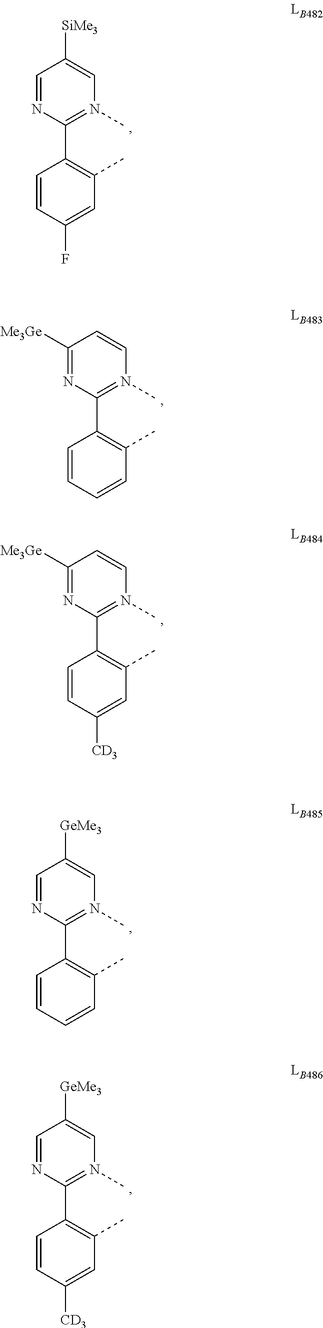 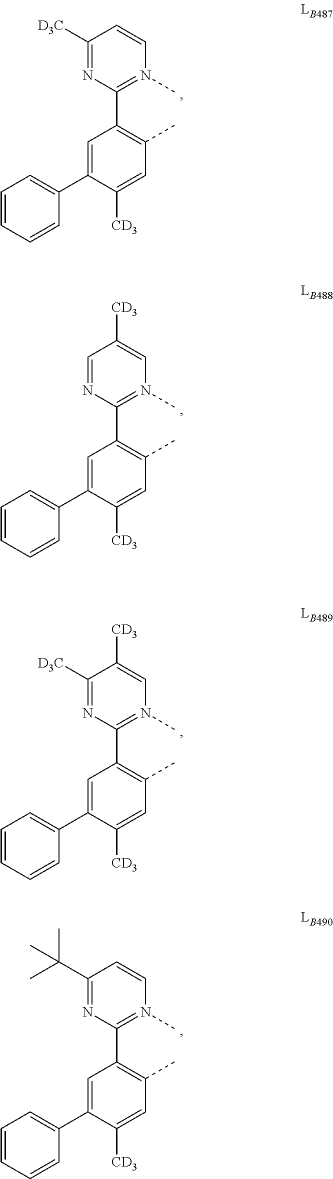 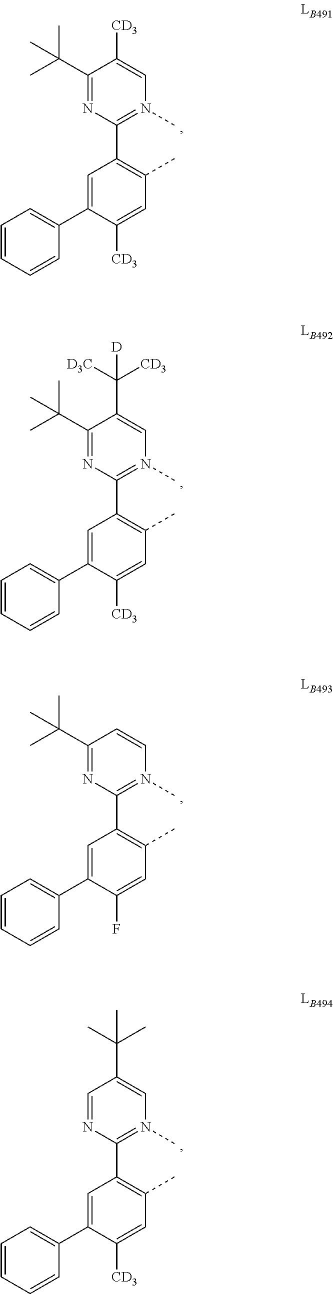 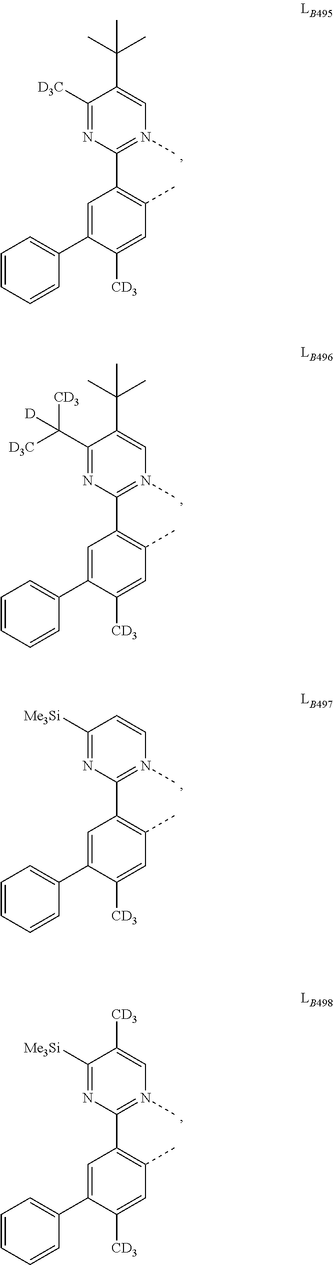 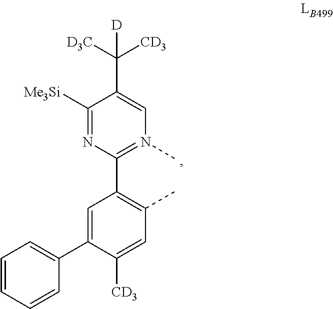 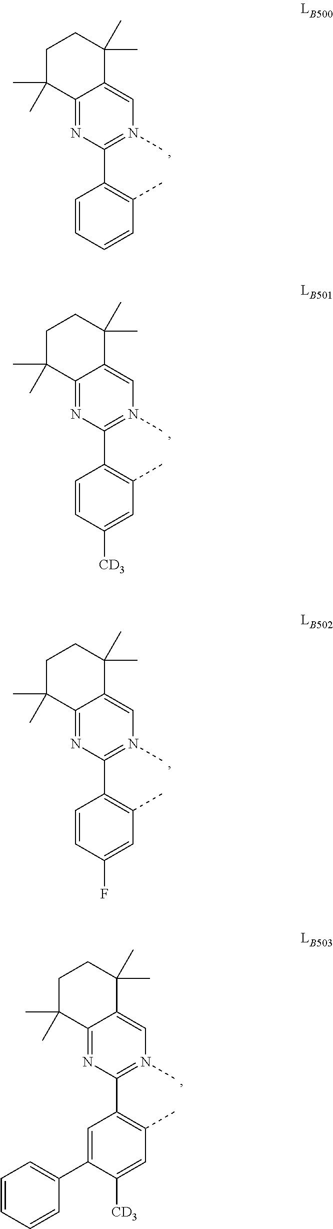 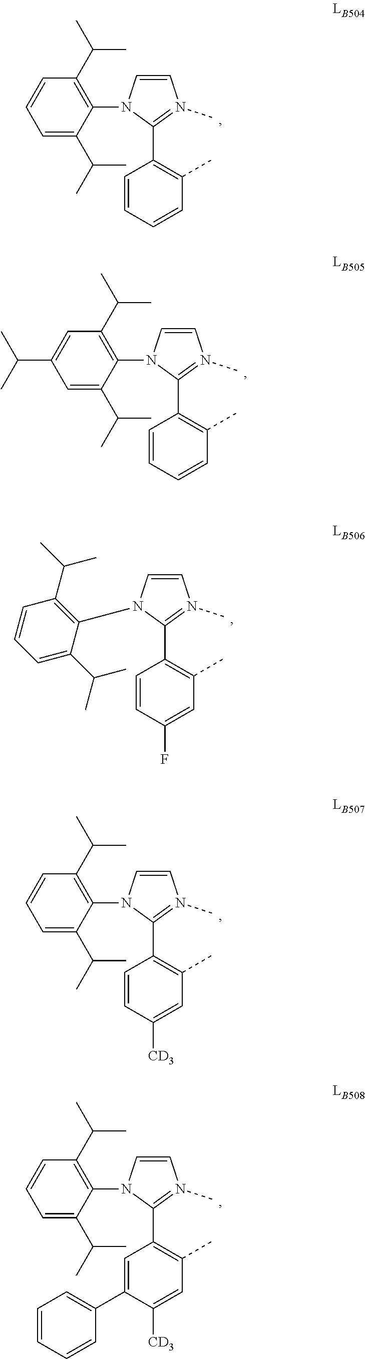 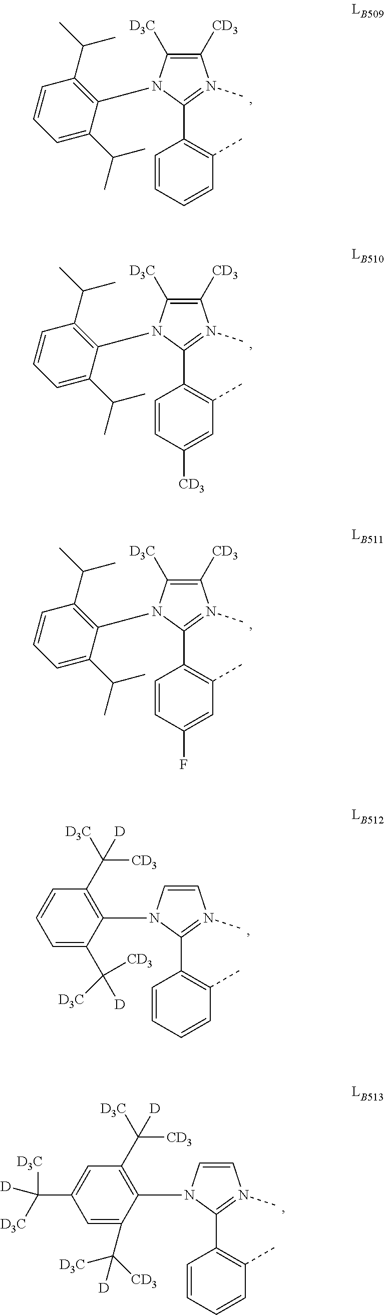 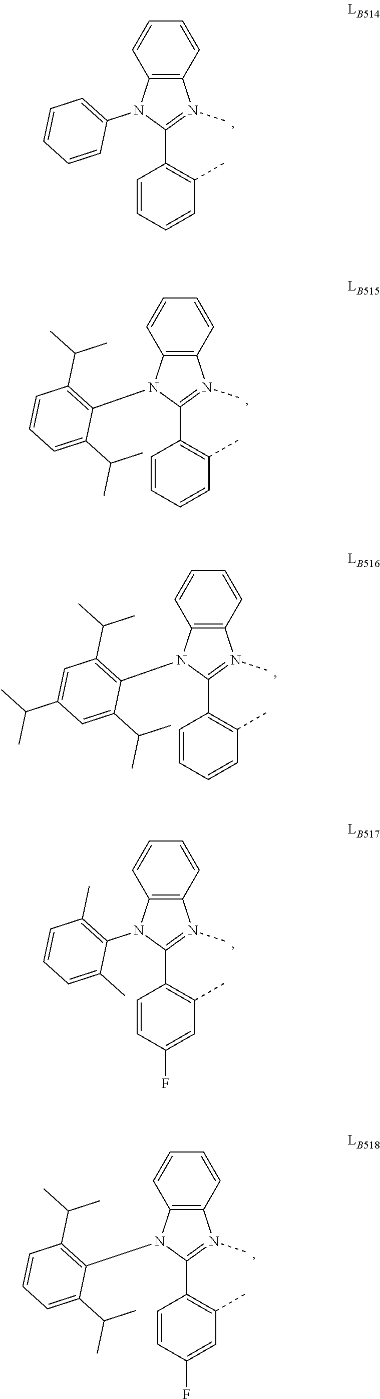 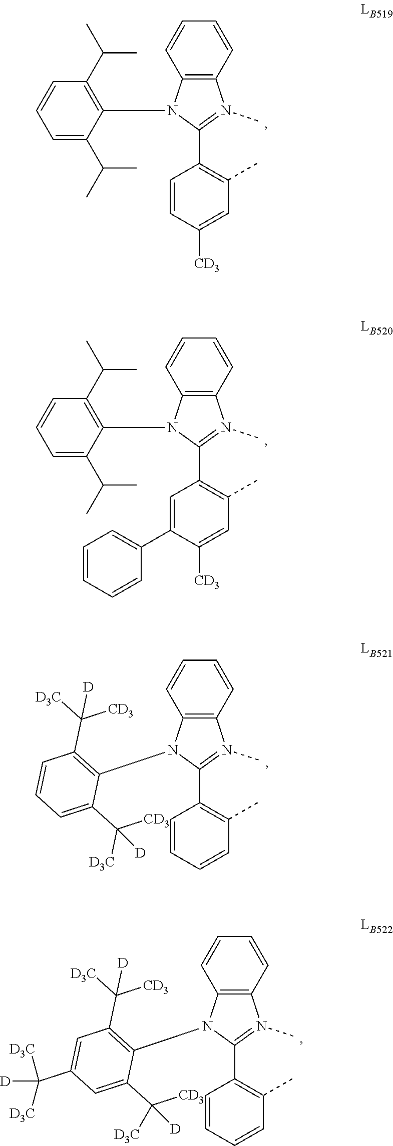 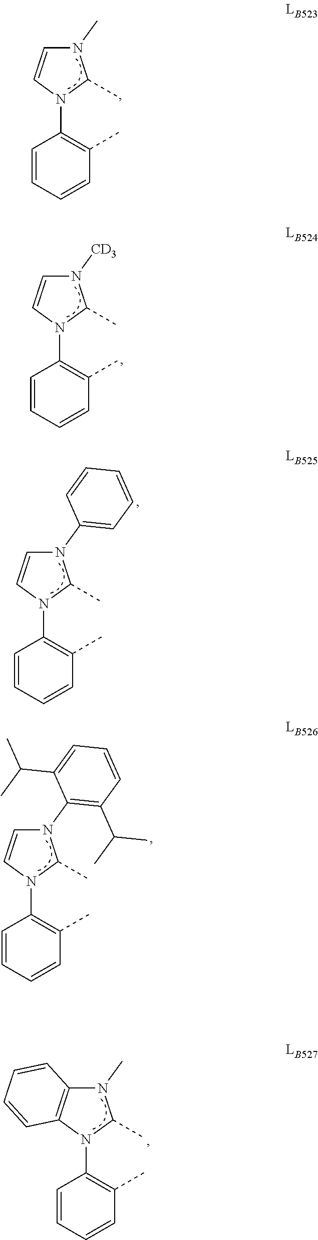 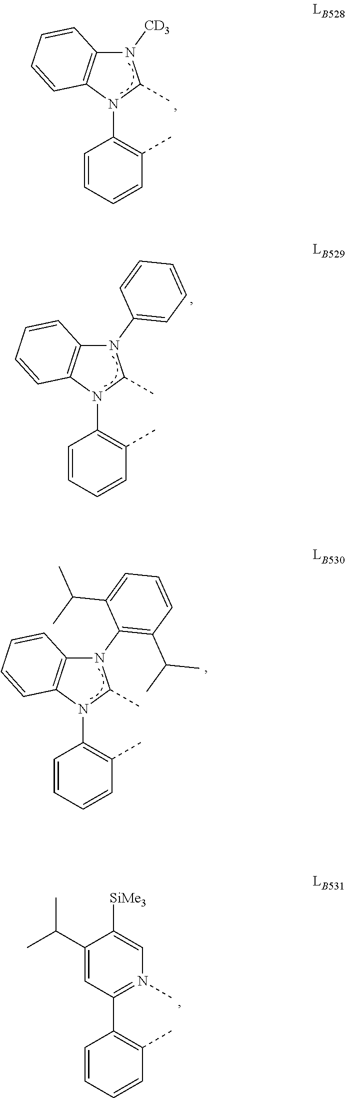 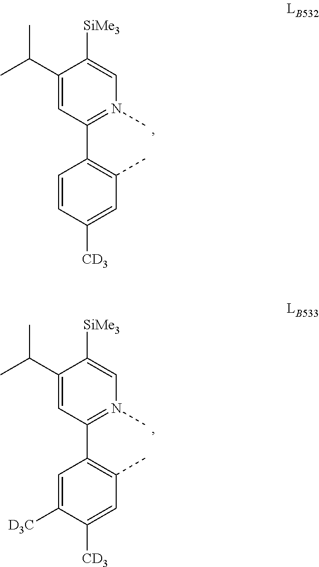 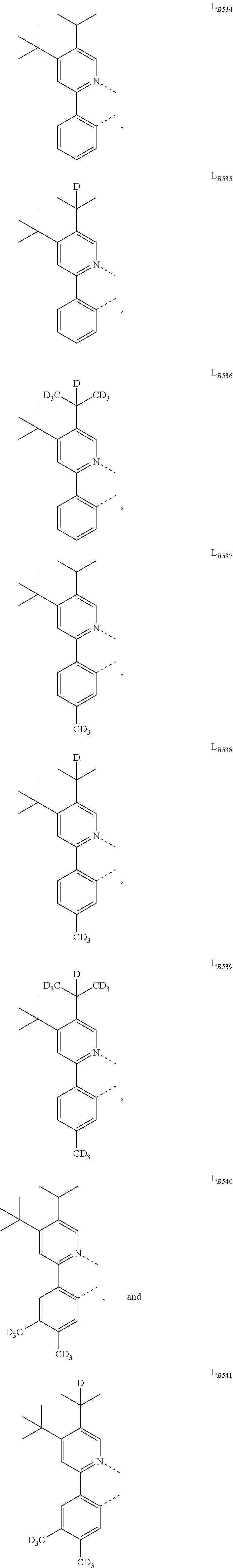
wherein each L_{Cj-I} R has a structure based on formula 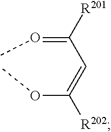
and
each L_{Cj-II} has a structure based on formula 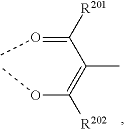
wherein for each L_{Cj} is L_{Cj-I} and L_{Cj-II}, R²⁰¹ and R²⁰² are defined as follows:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D149} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

wherein R^{D1} to R^{D246} have the following structures:

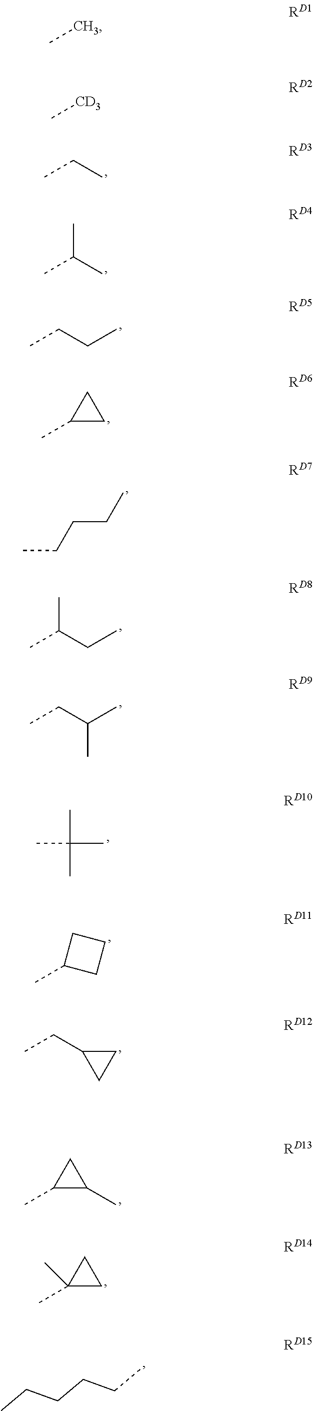

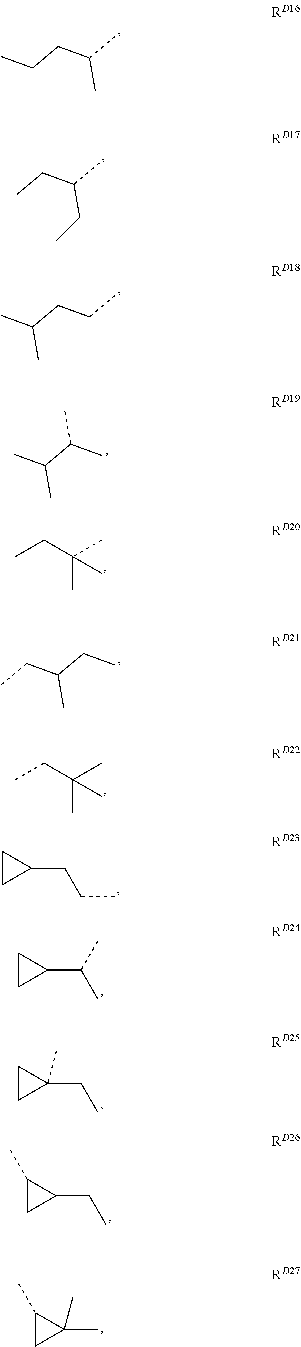

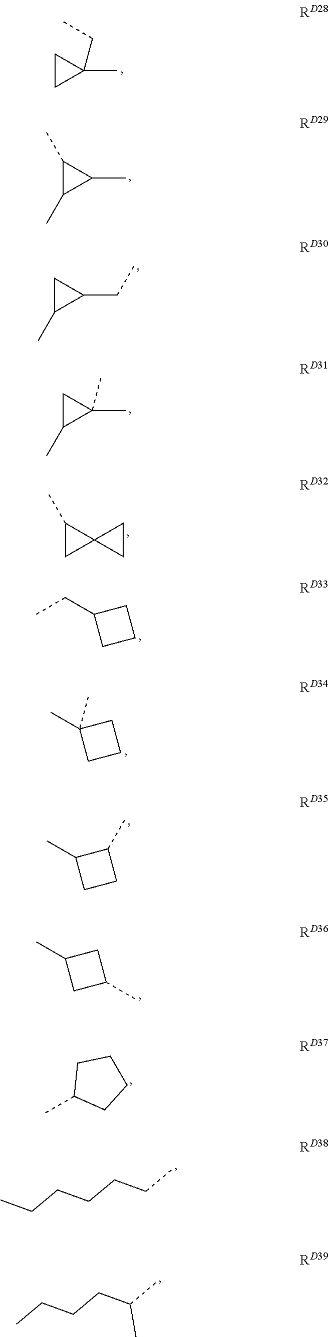

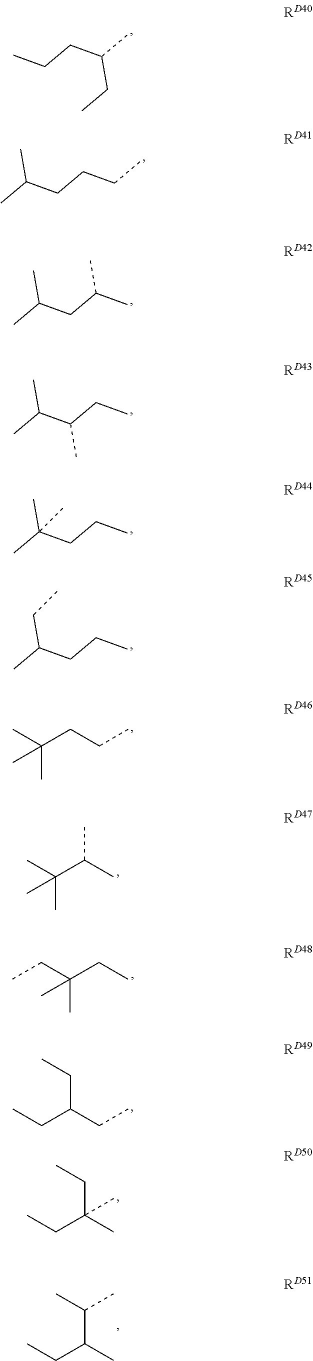

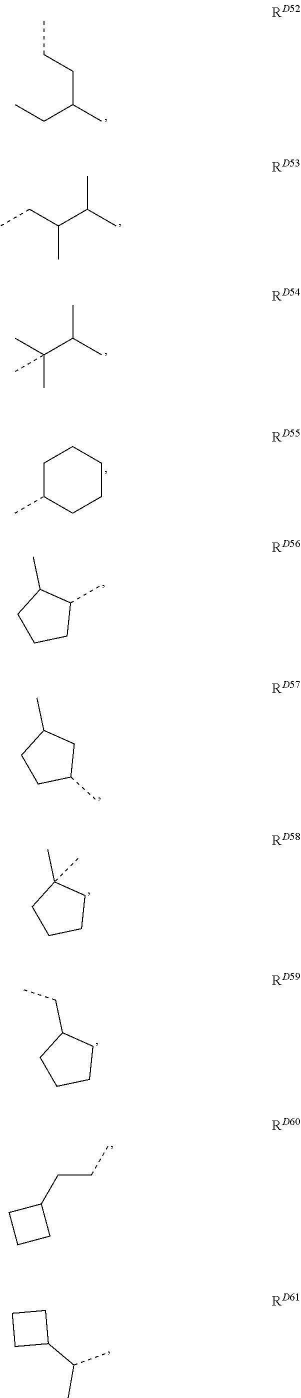

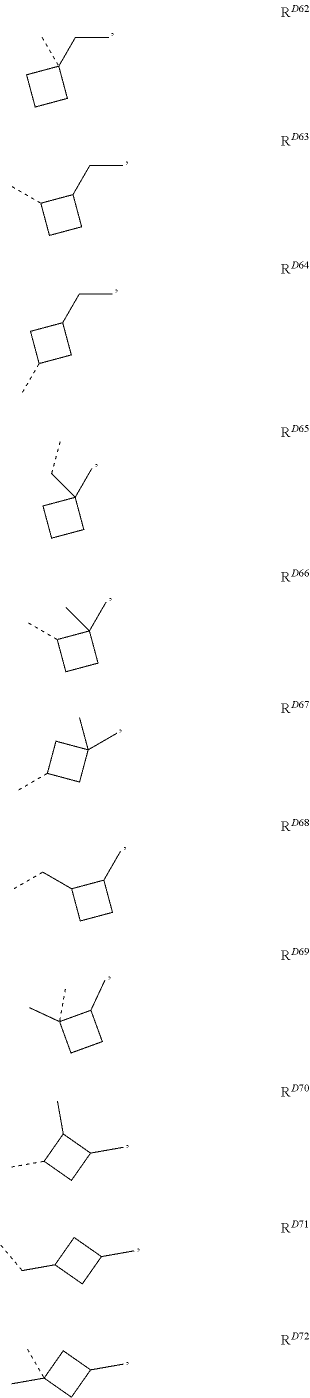

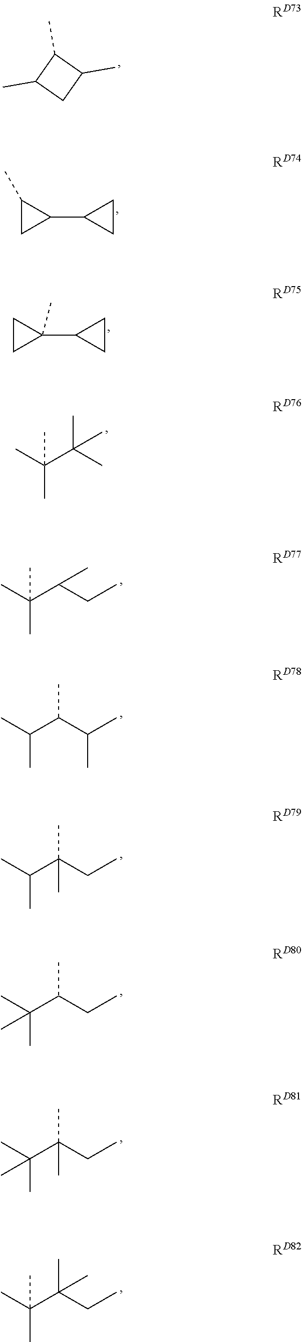

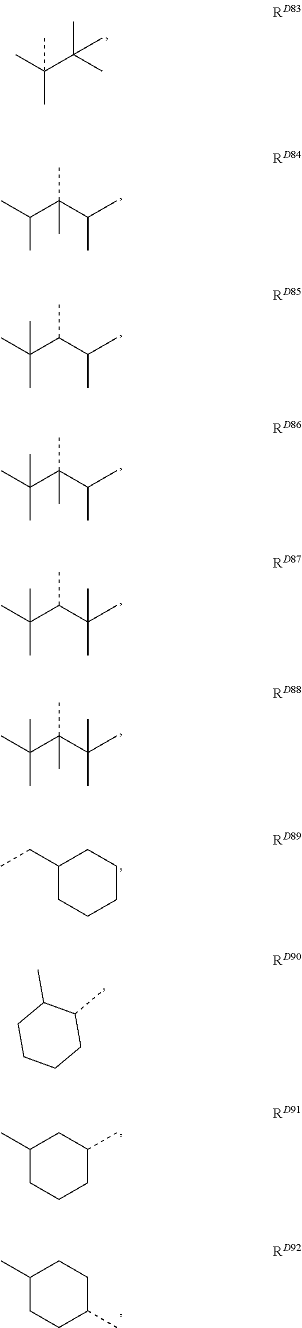

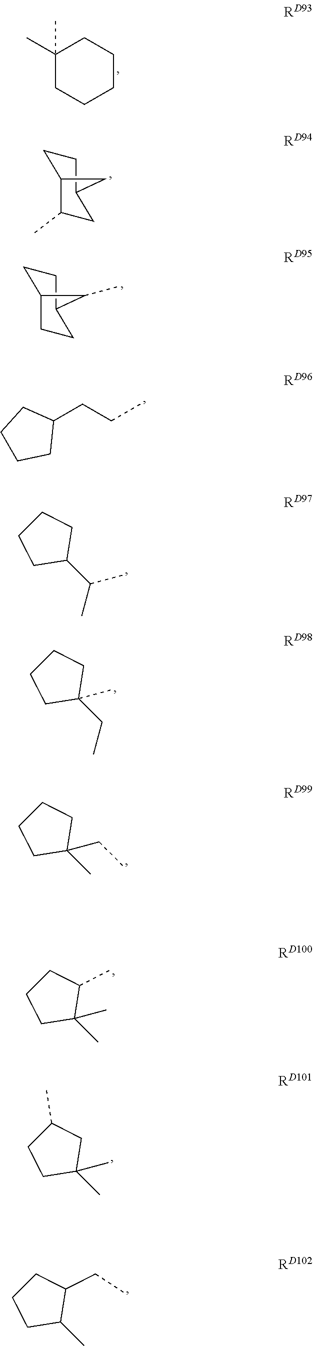

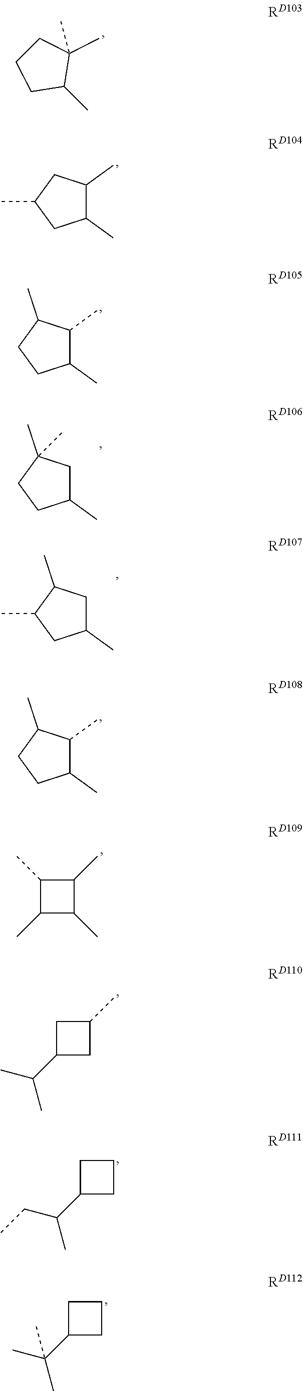

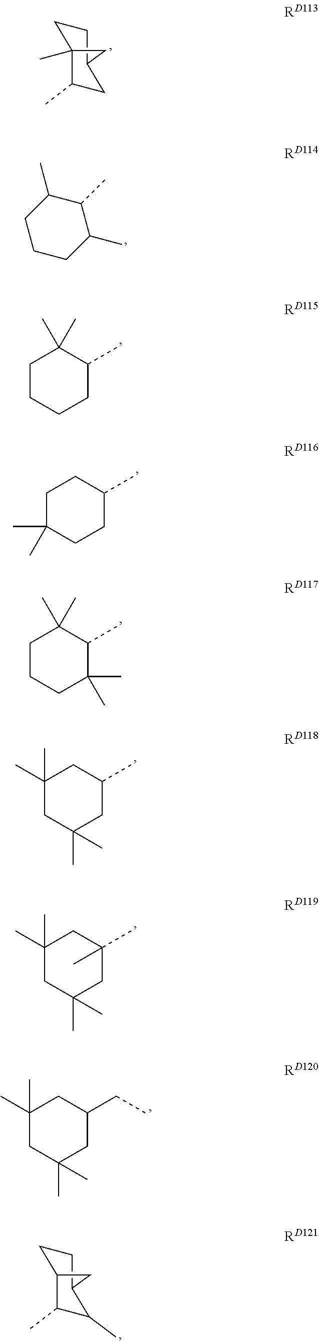

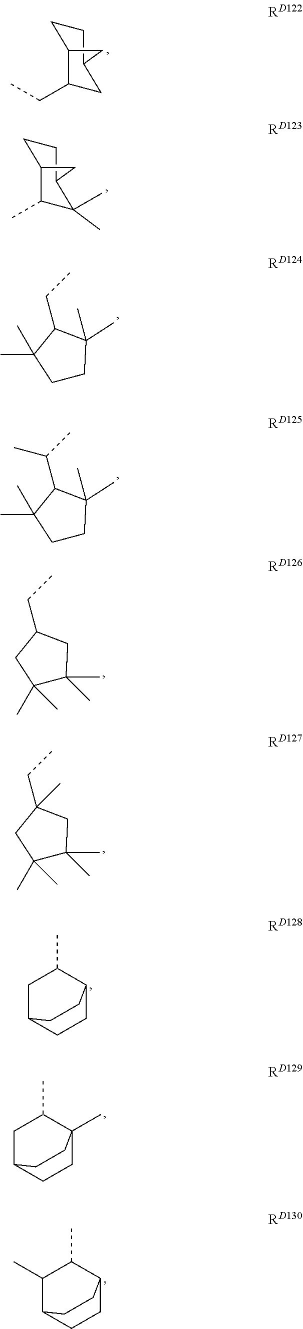

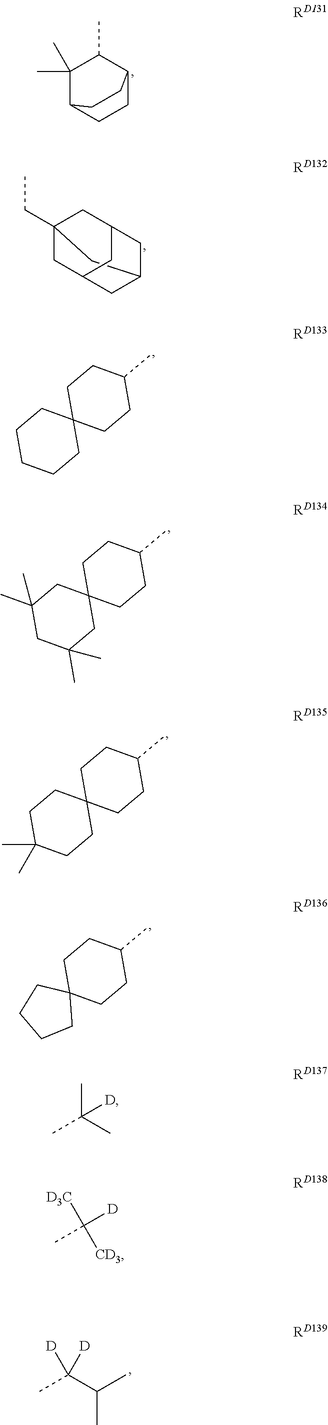

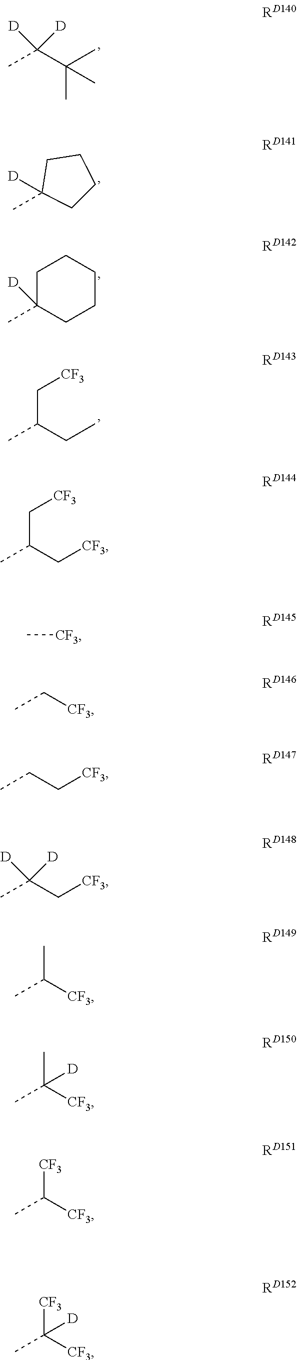

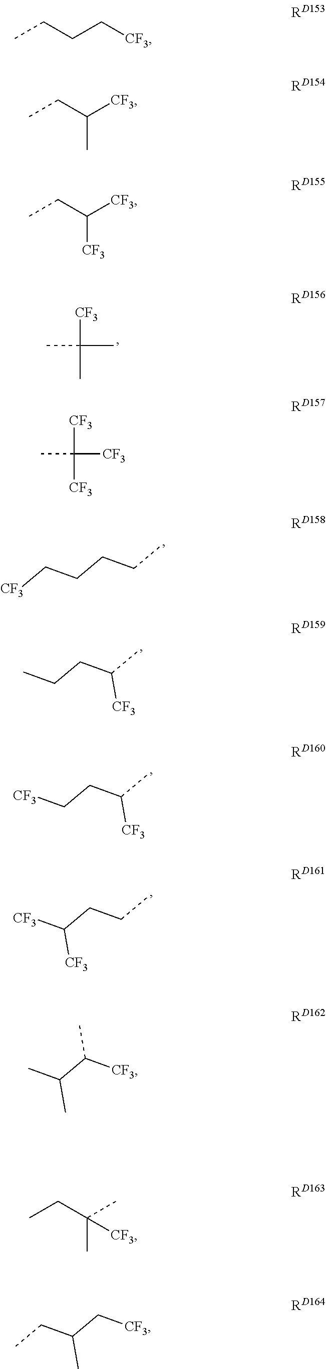

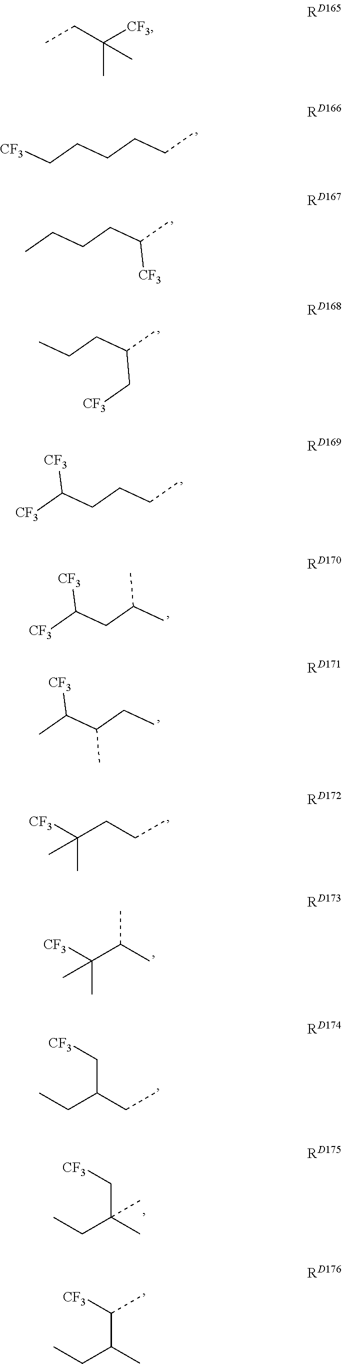

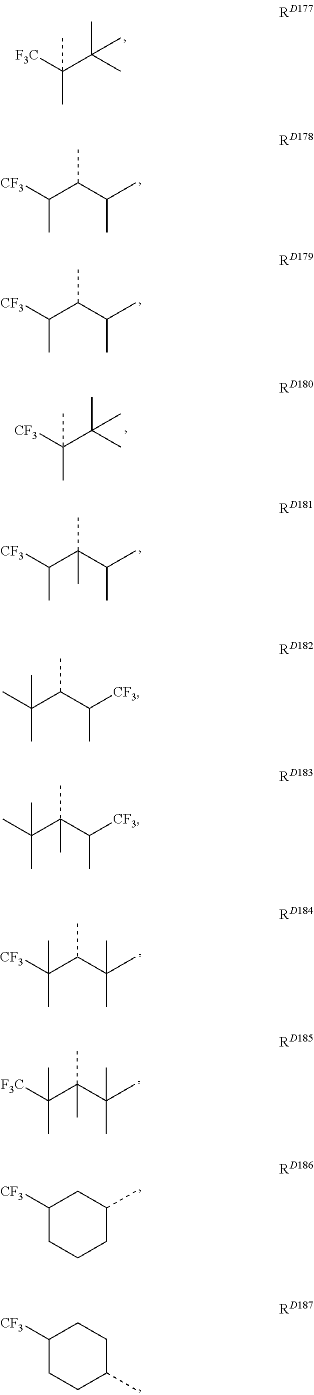

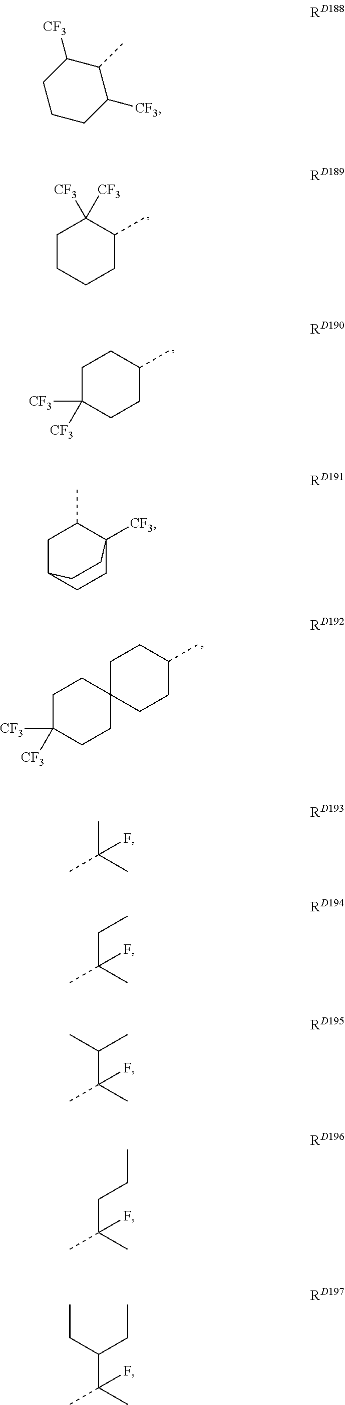

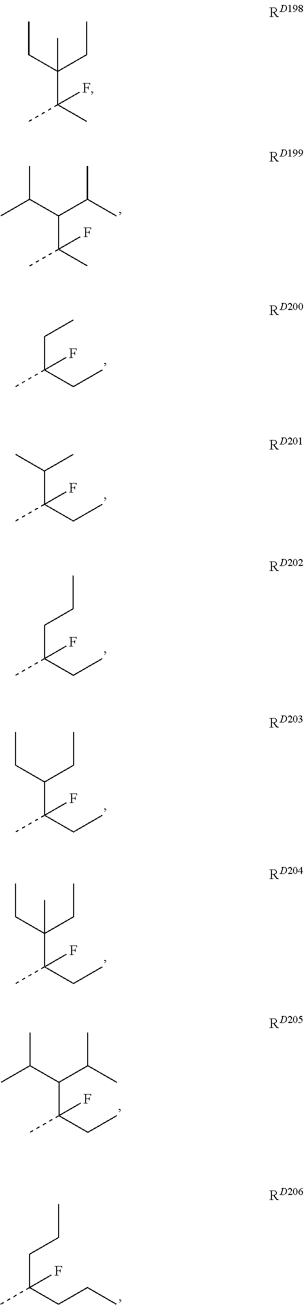

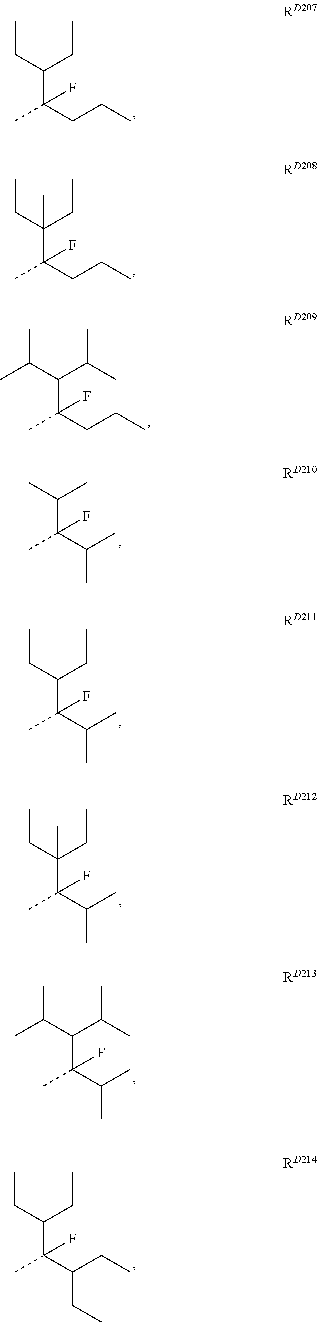

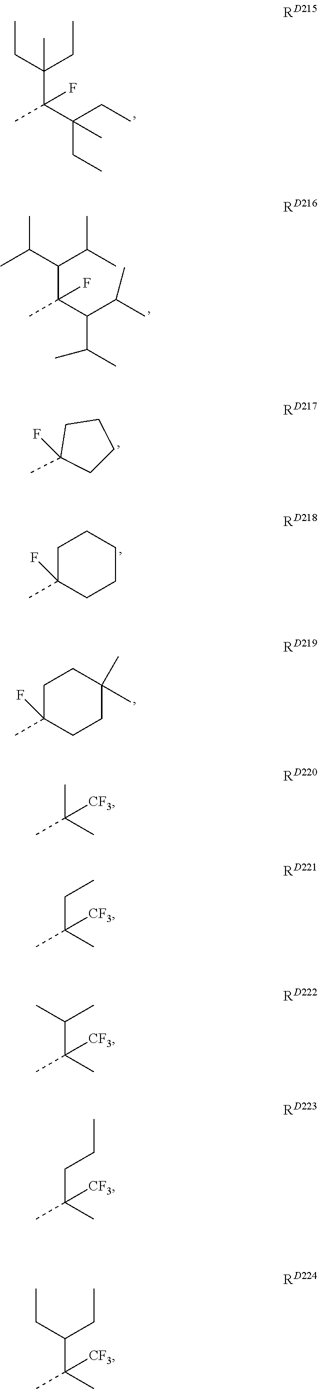

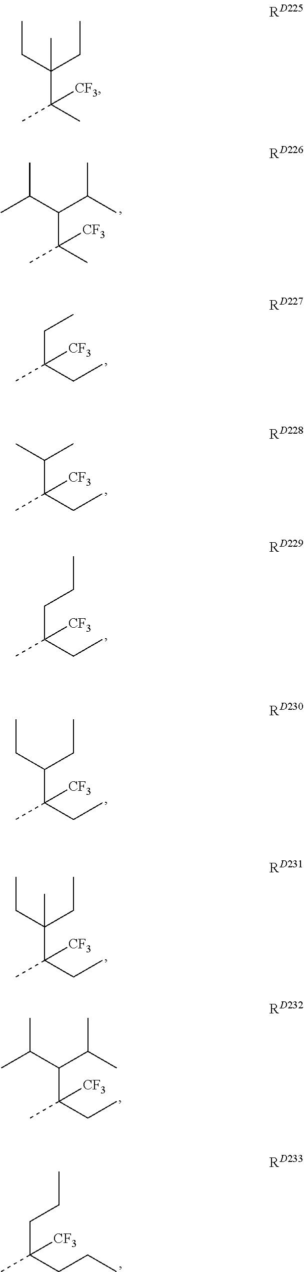

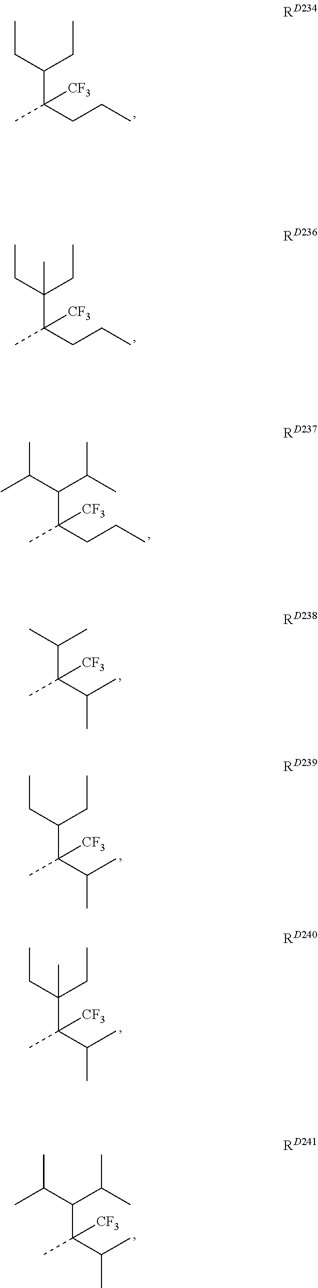

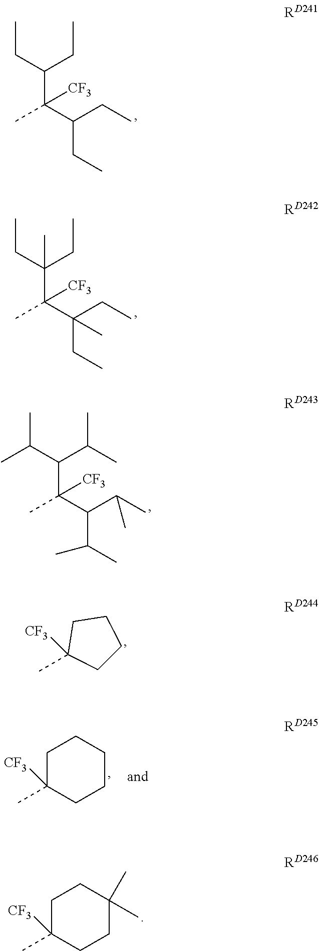

15. The compound of claim 1, wherein the compound is selected from the group consisting of:

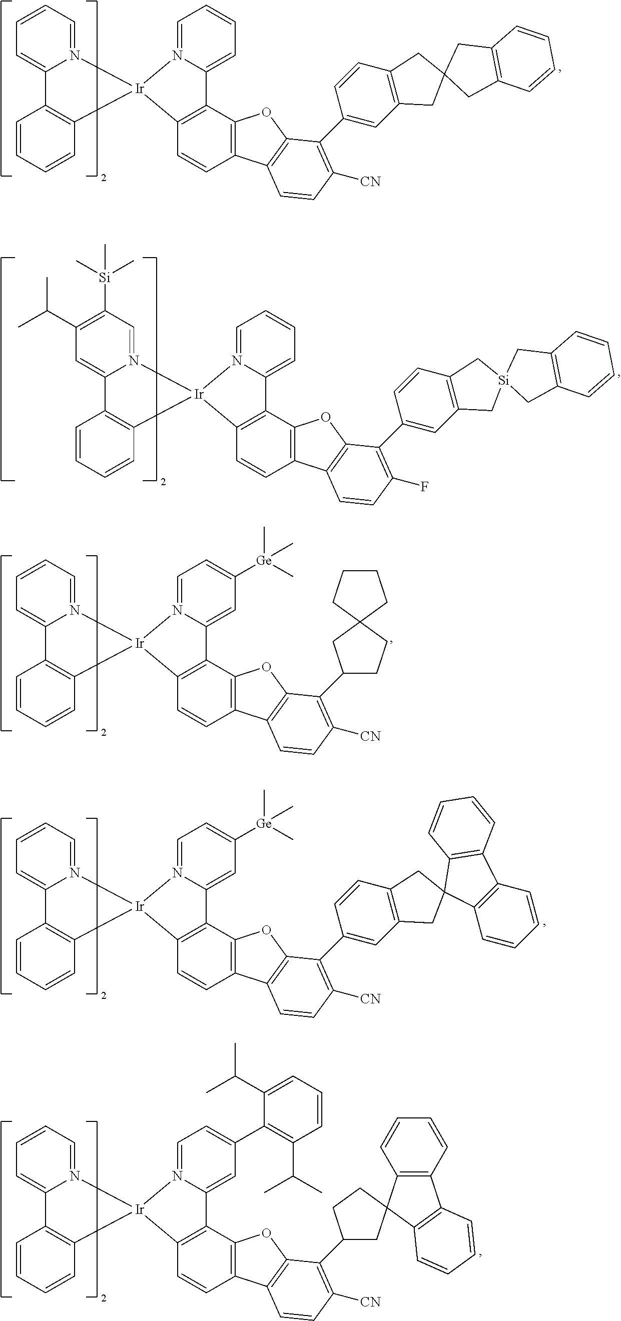

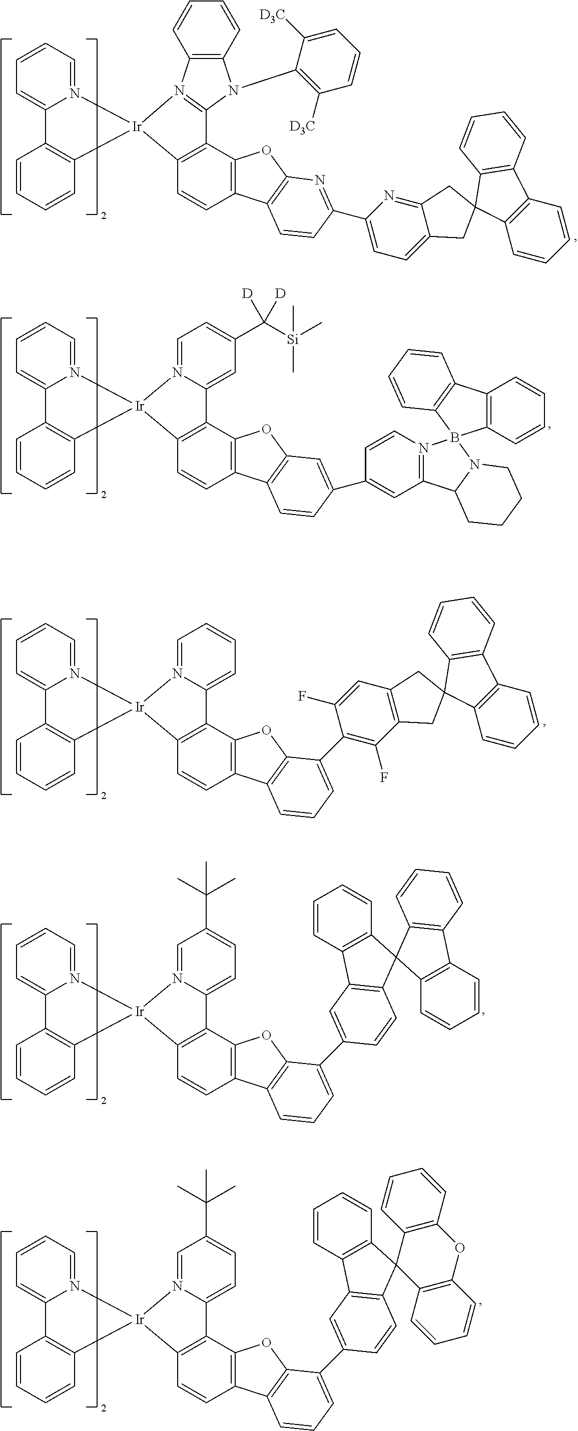

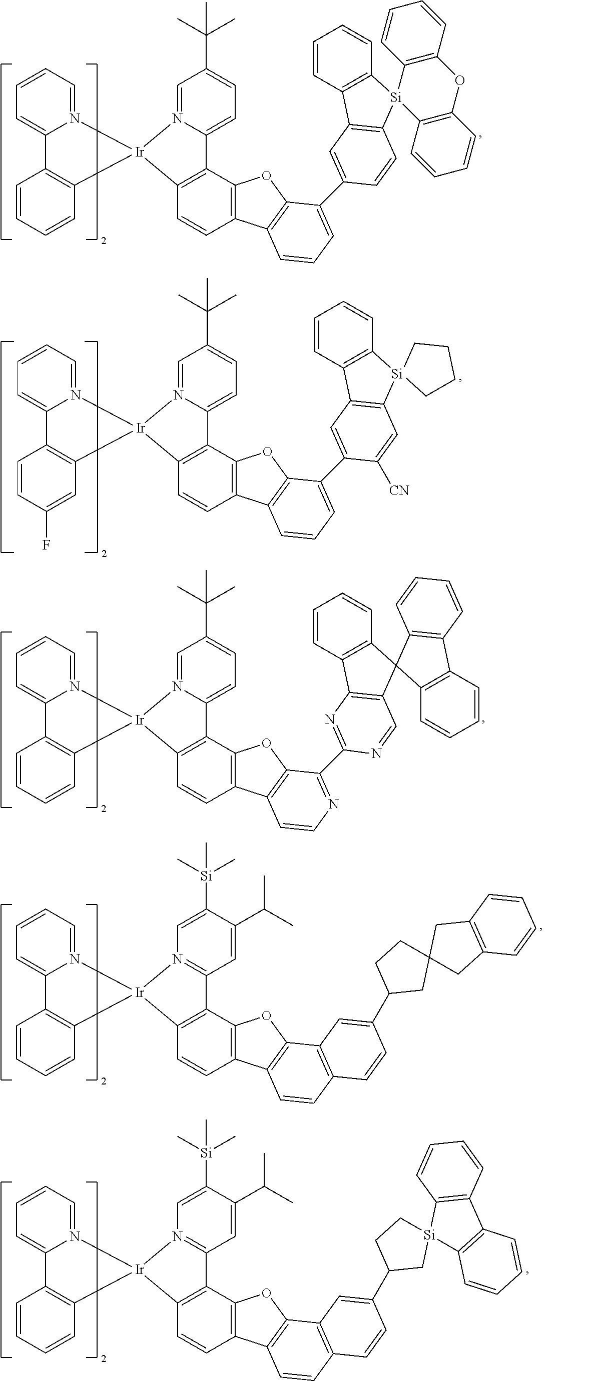

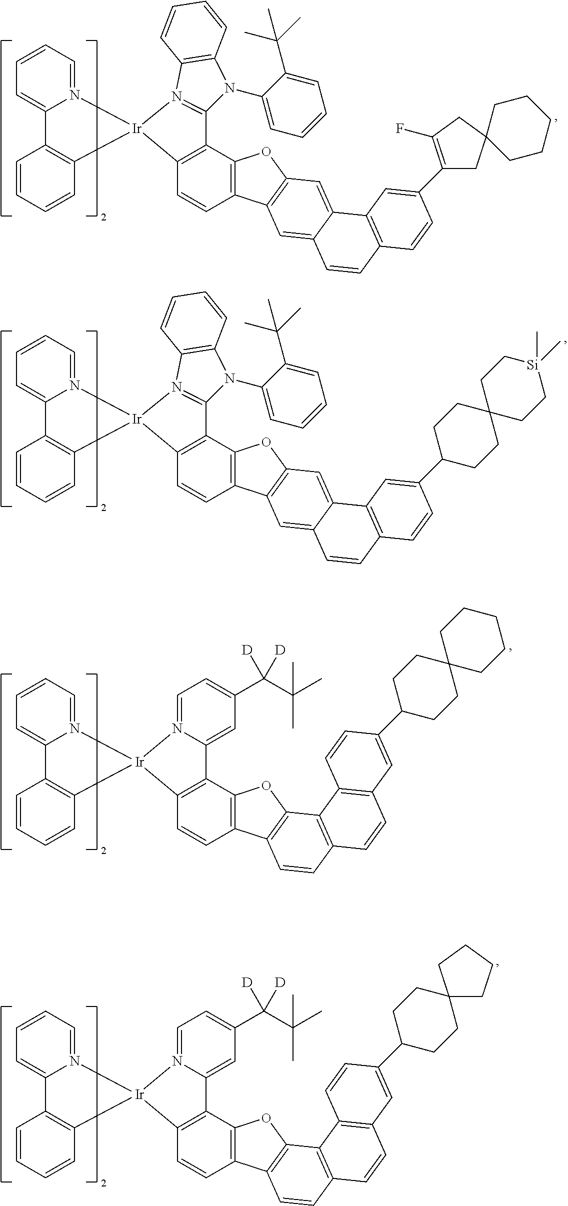

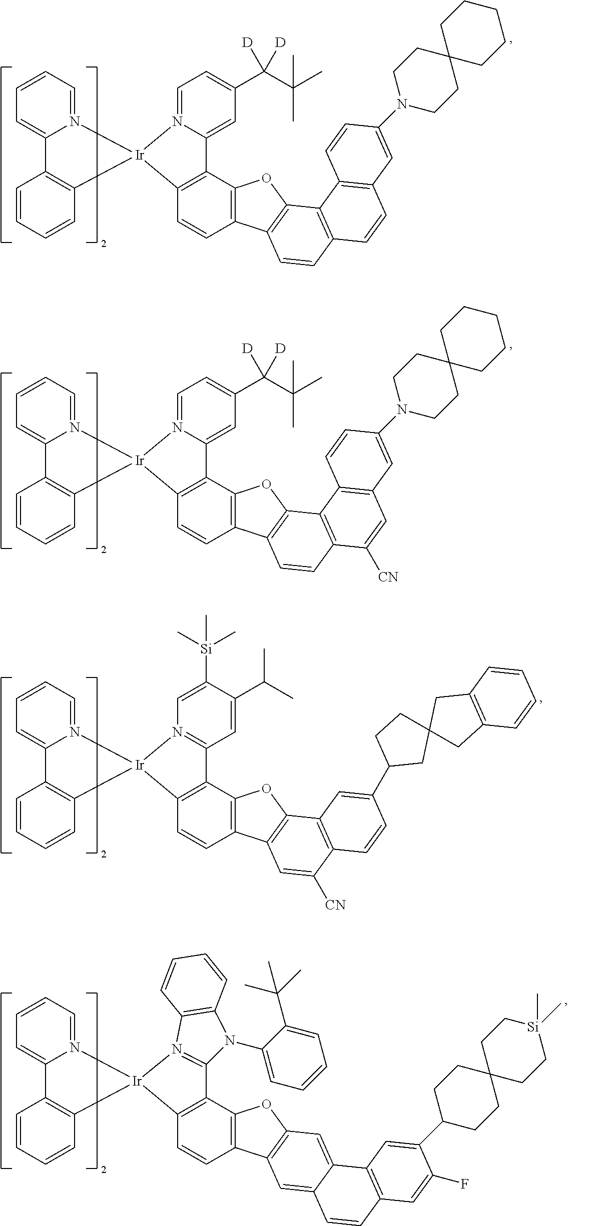

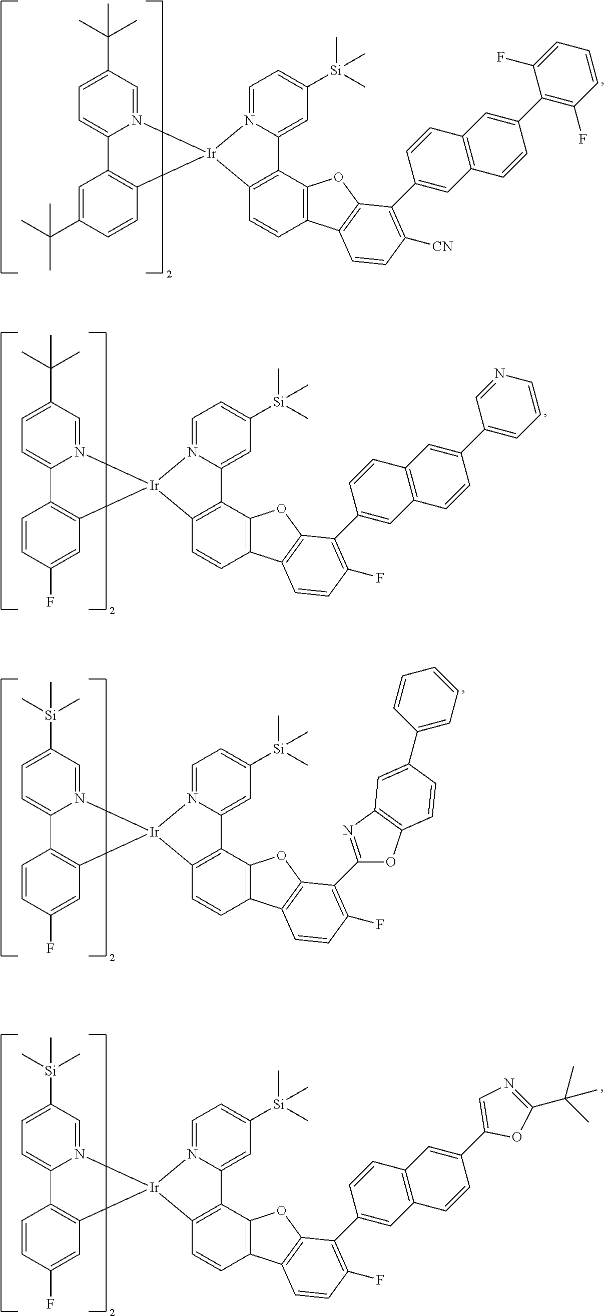

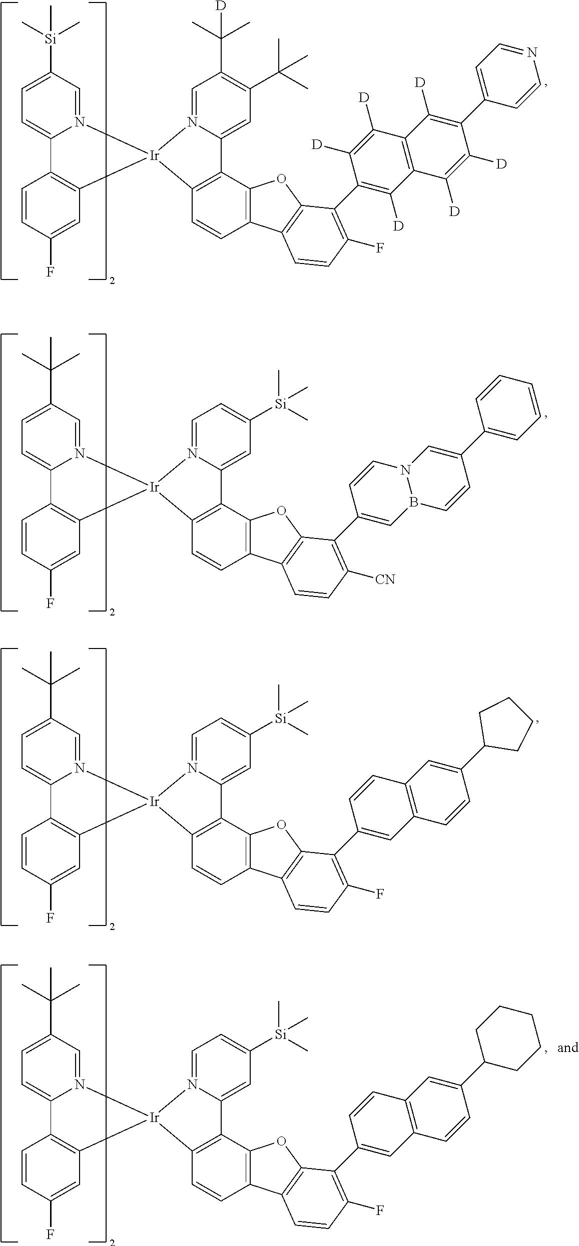

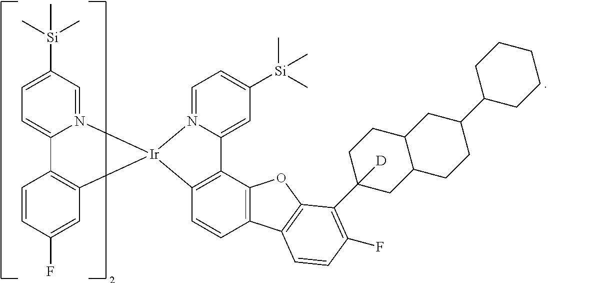

16. The compound of claim 11, wherein the compound has the Formula IV: 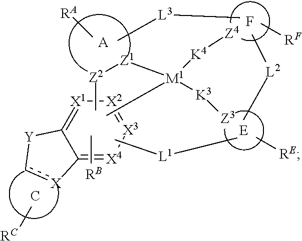
wherein:
M¹ is Pd or Pt;
moieties E′ and F′ are each independently monocyclic or polycyclic ring structure, wherein the monocyclic ring or each ring of the polycyclic fused ring system is independently a 5-membered to 10-membered carbocyclic or heterocyclic ring;
Z³ and Z⁴ are each independently C or N;
K³ and K⁴ are each independently selected from the group consisting of a direct bond, O, and S, wherein at least one of them is a direct bond;
L¹, L², and L³ are each independently absent or selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof, wherein at least one of L¹ and L² is present;
R^{E′} and R^{F′} each independently represents zero, mono, or up to a maximum allowed number of substitutions;
each of R, R′, R^{E′}, and R^{F′} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
two adjacent R^{A}, R^{B}, R^{C}, R^{D}, R^{E}, R^{F}, R^{G}, R^{E′}, and R^{F′} can be joined or fused together to form a ring.

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein the host is selected from the group consisting of: 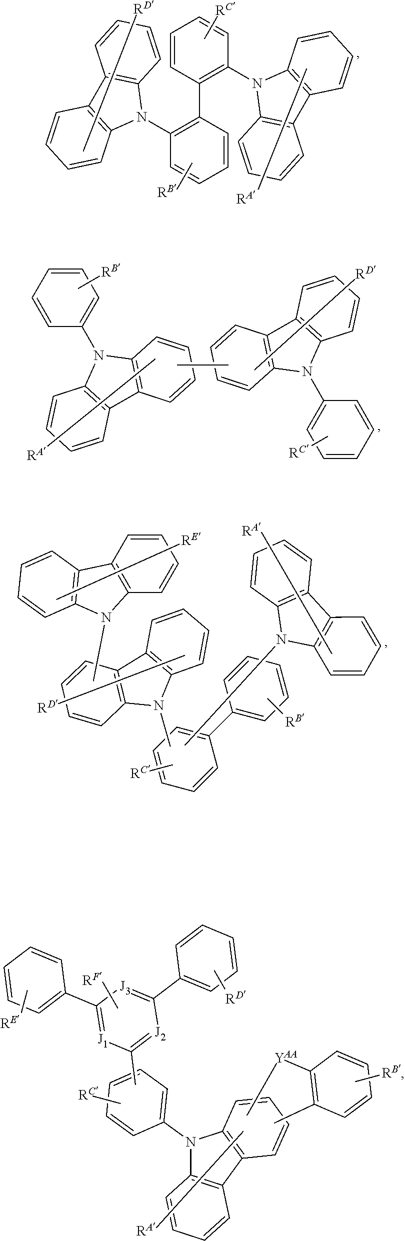 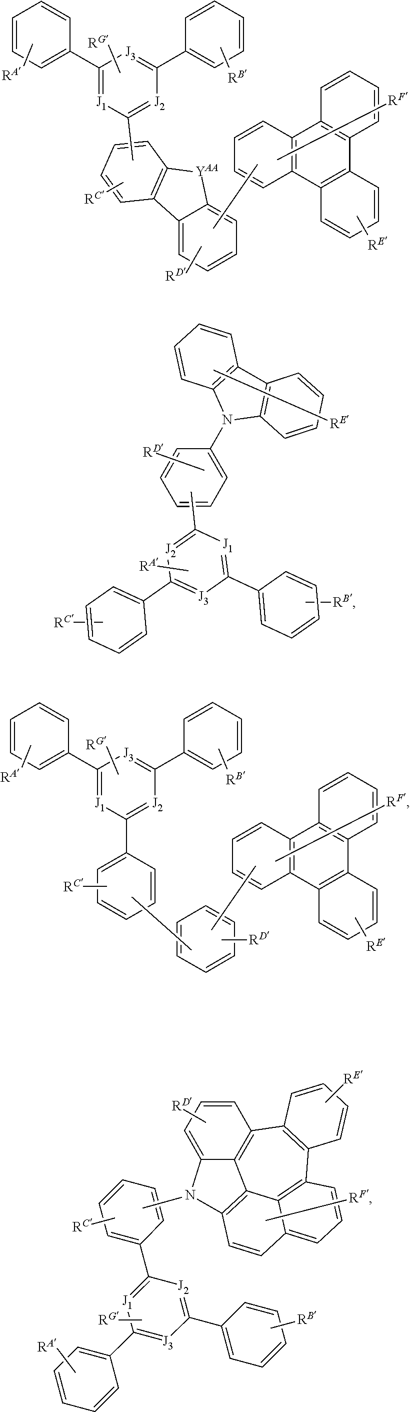 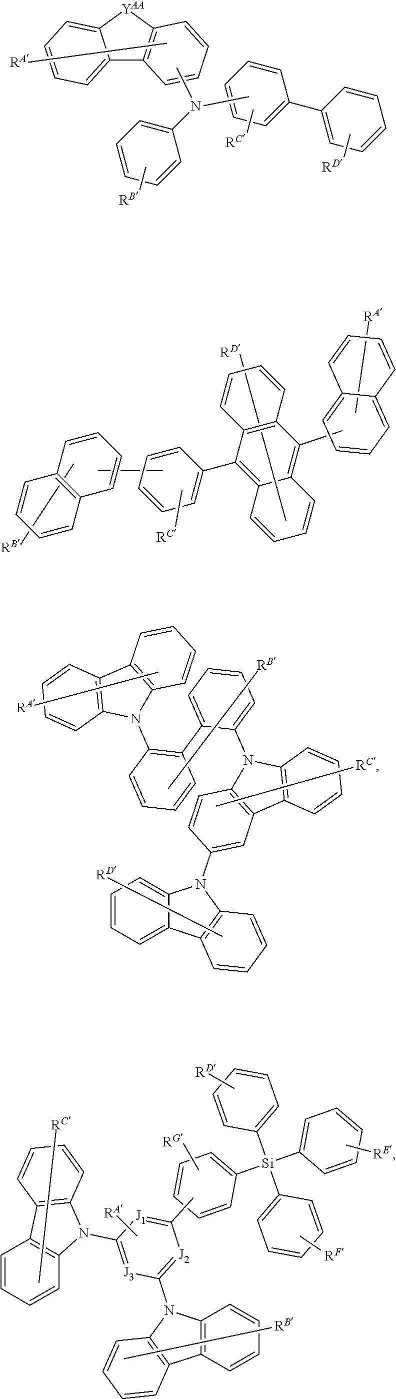 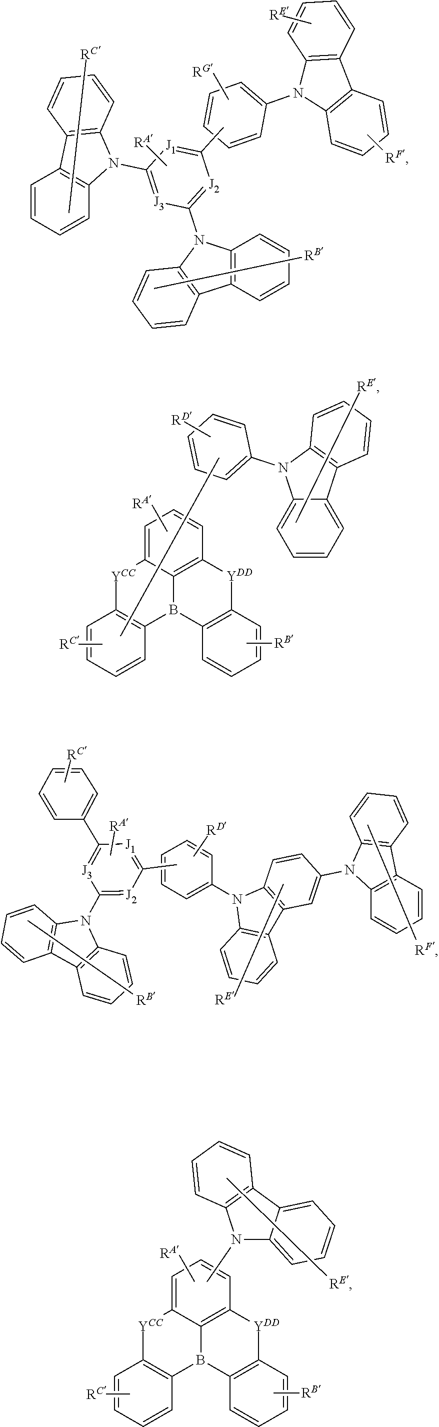 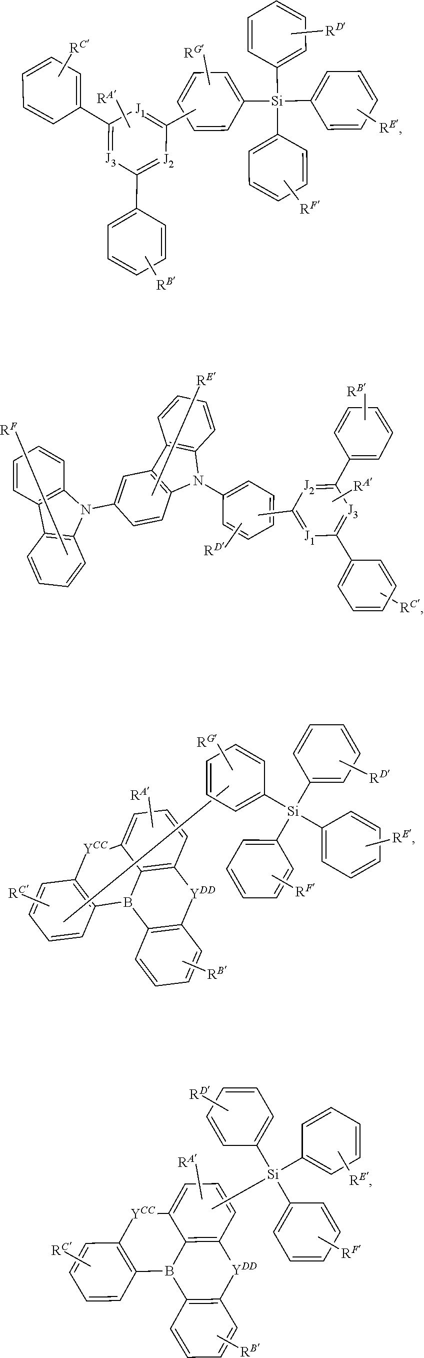 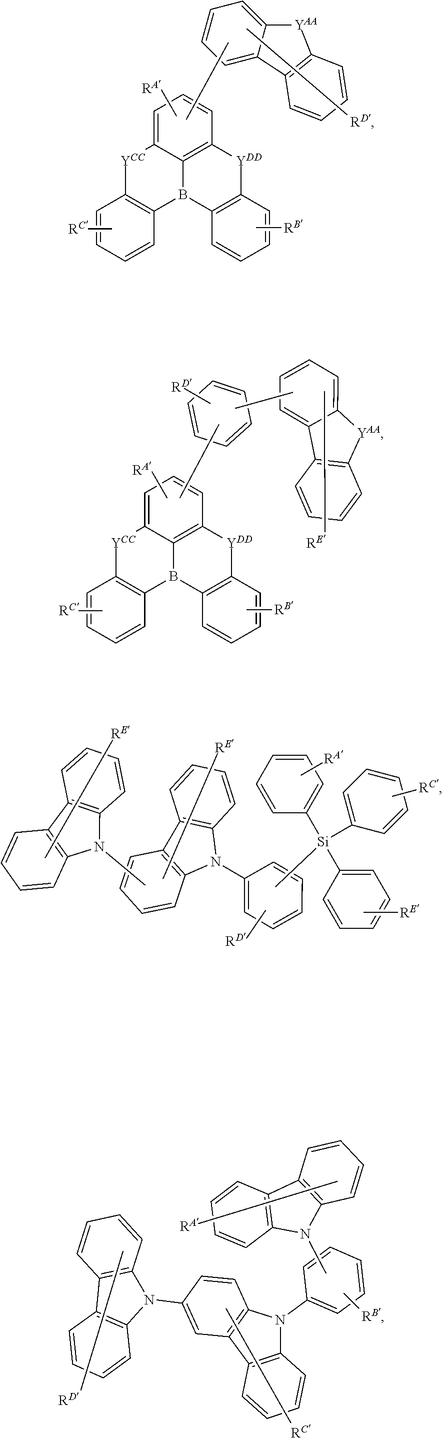 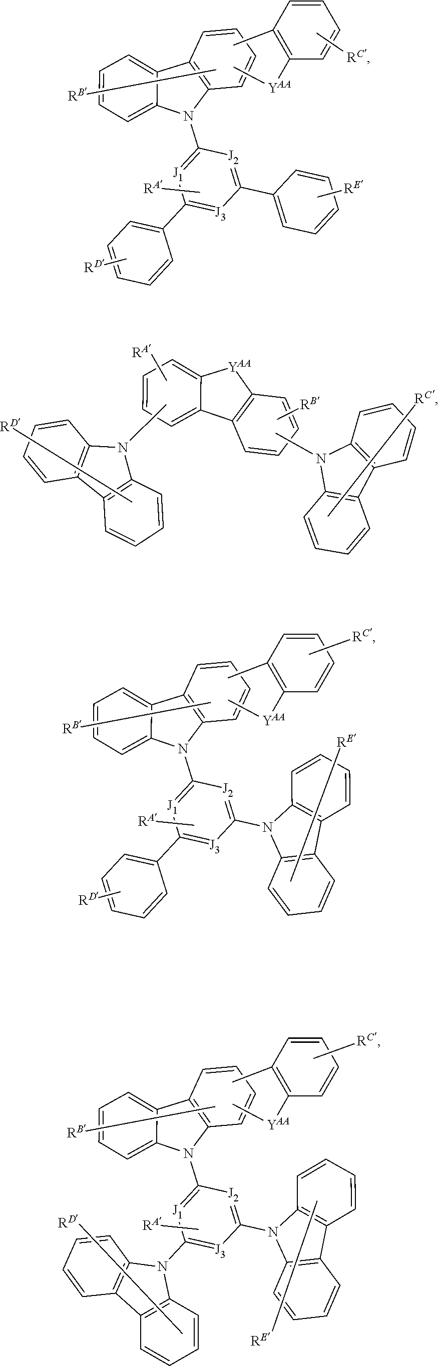 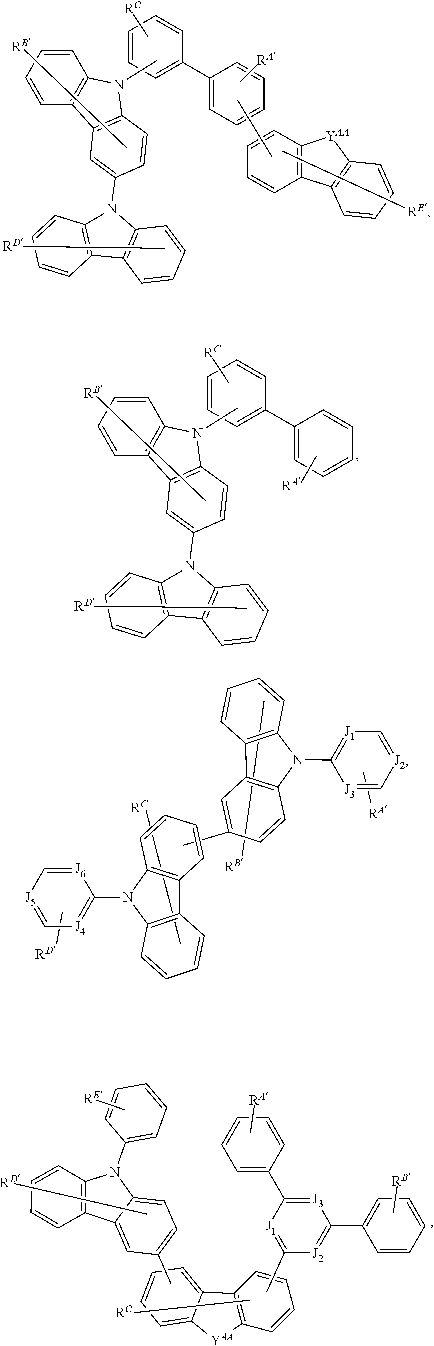 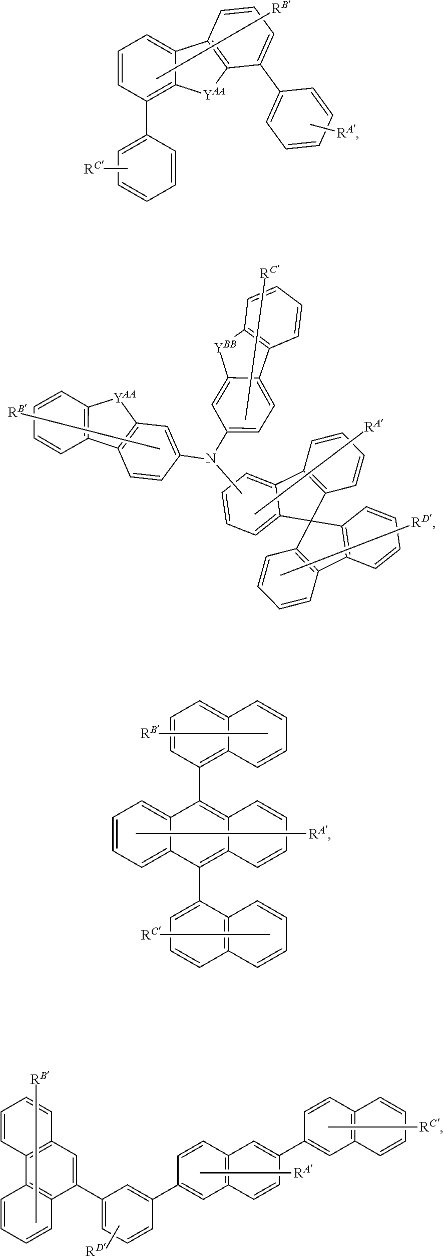 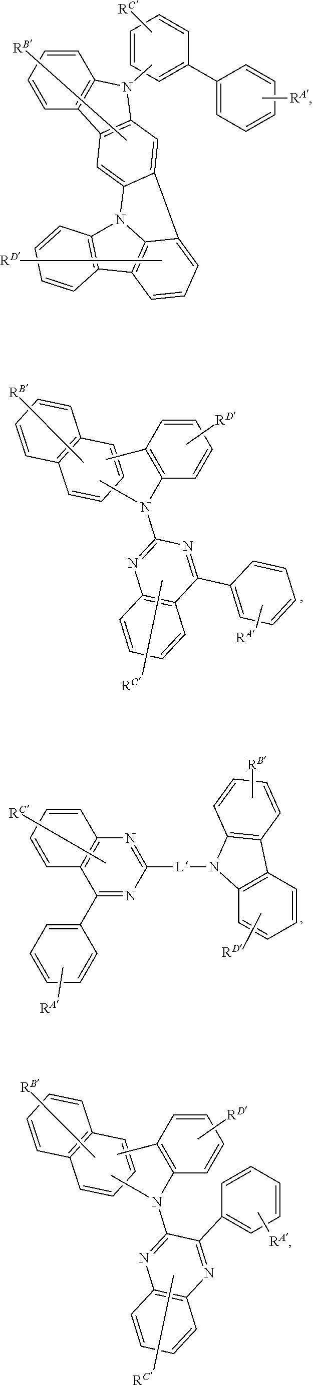 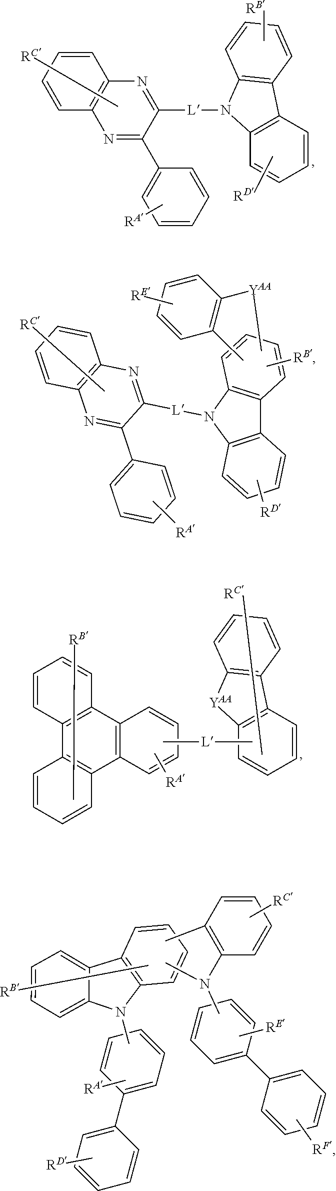 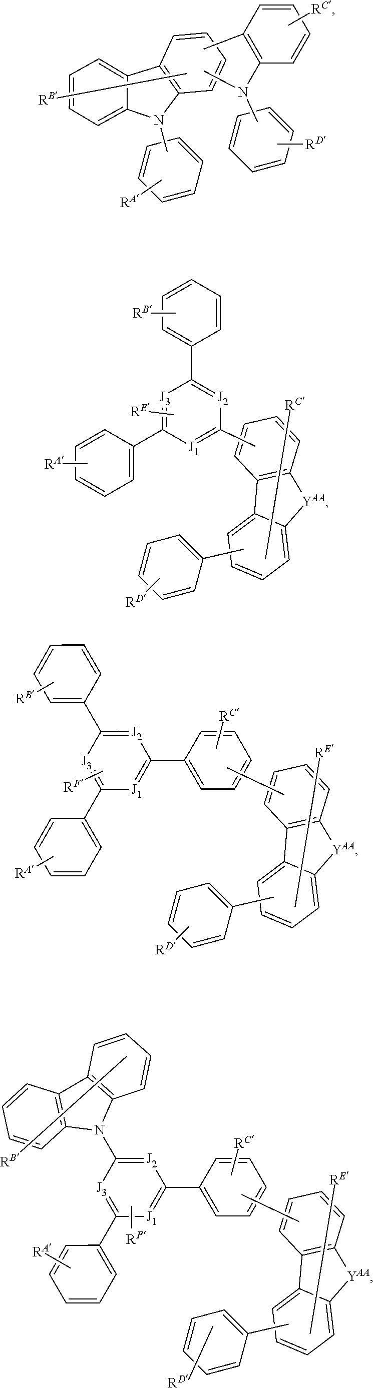 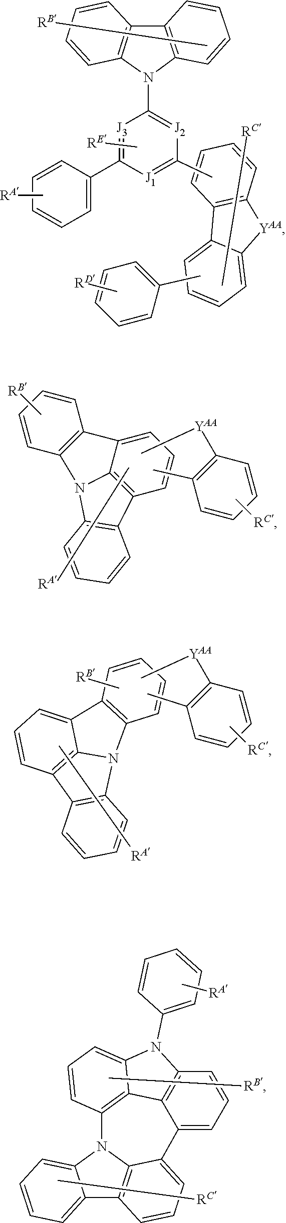 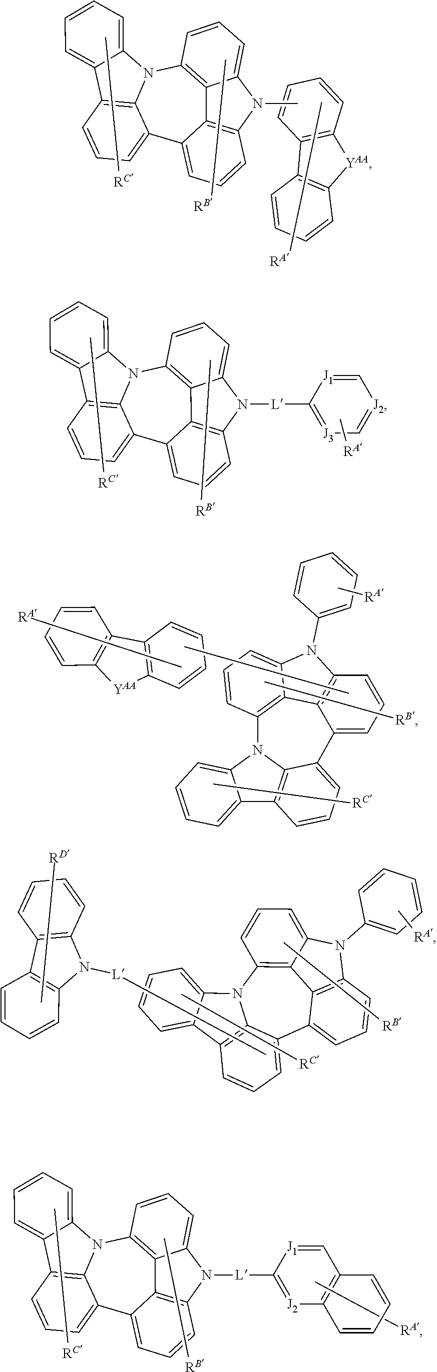 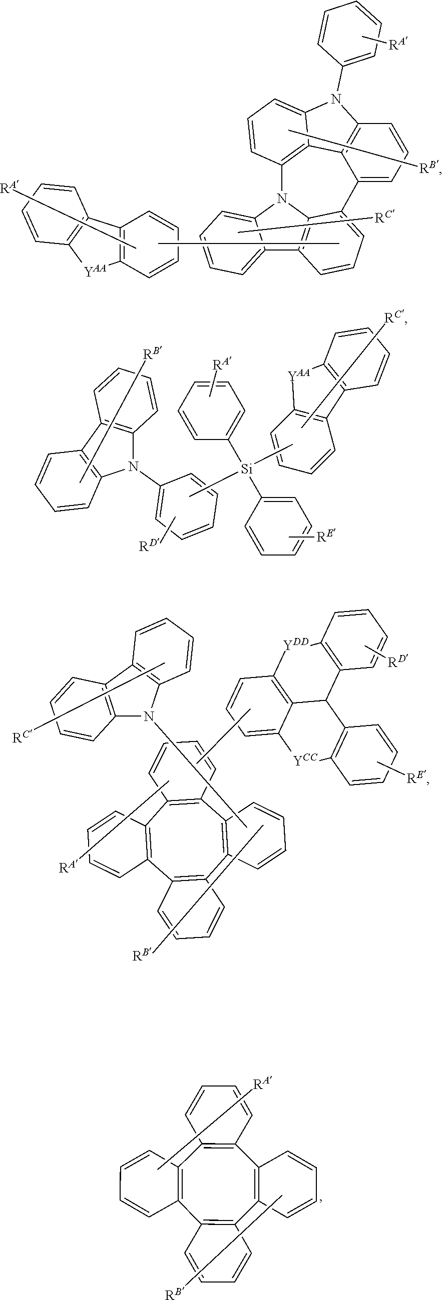 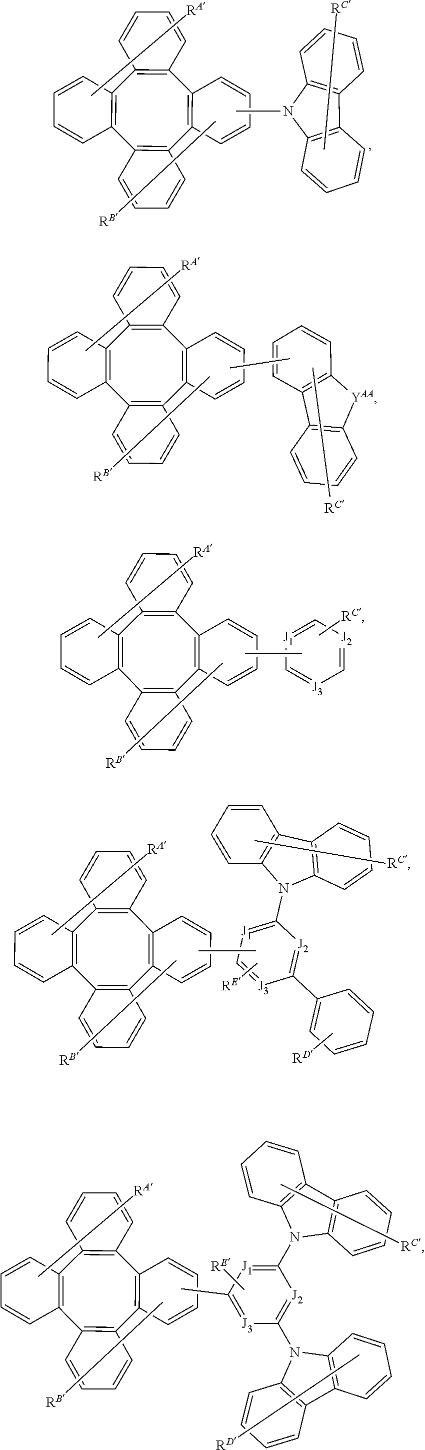 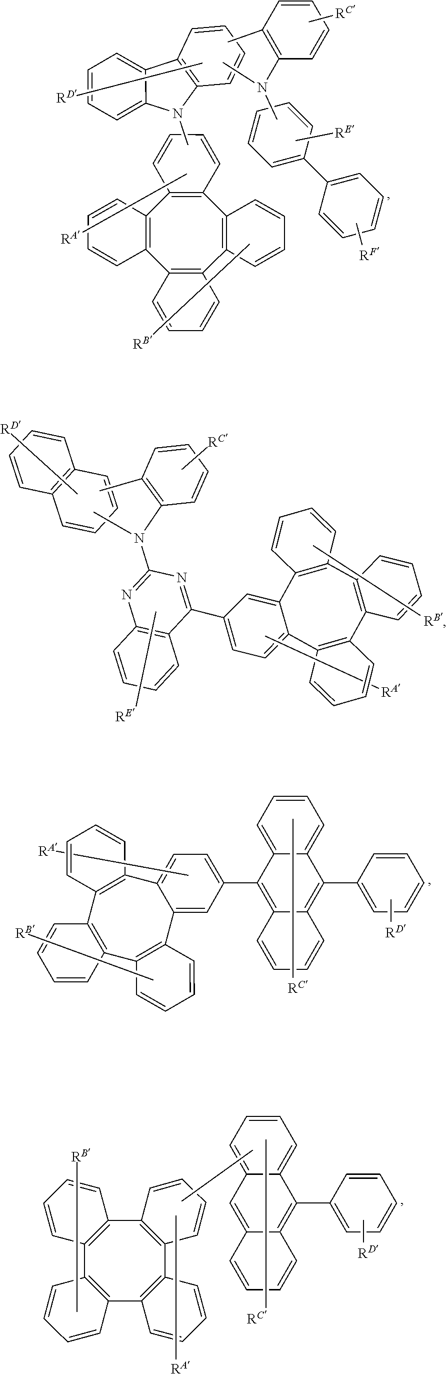 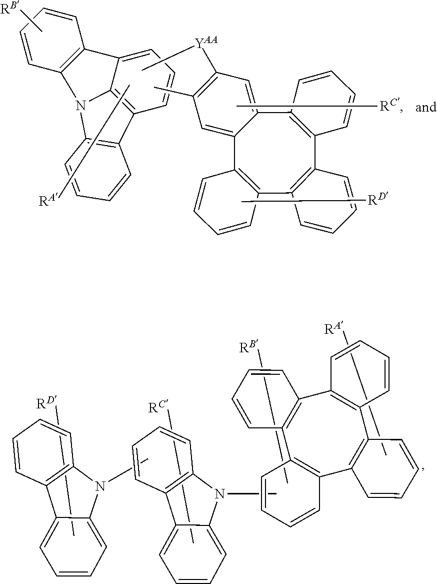
wherein:
each of J₁ to J₆ is independently C or N;
L′ is a direct bond or an organic linker;
each Y^{AA}, Y^{BB}, Y^{CC} and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; any two substituents can be joined or fused to form a ring; and
where possible, each unsubstituted aromatic carbon atom can be replaced with N to form an aza-substituted ring.

19. The OLED of claim 17, wherein the compound is a sensitizer, and the OLED further comprises an acceptor selected from the group consisting of a fluorescent emitter, a delayed fluorescence emitter, and combination thereof.

20. A consumer product comprising an organic light-emitting device comprising:
an anode;
a cathode; and
an organic layer disposed between the anode and the cathode, wherein the organic layer comprises a compound according to claim 1.
